(19) United States
(12) Patent Application Publication
(10) Pub. No.: US 2021/0403496 A1
(43) Pub. Date: Dec. 30, 2021

(54) PHOSPHORESCENT ORGANIC METAL COMPLEX AND USE THEREOF

(71) Applicant: BEIJING SUMMER SPROUT TECHNOLOGY CO., LTD., Beijing (CN)

(72) Inventors: Wei CAI, Beijing (CN); Ming SANG, Beijing (CN); Chi Yuen Raymond Kwong, Beijing (CN); Chuanjun XIA, Beijing (CN); Zhen WANG, Beijing (CN); Tao WANG, Beijing (CN); Hongbo LI, Beijing (CN)

(21) Appl. No.: 16/937,838

(22) Filed: Jul. 24, 2020

(30) Foreign Application Priority Data
Jun. 20, 2020 (CN) 202010558163.7

(51) Int. Cl. C07F 15/00; H01L 51/00

(52) U.S. Cl. CPC C07F 15/0033; H01L 51/0085; H01L 51/5012; H01L 51/0067; H01L 51/0094

(57) ABSTRACT

Provided are a phosphorescent organometallic complex and a use thereof. The metal complex has a ligand with a structure represented by Formula 1 and may be used as a light-emitting material in an electroluminescent device. These novel metal complexes can not only maintain high device efficiency and low voltage in electroluminescent devices but also allow these devices to have narrower half-peak width so as to greatly improve color saturation of light emitted by these devices, thereby providing better device performance. Further provided are an electroluminescent device and a compound formulation.

### CROSS-REFERENCE TO RELATED APPLICATION(S)

This application claims priority to Chinese Patent Application No. CN 202010558163.7 filed Jun. 20, 2020, the disclosure of which is incorporated herein by reference in its entirety.

### TECHNICAL FIELD

The present disclosure relates to compounds for organic electronic devices, for example, organic light-emitting devices. More particularly, the present disclosure relates to a metal complex comprising a ligand with a structure represented by Formula 1, and an organic electroluminescent device and a compound formulation including the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Cyano substituents are not often introduced into phosphorescent metal complexes, such as iridium complexes. US20140252333A1 disclosed a series of cyano-phenyl-substituted iridium complexes, which did not clearly show an effect of cyano groups. In addition, since cyano is a substituent having excellent electron-withdrawing ability, cyano is also used to blue-shift the emission spectrum of phosphorescent metal complex, such as that disclosed in US20040121184A1.

### SUMMARY

The present disclosure aims to provide a series of metal complexes containing a ligand with a structure represented by Formula 1 to solve at least part of the above-mentioned problems. The metal complexes may be used as light-emitting materials in organic electroluminescent devices. These novel compounds can not only maintain high device efficiency and low voltage in organic electroluminescent devices but also allow these devices to have narrower half-peak width and greatly improve color saturation of light emitted by these devices, thereby providing better device performance.

According to an embodiment of the present disclosure, disclosed is a metal complex, which comprises a metal M and a ligand Lₐ coordinated to the metal M, where Lₐ has a structure represented by Formula 1:

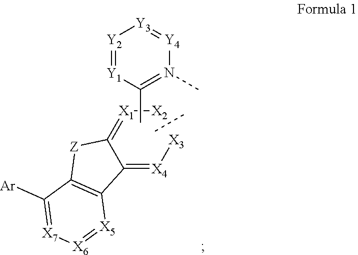

wherein,

the metal M is selected from a metal with a relative atomic mass greater than 40;

Z is selected from the group consisting of O, S, Se, NR, CRR, and SiRR, wherein when two R are present, the two R are the same or different;

X₁ to X₇ are, at each occurrence identically or differently, selected from C, CRₓ, or N;

Y₁ to Y₄ are, at each occurrence identically or differently, selected from CR_{y} or N;

at least one of X₁ to X₇ is CRₓ, and the Rₓ is cyano;

at least one of Y₁ to Y₄ is CR_{y}, and the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof; and adjacent substituents R, Rₓ, R_{y}, and Ar can be optionally joined to form a ring.

According to another embodiment of the present disclosure, further disclosed is an electroluminescent device, including an anode, a cathode, and an organic layer disposed between the anode and the cathode, wherein the organic layer comprises a metal complex comprising a metal M and a ligand Lₐ coordinated to the metal M, and wherein Lₐ has a structure represented by Formula 1:

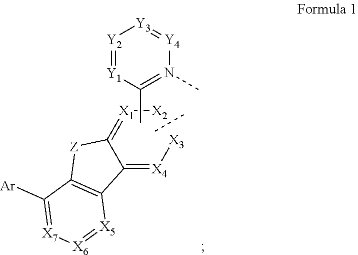

wherein

the metal M is selected from a metal with a relative atomic mass greater than 40;

Z is selected from the group consisting of O, S, Se, NR, CRR, and SiRR, wherein when two R are present, the two R are the same or different;

X₁ to X₇ are, at each occurrence identically or differently, selected from C, CRₓ, or N;

Y₁ to Y₄ are, at each occurrence identically or differently, selected from CR_{y} or N;

at least one of X₁ to X₇ is CRₓ, and the Rₓ is cyano;

at least one of Y₁ to Y₄ is CR_{y}, and the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof; and

adjacent substituents R, Rₓ, R_{y}, and Ar can be optionally joined to form a ring.

According to another embodiment of the present disclosure, further disclosed is a compound formulation which includes the metal complex described above.

The novel metal complex comprising a ligand with a structure represented by Formula 1, as disclosed by the present disclosure, may be used as a light-emitting material in an electroluminescent device. These novel compounds can not only maintain high device efficiency and low voltage in organic electroluminescent devices but also allow these devices to have narrower half-peak width and greatly improve color saturation of light emitted by these devices, thereby providing better device performance. The present disclosure discloses a series of novel metal complexes containing a ligand with a structure represented by Formula 1. Through the design of the ligand with the structure represented by Formula 1, the metal complexes can unexpectedly exhibit many characteristics, such as high efficiency, low voltage, and emission finely tunable in a small range. The most unexpected characteristic is a very narrow peak width of the emitted light. These advantages are of great help to improve the levels and color saturation of devices emitting green/white light.

### BRIEF DESCRIPTION OF DRAWINGS

FIG. 1 is a schematic diagram of an organic light-emitting apparatus that may include a metal complex and a compound formulation disclosed herein.

FIG. 2 is a schematic diagram of another organic light-emitting apparatus that may include a metal complex and a compound formulation disclosed herein.

### DETAILED DESCRIPTION

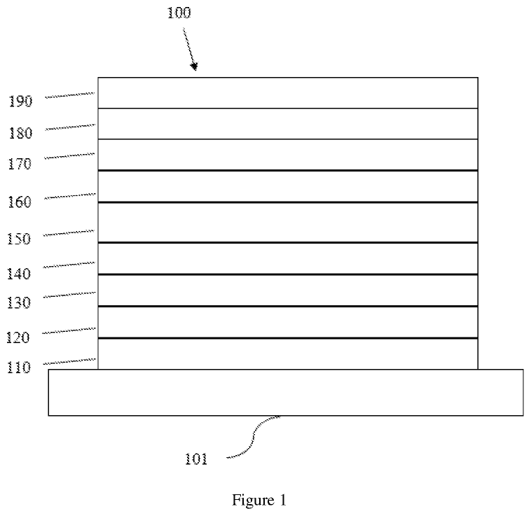

OLEDs can be fabricated on various types of substrates such as glass, plastic, and metal foil. FIG. 1 schematically shows an organic light emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may comprise a single layer or multiple layers.

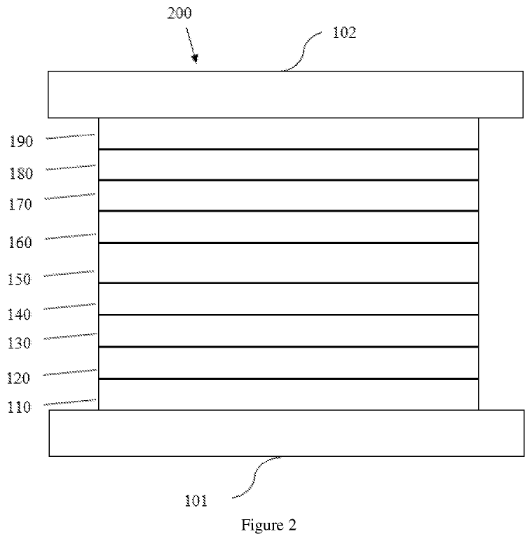

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AES-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcyclohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcyclohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylsilyl, dimethylethylsilyl, dimethylisopropylsilyl, t-butyldimethylsilyl, triethylsilyl, triisopropylsilyl, trimethylsilylmethyl, trimethylsilylethyl, and trimethylsilylisopropyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methyl vinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups includes saturated heterocyclic groups having 3 to 20 ring atoms and unsaturated non-aromatic heterocyclic groups having 3 to 20 ring atoms, wherein at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, wherein at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indenoazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, O-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, l-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic, as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

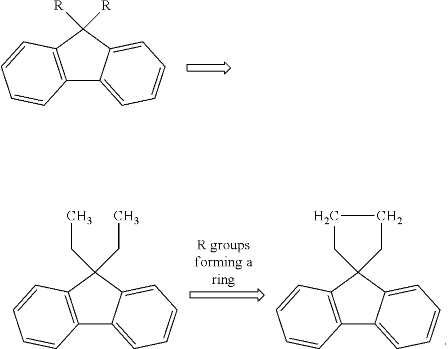

The expression that adjacent substituents can be optionally joined to form a ring is also intended to mean that two substituents bonded to carbon atoms which are directly bonded to each other are joined to each other via a chemical bond to form a ring, which can be exemplified by the following formula:

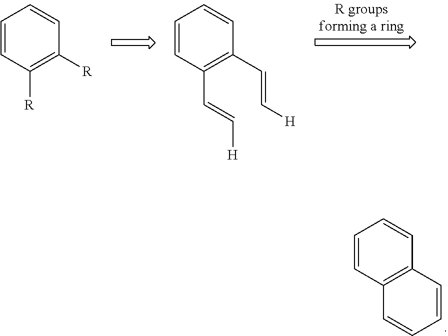

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

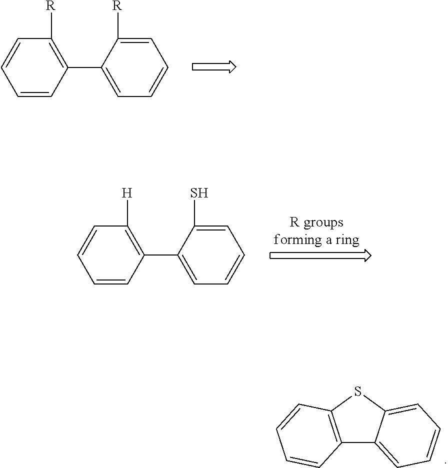

According to an embodiment of the present disclosure, disclosed is a metal complex, which includes a metal M and a ligand Lₐ coordinated to the metal M, where Lₐ has a structure represented by Formula 1:

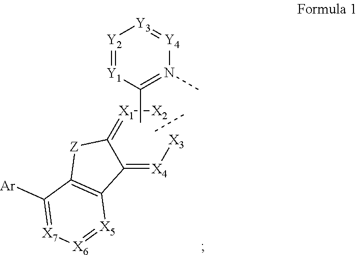

where

the metal M is selected from a metal with a relative atomic mass greater than 40;

Z is selected from the group consisting of O, S, Se, NR, CRR, and SiRR, where when two R are present, the two R are the same or different;

X₁ to X₇ are, at each occurrence identically or differently, selected from C, CRₓ, or N;

Y₁ to Y₄ are, at each occurrence identically or differently, selected from CR_{y} or N;

at least one of X₁ to X₇ is CRₓ, and the Rₓ is cyano;

at least one of Y₁ to Y₄ is CR_{y}, and the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R, Rₓ (referring to remaining Rₓ present in X₁ to X₇ other than the Rₓ selected from cyano), and R_{y} (referring to remaining R_{y} present in Y₁ to Y₄ other than the R_{y} selected from the group of substituents recorded in the above paragraph) are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof; and

adjacent substituents R, Rₓ, R_{y}, and Ar can be optionally joined to form a ring.

In the present disclosure, the expression that adjacent substituents R, Rₓ, R_{y}, and Ar can be optionally joined to form a ring is intended to mean that any one or more of the group of adjacent substituents, such as adjacent substituents R, adjacent substituents Rₓ, adjacent substituents R_{y}, substituents R and Ar, substituents Rₓ and Ar, and substituents R and R_{y}, can be joined to form a ring. Obviously, any of these groups of substituents may not be joined to form a ring.

According to an embodiment of the present disclosure, the metal complex has a general formula of M(Lₐ)ₘ(L_{b})ₙ(L_{c})_{q}; wherein

M is, at each occurrence identically or differently, selected from the group consisting of Cu, Ag, Au, Ru, Rh, Pd, Os, Ir, and Pt; preferably, M is, at each occurrence identically or differently, selected from Pt or Ir;

Lₐ, L_{b}, and L_{c} are the first ligand, the second ligand, and the third ligand coordinated to the metal M, respectively; and Lₐ, L_{b}, and L_{c} can be optionally linked to form a multidentate ligand; for example, any two of Lₐ, L_{b}, and L_{c} may be linked to form a tetradentate ligand; in another example, Lₐ, L_{b}, and L_{c} may be linked with each other to form a hexadentate ligand; in another example, none of Lₐ, L_{b}, and L_{c} are linked, so that no multidentate ligand is formed;

m is 1, 2, or 3, n is 0, 1, or 2, q is 0, 1, or 2, and m+n+q equals the oxidation state of the metal M; where when m is greater than or equal to 2, the multiple Lₐ are the same or different; when n is equal to 2, the two L_{b} are the same or different; when q is equal to 2, the two L_{c} are the same or different;

L_{b} and L_{c} are, at each occurrence identically or differently, selected from the structure represented by any one of the group consisting of the following structures:

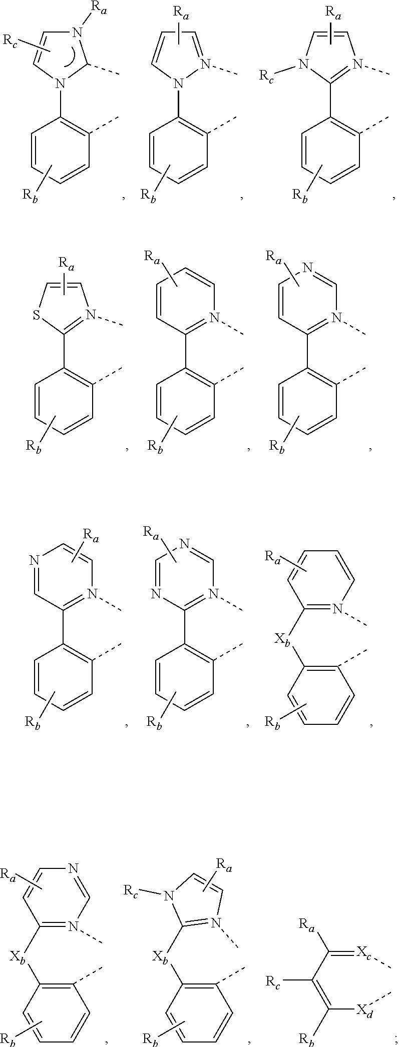

where

Rₐ, R_{b}, and R_{c} are, at each occurrence identically or differently, represent mono-substitution, multi-substitution, or non-substitution;

X_{b} is, at each occurrence identically or differently, selected from the group consisting of: O, S, Se, NR_{N1}, and CR_{C1}R_{C2};

X_{c} and X_{d} are, at each occurrence identically or differently, selected from the group consisting of: O, S, Se, and NR_{N2};

Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and

in structures of L_{b} and L_{c}, adjacent substituents Rₐ, R_{b}, R_{c}, R_{N1}, R_{N2}, R_{C1}, and R_{C2} can be optionally joined to form a ring.

In the present disclosure, the expression that in the structures of L_{b} and L_{c}, adjacent substituents Rₐ, R_{b}, R_{c}, R_{N1}, R_{N2}, R_{C1}, and R_{C2} can be optionally joined to form a ring is intended to mean that any one or more of the group of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and Rₐ, substituents R_{b} and R_{C2}, substituents Rₐ and R_{N2}, substituents R_{b} and R_{N2}, and substituents Rₐ and Rₐ, may be joined to form a ring. Obviously, any of these groups of substituents may not be joined to form a ring.

According to an embodiment of the present disclosure, Lₐ has a structure represented by any one of Formula 1a to Formula 1d:

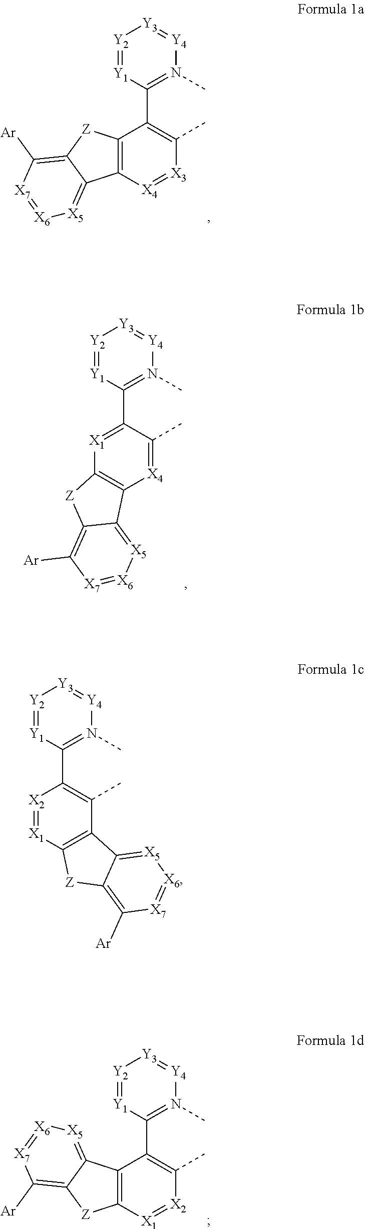

wherein,

Z is selected from the group consisting of O, S, Se, NR, CRR, and SiRR, where when two R are present, the two R are the same or different;

in Formula 1a, X₃ to X₇ are, at each occurrence identically or differently, selected from CRₓ or N;

in Formula 1b, X₁ and X₄ to X₇ are, at each occurrence identically or differently, selected from CRₓ or N;

in Formula 1c, X₁, X₂, and X₅ to X₇ are, at each occurrence identically or differently, selected from CRₓ or N;

in Formula 1d, X₁, X₂, and X₅ to X₇ are, at each occurrence identically or differently, selected from CRₓ or N;

Y₁ to Y₄ are, at each occurrence identically or differently, selected from CR_{y} or N;

R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof;

in Formula 1a, at least one of X₃ to X₇ is selected from CRₓ, and the Rₓ is cyano;

in Formula 1b, at least one of X₁ and X₄ to X₇ is selected from CRₓ, and the Rₓ is cyano;

in Formula 1c, at least one of X₁, X₂, and X₅ to X₇ is selected from CRₓ, and the Rₓ is cyano;

in Formula 1d, at least one of X₁, X₂, and X₅ to X₇ is selected from CRₓ, and the Rₓ is cyano;

at least one of Y₁ to Y₄ is CR_{y}, and the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and adjacent substituents R, Rₓ, R_{y}, and Ar can be optionally joined to form a ring.

According to an embodiment of the present disclosure, the metal complex has a general formula of Ir(Lₐ)ₘ(L_{b})₃₋ₘ and a structure represented by Formula 2:

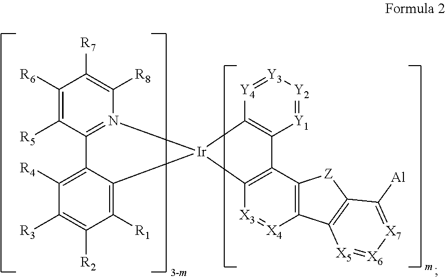

wherein,

m is selected from 1 or 2; where when m is equal to 2, the two Lₐ are the same or different; when m is equal to 1, the two L_{b} are the same or different;

Z is selected from the group consisting of O, S, Se, NR, CRR, and SiRR, where when two R are present, the two R are the same or different;

X₃ to X₇ are, at each occurrence identically or differently, selected from CRₓ or N;

Y₁ to Y₄ are, at each occurrence identically or differently, selected from CR_{y} or N;

at least one of X₃ to X₇ is CRₓ, and the Rₓ is cyano;

at least one of Y₁ to Y₄ is CR_{y}, and the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R, Rₓ, R_{y}, and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof; and

adjacent substituents R, Rₓ, R_{y}, Ar, and R₁ to R₈ can be optionally joined to form a ring.

In the present disclosure, the expression that adjacent substituents R, Rₓ, R_{y}, Ar, and R₁ to R₈ can be optionally joined to form a ring is intended to mean that any one or more of the group of adjacent substituents, such as adjacent substituents R, adjacent substituents Rₓ, adjacent substituents R_{y}, substituents Rₓ and R_{y}, substituents Rₓ and R, substituents Rₓ and Ar, substituents R_{y} and R, substituents R_{y} and Ar, substituents R and Ar, substituents R₁ and R₂, substituents R₂ and R₃, substituents R₃ and R₄, substituents R₄ and R₅, substituents R₅ and R₆, substituents R₆ and R₇, and substituents R₇ and R₈, can be joined to form a ring. Obviously, any of these groups of substituents may not be joined to form a ring.

According to an embodiment of the present disclosure, in Formula 1, Formula 1a to Formula 1d, and Formula 2, Z is selected from the group consisting of: O and S.

According to an embodiment of the present disclosure, in Formula 1, Formula 1a to Formula 1d, and Formula 2, Z is O.

According to an embodiment of the present disclosure, in Formula 1, X₁ to X₇ are, at each occurrence identically or differently, selected from C or CRₓ.

According to an embodiment of the present disclosure, in Formula 1, X₁ to X₇ are, at each occurrence identically or differently, selected from C, CRₓ, or N, and at least one of X₁ to X₇ is N.

According to an embodiment of the present disclosure, in Formula 1a to Formula 1d and Formula 2, X₁ to X₇ are, at each occurrence identically or differently, selected from CRₓ.

According to an embodiment of the present disclosure, in Formula 1a to Formula 1d and Formula 2, X₁ to X₇ are, at each occurrence identically or differently, selected from CRₓ or N, and at least one of X₁ to X₇ is N.

According to an embodiment of the present disclosure, in Formula 1, Formula 1a to Formula 1d, and Formula 2, at least two of X₁ to X₇ are selected from CRₓ, and wherein at least one Rₓ is cyano, and wherein at least one Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, in Formula 1, Formula 1a to Formula 1d, and Formula 2, at least two of X₁ to X₇ are selected from CRₓ, and wherein at least one of the Rₓ is cyano, and wherein at least one of the Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, in Formula 1, Formula 1a to Formula 1d, and Formula 2, at least one of X₅ to X₇ is selected from CRₓ, and the Rₓ is cyano.

According to an embodiment of the present disclosure, in Formula 1, Formula 1a to Formula 1d, and Formula 2, at least one of X₆ or X₇ is selected from CRₓ, and the Rₓ is cyano.

According to an embodiment of the present disclosure, in Formula 1, Formula 1a to Formula 1d, and Formula 2, X₇ is selected from CRₓ, and the Rₓ is cyano.

According to an embodiment of the present disclosure, in Formula 1, Formula 1a to Formula 1d, and Formula 2, X₇ is selected from CRₓ, and the Rₓ is not fluorine.

According to an embodiment of the present disclosure, in Formula 1, Formula 1a to Formula 1d, and Formula 2, Y₁ to Y₄ are, at each occurrence identically or differently, selected from CR_{y}.

According to an embodiment of the present disclosure, in Formula 1, Formula 1a to Formula 1d, and Formula 2, Y₁ to Y₄ are, at each occurrence identically or differently, selected from CR_{y} or N, and at least one of Y₁ to Y₄ is N; preferably, Y₃ is N.

According to an embodiment of the present disclosure, in Formula 1, Formula 1a to Formula 1d, and Formula 2, at least one of Y₁ to Y₄ is selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, and combinations thereof.

According to an embodiment of the present disclosure, in Formula 1, Formula 1a to Formula 1d, and Formula 2, at least one of Y₁ to Y₄ is selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, and combinations thereof.

According to an embodiment of the present disclosure, in Formula 1, Formula 1a to Formula 1d, and Formula 2, Y₂ and/or Y₃ are(is) selected from CR_{y}, and the R_{y} is, at each occurrence identically or differently, selected from substituted alkyl having 1 to 10 carbon atoms, substituted cycloalkyl having 3 to 10 ring carbon atoms, substituted aryl having 6 to 20 carbon atoms, or combinations thereof; and at least one substitution in the above substituted groups is a deuterium atom.

According to an embodiment of the present disclosure, in Formula 1, Formula 1a to Formula 1d, and Formula 2, Y₂ and/or Y₃ are(is) selected from CR_{y}, and the R_{y} is, at each occurrence identically or differently, selected from the group consisting of: partially or fully deuterated alkyl having 1 to 20 carbon atoms, partially or fully deuterated cycloalkyl having 3 to 20 ring carbon atoms, and combinations thereof.

According to an embodiment of the present disclosure, in Formula 1, Formula 1a to Formula 1d, and Formula 2, Y₂ and/or Y₃ are(is) selected from CR_{y}, and the R_{y} is, at each occurrence identically or differently, selected from the group consisting of: partially or fully deuterated alkyl having 1 to 20 carbon atoms, partially or fully deuterated cycloalkyl having 3 to 20 ring carbon atoms, and combinations thereof; and when a carbon atom at a benzylic position in the R_{y} is a primary carbon atom, a secondary carbon atom, or a tertiary carbon atom, at least one deuterium atom in the R_{y} is located at the benzylic position.

In the present disclosure, the carbon atom at the benzylic position in the substituent R_{y} refers to a carbon atom directly connected to an aromatic or heteroaromatic ring in the substituent R_{y}. When the carbon atom at the benzylic position is merely connected directly to one carbon atom, the carbon atom is a primary carbon atom; when the carbon atom at the benzylic position is merely connected directly to two carbon atoms, the carbon atom is a secondary carbon atom; when the carbon atom at the benzylic position is merely connected directly to three carbon atoms, the carbon atom is a tertiary carbon atom; and when the carbon atom at the benzylic position is connected directly to four carbon atoms, the carbon atom is a quaternary carbon atom.

According to an embodiment of the present disclosure, in Formula 1, Formula 1a to Formula 1d, and Formula 2, Y₂ and/or Y₃ are(is) selected from CR_{y}, and the R_{y} is, at each occurrence identically or differently, selected from the group consisting of: partially or fully deuterated alkyl having 1 to 20 carbon atoms, partially or fully deuterated cycloalkyl having 3 to 20 ring carbon atoms, and combinations thereof; when a carbon atom at a benzylic position in the R_{y} is a primary carbon atom, a secondary carbon atom, or a tertiary carbon atom, hydrogen at the benzylic position in the R_{y} is fully substituted by deuterium.

According to an embodiment of the present disclosure, in Formula 1, Formula 1a to Formula 1d, and Formula 2, Y₂ and/or Y₃ are(is) selected from CR_{y}, and the R_{y} is, at each occurrence identically or differently, selected from the group consisting of: CD₃, CD₂CH₃, CD₂CD₃, CD(CH₃)₂, CD(CD₃)₂, CD₂CH(CH₃)₂, CD₂C(CH₃)₃,

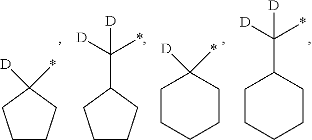

and combinations thereof.

According to an embodiment of the present disclosure, in Formula 1, Formula 1a to Formula 1d, and Formula 2, at least two of Y₁ to Y₄ are, at each occurrence identically or differently, selected from CR_{y}, and wherein at least one of the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group, a hydroxyl group, a sulfanyl group, and combinations thereof; and at least one of the R_{y} is selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group, a hydroxyl group, a sulfanyl group, or combinations thereof.

According to an embodiment of the present disclosure, in Formula 1, Formula 1a to Formula 1d, and Formula 2, at least two of Y₁ to Y₄ are, at each occurrence identically or differently, selected from CR_{y}, and wherein at least one of the R_{y} is selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof; and at least one of the R_{y} is selected from deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, or combinations thereof.

According to an embodiment of the present disclosure, in Formula 1, Formula 1a to Formula 1d, and Formula 2, at least two of Y₁ to Y₄ are, at each occurrence identically or differently, selected from CR_{y}, and wherein at least one of the R_{y} is selected from the group consisting of: substituted or unsubstituted alkyl having 1 to 20 carbon atoms, substituted or unsubstituted cycloalkyl having 3 to 20 ring carbon atoms, and combinations thereof; and, at least one of the R_{y} is deuterium.

According to an embodiment of the present disclosure, in Formula 1, Formula 1a to Formula 1d, and Formula 2, Y₂ and/or Y₃ are(is) selected from CR_{y}, and the R_{y} is, at each occurrence identically or differently, selected from partially or fully deuterated alkyl having 1 to 20 carbon atoms or partially or fully deuterated cycloalkyl having 3 to 20 ring carbon atoms; and Y₁ and/or Y₄ are(is) selected from CD.

According to an embodiment of the present disclosure, in Formula 1, Formula 1a to Formula 1d, and Formula 2, Ar is selected from substituted or unsubstituted phenyl, substituted or unsubstituted naphthyl, substituted or unsubstituted pyridyl, substituted or unsubstituted furyl, substituted or unsubstituted thienyl, substituted or unsubstituted benzofuryl, substituted or unsubstituted benzothienyl, substituted or unsubstituted dibenzofuryl, substituted or unsubstituted dibenzothienyl, or combinations thereof; optionally, hydrogen in Ar can be partially or fully substituted by deuterium.

According to an embodiment of the present disclosure, in Formula 1, Formula 1a to Formula 1d, and Formula 2, Ar is selected from substituted or unsubstituted phenyl; optionally, hydrogen in Ar can be partially or fully substituted by deuterium.

According to an embodiment of the present disclosure, the metal complex has the structure represented by Formula 2, and when both Y₁ and Y₄ are CH, Y₂ and Y₃ are each independently selected from CR_{y}, and the R_{y} is each independently selected from the group consisting of: hydrogen, deuterium, halogen, substituted or unsubstituted alkyl having 1 to 20 carbon atoms, substituted or unsubstituted heteroalkyl having 1 to 20 carbon atoms, substituted or unsubstituted alkoxy having 1 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and the sum of the number of carbon atoms of the R_{y} in Y₂ and Y₃ is less than or equal to 1; or

when at least one of Y₁ to Y₄ is not CH, Y₂ and Y₃ are each independently selected from CR_{y}, and the R_{y} is each independently selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, in Formula 2, X₃ and X₄ are each independently selected from CRₓ, and the Rₓ is selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, in Formula 2, X₃ and X₄ are each independently selected from CRₓ, and at least one of the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, in Formula 2, at least one or two of R₁ to R₈ is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least one of R₁ to R₈ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, in Formula 2, at least one, two, three, or all of R₂, R₃, R₆, and R₇ is(are) selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, one, two, three, or all of R₂, R₃, R₆, and R₇ is(are) selected from the group consisting of: deuterium, substituted or unsubstituted alkyl having 1 to 20 carbon atoms, substituted or unsubstituted cycloalkyl having 3 to 20 ring carbon atoms, and combinations thereof.

According to an embodiment of the present disclosure, one, two, three, or all of R₂, R₃, R₆, and R₇ is(are) selected from the group consisting of: deuterium, methyl, ethyl, propyl, isopropyl, n-butyl, isobutyl, t-butyl, cyclopentyl, cyclohexyl, and combinations thereof; optionally, the above groups may be partially or fully deuterated.

According to an embodiment of the present disclosure, in Formula 2, R₂ is selected from hydrogen, deuterium, or fluorine; at least one, two, or three of R₃, R₆, and R₇ is(are) selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, in Formula 1a to Formula 1d, at least one of Y₁ to Y₄ is selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, a hydroxyl group, a sulfanyl group, and combinations thereof.

According to an embodiment of the present disclosure, in Formula 1a to Formula 1d, at least one of Y₁ to Y₂ is selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, a hydroxyl group, a sulfanyl group, and combinations thereof.

According to an embodiment of the present disclosure, in Formula 1a to Formula 1d, X₁ to X₇ are, at each occurrence identically or differently, selected from CRₓ or N, and the Rₓ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and when the Rₓ is selected from substituted alkyl having 1 to 20 carbon atoms or substituted cycloalkyl having 3 to 20 ring carbon atoms, the substituent in the alkyl and cycloalkyl is selected from the group consisting of: unsubstituted alkyl having 1 to 20 carbon atoms, unsubstituted cycloalkyl having 3 to 20 ring carbon atoms, unsubstituted heteroalkyl having 1 to 20 carbon atoms, unsubstituted heterocyclic groups having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and wherein at least one Rₓ is cyano; and

adjacent substituents Rₓ are not joined to form a ring.

According to an embodiment of the present disclosure, the ligand Lₐ is, at each occurrence identically or differently, any one selected from the group consisting of Lₐ₁ to Lₐ₈₅₄ whose specific structures are referred to claim 20.

According to an embodiment of the present disclosure, the ligand L_{b} is, at each occurrence identically or differently, any one selected from the group consisting of L_{b1} to L_{b78} whose specific structures are referred to claim 21.

According to an embodiment of the present disclosure, the ligand L_{c} is, at each occurrence identically or differently, any one selected from the group consisting of L_{c1} to L_{c360} whose specific structures are referred to claim 21.

According to an embodiment of the present disclosure, the metal complex has a structure represented by any one of Ir(Lₐ)₂(L_{b}), Ir(Lₐ)(L_{b})₂, Ir(Lₐ)(L_{b})(L_{c}), or Ir(Lₐ)₂(L_{c}); where when the metal complex has the structure of Ir(Lₐ)₂(L_{b}), Lₐ is, at each occurrence identically or differently, selected from any one or any two of the group consisting of Lₐ₁ to Lₐ₈₅₄, and L_{b} is selected from any one of the group consisting of L_{b1} to L_{b78}; when the metal complex has the structure of Ir(Lₐ)(L_{b})₂, Lₐ is selected from any one of the group consisting of Lₐ₁ to Lₐ₈₅₄, and L_{b} is, at each occurrence identically or differently, selected from any one or any two of the group consisting of L_{b1} to L_{b78}; when the metal complex has the structure of Ir(Lₐ)(L_{b})(L_{c}), Lₐ is selected from any one of the group consisting of Lₐ₁ to Lₐ₈₅₄, L_{b} is selected from any one of the group consisting of L_{b1} to L_{b78}, and L_{c} is selected from any one of the group consisting of L_{c1} to L_{c360}; when the metal complex has the structure of Ir(Lₐ)₂(L_{c}), Lₐ is, at each occurrence identically or differently, selected from any one or any two of the group consisting of Lₐ₁ to Lₐ₈₅₄, and L_{c} is selected from any one of the group consisting of L_{c1} to L_{c360}.

According to an embodiment of the present disclosure, the metal complex is selected from the group consisting of metal complex 1 to metal complex 706, whose specific structures are referred to claim 22.

According to an embodiment of the present disclosure, further disclosed is an electroluminescent device, comprising:

an anode,

a cathode, and

an organic layer disposed between the anode and the cathode, wherein the organic layer comprises a metal complex which comprises a metal M and a ligand Lₐ coordinated to the metal M, wherein Lₐ has a structure represented by Formula 1:

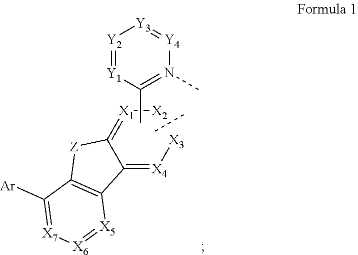

wherein,

the metal M is selected from a metal with a relative atomic mass greater than 40;

Z is selected from the group consisting of O, S, Se, NR, CRR, and SiRR, where when two R are present, the two R are the same or different;

X₁ to X₇ are, at each occurrence identically or differently, selected from C, CRₓ, or N;

Y₁ to Y₄ are, at each occurrence identically or differently, selected from CR_{y} or N;

at least one of X₁ to X₇ is CRₓ, and the Rₓ is cyano;

at least one of Y₁ to Y₄ is CR_{y}, and the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof; and

adjacent substituents R, Rₓ, R_{y}, and Ar can be optionally joined to form a ring.

According to an embodiment of the present disclosure, in the device, the organic layer is a light-emitting layer.

According to an embodiment of the present disclosure, in the device, the organic layer is a light-emitting layer, and the metal complex is a light-emitting material.

According to an embodiment of the present disclosure, the device emits green light.

According to an embodiment of the present disclosure, the device emits white light.

According to an embodiment of the present disclosure, in the device, the light-emitting layer further includes at least one host compound.

According to an embodiment of the present disclosure, in the device, the light-emitting layer further includes at least two host compounds.

According to an embodiment of the present disclosure, in the device, at least one of the host compounds comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to another embodiment of the present disclosure, further disclosed is a compound formulation which includes a metal complex whose specific structure is as shown in any one of the embodiments described above.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing a compound in the present disclosure is not limited herein. Typically, the following compounds are taken as examples without limitations, and synthesis routes and preparation methods thereof are described below.

### Synthesis Example 1: Synthesis of Metal Complex 55

Step 1:

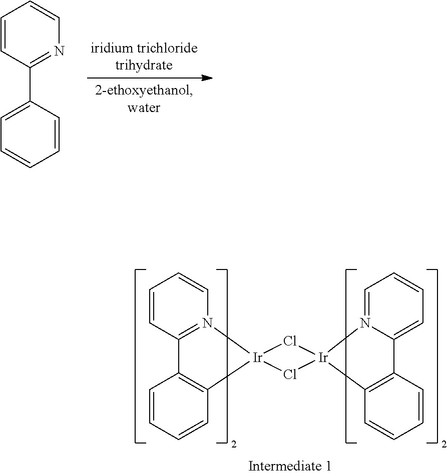

2-phenylpyridine (6.5 g, 4T9 mmol), iridium trichloride trihydrate (3.6 g, 10.2 mmol), 300 mL of 2-ethoxy ethanol, and 100 mL of water were sequentially added into a dry 500 mL round-bottom flask, purged with nitrogen three times, placed in a 130° C. heating mantle, and heated and stirred for 24 h under nitrogen protection. The reaction product was cooled, filtered, washed three times with methanol and n-hexane respectively, and pumped to dryness to obtain 5.4 g of Intermediate 1 (yield: 99%).

Step 2:

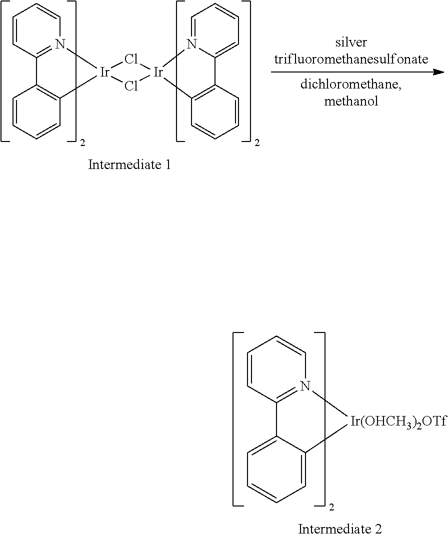

Intermediate 1 (5.4 g, 5.0 mmol), 250 mL of anhydrous dichloromethane, 10 mL of methanol, and silver trifluoromethanesulfonate (2.6 g, 10.1 mmol) were sequentially added into a dry 500 mL round-bottom flask, purged with nitrogen three times, and stirred overnight at room temperature under nitrogen protection. The reaction product was filtered through Celite and washed twice with dichloromethane. The organic phase below was collected and concentrated under reduced pressure to obtain 7.1 g of Intermediate 2 (yield: 99%).

Step 3:

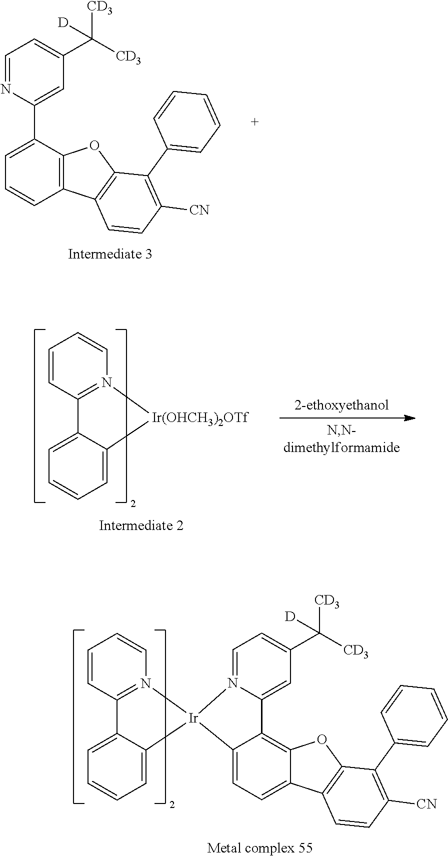

Intermediate 3 (1.8 g, 4.5 mmol), Intermediate 2 (2.2 g, 3.0 mmol), 50 mL of 2-ethoxyethanol, and 50 mL of N,N-dimethylformamide were sequentially added into a dry 500 mL round-bottom flask, purged with nitrogen three times, and heated at 100° C. for 96 h under 5 nitrogen protection. The reaction was cooled, filtered through Celite, and rinsed twice separately with methanol and n-hexane. Yellow solids on the Celite were dissolved in dichloromethane. The organic phase was collected, concentrated under reduced pressure, and purified by column chromatography to obtain 1.5 g of metal complex 55 (yield: 56%). The product structure was confirmed as the target product with a molecular weight of 895.

### Synthesis Example 2: Synthesis of Metal Complex 97

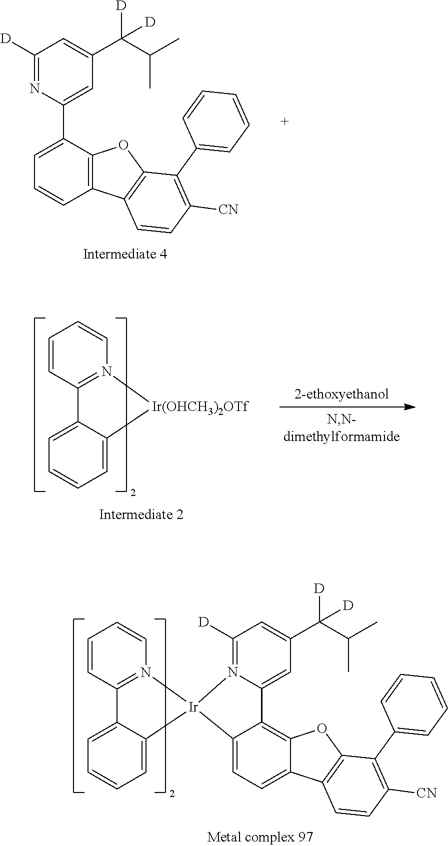

Intermediate 4 (1.8 g, 4.4 mmol), Intermediate 2 (2.1 g, 3.0 mmol), 50 mL of 2-ethoxyethanol, and 50 mL of N,N-dimethylformamide were sequentially added into a dry 500 mL round-bottom flask, purged with nitrogen three times, and heated at 100° C. for 96 h under nitrogen protection. The reaction was cooled, filtered through Celite, and rinsed twice separately with methanol and n-hexane. Yellow solids on the Celite were dissolved with dichloromethane. The organic phase was collected, concentrated under reduced pressure, and purified by column chromatography to obtain 1.5 g of metal complex 97 (yield: 55%). The product structure was confirmed as the target product with a molecular weight of 905.

### Synthesis Example 3: Synthesis of Metal Complex 261

Step 1:

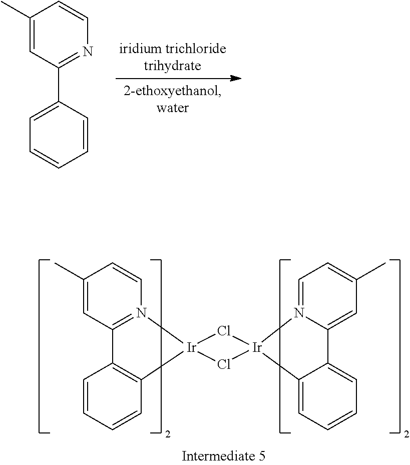

4-methyl-2-phenylpyridine (10.0 g, 59.2 mmol), iridium trichloride trihydrate (5.0 g, 14.2 mmol), 300 mL of 2-ethoxyethanol, and 100 mL of water were sequentially added into a dry 500 mL round-bottom flask, purged with nitrogen three times, placed in a 130° C. heating mantle, and heated and stirred for 24 h under nitrogen protection. The reaction product was cooled, filtered, washed three times with methanol and n-hexane respectively, and pumped to dryness to obtain 7.9 g of Intermediate 5 (yield: 99%).

Step 2:

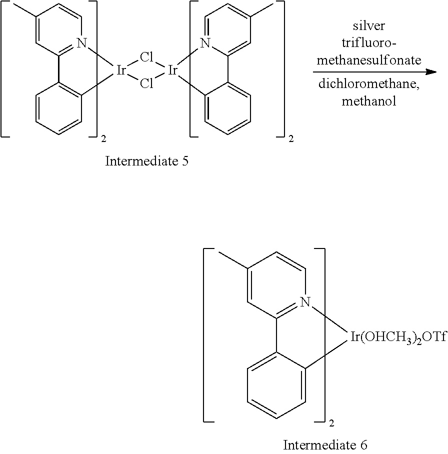

Intermediate 5 (7.9 g, 7.0 mmol), 250 mL of anhydrous dichloromethane, 10 mL of methanol, and silver trifluoromethanesulfonate (3.8 g, 14.8 mmol) were sequentially added into a dry 500 mL round-bottom flask, purged with nitrogen three times, and stirred overnight at room temperature under nitrogen protection. The reaction product was filtered through Celite and washed twice with dichloromethane. The organic phase below was collected and concentrated under reduced pressure to obtain 10.0 g of Intermediate 6 (yield: 96%).

Step 3:

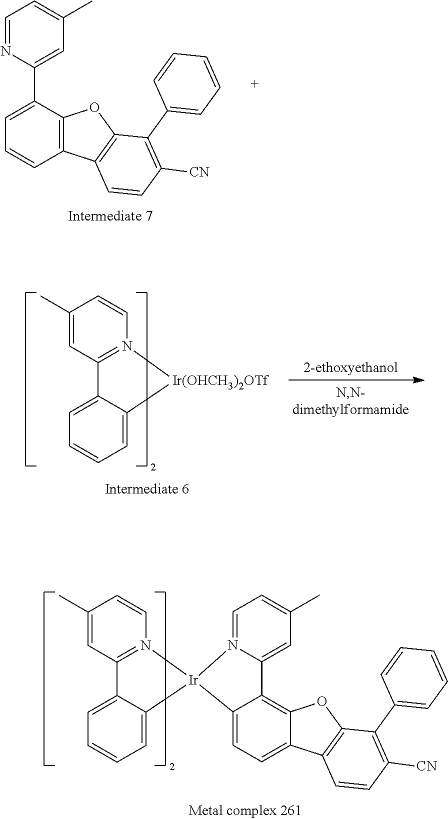

Intermediate 7 (2.2 g, 6.1 mmol), Intermediate 6 (3.0 g, 4.0 mmol), 50 mL of 2-ethoxyethanol, and 50 mL of N,N-dimethylformamide were sequentially added into a dry 500 mL round-bottom flask, purged with nitrogen three times, and heated at 100° C. for 96 h under nitrogen protection. The reaction was cooled, filtered through Celite, and washed twice with methanol and n-hexane respectively. Yellow solids on the Celite were dissolved with dichloromethane. The organic phase was collected, concentrated under reduced pressure, and purified by column chromatography to obtain the metal complex 261 as a yellow solid (2.1 g, 59% yield). The product structure was confirmed as the target product with a molecular weight of 888.

### Synthesis Example 4: Synthesis of Metal Complex 131

Step 1:

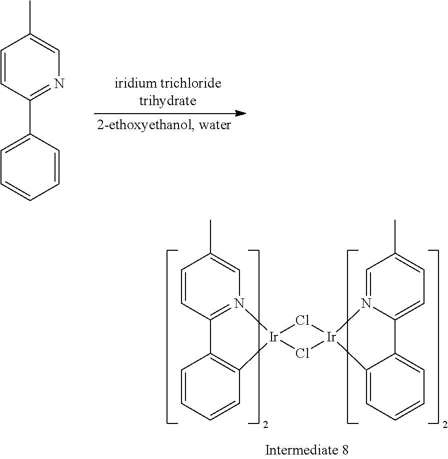

5-methyl-2-phenylpyridine (10.0 g, 59.2 mmol), iridium trichloride trihydrate (5.0 g, 14.2 mmol), 300 mL of 2-ethoxyethanol, and 100 mL of water were sequentially added into a dry 500 mL round-bottom flask, purged with nitrogen three times, placed in a 130° C. heating jacket, and heated and stirred for 24 h under nitrogen protection. The reaction product was cooled, filtered, washed three times with methanol and n-hexane respectively, and pumped to dryness to obtain 7.5 g of Intermediate 8 as a yellow solid (yield: 97%).

Step 2:

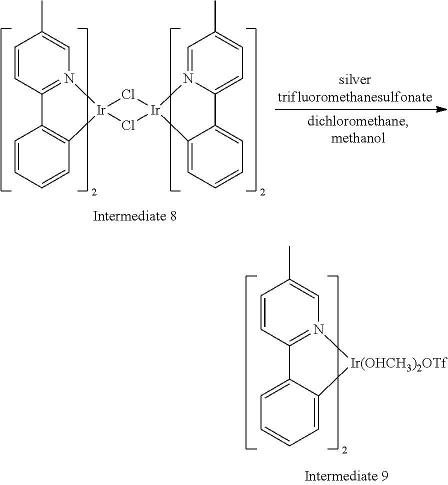

Intermediate 8 (7.5 g, 6.8 mmol), 250 mL of anhydrous dichloromethane, 10 mL of methanol, and silver trifluoromethanesulfonate (3.8 g, 14.8 mmol) were sequentially added into a dry 500 mL round-bottom flask, purged with nitrogen three times, and stirred overnight at room temperature under nitrogen protection. The reaction product was filtered through Celite and washed twice with dichloromethane. The organic phase below was collected and concentrated under reduced pressure to obtain 9.2 g of Intermediate 9 (yield: 93%).

Step 3:

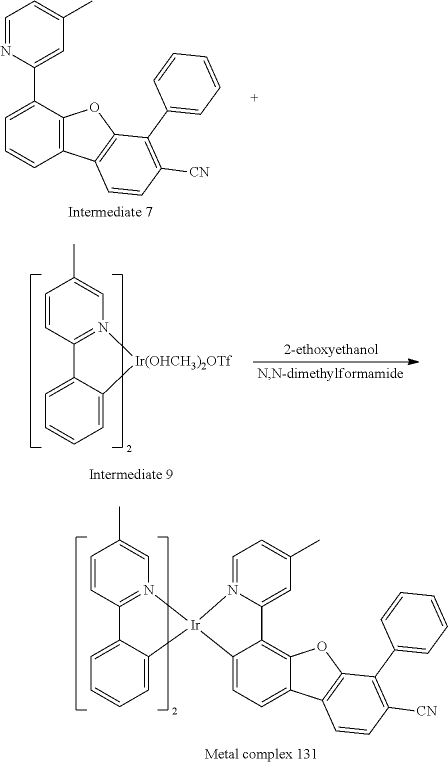

Intermediate 7 (2.2 g, 6.1 mmol), Intermediate 9 (3.0 g, 4.0 mmol), 50 mL of 2-ethoxyethanol, and 50 mL of N,N-dimethylformamide were sequentially added into a dry 500 mL round-bottom flask, purged with nitrogen three times, and heated at 100° C. for 96 h under nitrogen protection. The reaction was cooled, filtered through Celite, and washed twice separately with methanol and n-hexane. Yellow solids on the Celite were dissolved with dichloromethane. The organic phase was collected, concentrated under reduced pressure, and purified by column chromatography to obtain the metal complex 131 as a yellow solid (1.5 g, 42% yield). The product structure was confirmed as the target product with a molecular weight of 888.

Those skilled in the art will appreciate that the above preparation method is merely illustrative example. Those skilled in the art can obtain other compound structures of the present disclosure through the modification of the preparation method.

### Device Example 1

First, a glass substrate having an Indium Tin Oxide (ITO) anode with a thickness of 80 nm was cleaned, and then treated with oxygen plasma and UV ozone. After the treatment, the substrate was dried in a glovebox to remove water. The substrate was mounted on a substrate support and placed in a vacuum chamber. Organic layers specified below were sequentially deposited through vacuum thermal evaporation on the ITO anode at a rate of 0.2 to 2 Angstroms per second at a vacuum degree of about 10⁻⁸ torr. Compound HI was used as a hole injection layer (HIL). Compound HT was used as a hole transporting layer (HTL). Compound EB was used as an electron blocking layer (EBL). The metal complex 55 of the present disclosure was doped in Compound EB and Compound HB, and the resulting mixture was co-deposited for use as an emissive layer (EML). On the EML, Compound HB was deposited for use as a hole blocking layer (HBL). On the HBL, Compound ET and 8-hydroxyquinolinolato-lithium (Liq) were co-deposited for use as an electron transporting layer (ETL). Finally, 8-hydroxyquinolinolato-lithium (Liq) with a thickness of 1 nm was deposited for use as an electron injection layer, and Al with a thickness of 120 nm was deposited for use as a cathode. The device was transferred back to the glovebox and encapsulated with a glass lid and a moisture getter to complete the device.

### Device Example 2

The implementation mode in Device Example 2 was the same as that in Device Example 1, except that the metal complex 55 of the present disclosure in the EML was replaced with the metal complex 97 of the present disclosure.

### Device Example 3

The implementation mode in Device Example 3 was the same as that in Device Example 1, except that the metal complex 55 of the present disclosure in the EML was replaced with the metal complex 261 of the present disclosure.

### Device Example 4

The implementation mode in Device Example 4 was the same as that in Device Example 1, except that the metal complex 55 of the present disclosure in the EML was replaced with the metal complex 131 of the present disclosure.

### Device Comparative Example 1

The implementation mode in Device Comparative Example 1 was the same as that in Device Example 1, except that the metal complex 55 of the present disclosure in the EML was replaced with a comparative compound GD1.

### Device Comparative Example 2

The implementation mode in Device Comparative Example 2 was the same as that in Device Example 1, except that the metal complex 55 of the present disclosure in the EML was replaced with a comparative compound GD2.

### Device Comparative Example 3

The implementation mode in Device Comparative Example 3 was the same as that in Device Example 1, except that the metal complex 55 of the present disclosure in the EML was replaced with a comparative compound GD3.

### Device Comparative Example 4

The implementation mode in Device Comparative Example 4 was the same as that in Device Example 1, except that the metal complex 55 of the present disclosure in the EML was replaced with a comparative compound GD4.

### Device Comparative Example 5

The implementation mode in Device Comparative Example 5 was the same as that in Device Example 1, except that the metal complex 55 of the present disclosure in the EML was replaced with a comparative compound GD5.

### Device Comparative Example 6

The implementation mode in Device Comparative Example 6 was the same as that in Device Example 1, except that the metal complex 55 of the present disclosure in the EML was replaced with a comparative compound GD7.

Detailed structures and thicknesses of layers of the device are shown in the following table. A layer using more than one material is obtained by doping different compounds in their weight ratio as described.

TABLE 1
Device structures in device examples

| Device ID | HIL | HTL | EBL | EML | HBL | ETL |
|---|---|---|---|---|---|---|
| Example 1 | Compound HI | Compound HT | Compound EB | Compound EB:compound | Compound HB | Compound |
| | (100 Å) | (350 Å) | (50 Å) | HB:metal | (100 Å) | ET:Liq |
| | | | | complex 55 | | (40:60) |
| | | | | (46:46:8) | | (350 Å) |
| | | | | (400 Å) | | |
| Example 2 | Compound HI | Compound HT | Compound EB | Compound EB:compound | Compound HB | Compound |
| | (100 Å) | (350 Å) | (50 Å) | HB:metal | (100 Å) | ET:Liq |
| | | | | complex 97 | | (40:60) |
| | | | | (46:46:8) | | (350 Å) |
| | | | | (400 Å) | | |
| Example 3 | Compound HI | Compound HT | Compound EB | Compound EB:compound | Compound HB | Compound |
| | (100 Å) | (350 Å) | (50 Å) | HB:metal | (100 Å) | ET:Liq |
| | | | | complex 261 | | (40:60) |
| | | | | (46:46:8) | | (350 Å) |
| | | | | (400 Å) | | |
| Example 4 | Compound HI | Compound HT | Compound EB | Compound EB:compound | Compound HB | Compound |
| | (100 Å) | (350 Å) | (50 Å) | HB:metal | (100 Å) | ET:Liq |
| | | | | complex 131 | | (40:60) |
| | | | | (46:46:8) | | (350 Å) |
| | | | | (400 Å) | | |
| Comparative | Compound HI | Compound HT | Compound EB | Compound EB:compound | Compound HB | Compound |
| Example 1 | (100 Å) | (350 Å) | (50 Å) | HB:Compound | (100 Å) | ET:Liq |
| | | | | GD1 | | (40:60) |
| | | | | (46:46:8) | | (350 Å) |
| | | | | (400 Å) | | |
| Comparative | Compound HI | Compound HT | Compound EB | Compound EB:compound | Compound HB | Compound |
| Example 2 | (100 Å) | (350 Å) | (50 Å) | HB:Compound | (100 Å) | ET:Liq |
| | | | | GD2 | | (40:60) |
| | | | | (46:46:8) | | (350 Å) |
| | | | | (400 Å) | | |
| Comparative | Compound HI | Compound HT | Compound EB | Compound EB:compound | Compound HB | Compound |
| Example 3 | (100 Å) | (350 Å) | (50 Å) | HB:Compound | (100 Å) | ET:Liq |
| | | | | GD3 | | (40:60) |
| | | | | (46:46:8) | | (350 Å) |
| | | | | (400 Å) | | |
| Comparative | Compound HI | Compound HT | Compound EB | Compound EB:compound | Compound HB | Compound |
| Example 4 | (100 Å) | (350 Å) | (50 Å) | HB:Compound | (100 Å) | ET:Liq |
| | | | | GD4 | | (40:60) |
| | | | | (46:46:8) | | (350 Å) |
| | | | | (400 Å) | | |
| Comparative | Compound HI | Compound HT | Compound EB | Compound EB:compound | Compound HB | Compound |
| Example 5 | (100 Å) | (350 Å) | (50 Å) | HB:Compound | (100 Å) | ET:Liq |
| | | | | GD5 | | (40:60) |
| | | | | (46:46:8) | | (350 Å) |
| | | | | (400 Å) | | |
| Comparative | Compound HI | Compound HT | Compound EB | Compound EB:compound | Compound HB | Compound |
| Example 6 | (100 Å) | (350 Å) | (50 Å) | HB:Compound | (100 Å) | ET:Liq |
| | | | | GD7 | | (40:60) |
| | | | | (46:46:8) | | (350 Å) |
| | | | | (400 Å) | | |

Structures of the materials used in the devices are shown as follows:

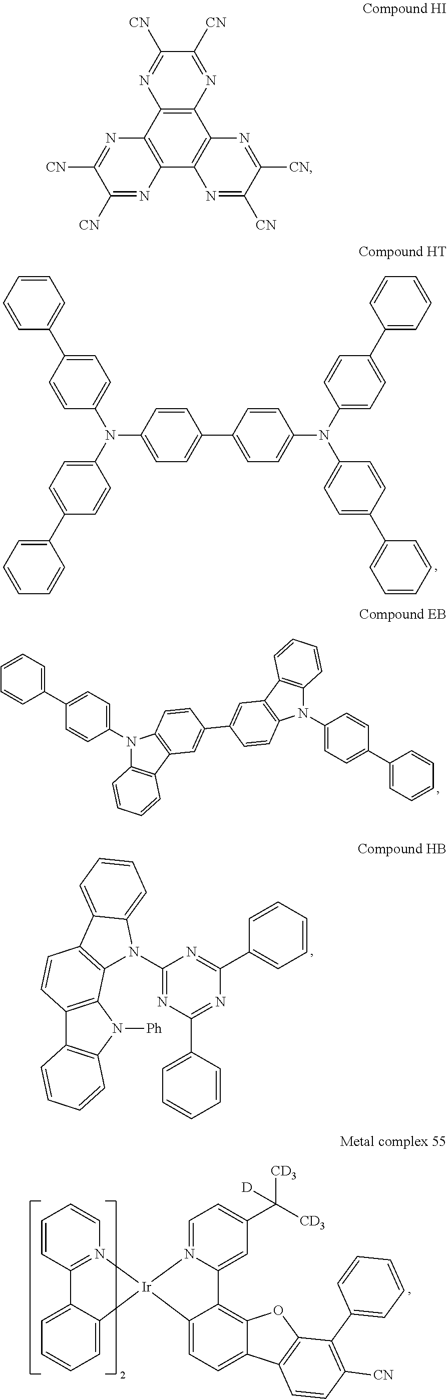

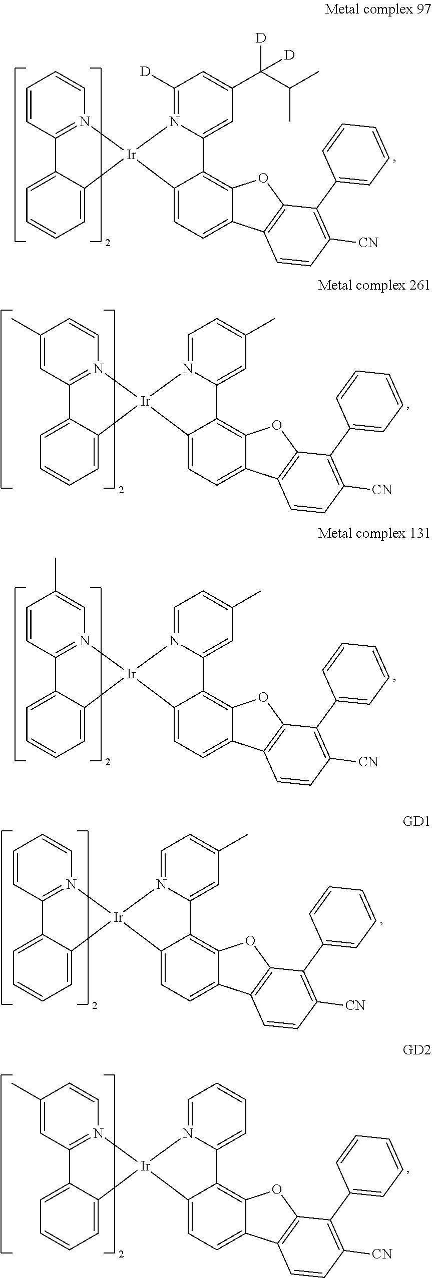

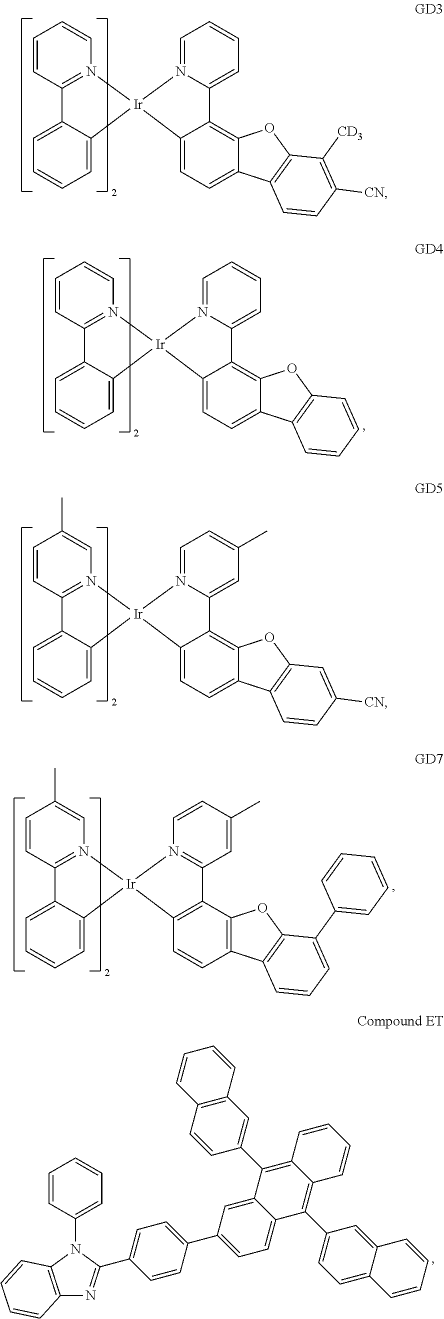

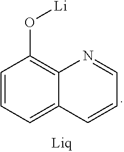

Current-voltage-luminance (IVL) characteristics of the devices were measured. Under a condition of 1000 cd/m², CIE data, λₘₐₓ, full width at half maximum (FWHM), driving voltage (V), current efficiency (CE), power efficiency (PE), and external quantum efficiency (EQE) of the devices were measured. The data was recorded and shown in Table 2.

TABLE 2
Device data

| | | | | Volt- | | | |
|---|---|---|---|---|---|---|---|
| Device | CIE | λₘₐₓ | FWHM | age | CE | PE | EQE |
| ID | (x, y) | (nm) | (nm) | (V) | (cd/A) | (lm/W) | (%) |
| Example 1 | (0.314, | 525 | 36.5 | 2.74 | 97 | 111 | 25.1 |
| | 0.649) | | | | | | |
| Example 2 | (0.313, | 523 | 35.1 | 2.75 | 94 | 108 | 24.5 |
| | 0.649) | | | | | | |
| Example 3 | (0.335, | 528 | 36.8 | 2.75 | 100 | 114 | 25.7 |
| | 0.649) | | | | | | |
| Example 4 | (0.328, | 528 | 36.8 | 2.73 | 98 | 113 | 25.1 |
| | 0.642) | | | | | | |
| Comparative | (0.335, | 528 | 42.7 | 2.76 | 103 | 117 | 26.0 |
| Example 1 | 0.638) | | | | | | |
| Comparative | (0.354, | 532 | 42.9 | 2.72 | 103 | 119 | 26.1 |
| Example 2 | 0.626) | | | | | | |
| Comparative | (0.331, | 527 | 51.3 | 2.73 | 91 | 105 | 23.3 |
| Example 3 | 0.639) | | | | | | |
| Comparative | (0.341, | 528 | 59.3 | 2.98 | 87 | 92 | 22.5 |
| Example 4 | 0.630) | | | | | | |
| Comparative | (0.329, | 526 | 51.2 | 2.72 | 93 | 108 | 24.1 |
| Example 5 | 0.639) | | | | | | |
| Comparative | (0.335, | 523 | 62.3 | 3.45 | 82 | 75 | 21.9 |
| Example 6 | 0.629) | | | | | | |

Discussion:

From the data shown in Table 2, although the EQE of Device Examples 1 to 3 is slightly lower than that of Device Comparative Examples 1 and 2, such EQE levels are still very high in the industry. However, the half-peak width of Device Example 1 which is 6.2 nm narrower than that of Device Comparative Example 1, the half-peak width of Device Example 2 which is 7.6 nm narrower than that of Device Comparative Example 1, and the half-peak width of Device example 3 which is 6.1 nm narrower than that of Device Comparative Example 2 reach 36.5 nm, 35.1 nm, and 36.8 nm, respectively, which are very narrow. This indicates that the emitted light has very high color saturation, which is very rare. In addition, in terms of current efficiency and power efficiency, it can be seen from the comparison of relevant data in Examples 1, 2, 3, and 4 and Comparative Examples 1, 2, and 3 that the introduction of deuterium, alkyl, deuterated alkyl, and other substituents into a pyridine ring of the ligand in the metal complex disclosed by the present disclosure can still allow related device efficiency to be maintain at high levels in the industry. In addition, the introduction of substitution into the pyridine ring of the dibenzofuran-pyridine ligand in the metal complex disclosed by the present disclosure allows a blue shift in the emission wavelength of the device to be successfully achieved, thereby effectively adjusting the color of the light emitted by the device.

The EQE of Device Example 1 and the EQE of Device Example 2 are 7.7% and 5.2% higher than that of Device Comparative Example 3, respectively, indicating that aryl substitution at a specific position in the metal complex disclosed by the present disclosure can improve the EQE of the material. Meanwhile, the half-peak width of Device Example 1 and the half-peak width of Device Example 2 are 14.8 nm and 16.2 nm narrower than that of Device Comparative Example 3, respectively, indicating more significant advantages.

Compared with Device Comparative Example 5, Device Example 4 improves the EQE by 4%, significantly improves the current efficiency and the power efficiency, and more importantly, narrows the half-peak width greatly by 14.4 nm, indicating very significant advantages. This proves again that the aryl substitution at a specific position in the metal complex disclosed by the present disclosure brings excellent effects.

Compared with Device Comparative Example 6, Device Example 4 improves the EQE by 14.6%, significantly improves the current efficiency and the power efficiency, significantly reduces the driving voltage, and more importantly, narrows the half-peak width greatly by 25.5 nm, indicating very significant advantages. This proves again that the cyano substitution at a specific position in the metal complex disclosed by the present disclosure brings excellent effects.

In addition, compared with the prior art (Comparative Example 4), Device Example 1, Device Example 2, Device Example 3, and Device Example 4 all exhibit huge advantages in various aspects of device performance. Compared with Device Comparative Example 4, Device Example 1, Device Example 2, Device Example 3, and Device Example 4 have half-peak widths which are narrowed by 22.8 nm, 24.2 nm, 22.5 nm, and 22.5 nm respectively, driving voltages which are decreased by 0.24 V, 0.23 V, 0.23 V, and 0.25 V respectively, and EQE which is improved by 11.6%, 8.9%, 14.2% and 11.6% respectively. The results show that compared with the prior art (Comparative Example 4), the present disclosure has significantly improved the device performance from various effects through cyano, aryl, and alkyl substitution at different positions of the dibenzofuran-pyridine ligand in the metal complex disclosed herein.

In summary, compared with the prior art, the metal complex of the present disclosure has remarkable effects of significantly narrowed half-peak width, greatly improved color saturation of the light emitted by the device, and meanwhile, significantly improved high efficiency and low voltage by structural design by introducing a specific aromatic ring and a cyano substituent into a specific ring of the ligand and meanwhile introducing a substituent into another specific ring of the ligand. The metal complex disclosed by the present disclosure has huge advantages and broad prospects in industrial applications.

Spectroscopy Data

The photoluminescence (PL) spectroscopy data of the metal complex of the present disclosure and the comparative compounds was measured using a fluorescence spectrophotometer F98 produced by SHANGHAI LENGGUANG TECHNOLOGY CO., LTD. The metal complex 131 of the present disclosure and the comparative compounds GD5, GD6, GD7, GD8, and GD9 were prepared into solutions each with a concentration of 3×10⁻⁵ mol/L by using HPLC-grade toluene, and then excited at room temperature (298 K) using light with a wavelength of 500 nm, and their emission spectrums were measured.

The metal complex 131 of the present disclosure and the comparative compounds GD5, GD6, GD7, GD8, and GD9 have the following structures:

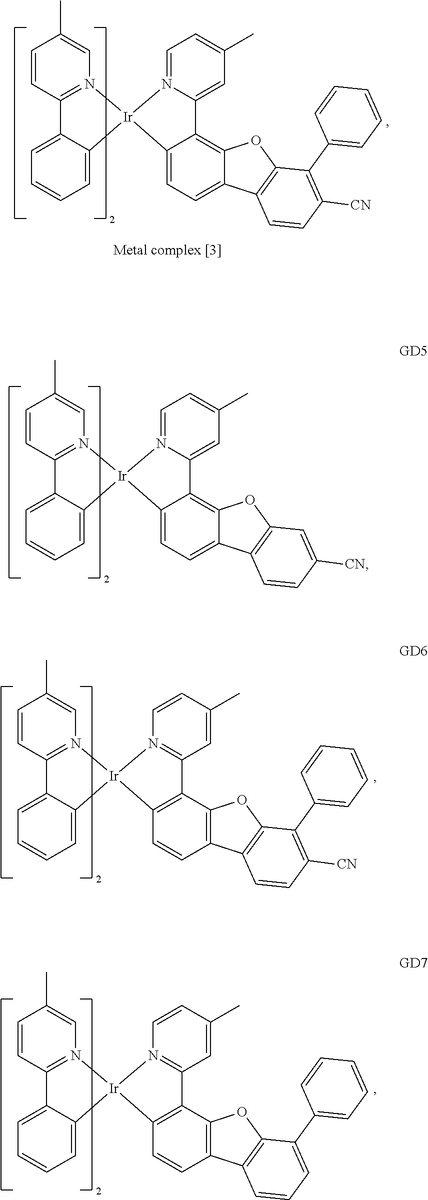

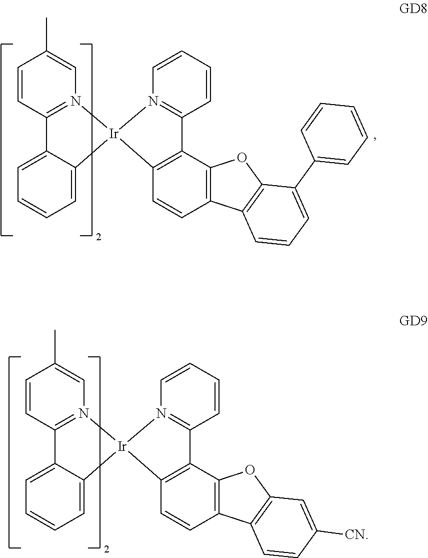

The maximum emission wavelength (λₘₐₓ) and the full width at half maximum (FWHM) of each of these compounds in PL spectroscopy are shown in Table 3.

TABLE 3
Spectroscopy data

| | λₘₐₓ | FWHM |
|---|---|---|
| Compound No. | (nm) | (nm) |
| Metal complex 131 | 524 | 33.9 |
| GD5 | 523 | 46.1 |
| GD6 | 528 | 38.8 |
| GD7 | 522 | 56.3 |
| GD8 | 528 | 55.3 |
| GD9 | 527 | 49.1 |

It can be seen from the data in Table 3 that compared with those of the comparative compounds GD5 and GD9, the half-peak width of the metal complex 131 disclosed by the present disclosure is significantly narrowed by 12.2 nm and 15.2 nm respectively, indicating that the introduction of phenyl (aromatic ring) and methyl (substituent) into the ligand structure of the metal complex disclosed by the present disclosure can bring the beneficial effect of greatly narrowed half-peak width of the PL emission peak for the metal complex. Compared with those of the comparative compounds GD7 and GD8, the half-peak width of the metal complex 131 is narrowed by 22.4 nm and 21.4 nm respectively, indicating that the introduction of cyano substitution and methyl (substituent) into the ligand structure of the metal complex disclosed by the present disclosure can bring the beneficial effect of greatly narrowed half-peak width of the PL emission peak for the metal complex.

In addition, it can be found from the comparison of data between compounds GD7 and GD8 that GD7 introduces a methyl group (substituent) into the pyridine ring of the ligand, while the half-peak width of GD7 is 1 nm wider. However, the metal complex 131 disclosed by the present disclosure also introduces a methyl group (substituent) into the pyridine ring of the ligand, but surprisingly, its half-peak width was unexpectedly further narrowed greatly by 4.9 nm based on the very narrow half-peak width (38.8 nm) of the comparative compound GD6. This result indicates that the introduction of methyl substitution into the pyridine ring in the pyridine-dibenzofuran ligand structure of the metal complex disclosed by the present disclosure brings the unexpected excellent effect of greatly narrowed half-peak width of the PL emission peak for the metal complex.

The metal complex 131 of the present disclosure differs in structure from the compound GD6 by one alkyl substituent, and the compound GD5 likewise differs in structure from the compound GD9 by one alkyl substituent at the same substitution position. However, the half-peak width of the metal complex 131 of the present disclosure was 4.9 nm narrower than that of GD6, and the half-peak width of the compound GD5 was 3 nm narrower than that of GD9. This result proves again that the metal complex of the present disclosure can achieve significant and unexpected excellent effects through a structural design, that is, the structural modification comprising introduction of a substituent into the pyridine ring of the ligand structure in combination with introduction of cyano and aromatic ring substitution into the dibenzofuran structure.

The above data shows that the PL emission wavelength of the metal complex of the present disclosure can be finely adjusted, and the metal complex can achieve unexpected excellent effect of greatly narrowed PL emission half-peak width by structural design by introducing a specific aromatic ring and a cyano substituent into a specific ring of the ligand and meanwhile introducing a substituent into another specific ring of the ligand.

It should be understood that various embodiments described herein are merely examples and not intended to limit the scope of the present disclosure. Therefore, it is apparent to those skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex, comprising a metal M and a ligand Lₐ coordinated to the metal M, wherein Lₐ has a structure represented by Formula 1: 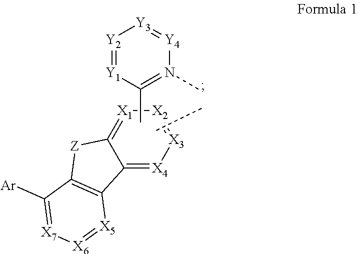
wherein
the metal M is selected from a metal with a relative atomic mass greater than 40;
Z is selected from the group consisting of O, S, Se, NR, CRR, and SiRR, wherein when two R are present, the two R are the same or different;
X₁ to X₇ are, at each occurrence identically or differently, selected from C, CRₓ, or N;
Y₁ to Y₄ are, at each occurrence identically or differently, selected from CR_{y} or N;
at least one of X₁ to X₇ is CRₓ, and the Rₓ is cyano;
at least one of Y₁ to Y₄ is CR_{y}, and the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof; and
adjacent substituents R, Rₓ, R_{y}, and Ar can be optionally joined to form a ring.

2. The metal complex of claim 1, having a general formula of M(Lₐ)ₘ(L_{b})ₙ(L_{c})_{q}; wherein
M is, at each occurrence identically or differently, selected from the group consisting of Cu, Ag, Au, Ru, Rh, Pd, Os, Ir, and Pt; preferably, M is, at each occurrence identically or differently, selected from Pt or Ir;
Lₐ, L_{b}, and L_{c} are the first ligand, the second ligand, and the third ligand coordinated to the metal M, respectively; and Lₐ, L_{b}, and L_{c} can be optionally linked to form a multi dentate ligand;
m is 1, 2, or 3, n is 0, 1, or 2, q is 0, 1, or 2, and m+n+q equals the oxidation state of the metal M; wherein when m is greater than or equal to 2, the multiple Lₐ are the same or different; when n is equal to 2, the two L_{b} are the same or different; when q is equal to 2, the two L_{c} are the same or different;
L_{b} and L_{c} are, at each occurrence identically or differently, any one selected from the group consisting of following structures: 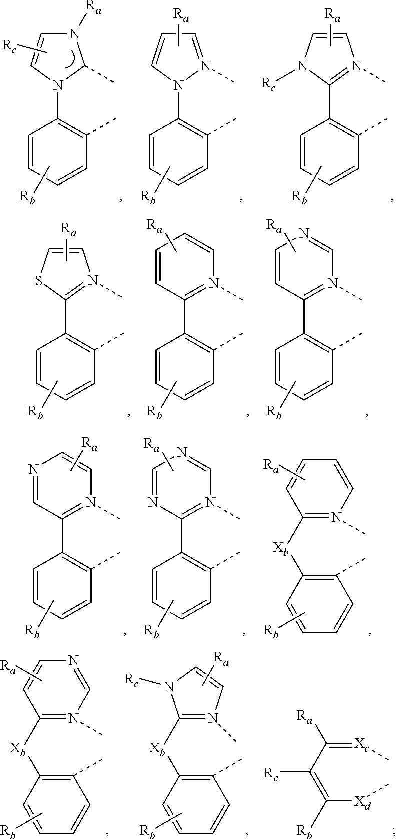
wherein
Rₐ, R_{b}, and R_{c} are, at each occurrence identically or differently, represent mono-substitution, multi-substitution, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
in structures of L_{b} and L_{c}, adjacent substituents Rₐ, R_{b}, R_{c}, R_{N1}, R_{N2}, R_{C1}, and R_{C2} can be optionally joined to form a ring.

3. The metal complex of claim 1, wherein Lₐ has a structure represented by any one of Formula 1a to Formula 1d: 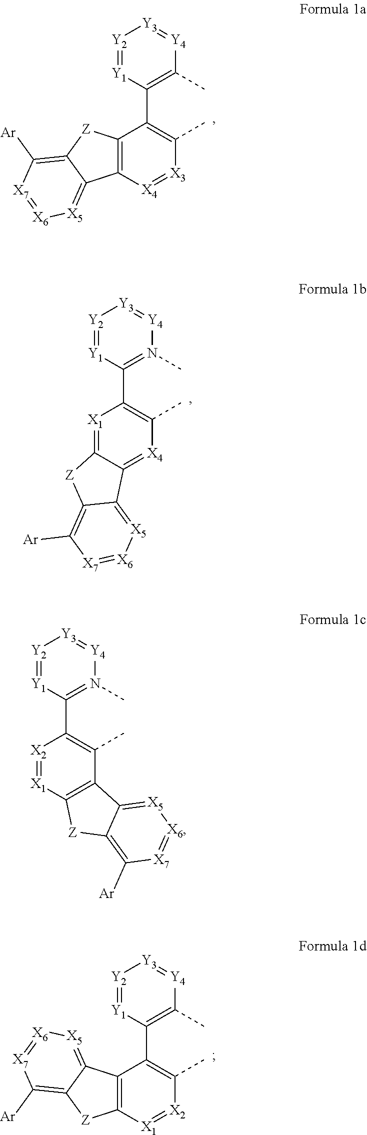
wherein Z, Ar, X₁ to X₇, and Y₁ to Y₄ have same definitions and scopes as those in claim 1.

4. The metal complex of claim 3, having a general formula of Ir(Lₐ)ₘ(L_{b})₃₋ₘ and a structure represented by Formula 2: 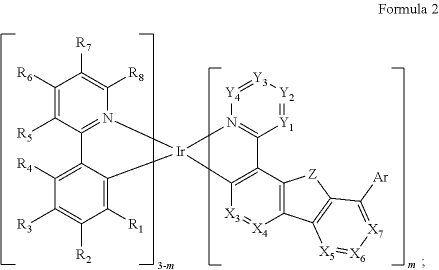
wherein
m is selected from 1 or 2; wherein when m is equal to 2, the two Lₐ are the same or different; when m is equal to 1, the two L_{b} are the same or different;
Z is selected from the group consisting of O, S, Se, NR, CRR, and SiRR, wherein when two R are present, the two R are the same or different;
X₃ to X₇ are, at each occurrence identically or differently, selected from CRₓ or N;
Y₁ to Y₄ are, at each occurrence identically or differently, selected from CR_{y} or N;
at least one of X₃ to X₇ is CRₓ, and the Rₓ is cyano;
at least one of Y₁ to Y₄ is CR_{y}, and the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
R, Rₓ, R_{y}, and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar is, at each occurrence identically or differently, selected from the group consisting of: substituted or unsubstituted aryl having 6 to 30 carbon atoms, substituted or unsubstituted heteroaryl having 3 to 30 carbon atoms, and combinations thereof; and
adjacent substituents R, Rₓ, R_{y}, Ar, and R₁ to R₈ can be optionally joined to form a ring.

5. The metal complex of claim 4, wherein Z is selected from the group consisting of: O and S;
preferably, Z is O.

6. The metal complex of claim 4, wherein in Formula 1a to Formula 1d and Formula 2, X₁ to X₇ are, at each occurrence identically or differently, selected from CRₓ.

7. The metal complex of claim 4, wherein in Formula 1a to Formula 1d and Formula 2, X₁ to X₇ are, at each occurrence identically or differently, selected from CRₓ or N, and at least one of X₁ to X₇ is N.

8. The metal complex of claim 4, wherein in Formula 1, Formula 1a to Formula 1d, and Formula 2, at least two of X₁ to X₇ are selected from CRₓ, and wherein at least one of the Rₓ is cyano, and at least one of the Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, in Formula 1, Formula 1a to Formula 1d, and Formula 2, at least two of X₁ to X₇ are selected from CRₓ, and wherein at least one of the Rₓ is cyano, and at least one of the Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

9. The metal complex of claim 4, wherein in Formula 1, Formula 1a to Formula 1d, and Formula 2, at least one of X₅ to X₇ is selected from CRₓ, and the Rₓ is cyano;
preferably, at least one of X₆ to X₇ is selected from CRₓ, and the Rₓ is cyano;
more preferably, X₇ is selected from CRₓ, and the Rₓ is cyano.

10. The metal complex of claim 4, wherein in Formula 1, Formula 1a to Formula 1d, and Formula 2, Y₁ to Y₄ are, at each occurrence identically or differently, selected from CR_{y}.

11. The metal complex of claim 4, wherein in Formula 1, Formula 1a to Formula 1d, and Formula 2, Y₁ to Y₄ are, at each occurrence identically or differently, selected from CR_{y} or N, and at least one of Y₁ to Y₄ is N; preferably, Y₃ is N.

12. The metal complex of claim 4, wherein in Formula 1, Formula 1a to Formula 1d, and Formula 2, at least one of Y₁ to Y₄ is selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, and combinations thereof;
preferably, at least one of Y₁ to Y₄ is selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, and combinations thereof;
more preferably, Y₂ and/or Y₃ are(is) selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, and combinations thereof.

13. The metal complex of claim 12, wherein in Formula 1, Formula 1a to Formula 1d, and Formula 2, Y₂ and/or Y₃ are(is) selected from CR_{y}, and the R_{y} is, at each occurrence identically or differently, selected from substituted alkyl having 1 to 20 carbon atoms, substituted cycloalkyl having 3 to 20 ring carbon atoms, substituted aryl having 6 to 20 carbon atoms, or combinations thereof; and the substitution in the above substituted groups comprises at least one deuterium atom;
preferably, the R_{y} is, at each occurrence identically or differently, selected from the group consisting of: partially or fully deuterated alkyl having 1 to 20 carbon atoms, partially or fully deuterated cycloalkyl having 3 to 20 ring carbon atoms, and combinations thereof;
more preferably, when a carbon atom at a benzylic position in the R_{y} is a primary carbon atom, a secondary carbon atom, or a tertiary carbon atom, at least one deuterium atom in the R_{y} is located at the benzylic position.

14. The metal complex of claim 13, wherein in Formula 1, Formula 1a to Formula 1d, and Formula 2, Y₂ and/or Y₃ are(is) selected from CR_{y}, and the R_{y} is, at each occurrence identically or differently, selected from the group consisting of: partially or fully deuterated alkyl having 1 to 20 carbon atoms, partially or fully deuterated cycloalkyl having 3 to 20 ring carbon atoms, and combinations thereof; when a carbon atom at a benzylic position in the R_{y} is a primary carbon atom, a secondary carbon atom, or a tertiary carbon atom, hydrogen at the benzylic position in the R_{y} is fully substituted by deuterium;
preferably, the R_{y} is, at each occurrence identically or differently, selected from the group consisting of: CD₃, CD₂CH₃, CD₂CD₃, CD(CH₃)₂, CD(CD₃)₂, CD₂CH(CH₃)₂, CD₂C(CH₃)₃, 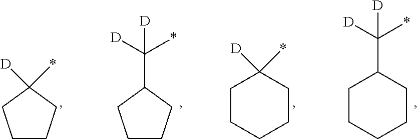 [SMILES: *C1([2H])CCCC1 ; *C([2H])([2H])C1CCCC1 ; *C1([2H])CCCCC1 ; *C([2H])([2H])C1CCCCC1]
and combinations thereof.

15. The metal complex of claim 4, wherein in Formula 1, Formula 1a to Formula 1d, and Formula 2, at least two of Y₁ to Y₄ are, at each occurrence identically or differently, selected from CR_{y}, and wherein at least one of the R_{y} is selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, and combinations thereof; and at least one of the R_{y} is selected from deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, or combinations thereof;
preferably, at least two of Y₁ to Y₄ are, at each occurrence identically or differently, selected from CR_{y}, and wherein at least one of the R_{y} is selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof; and at least one of the R_{y} is selected from deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, or combinations thereof;
more preferably, at least two of Y₁ to Y₄ are, at each occurrence identically or differently, selected from CR_{y}, and wherein at least one of the R_{y} is selected from the group consisting of: substituted or unsubstituted alkyl having 1 to 20 carbon atoms, substituted or unsubstituted cycloalkyl having 3 to 20 ring carbon atoms, and combinations thereof; and, at least one of the R_{y} is deuterium.

16. The metal complex of claim 15, wherein in Formula 1, Formula 1a to Formula 1d, and Formula 2, Y₂ and/or Y₃ are(is) selected from CR_{y}, and the R_{y} is, at each occurrence identically or differently, selected from partially or fully deuterated alkyl having 1 to 20 carbon atoms or partially or fully deuterated cycloalkyl having 3 to 20 ring carbon atoms; and Y₁ and/or Y₄ are(is) selected from CD.

17. The metal complex of claim 4, wherein in Formula 1, Formula 1a to Formula 1d, and Formula 2, Ar is selected from substituted or unsubstituted phenyl, substituted or unsubstituted naphthyl, substituted or unsubstituted pyridyl, substituted or unsubstituted furyl, substituted or unsubstituted thienyl, substituted or unsubstituted benzofuryl, substituted or unsubstituted benzothienyl, substituted or unsubstituted dibenzofuryl, substituted or unsubstituted dibenzothienyl, or combinations thereof; optionally, hydrogen in Ar is partially or fully substituted by deuterium;
preferably, Ar is selected from substituted or unsubstituted phenyl; optionally, hydrogen in Ar is partially or fully substituted by deuterium.

18. The metal complex of claim 4, wherein in Formula 2, at least one or two of R₁ to R₈ is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least one of R₁ to R₈ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

19. The metal complex of claim 4, wherein in Formula 2, at least one, two, three, or all of R₂, R₃, R₆, and R₇ is(are) selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, one, two, three, or all of R₂, R₃, R₆, and R₇ is(are) selected from the group consisting of: deuterium, substituted or unsubstituted alkyl having 1 to 20 carbon atoms, substituted or unsubstituted cycloalkyl having 3 to 20 ring carbon atoms, and combinations thereof;
more preferably, one, two, three, or all of R₂, R₃, R₆, and R₇ is(are) selected from the group consisting of: deuterium, methyl, ethyl, propyl, isopropyl, n-butyl, isobutyl, t-butyl, cyclopentyl, cyclohexyl, and combinations thereof; optionally, the above groups may be partially or fully deuterated.

20. The metal complex of claim 1, wherein the ligand Lₐ is, at each occurrence identically or differently, any one selected from the group consisting of:

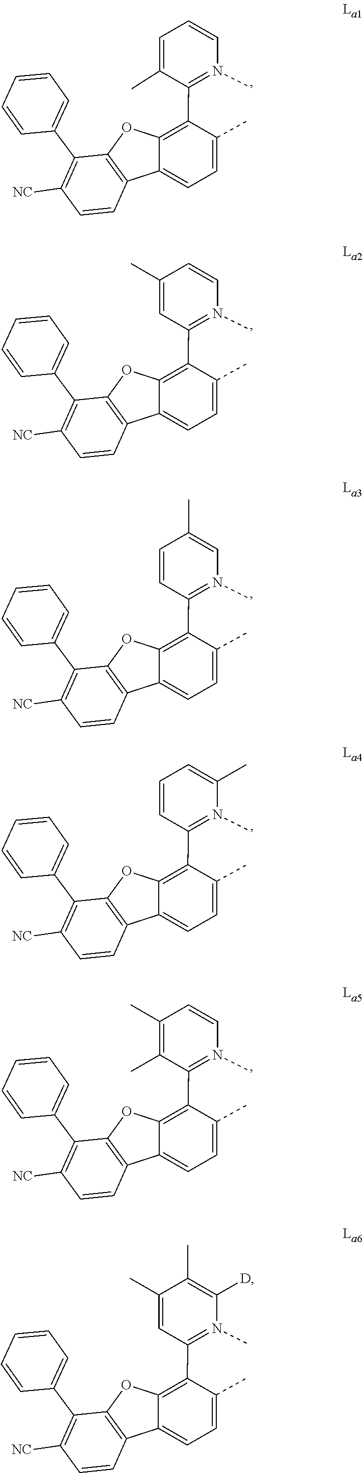

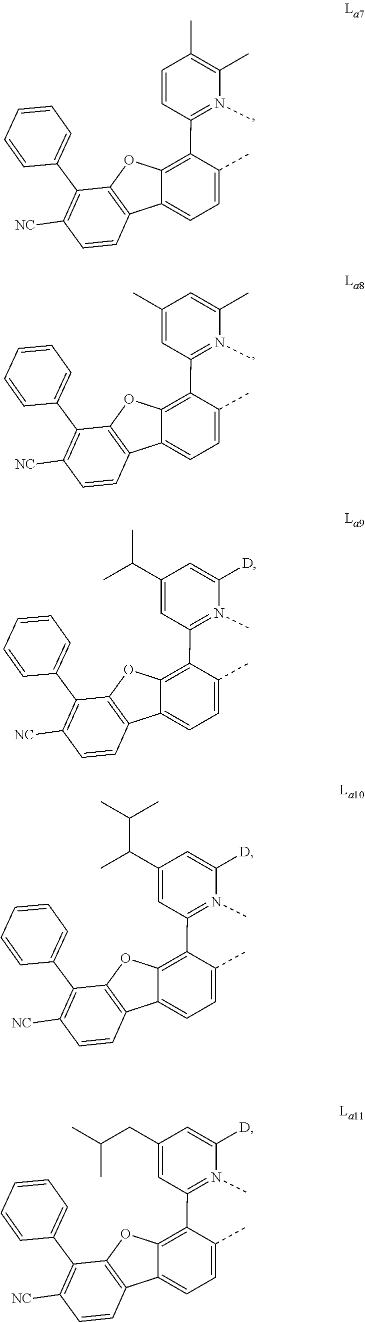

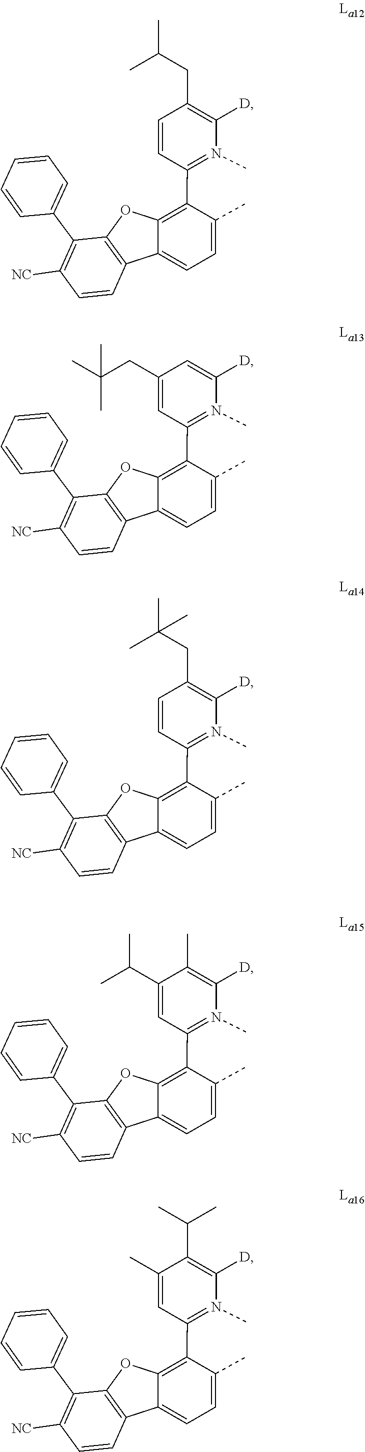

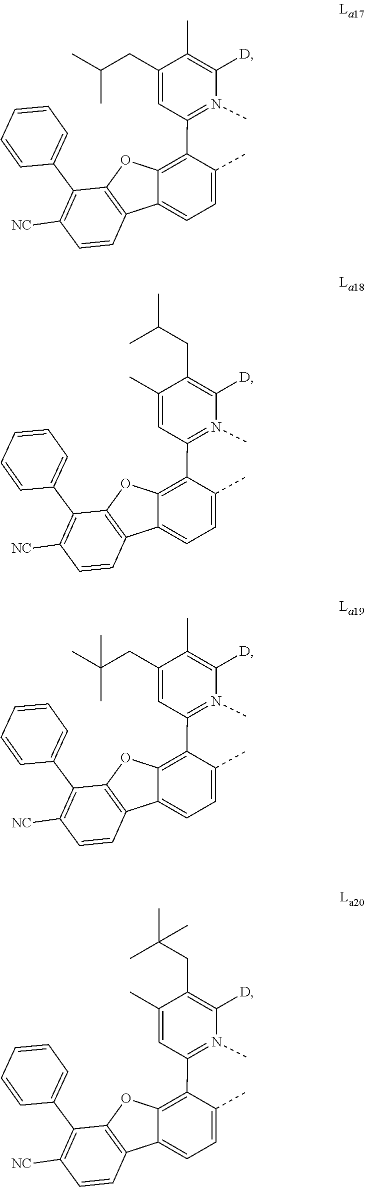

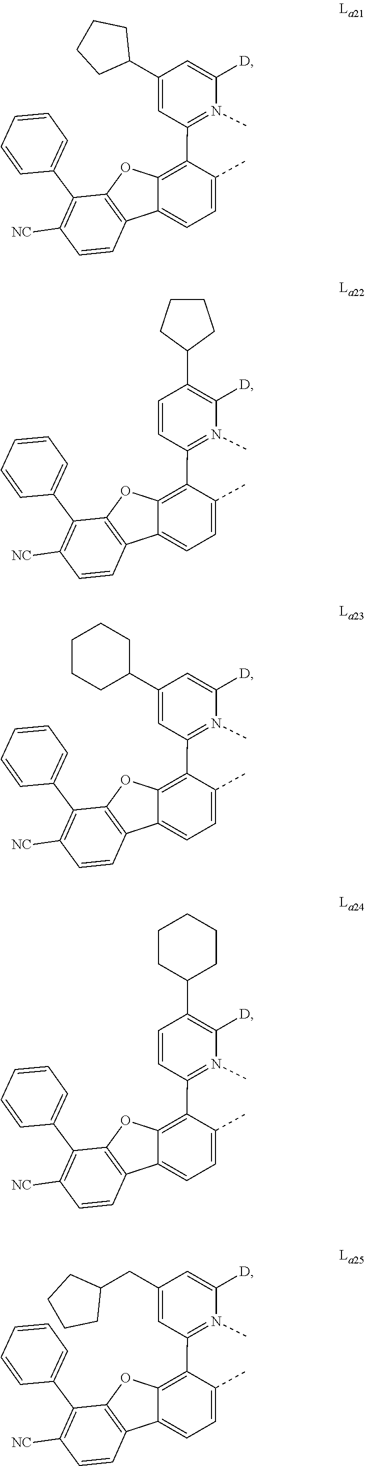

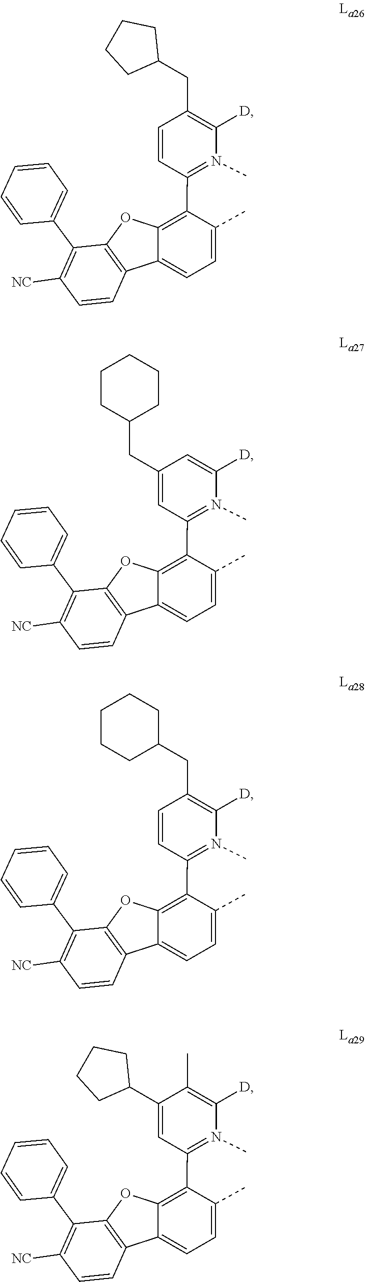

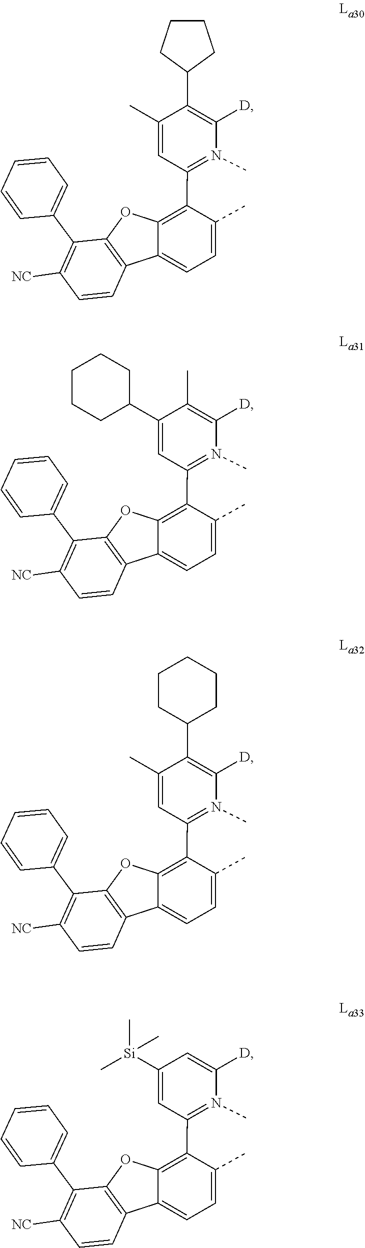

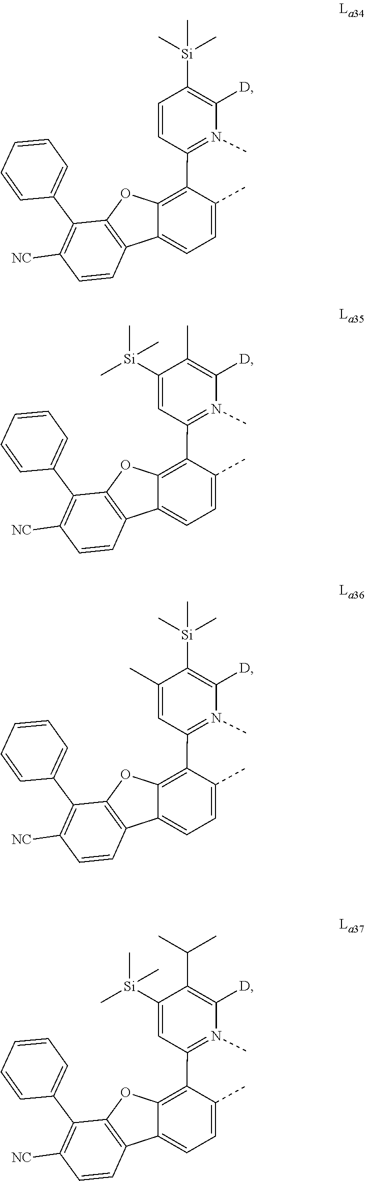

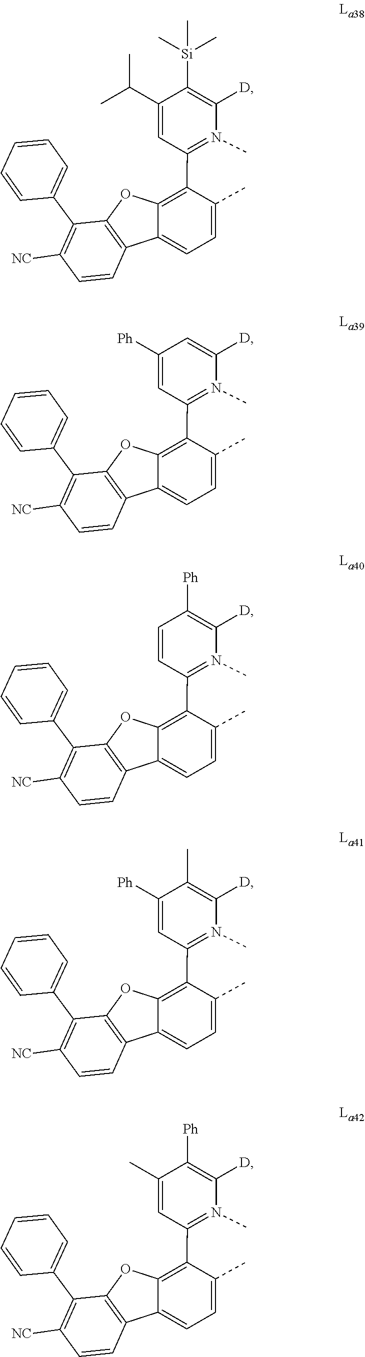

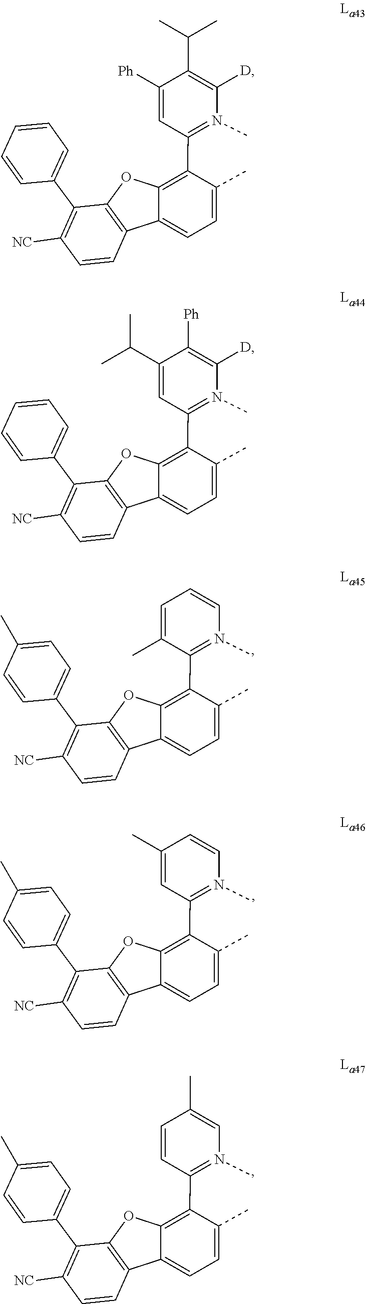

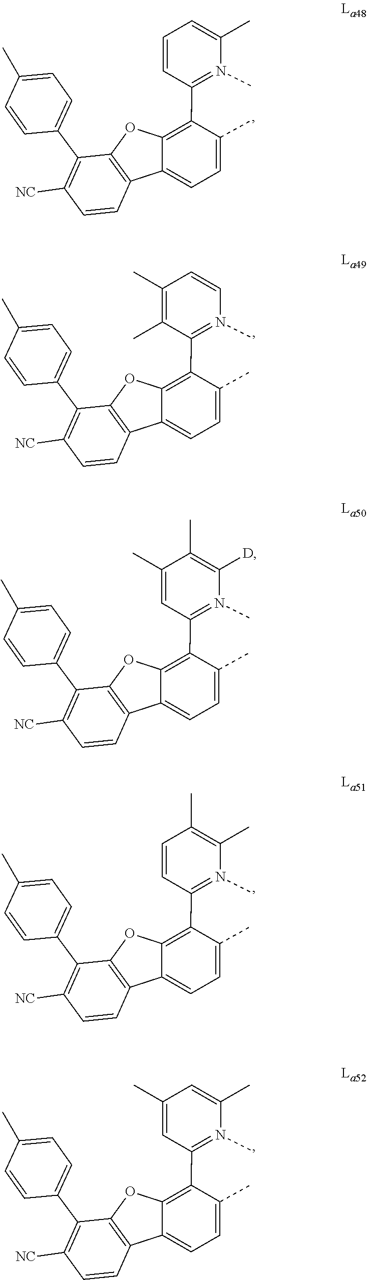

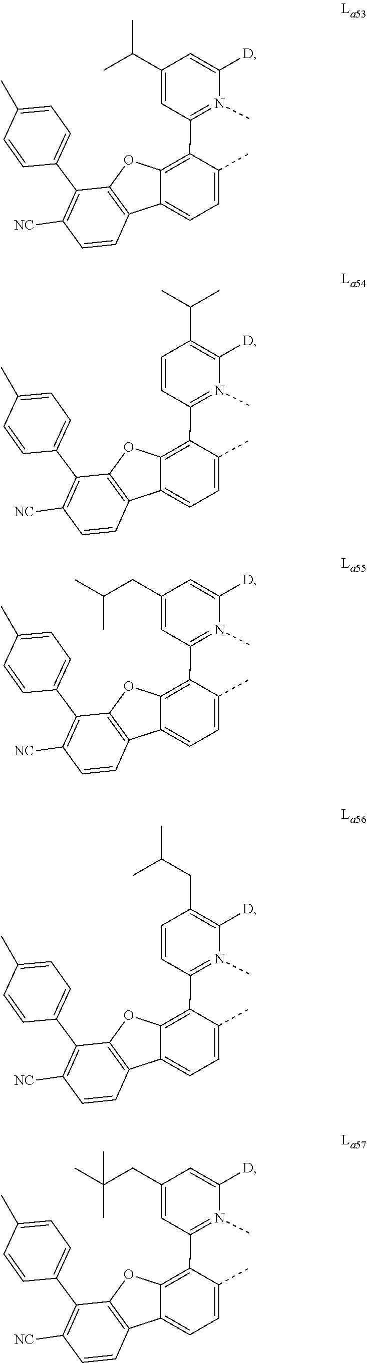

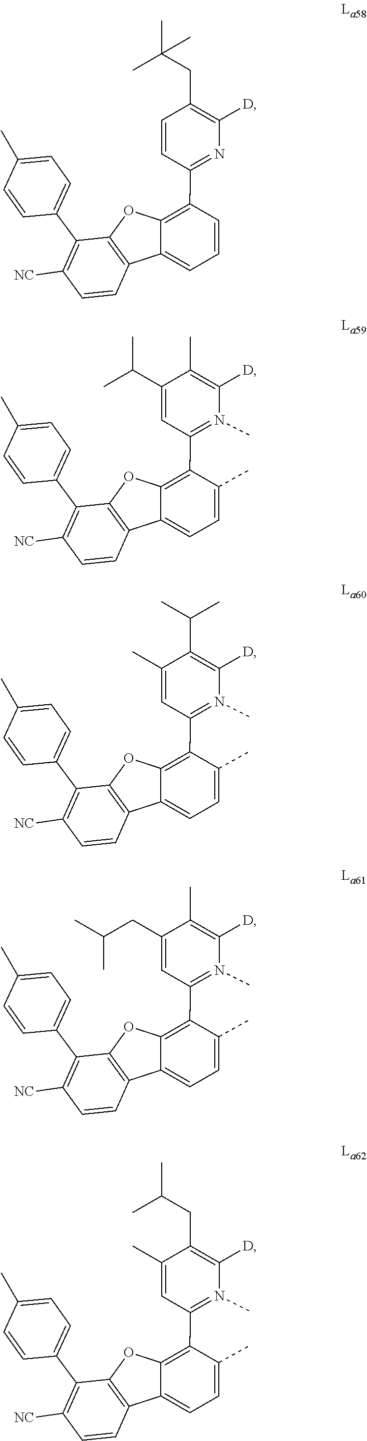

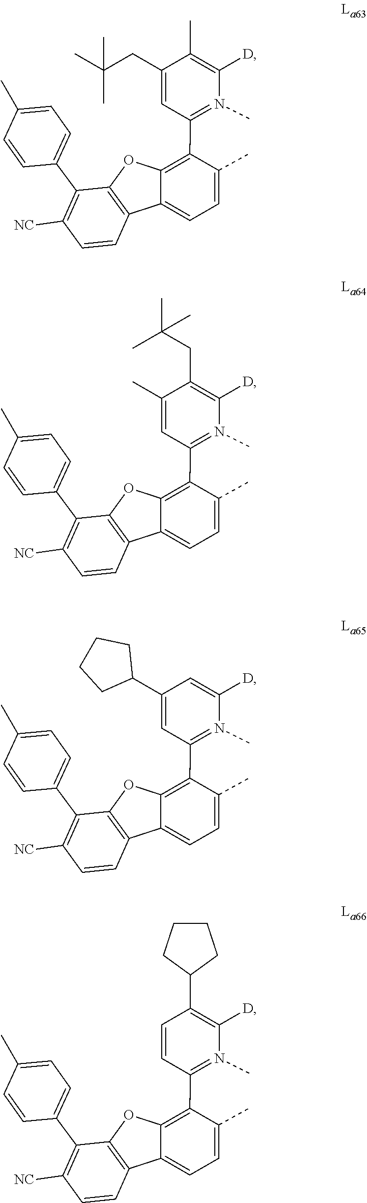

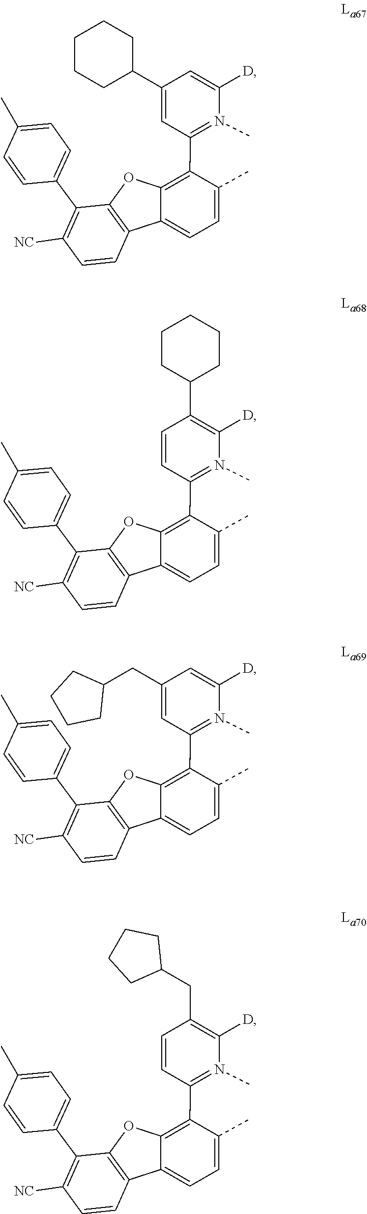

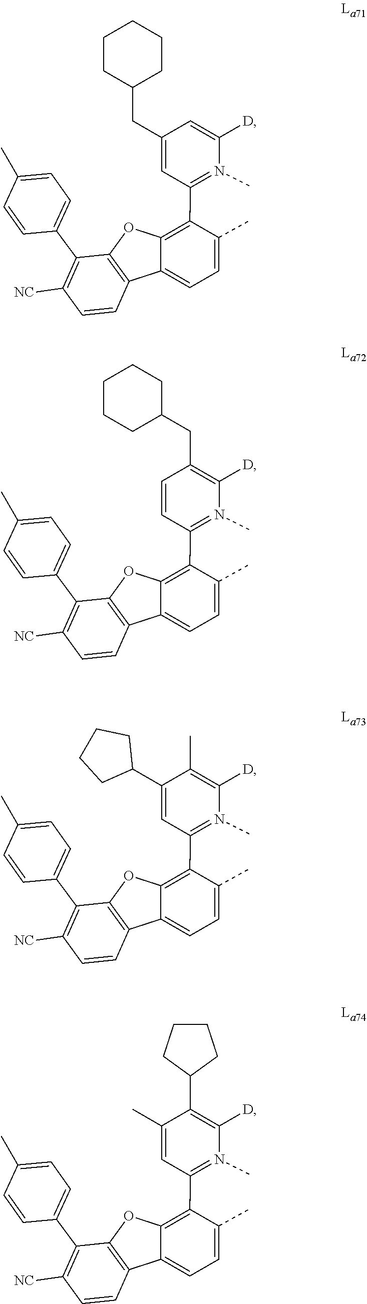

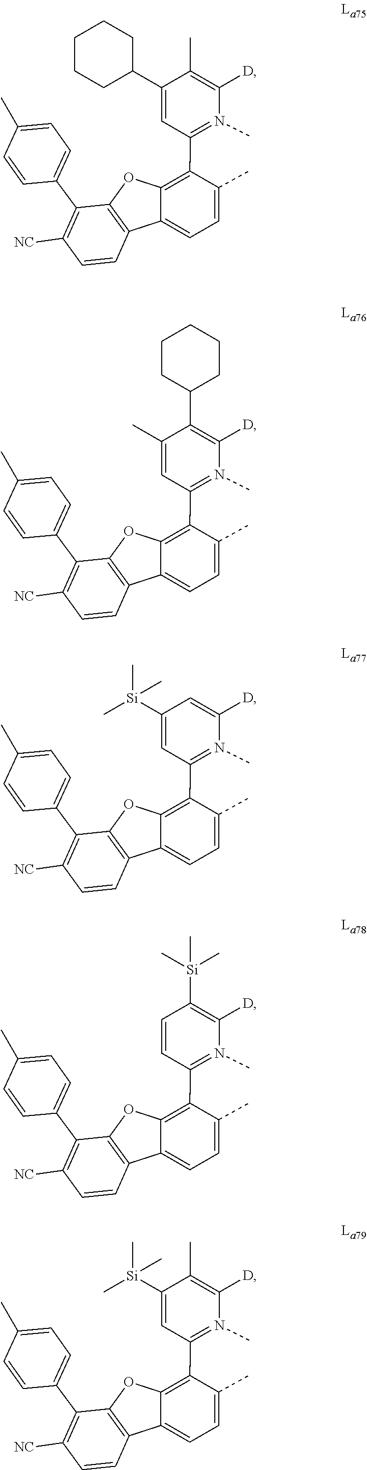

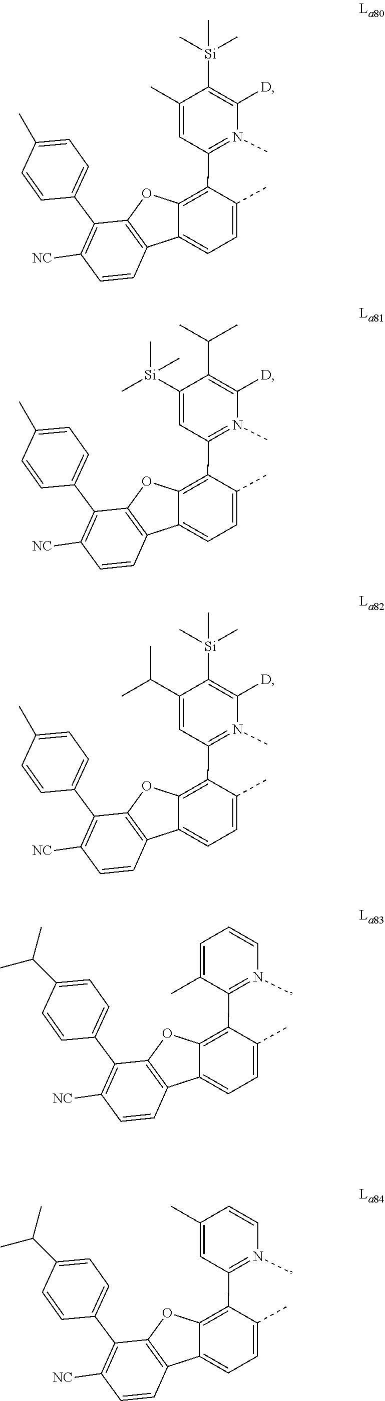

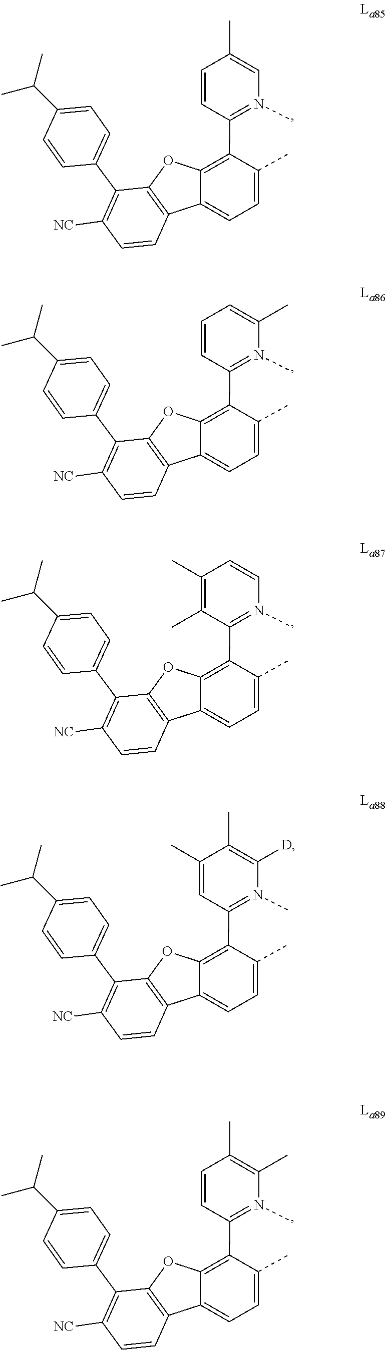

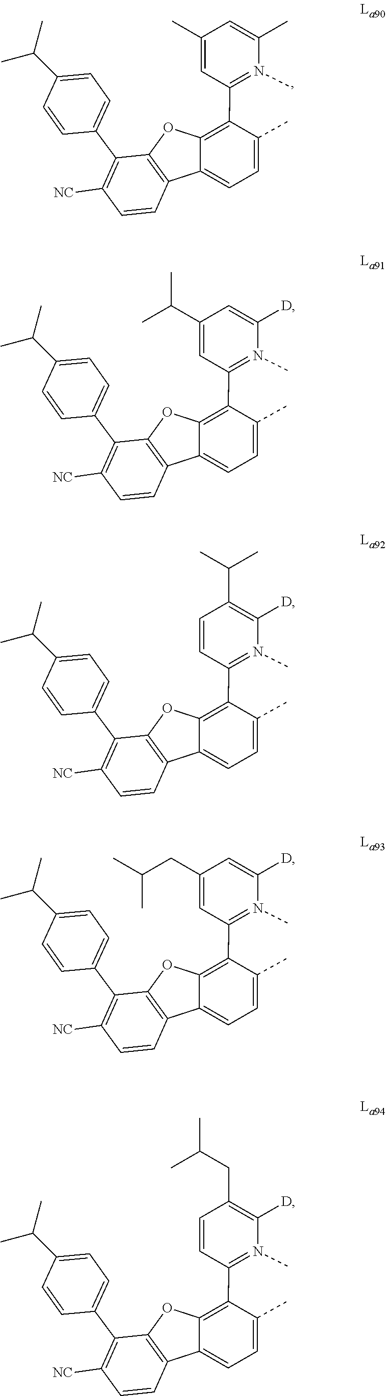

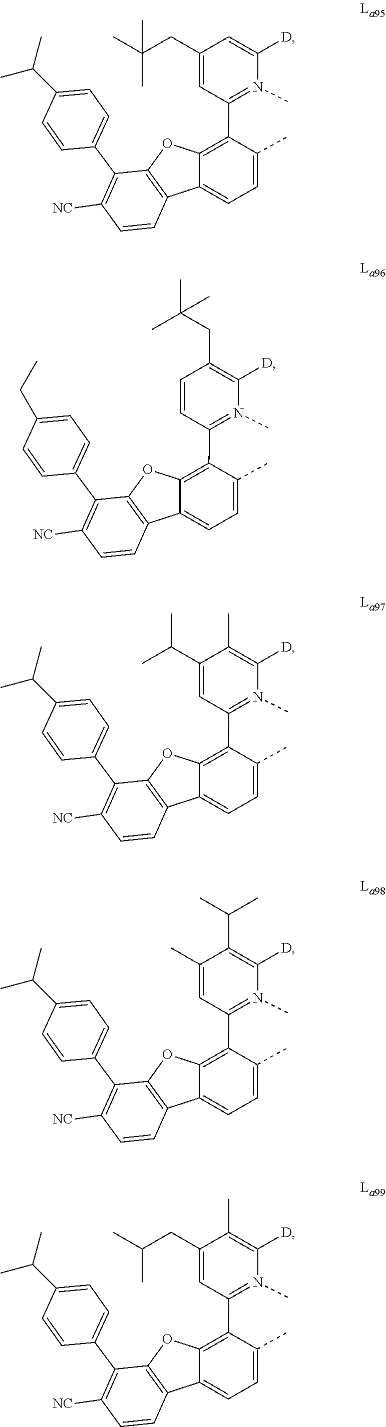

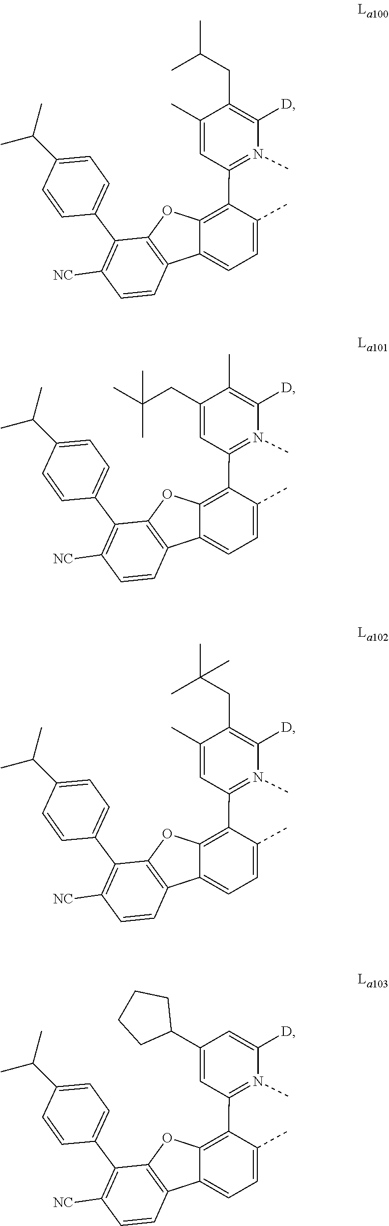

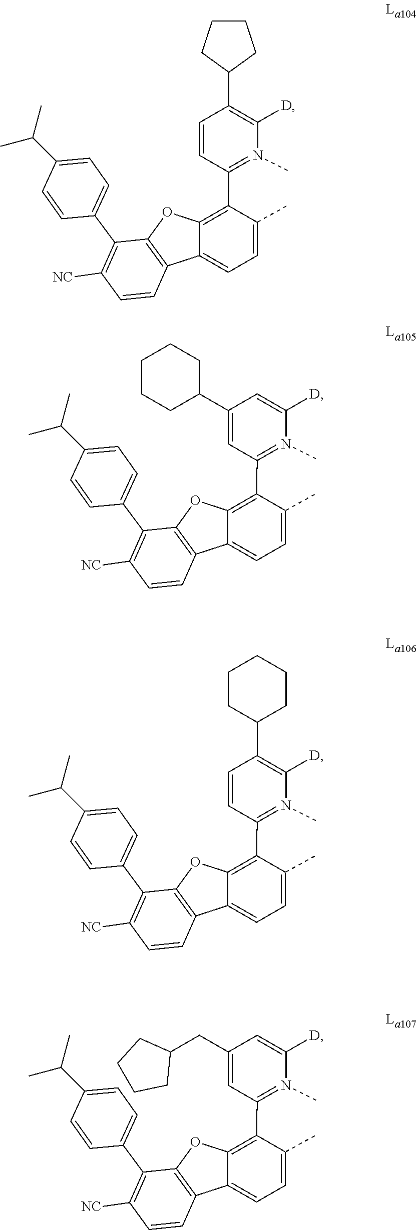

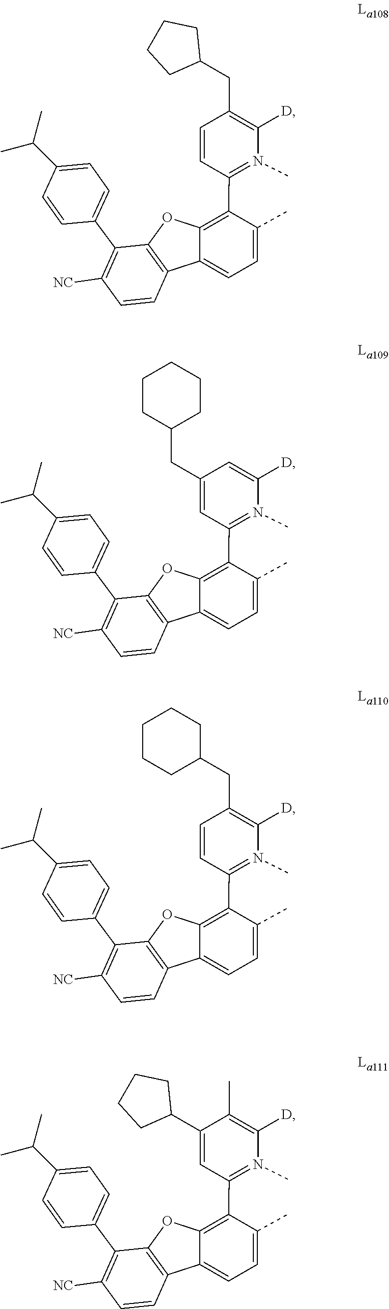

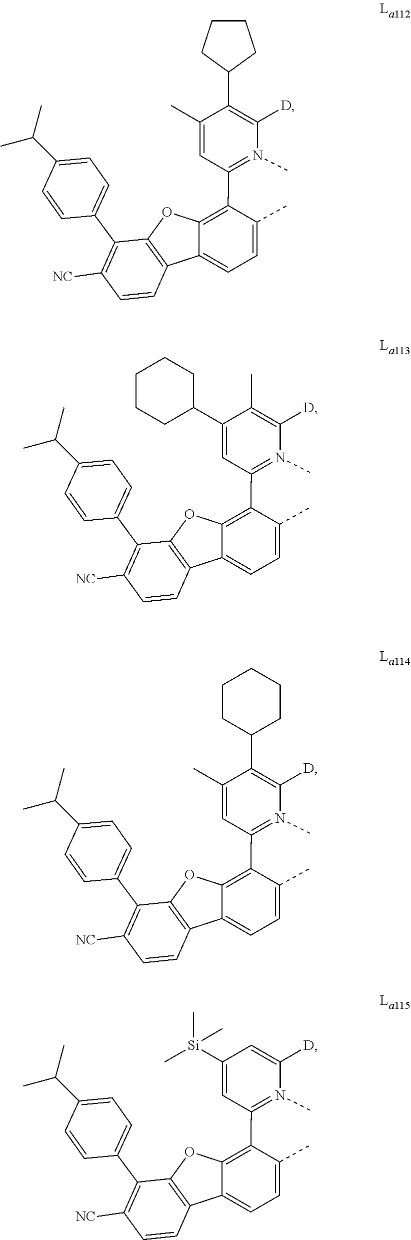

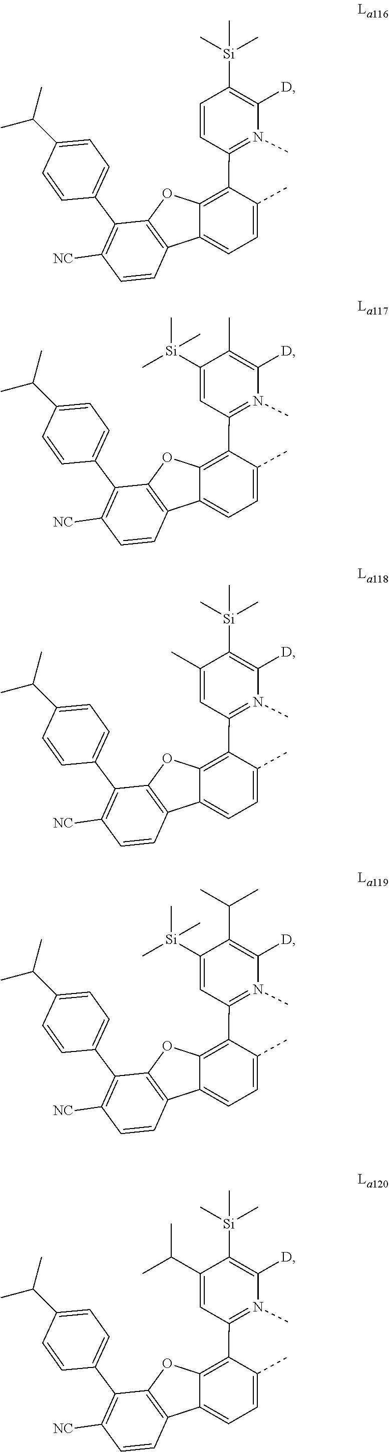

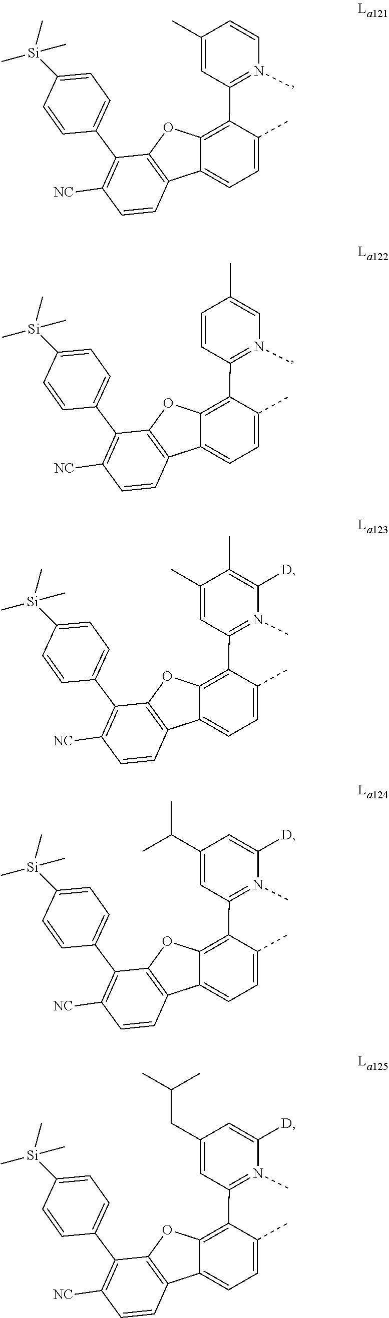

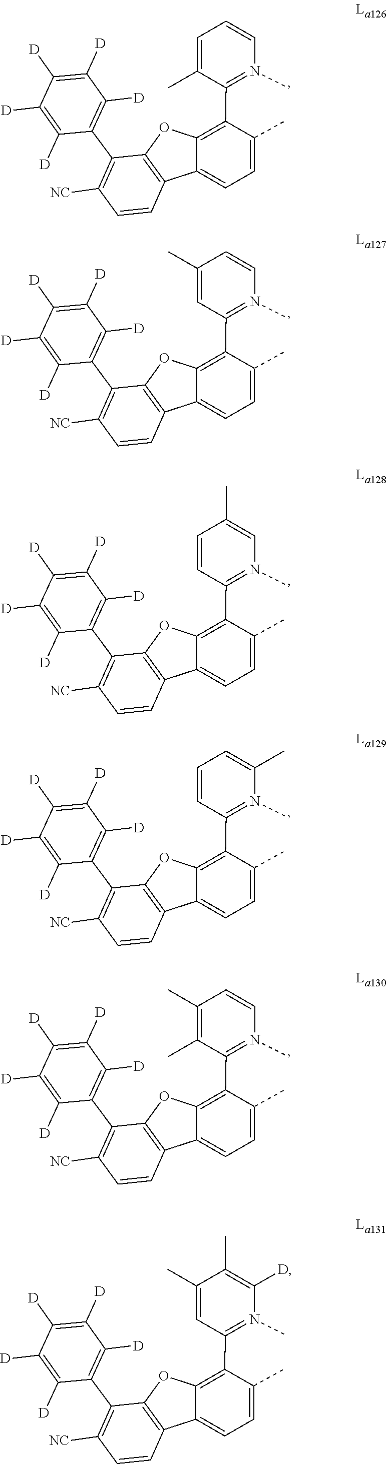

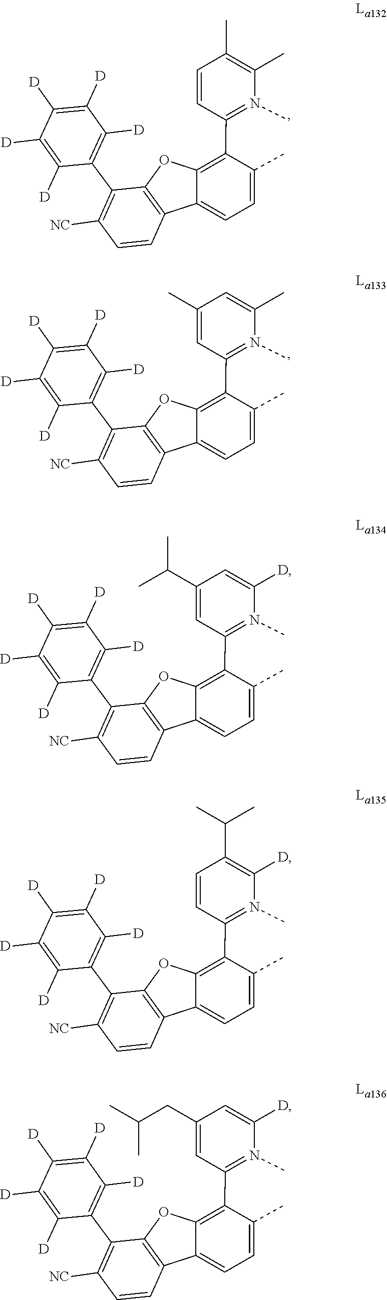

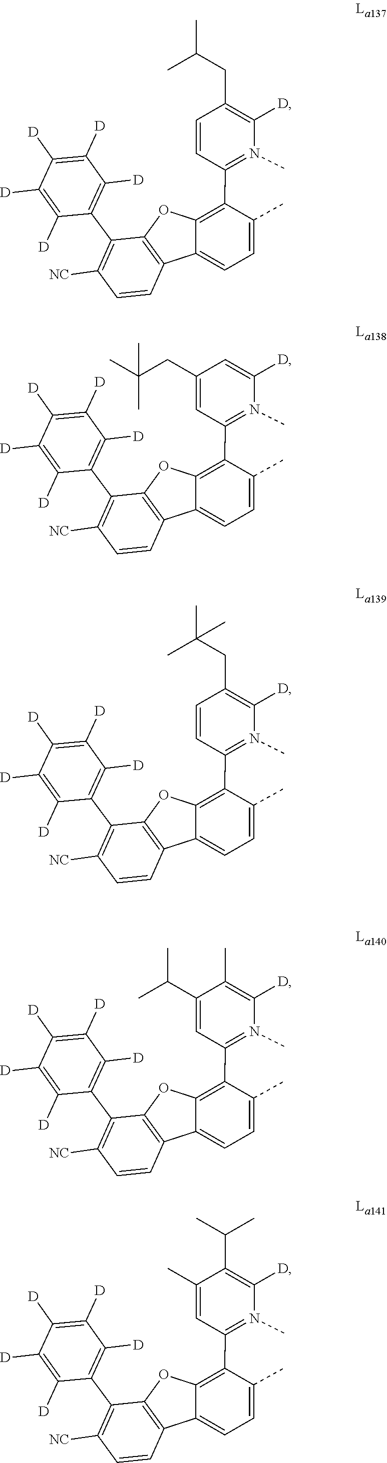

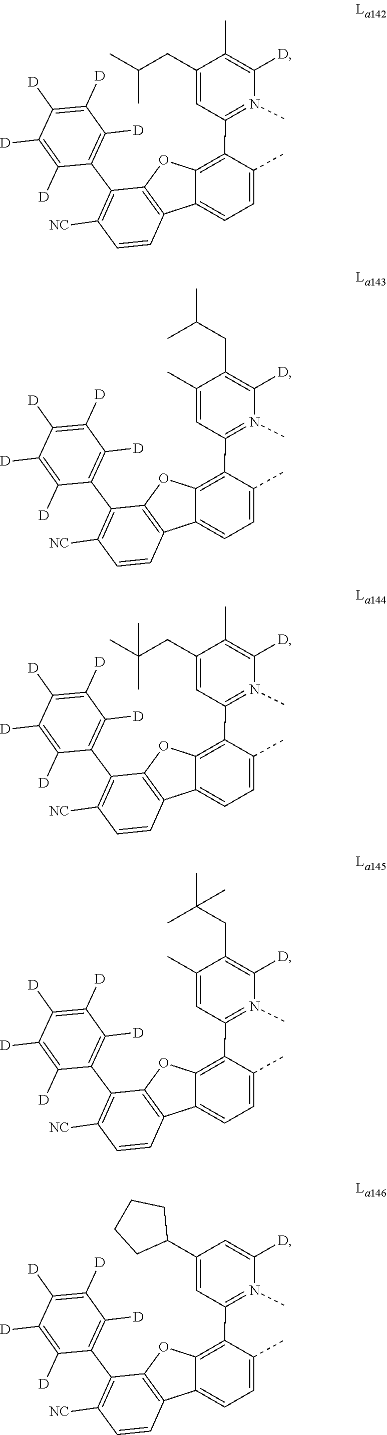

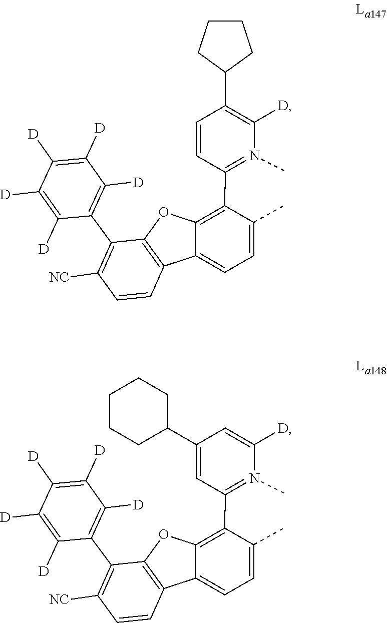

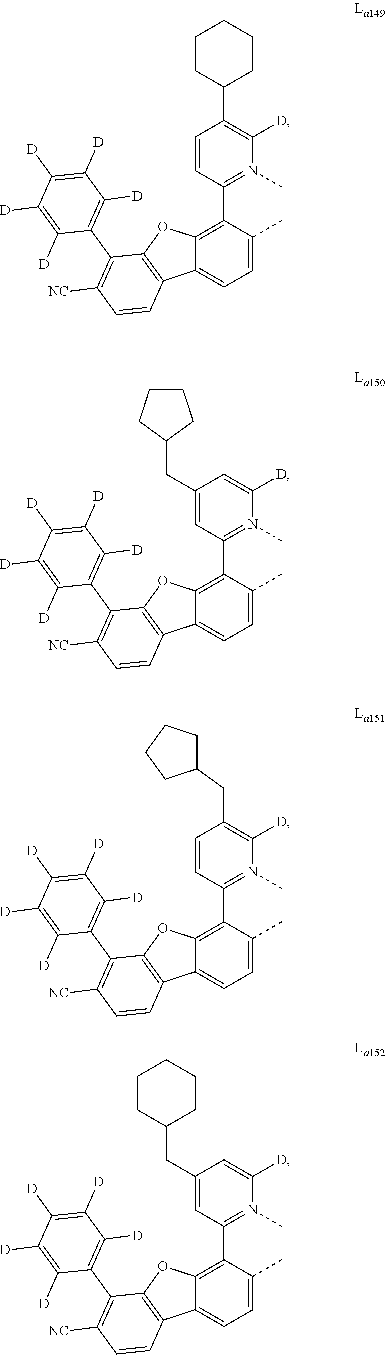

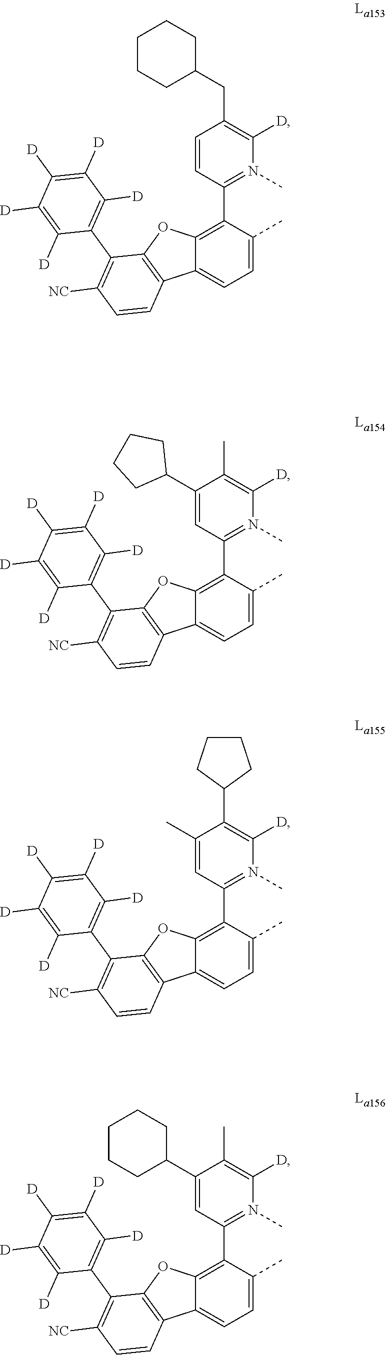

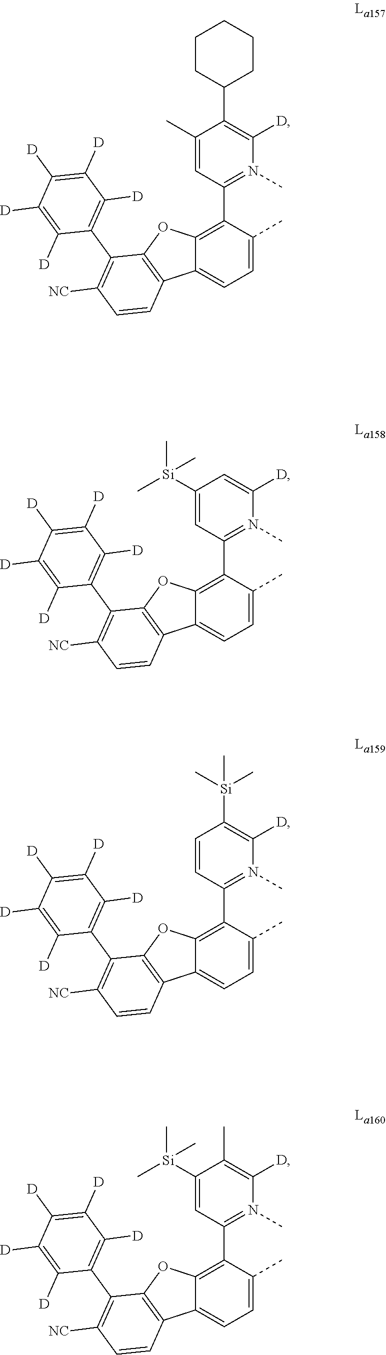

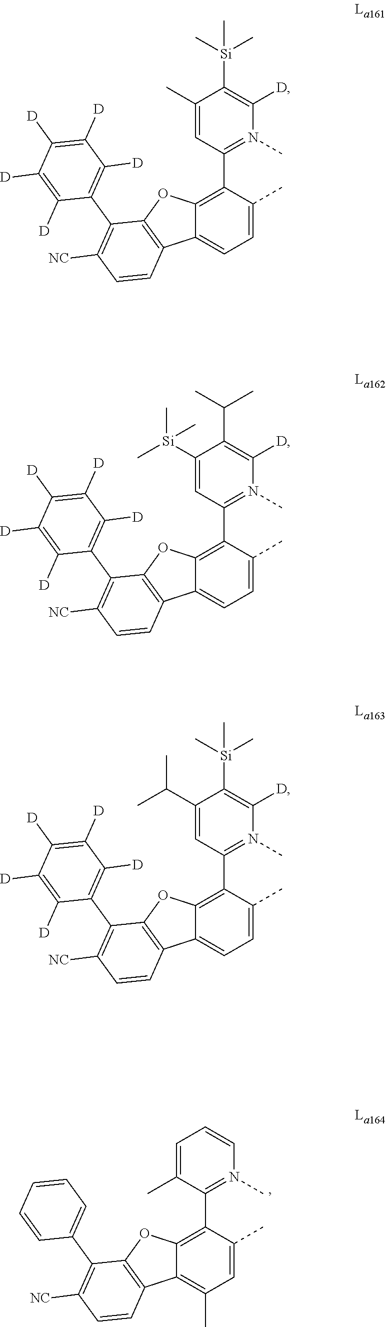

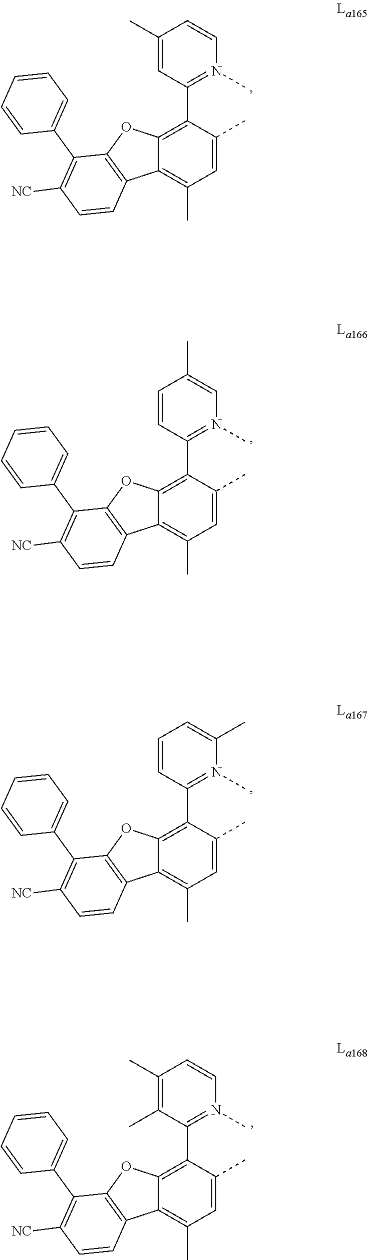

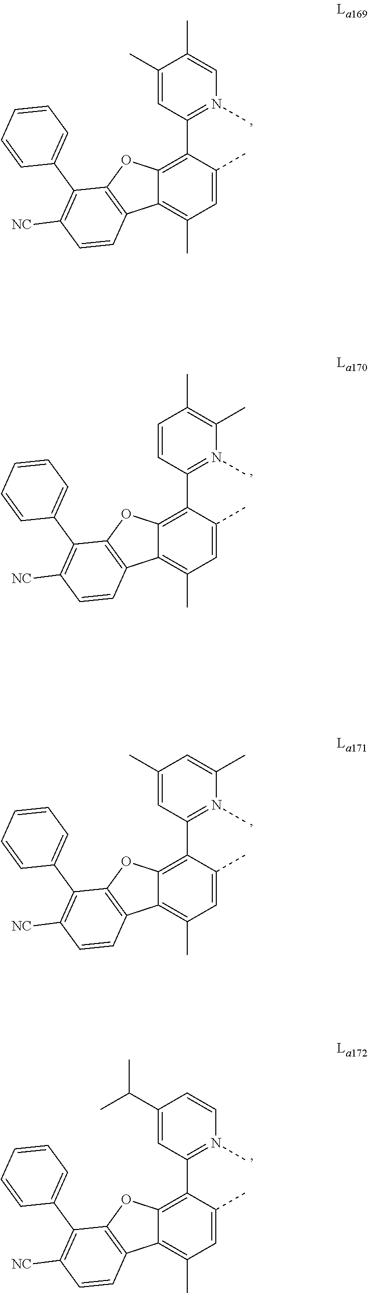

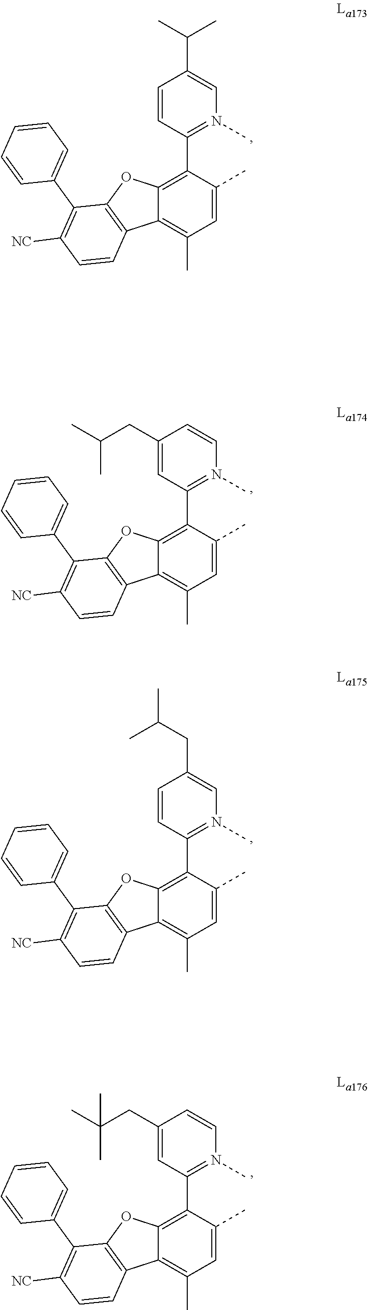

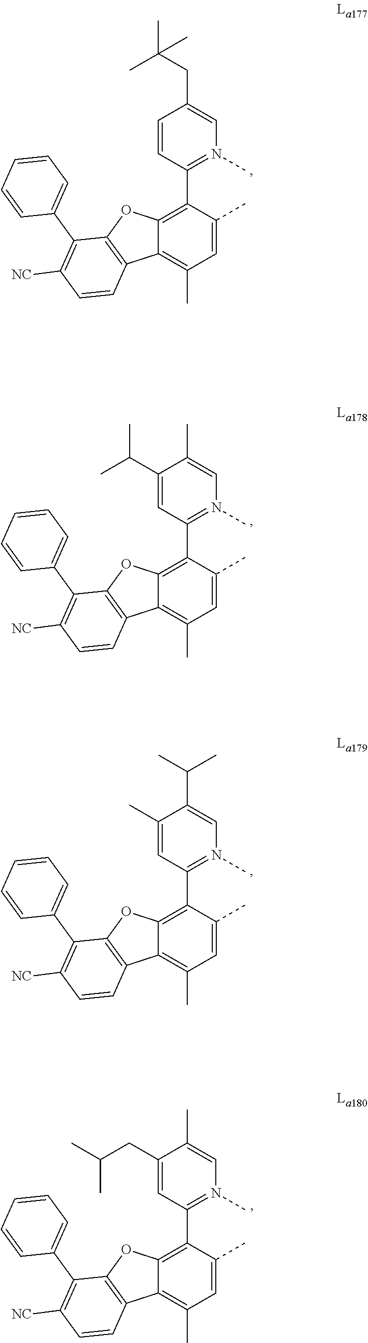

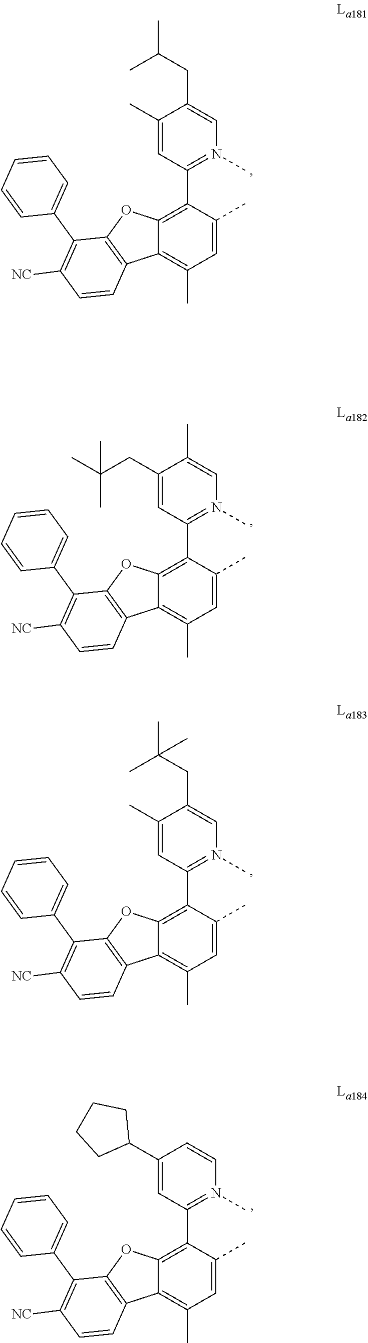

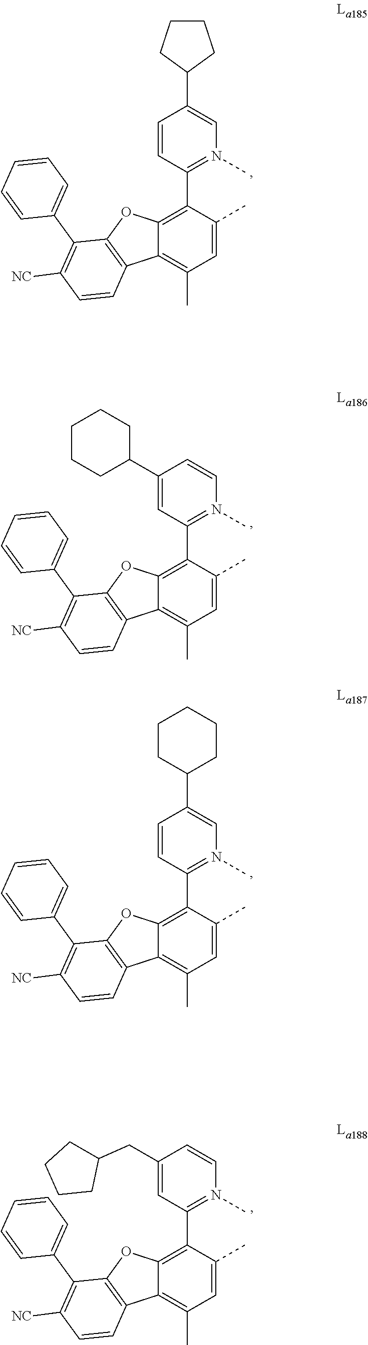

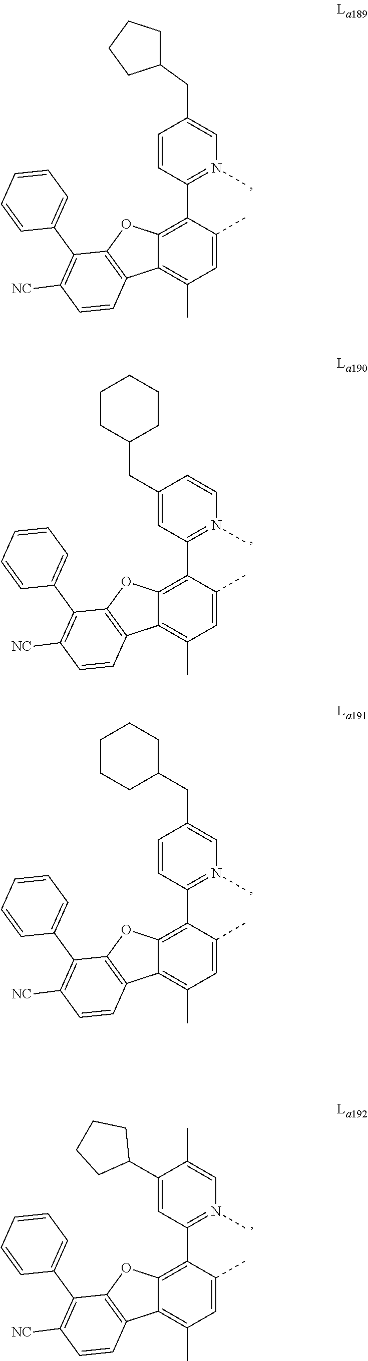

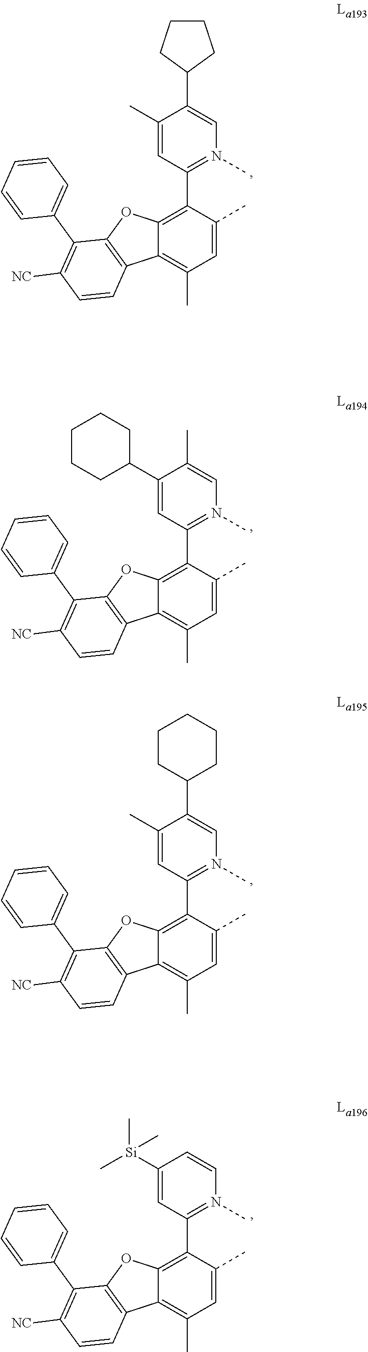

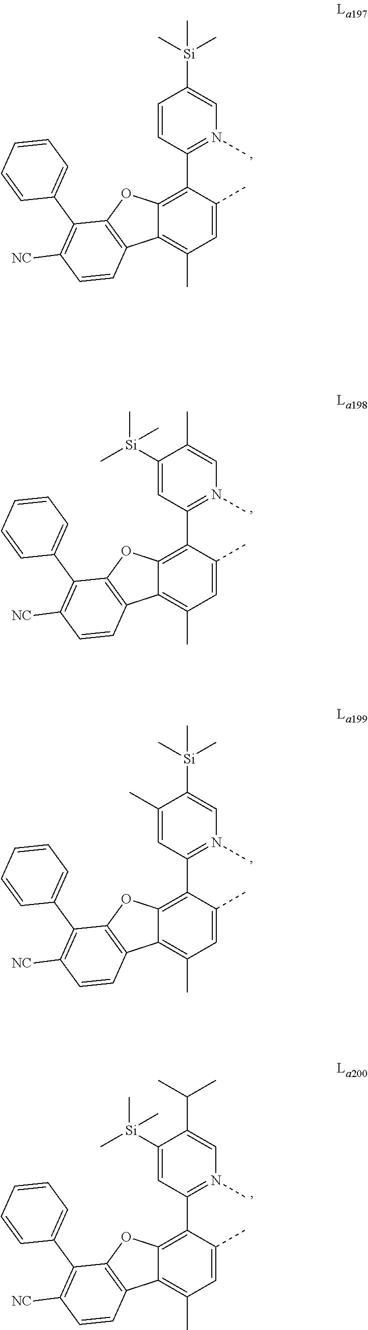

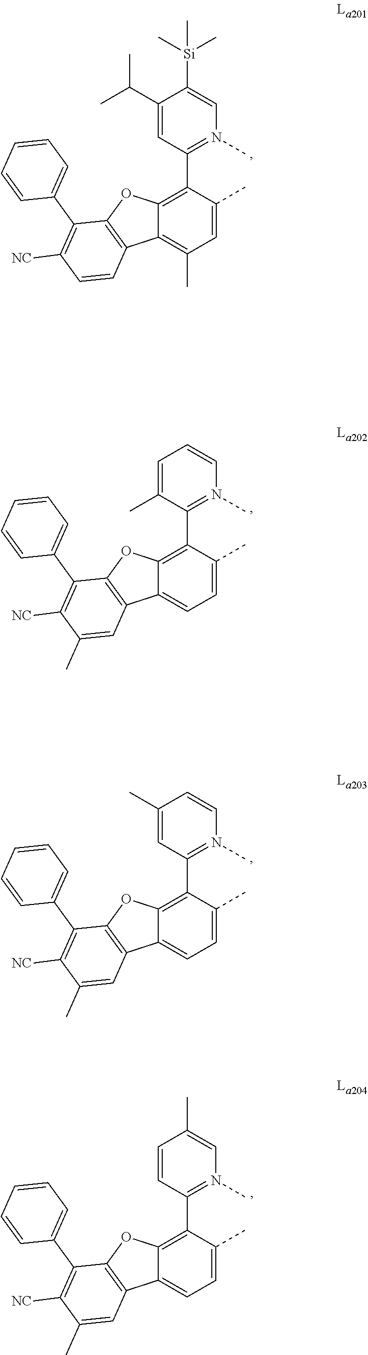

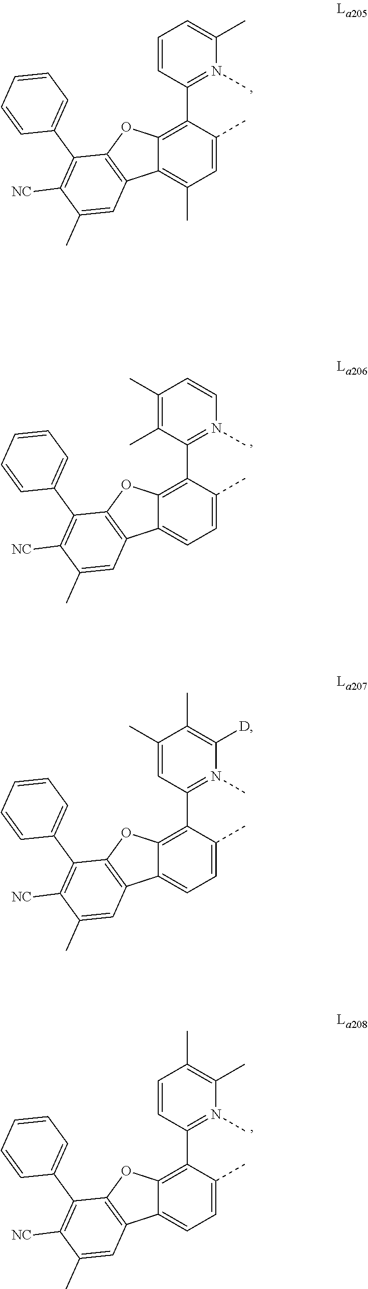

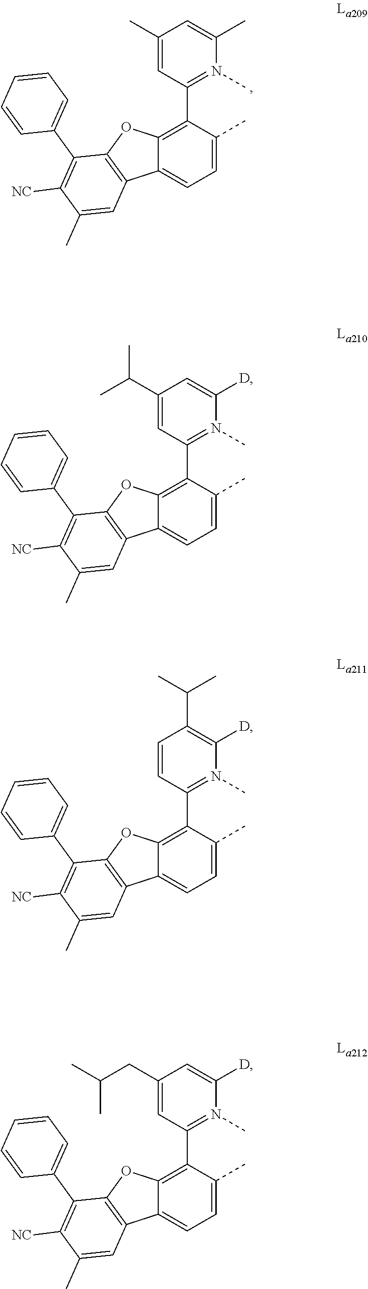

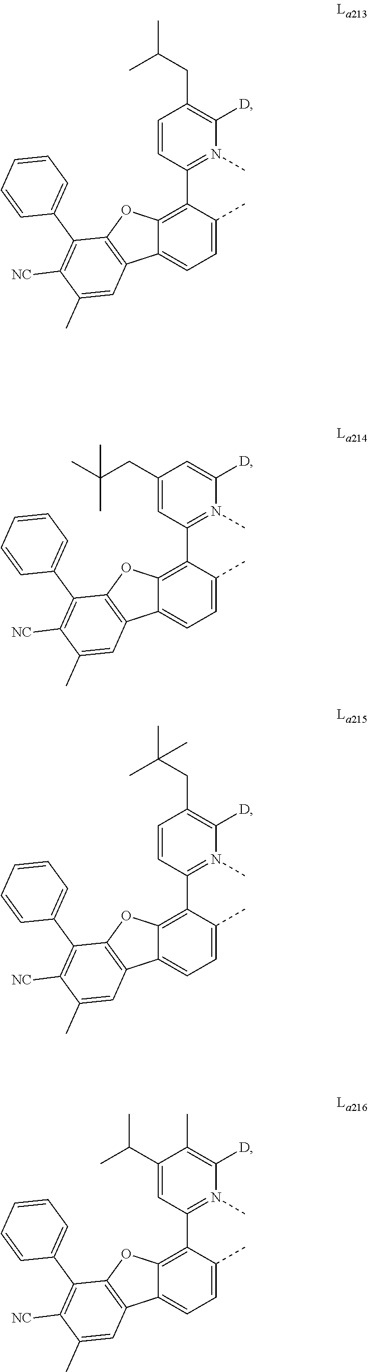

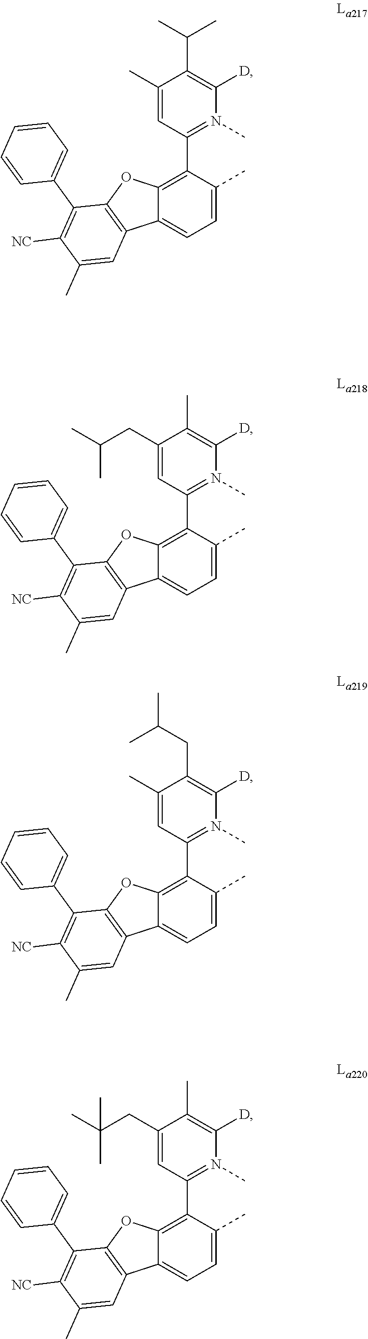

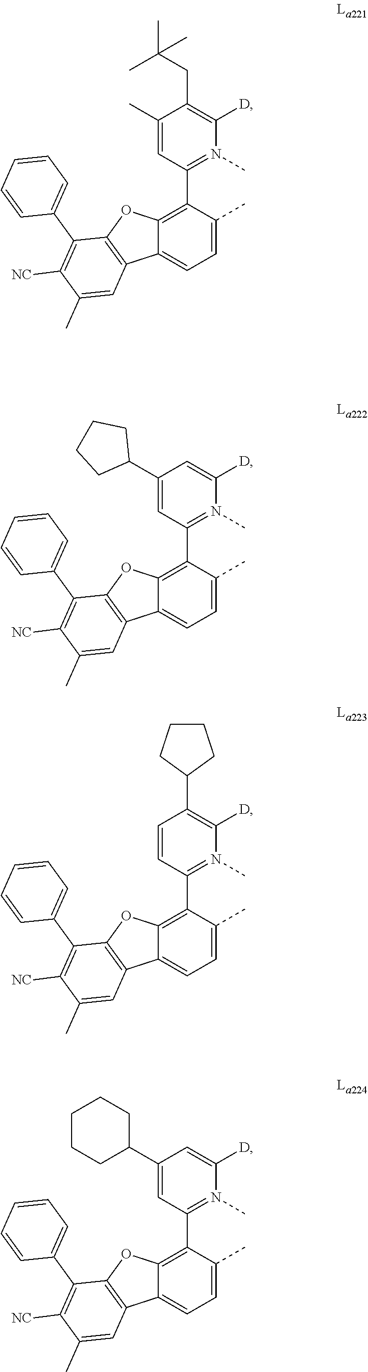

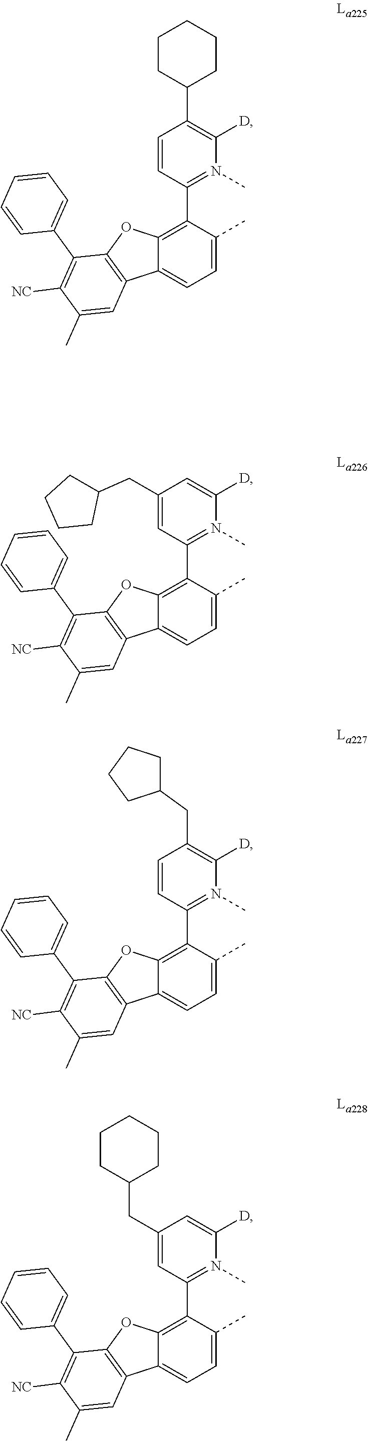

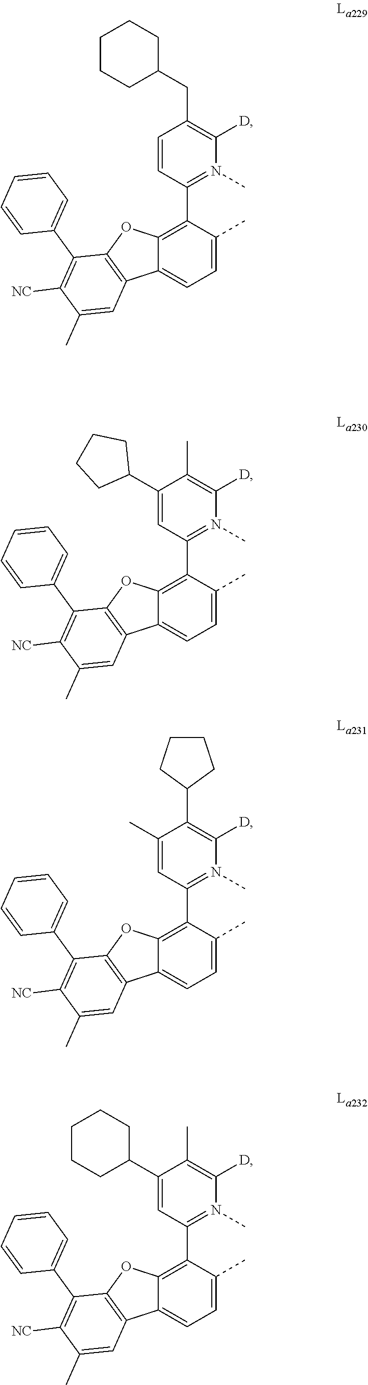

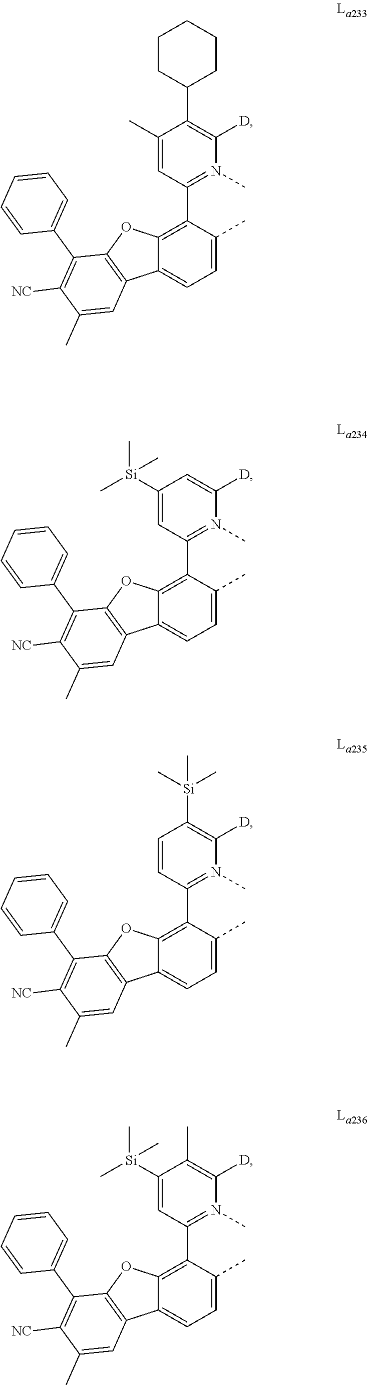

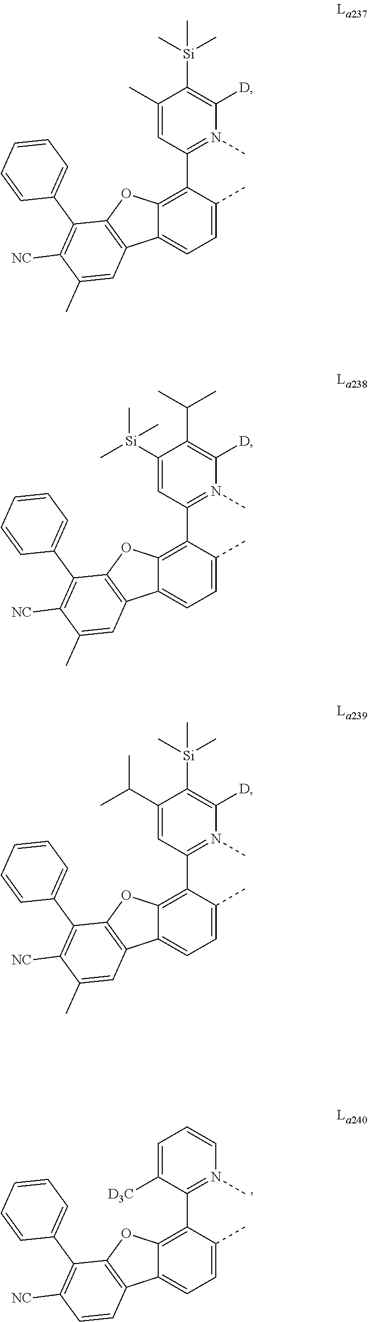

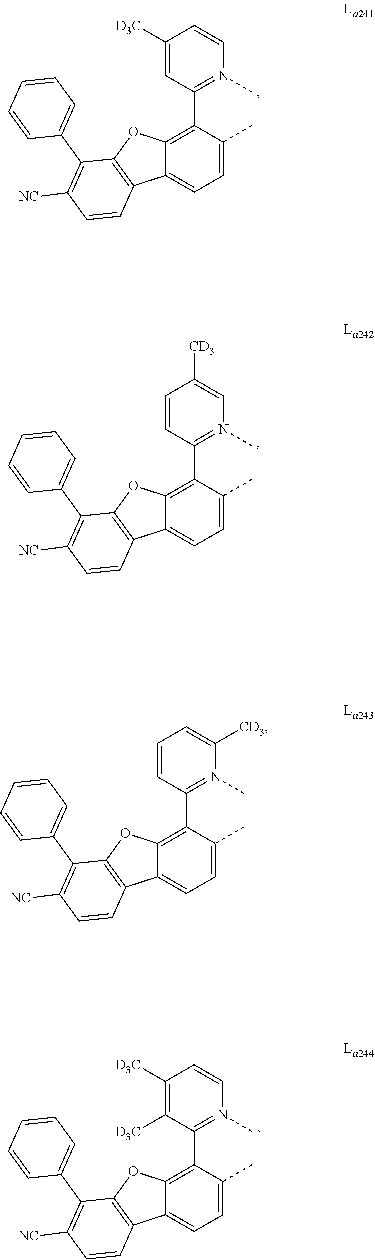

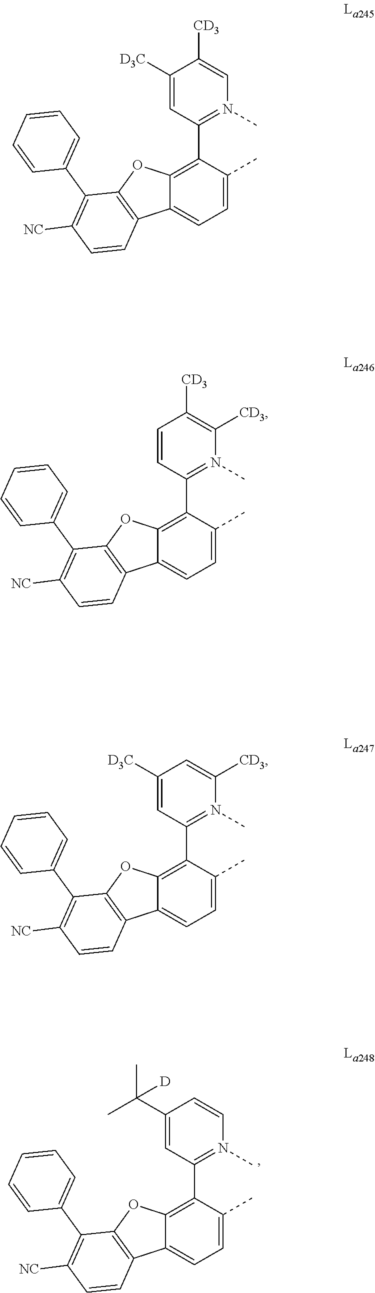

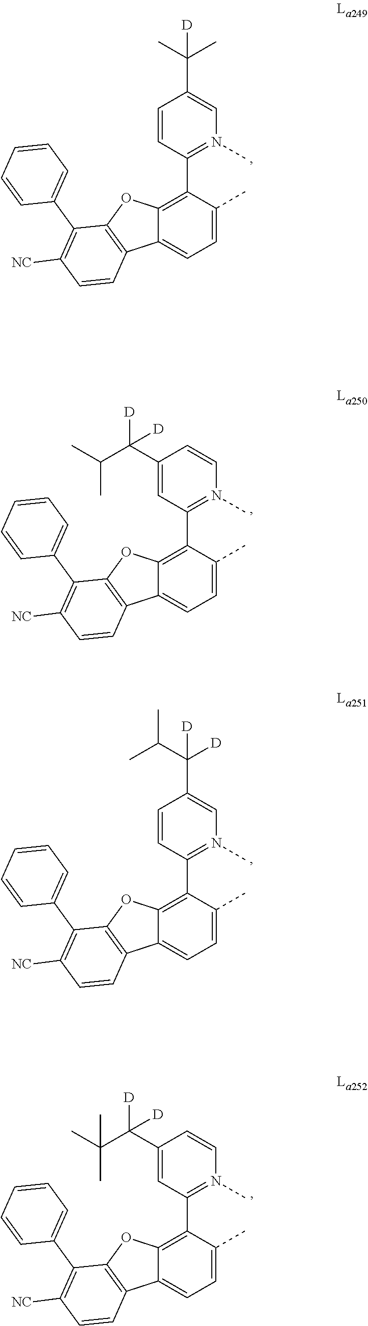

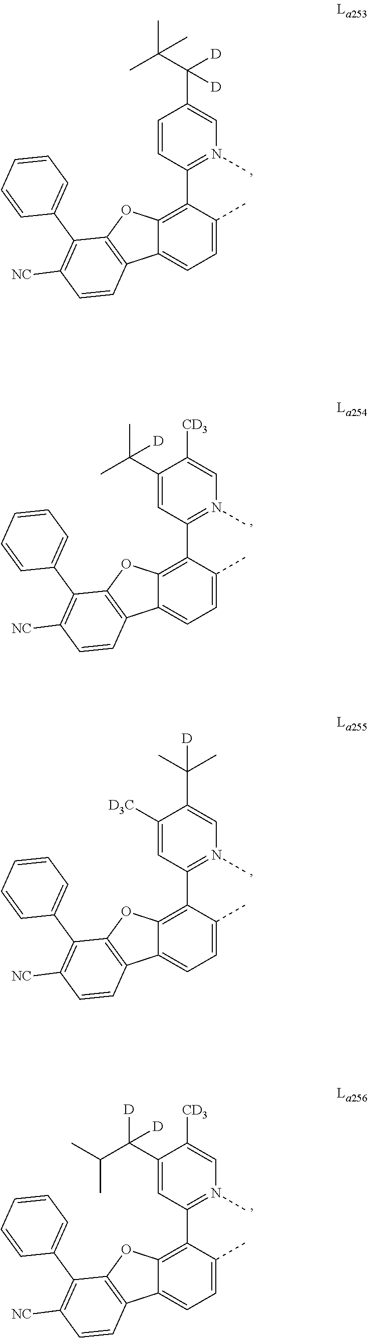

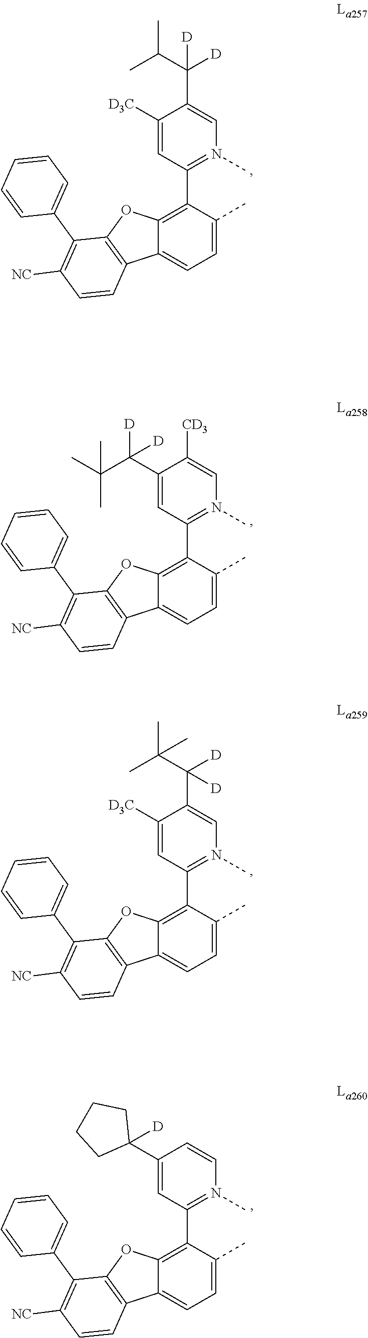

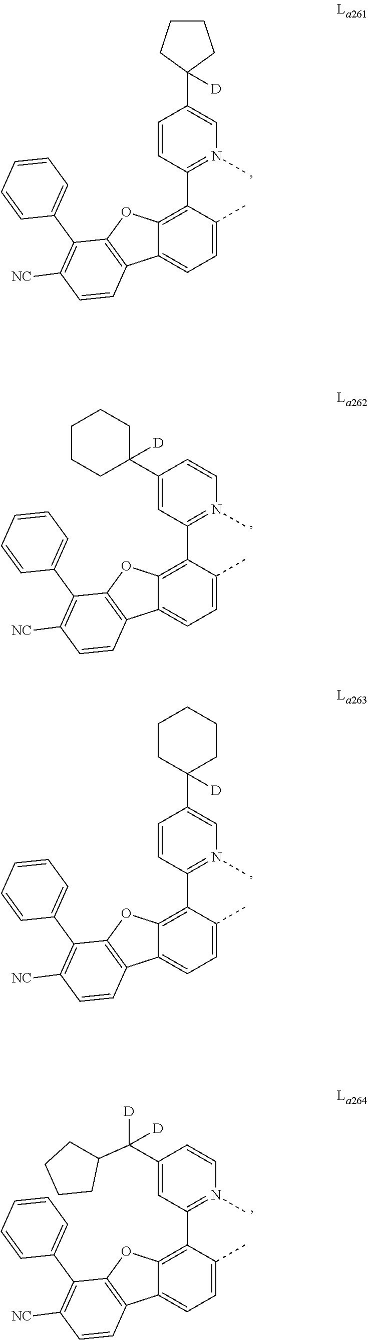

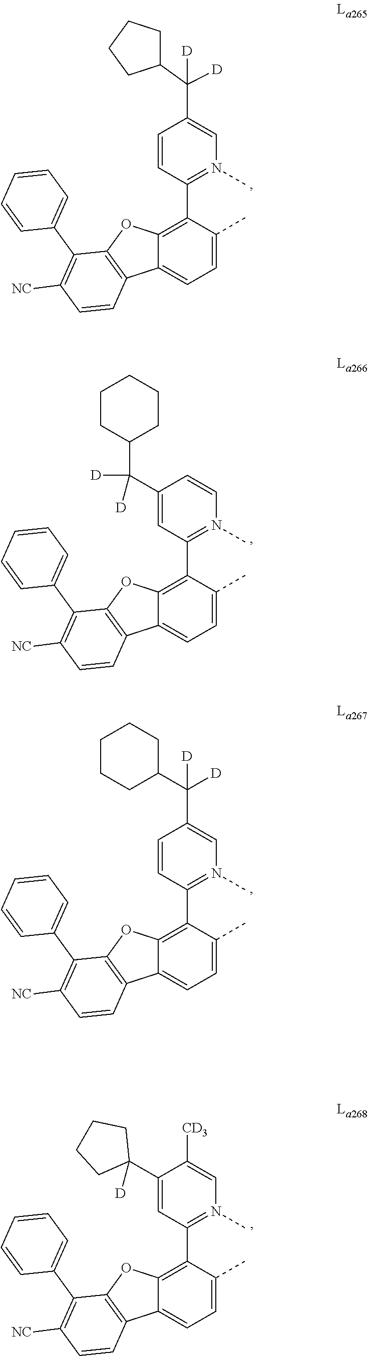

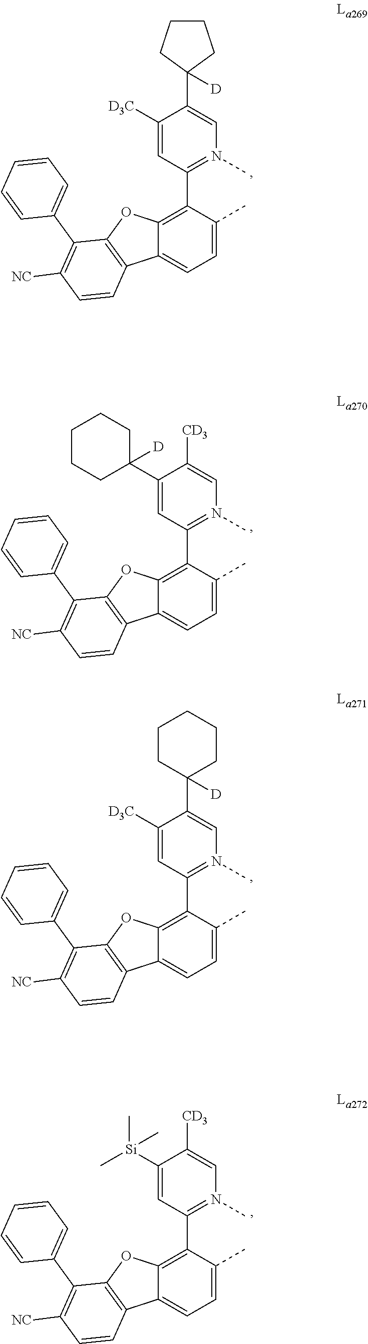

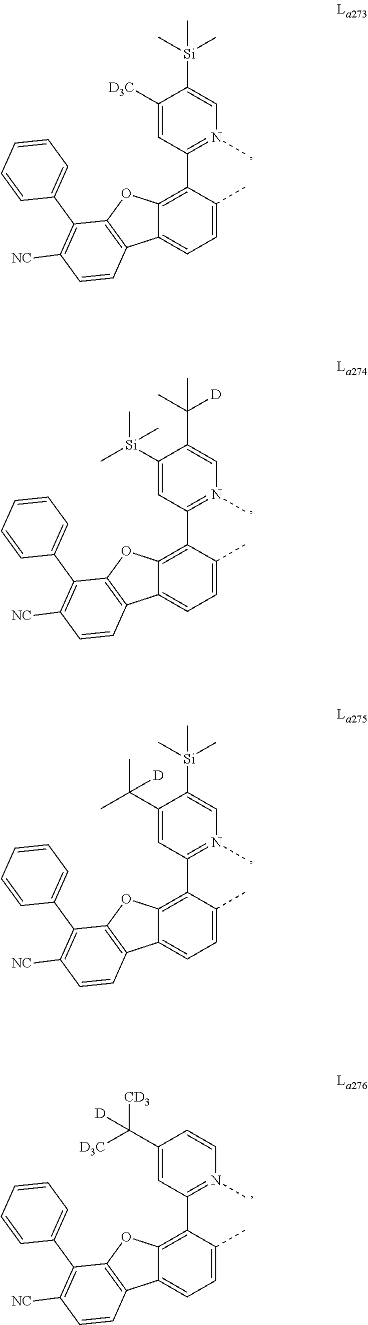

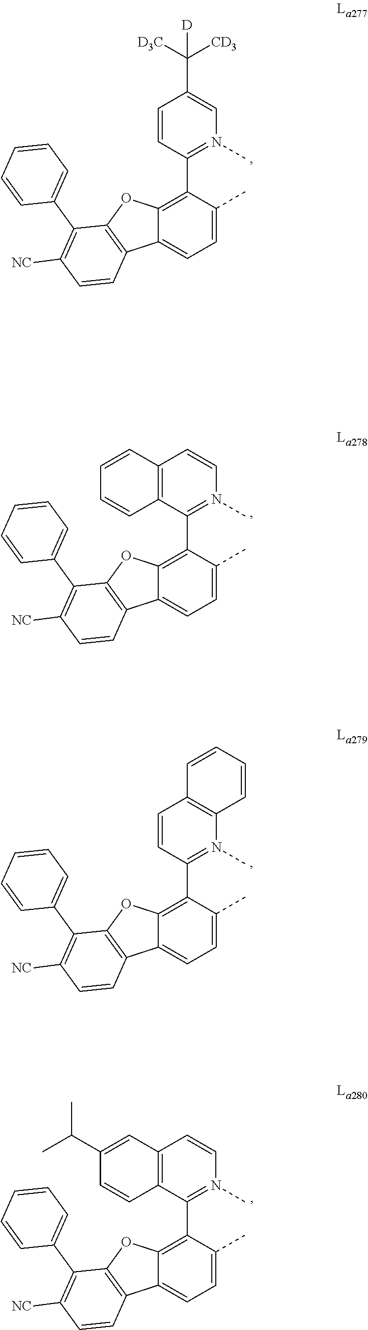

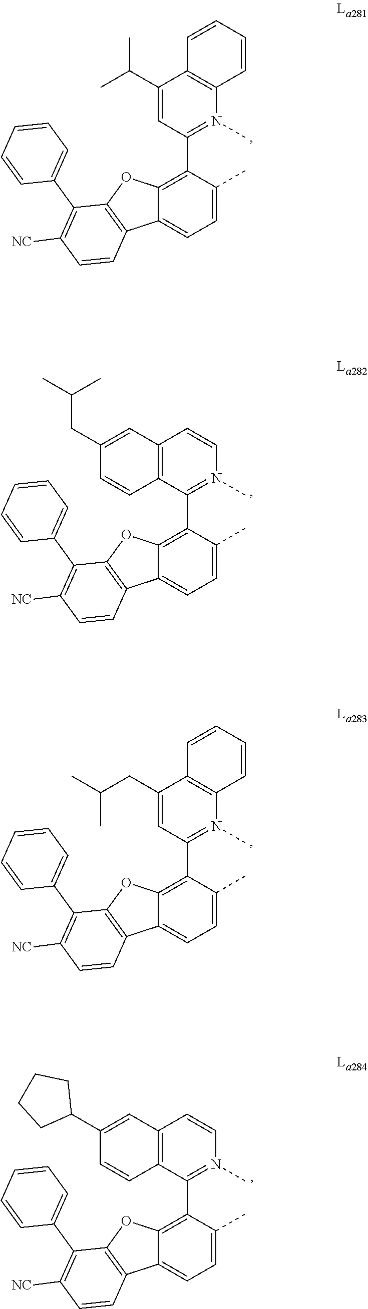

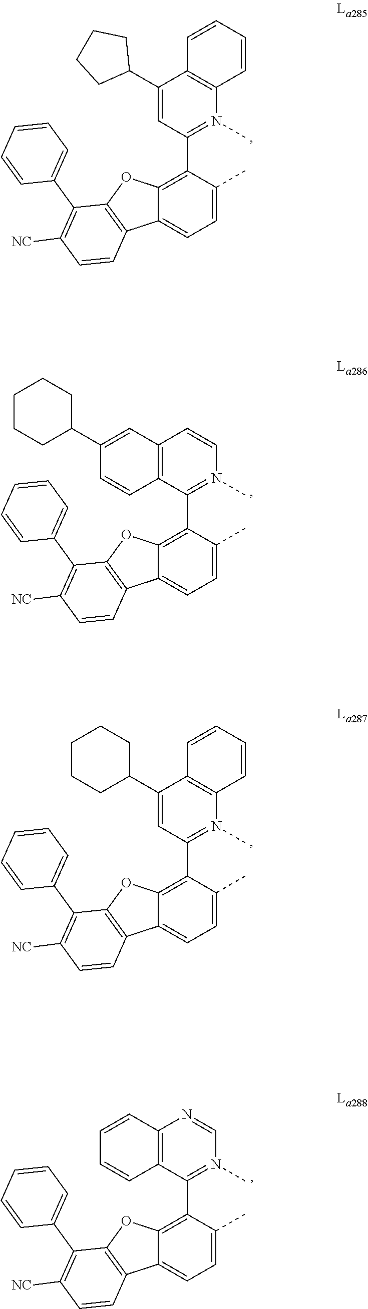

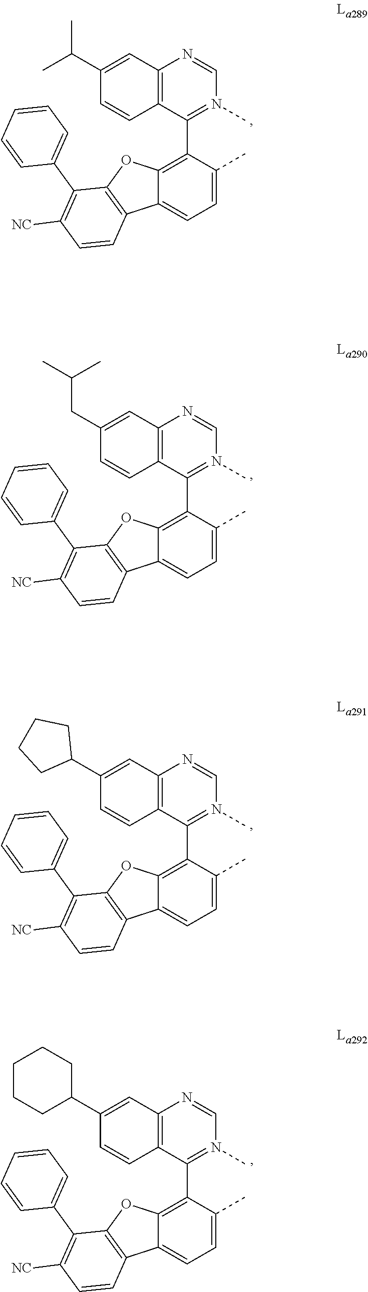

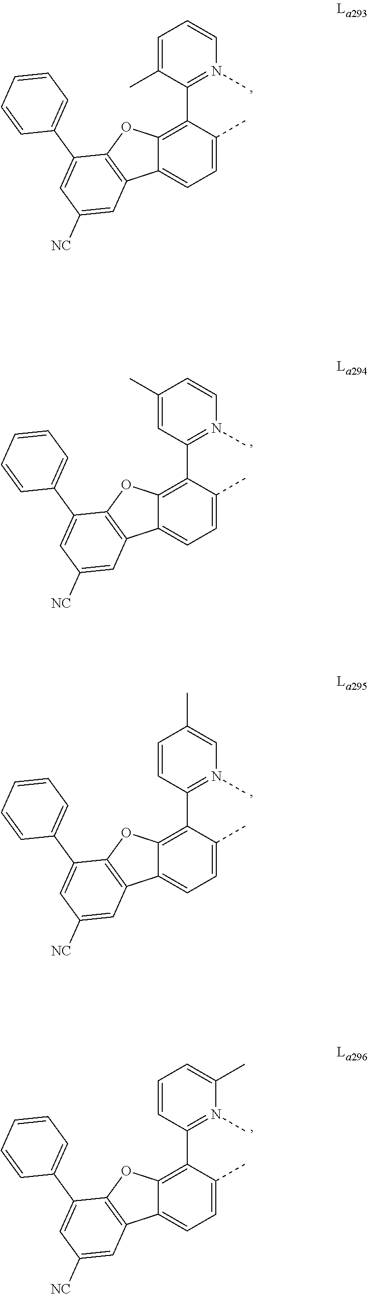

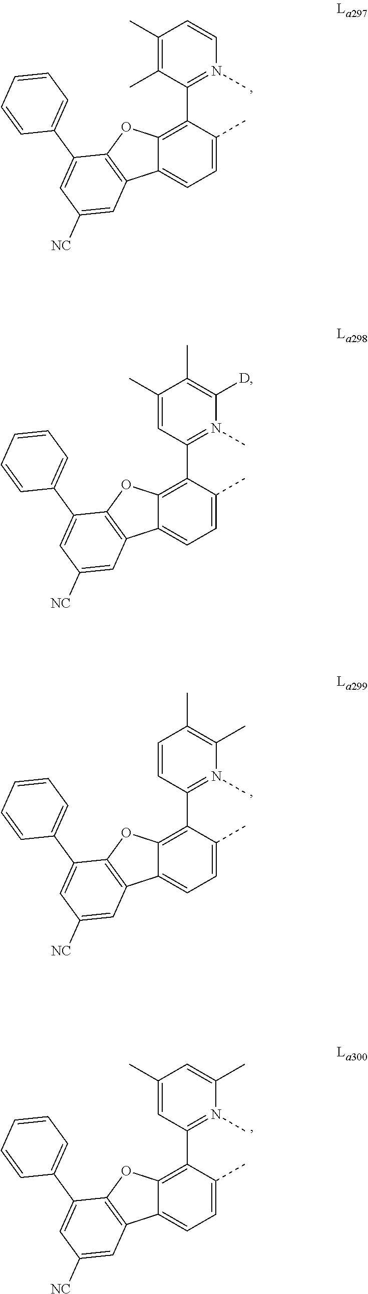

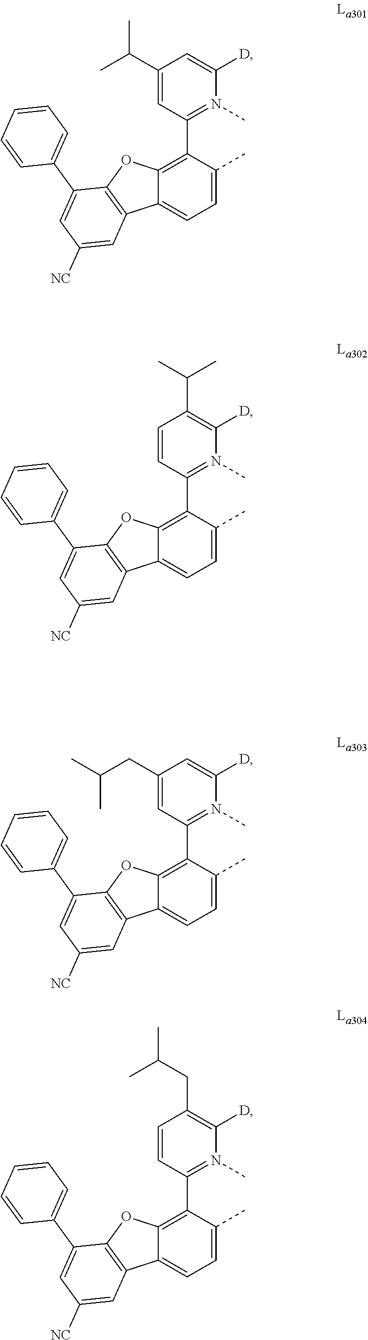

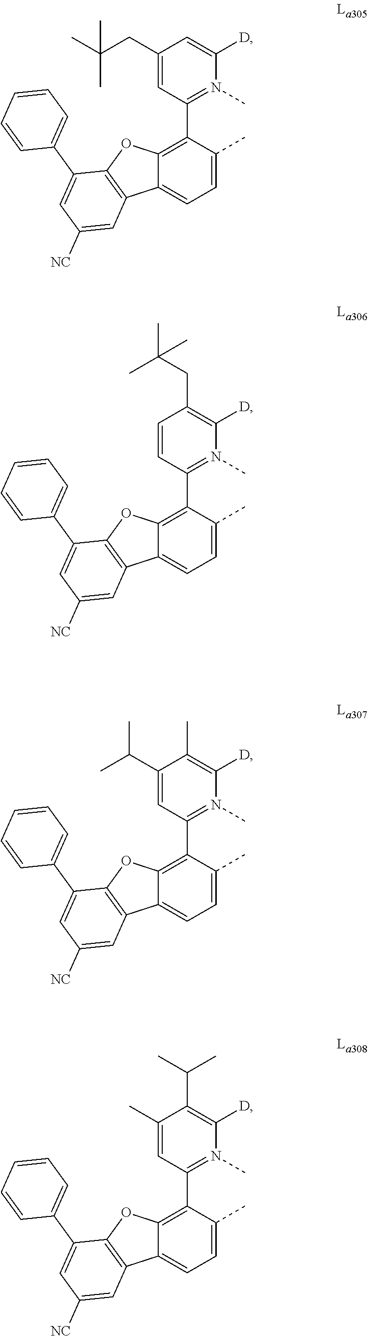

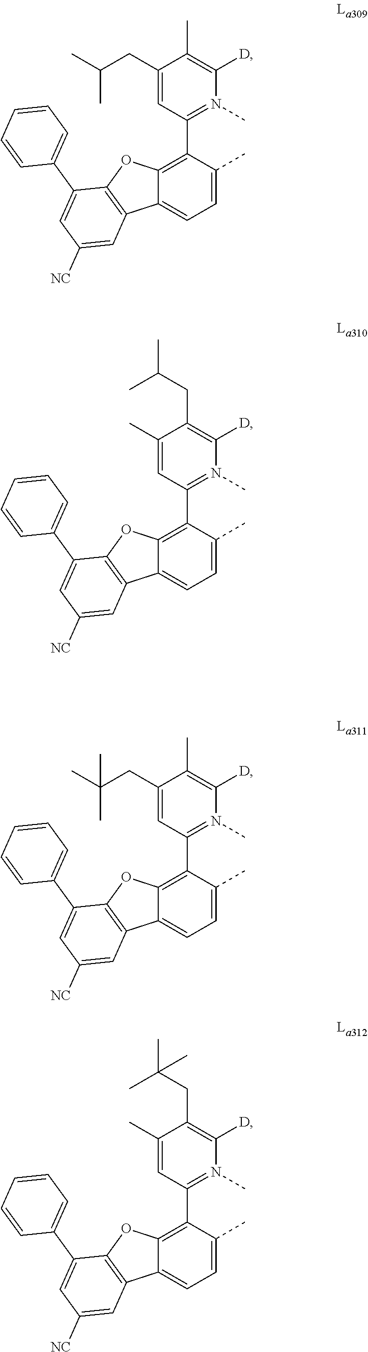

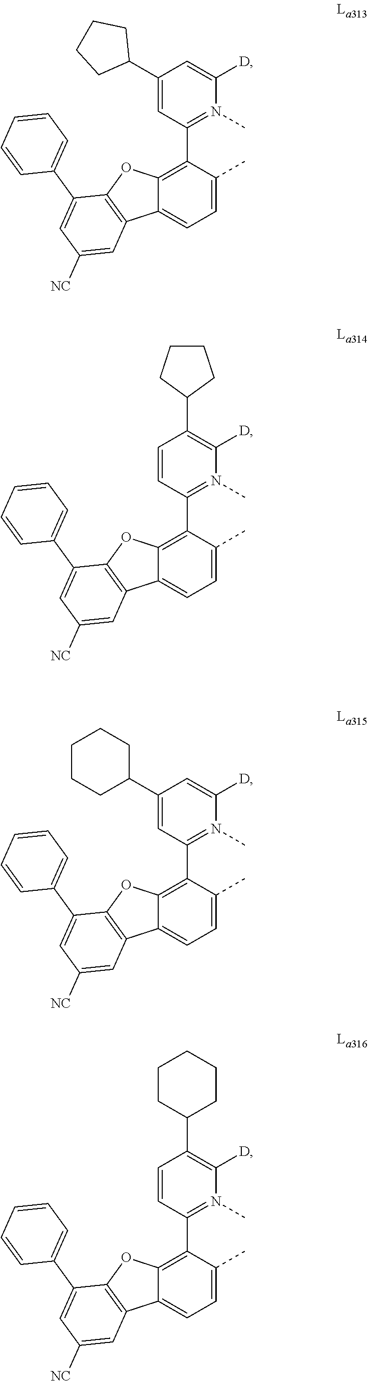

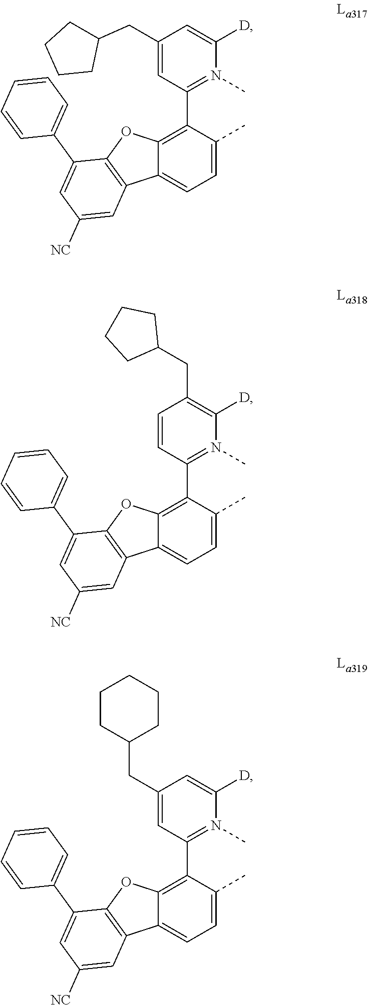

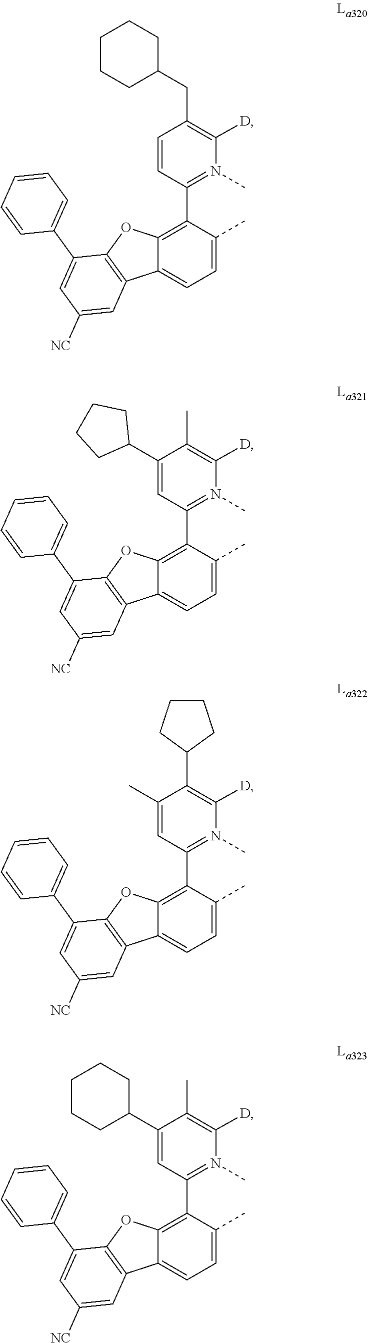

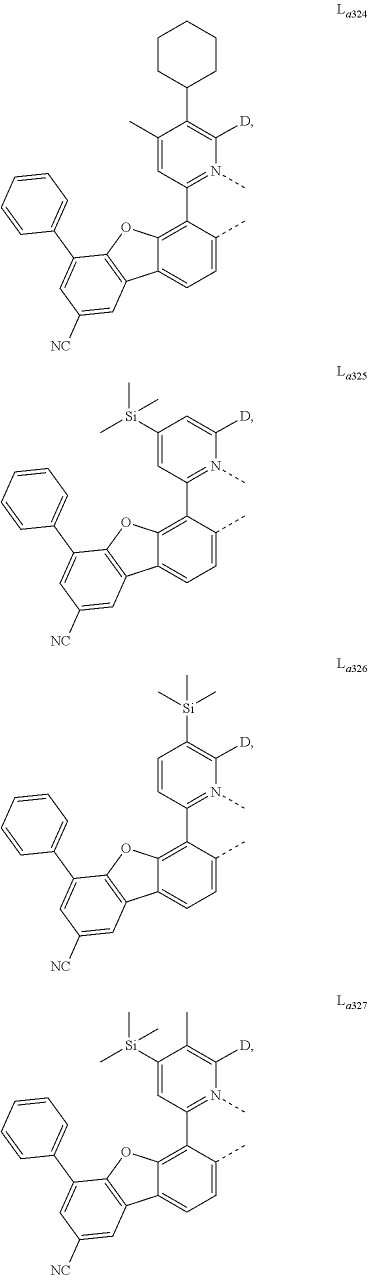

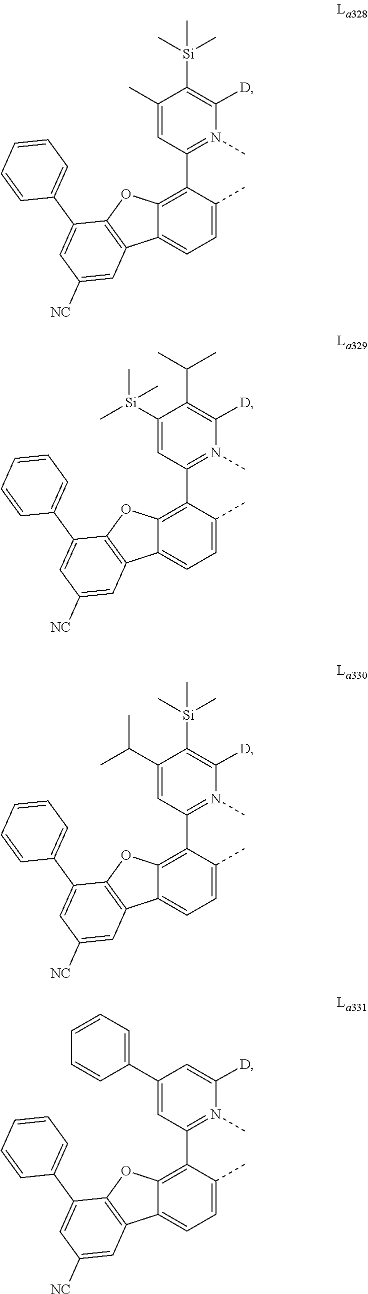

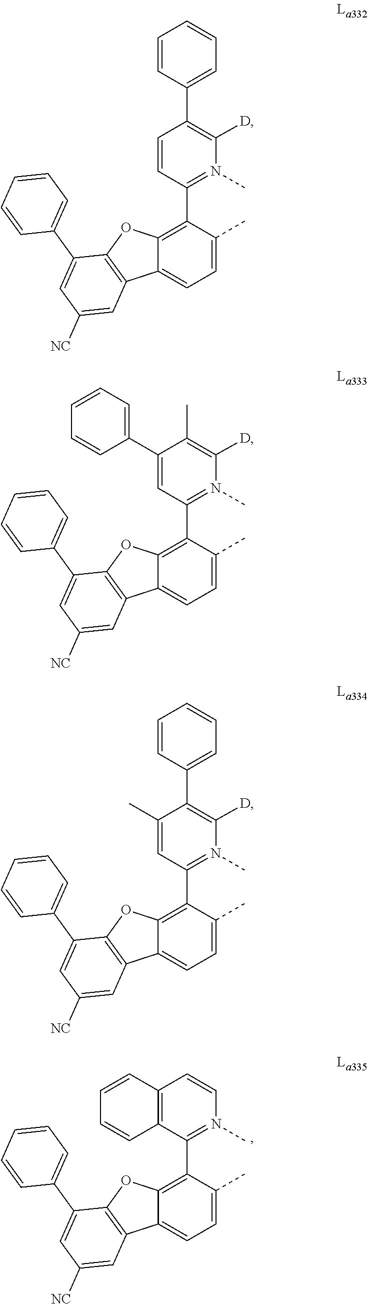

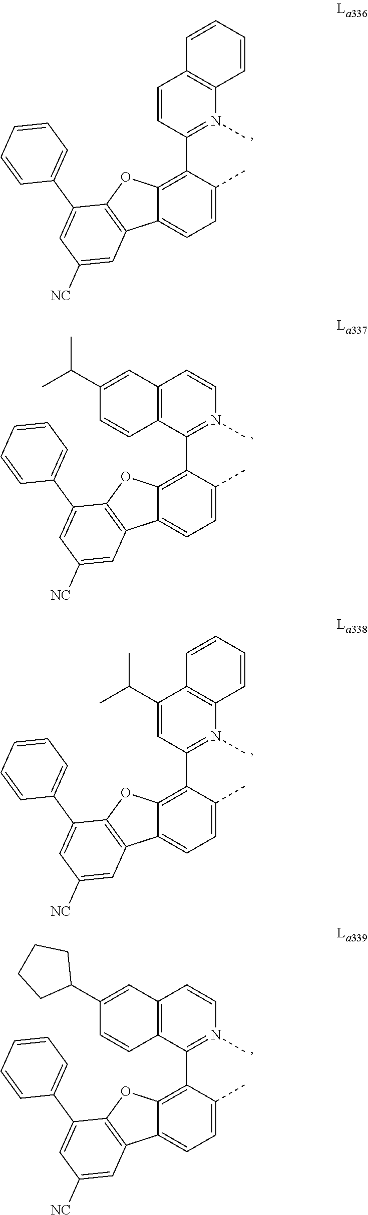

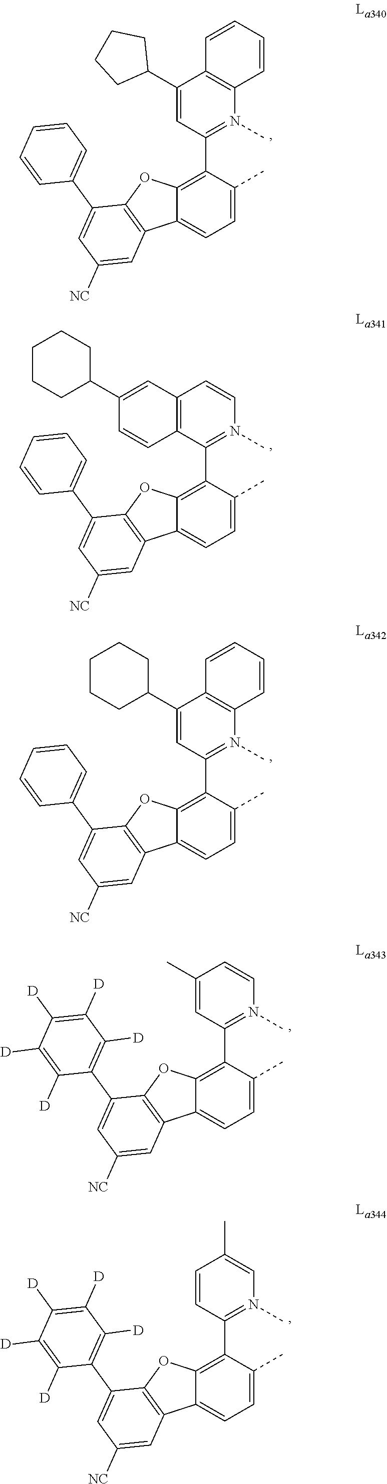

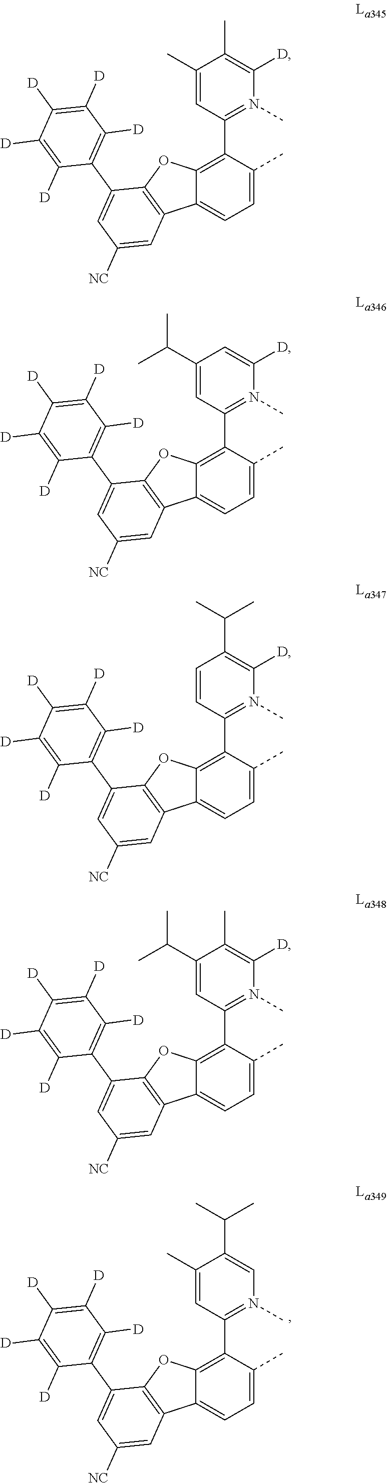

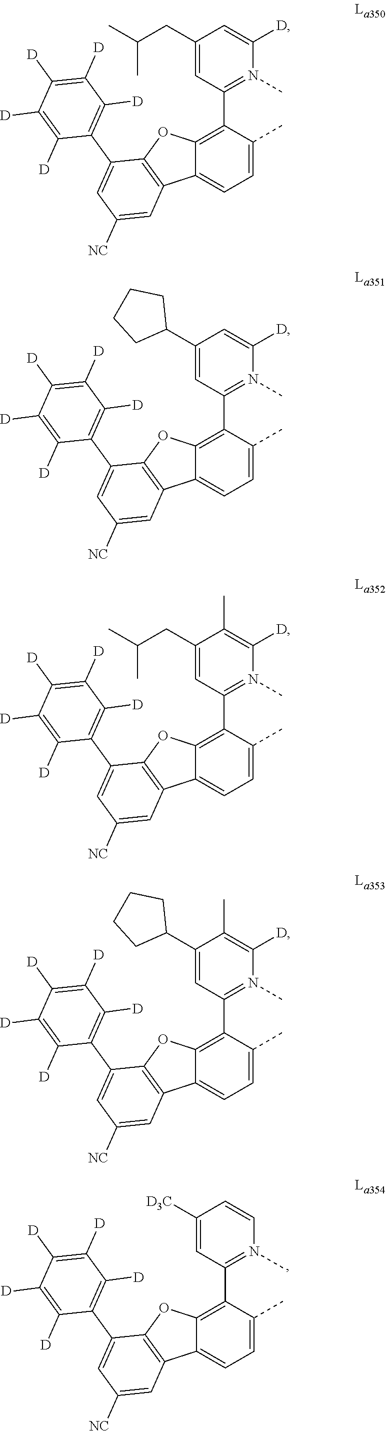

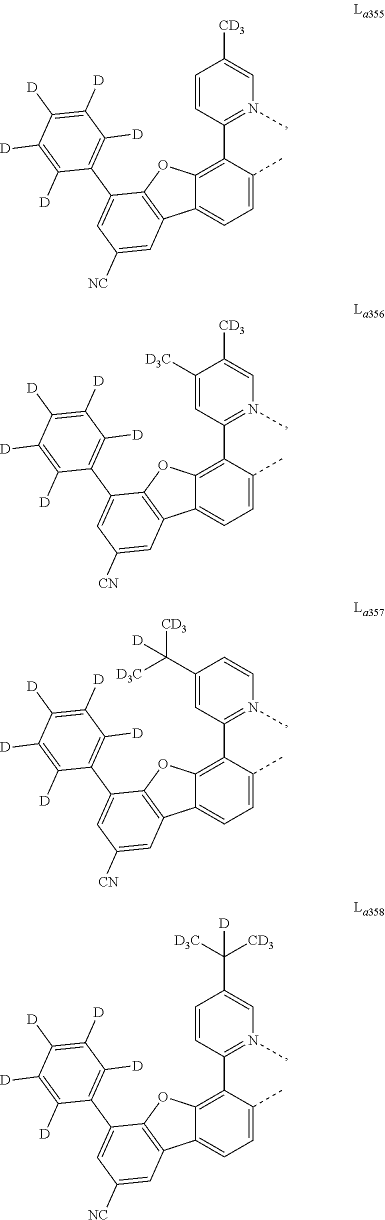

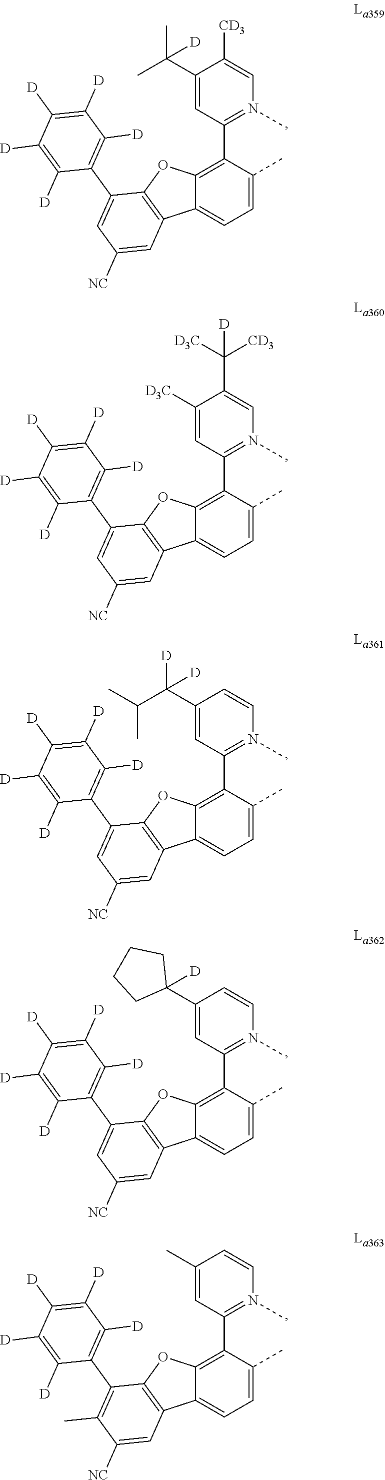

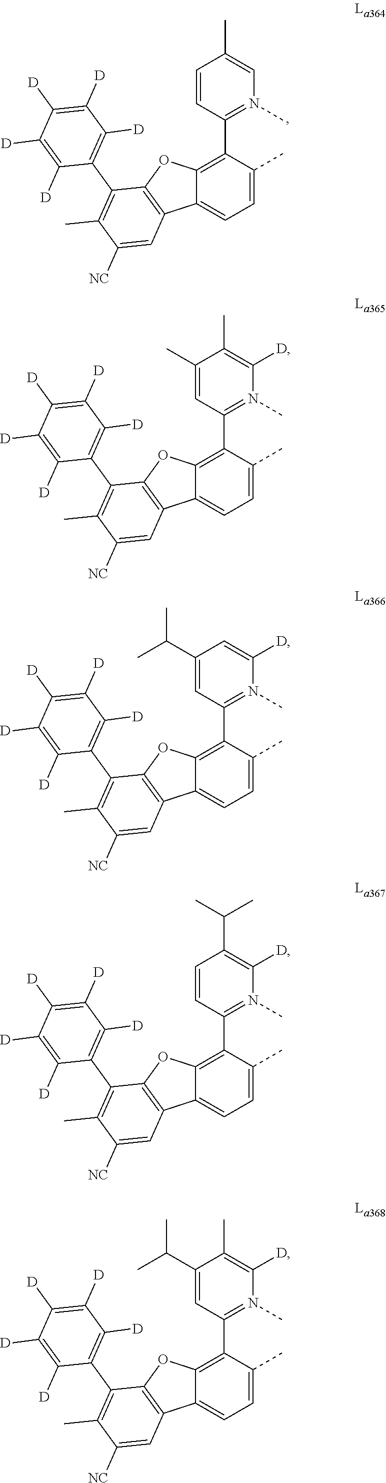

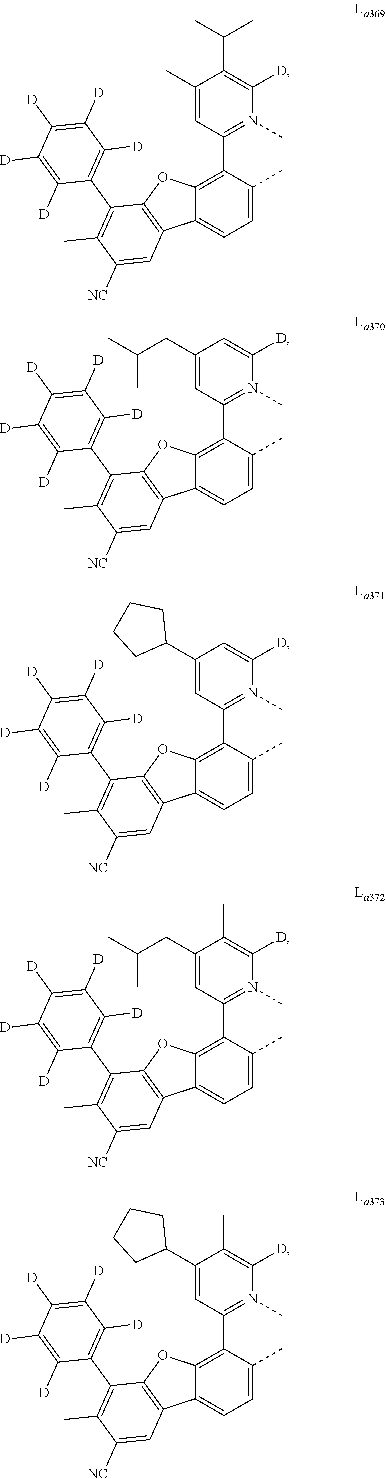

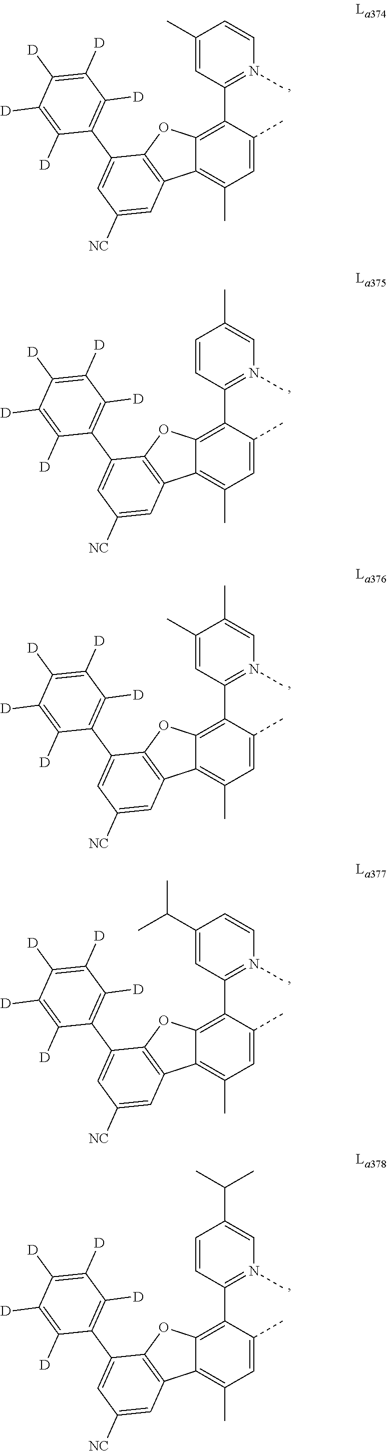

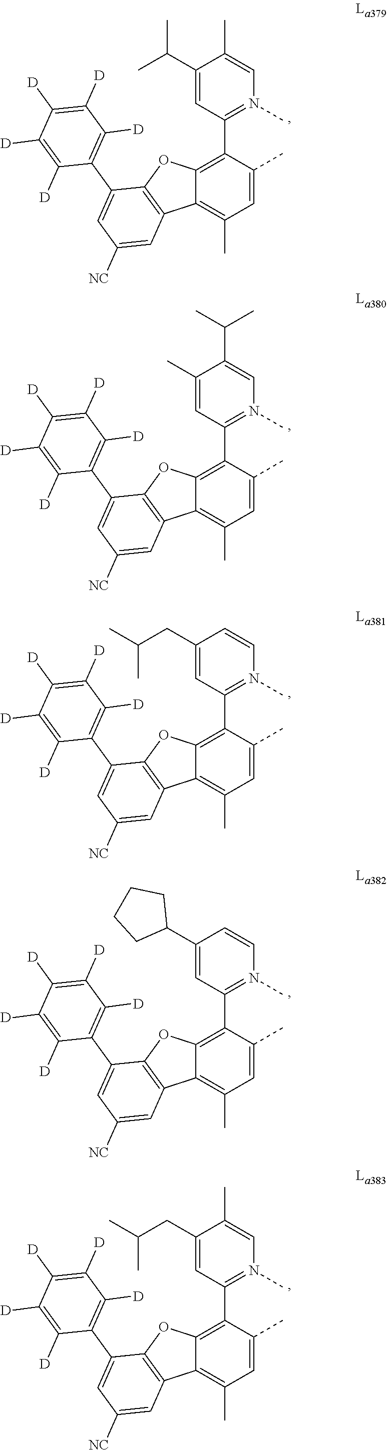

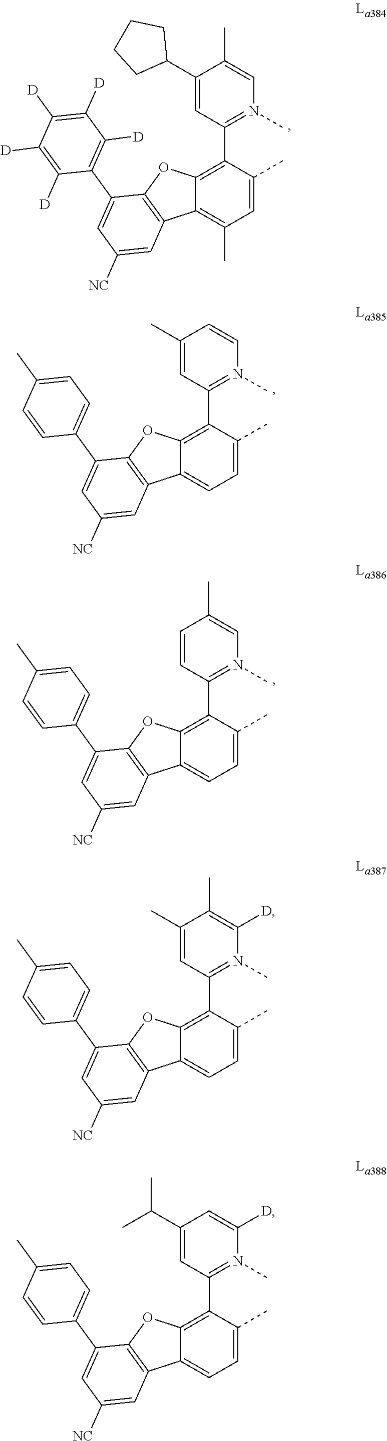

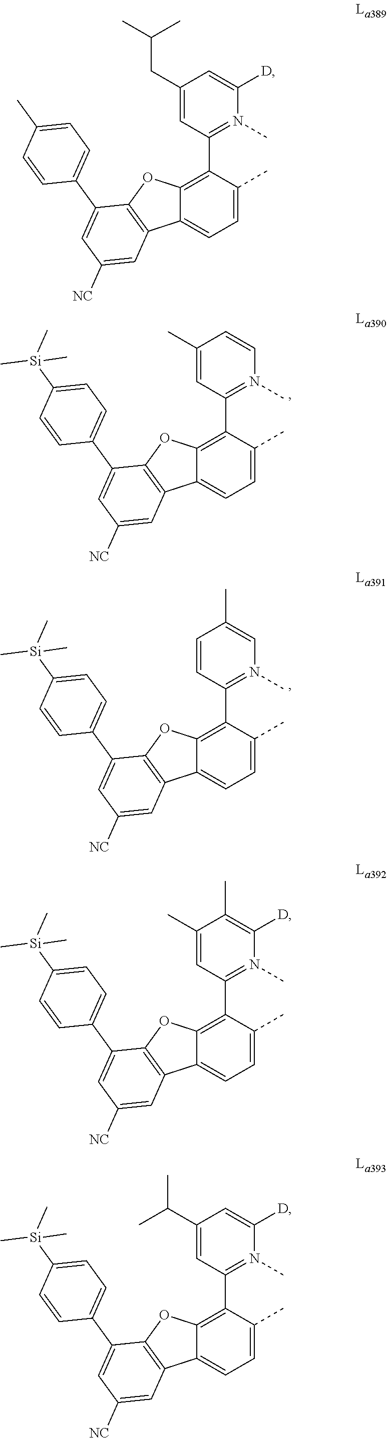

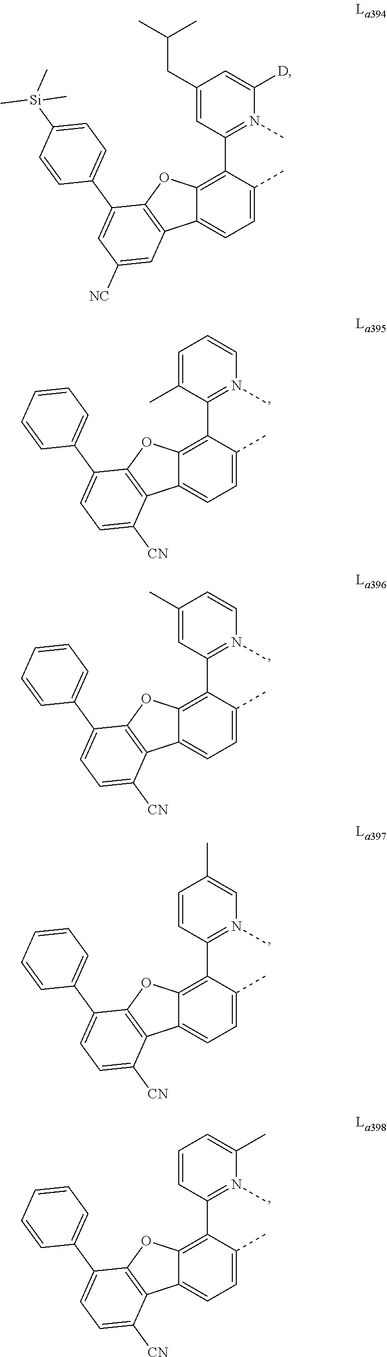

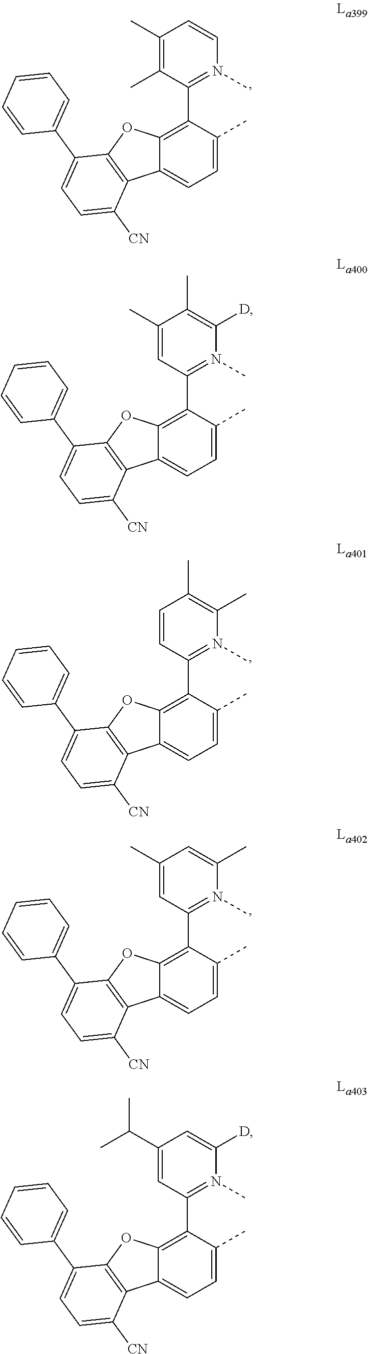

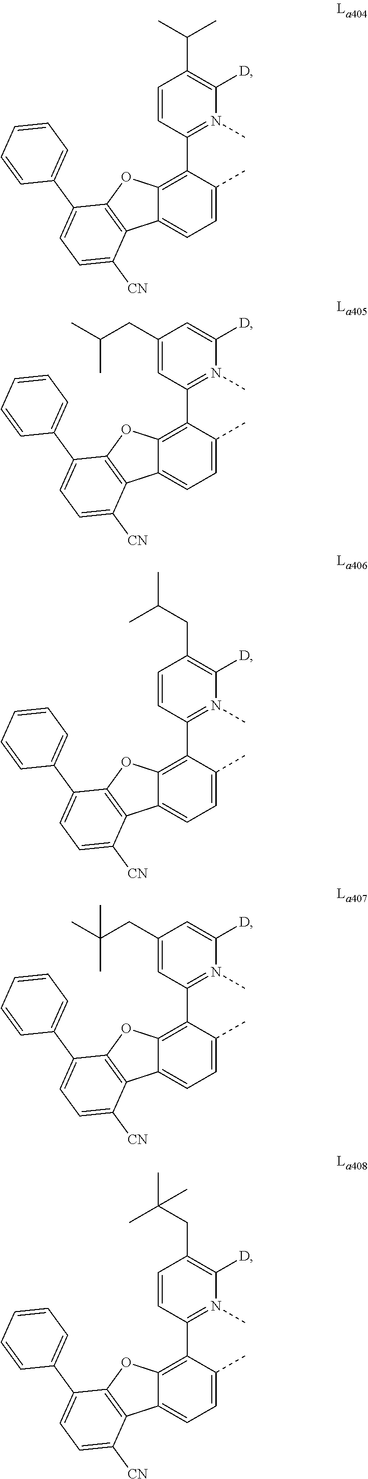

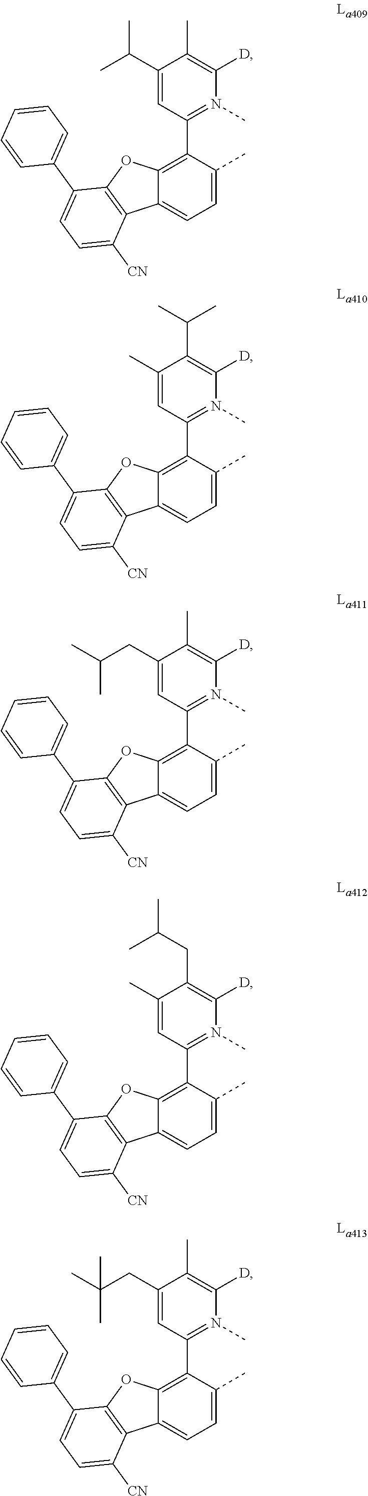

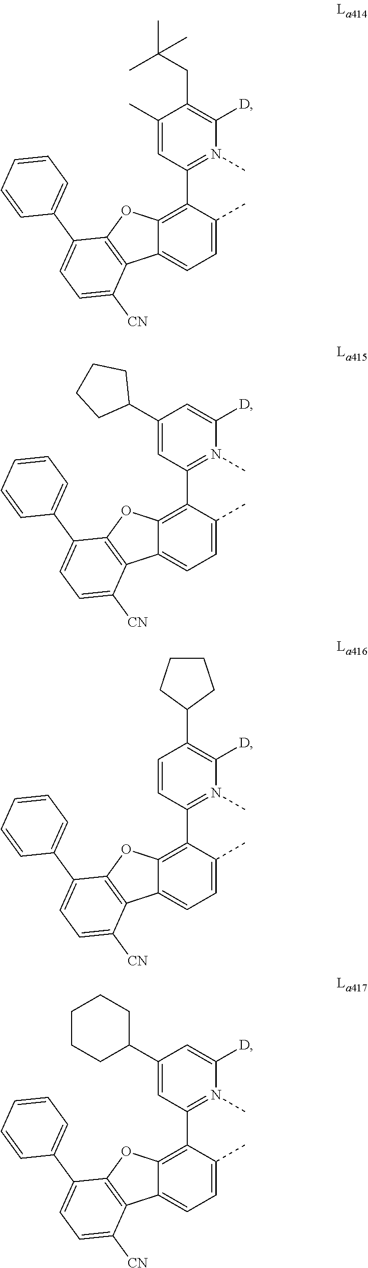

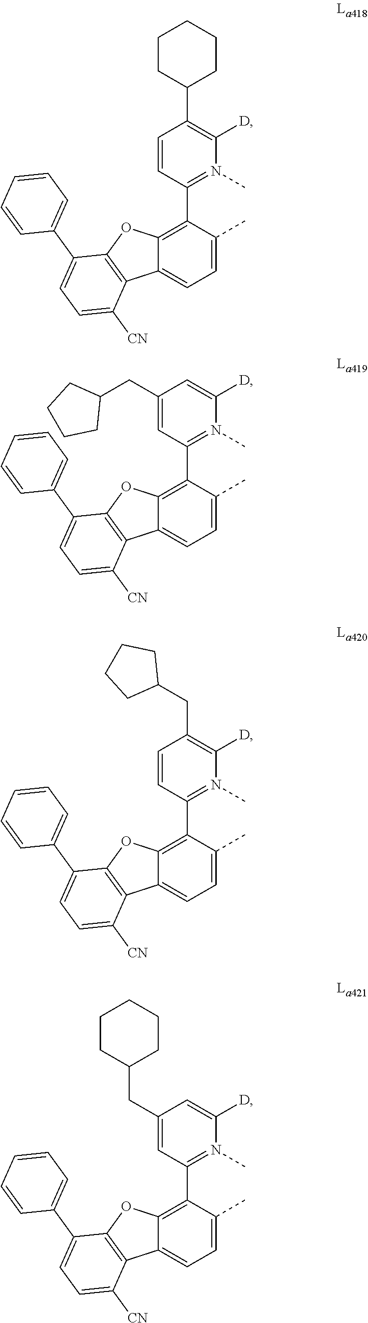

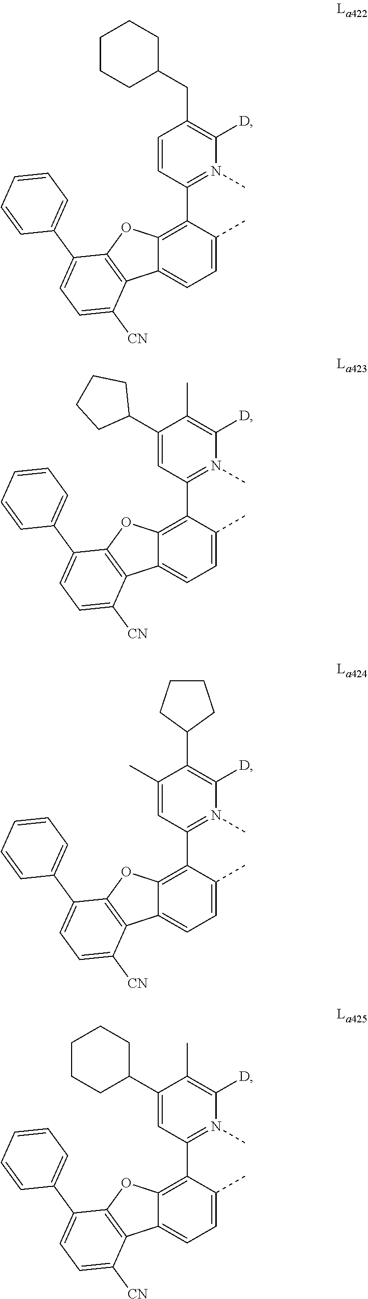

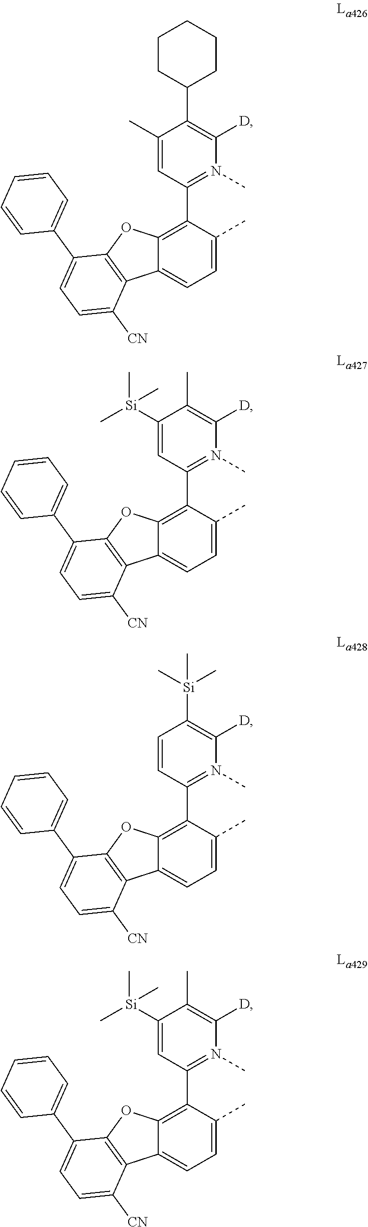

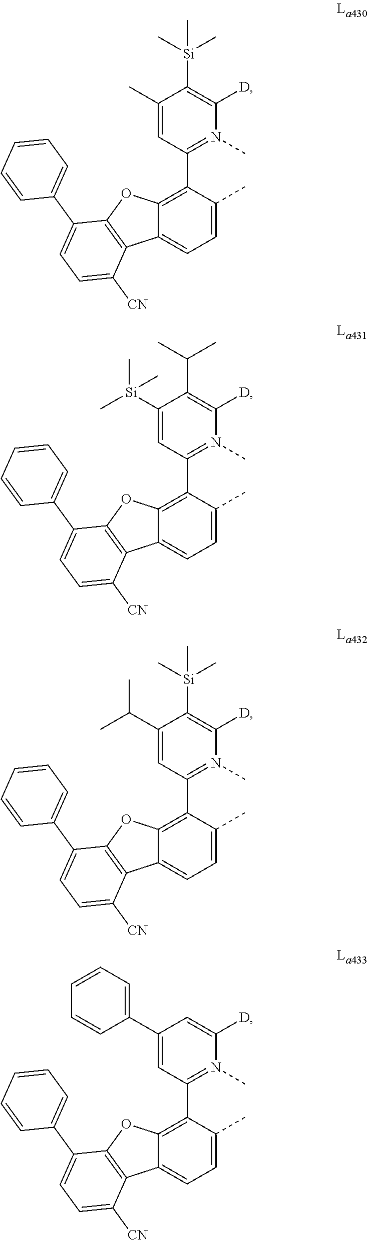

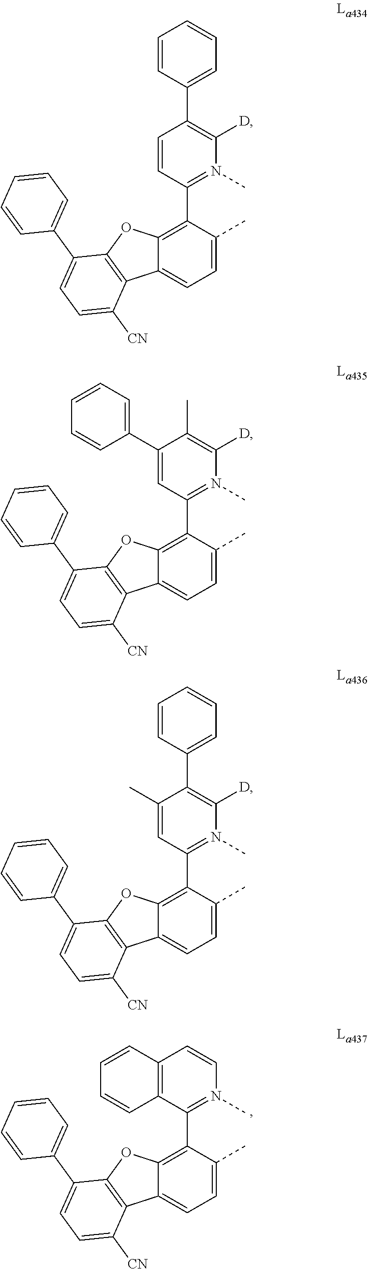

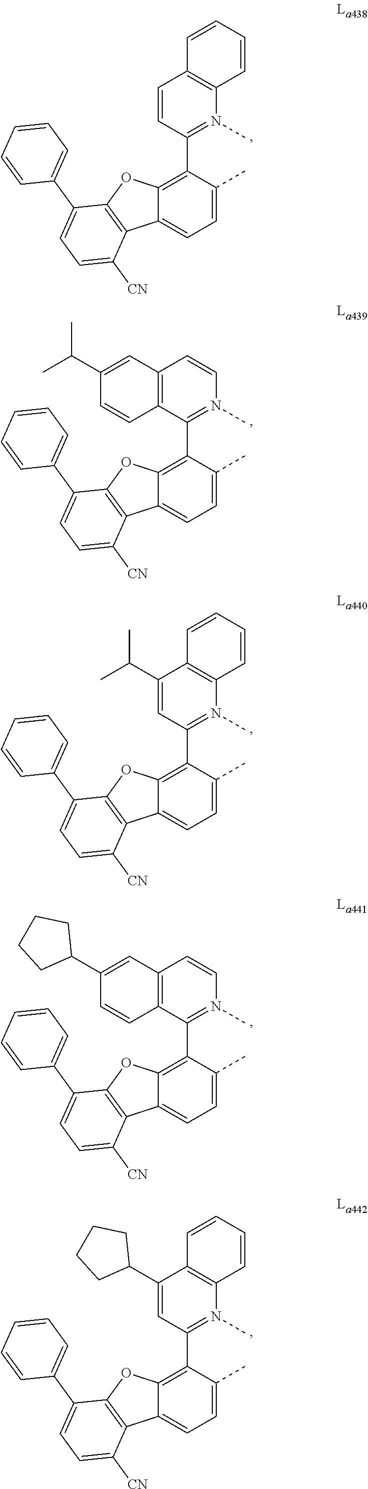

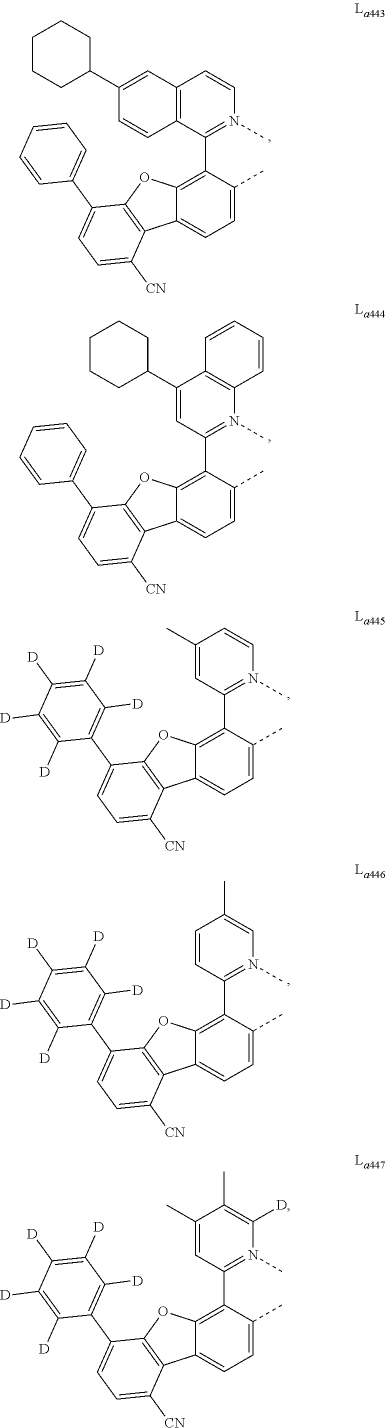

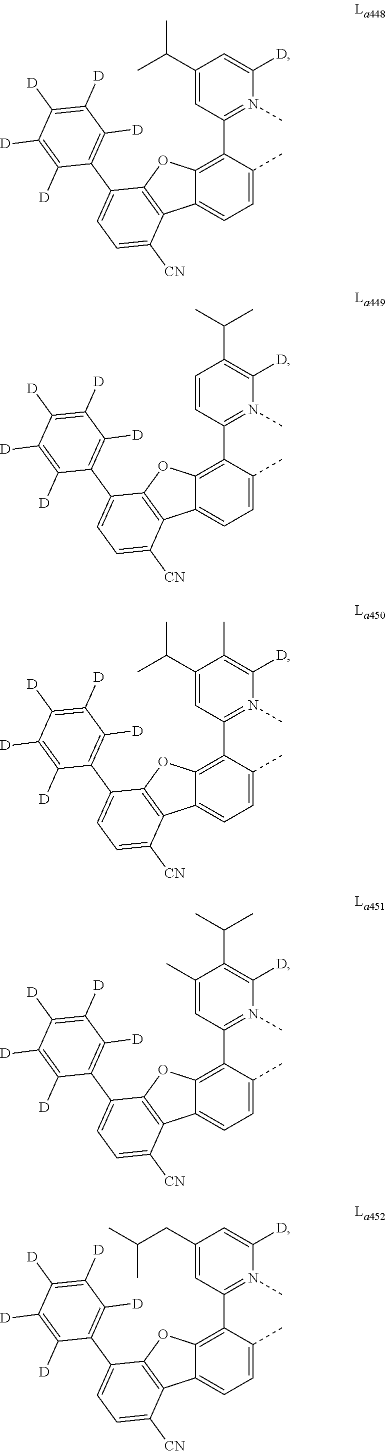

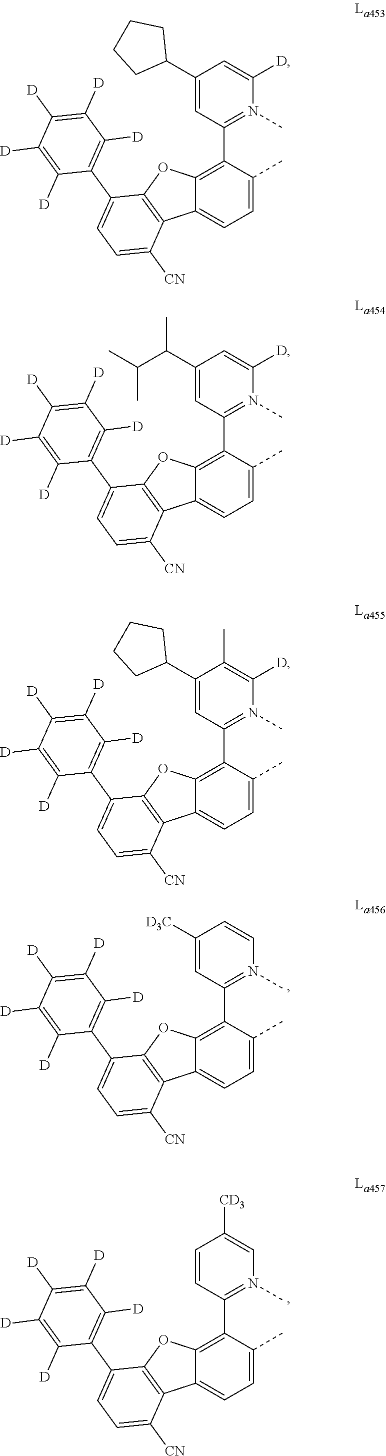

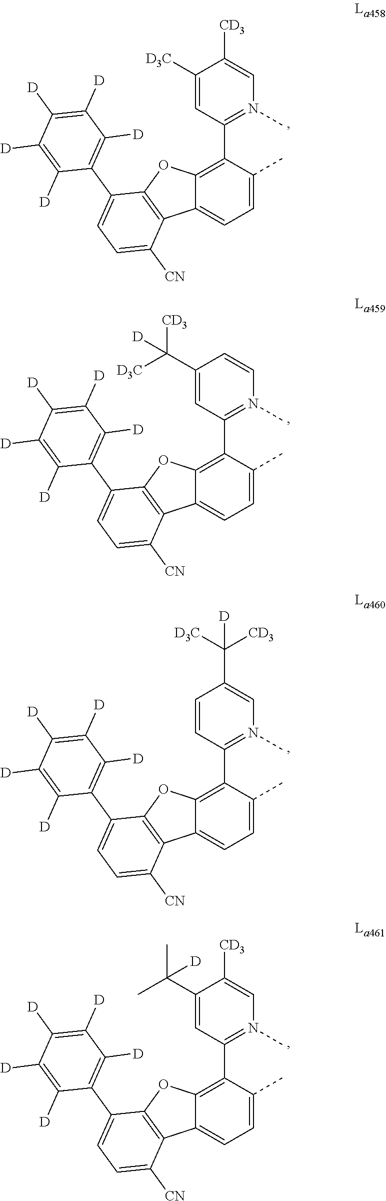

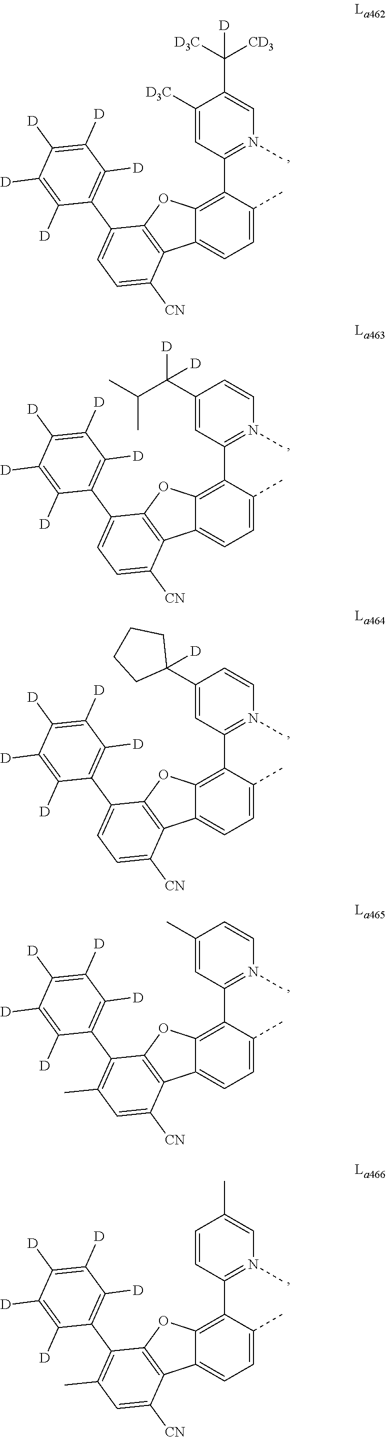

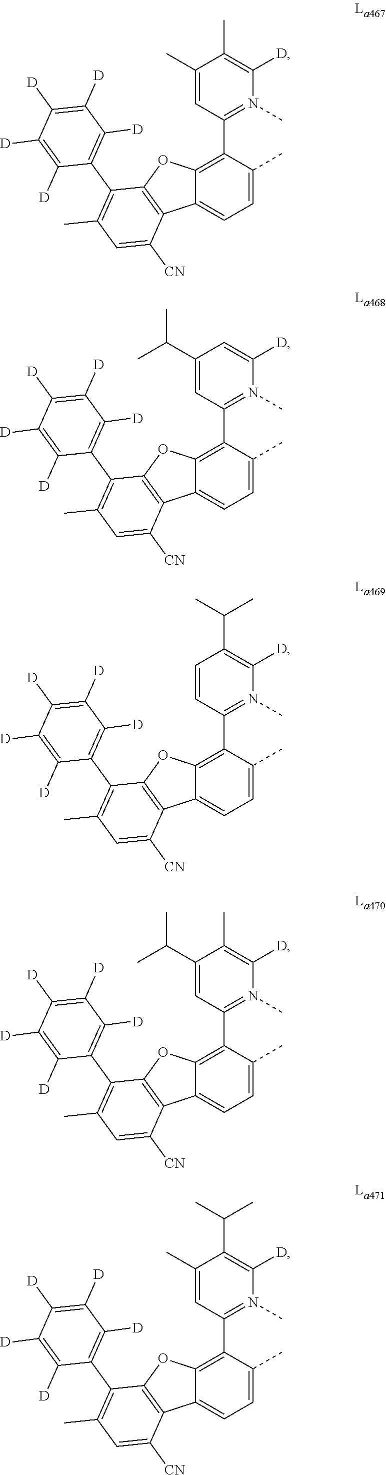

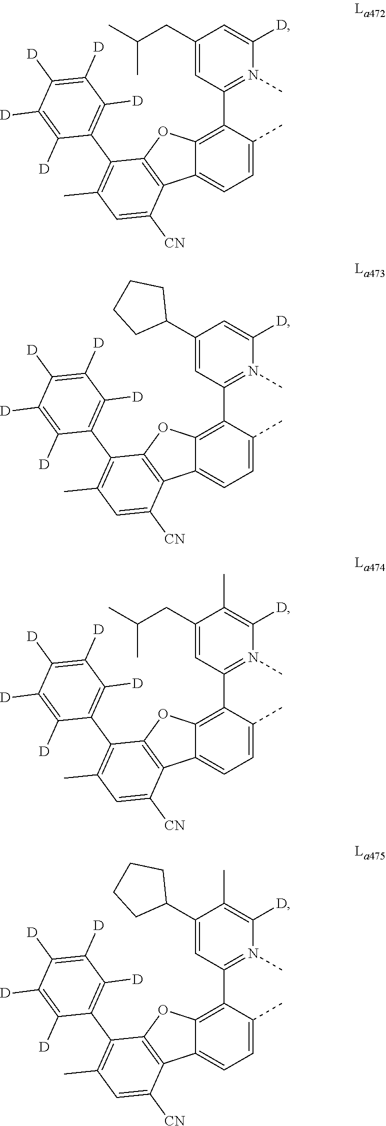

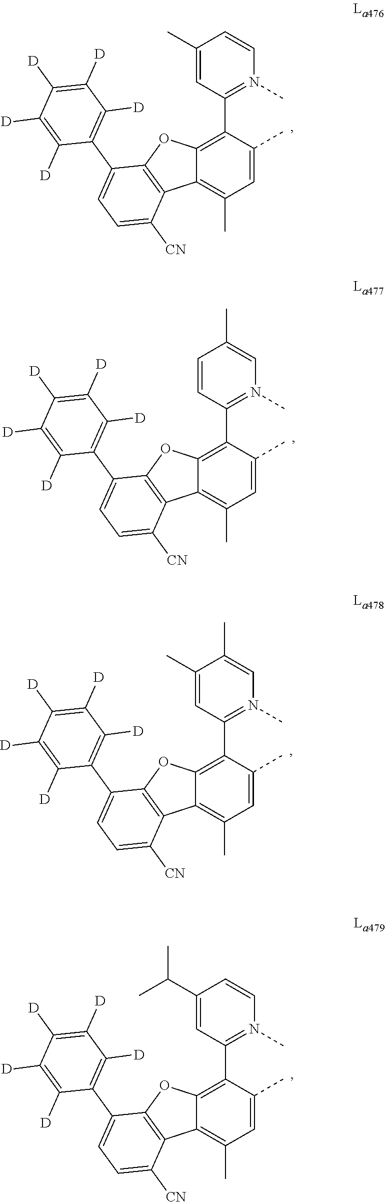

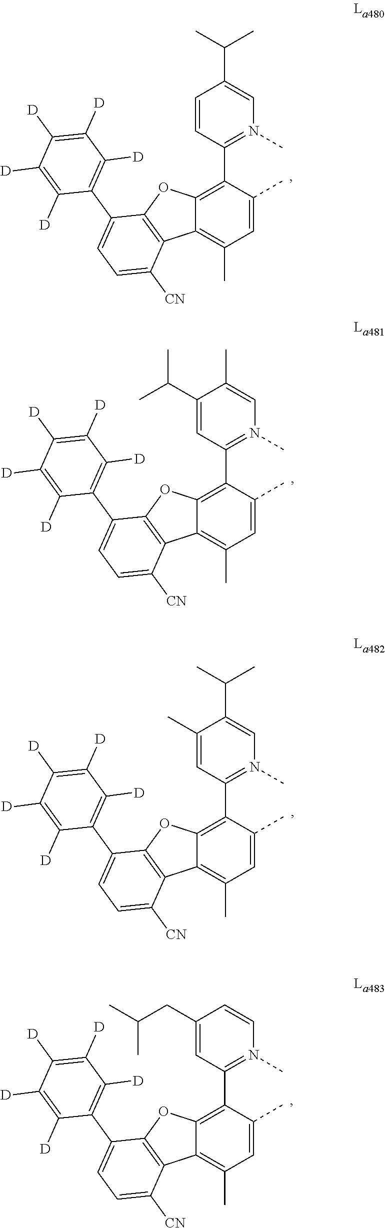

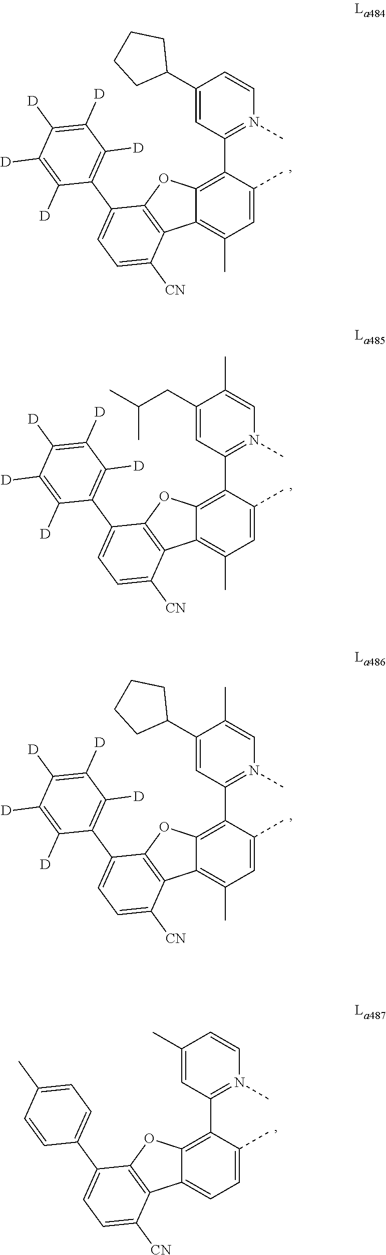

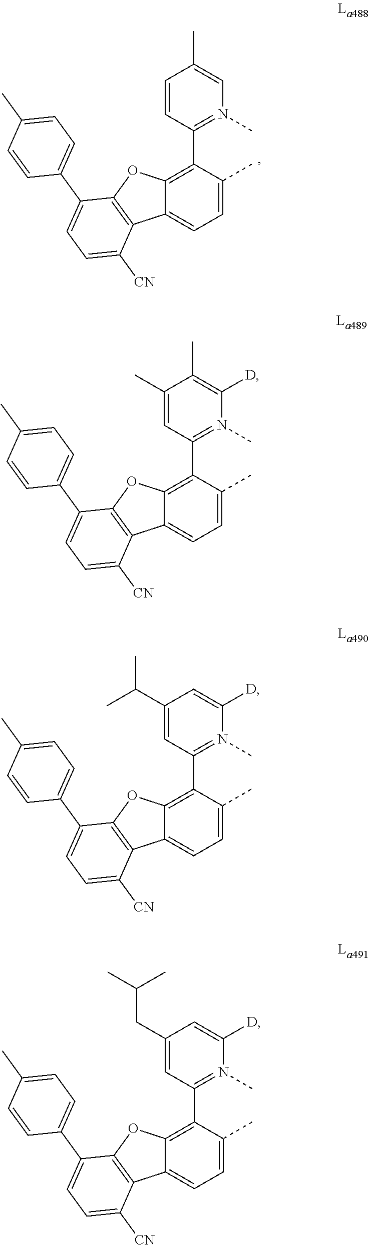

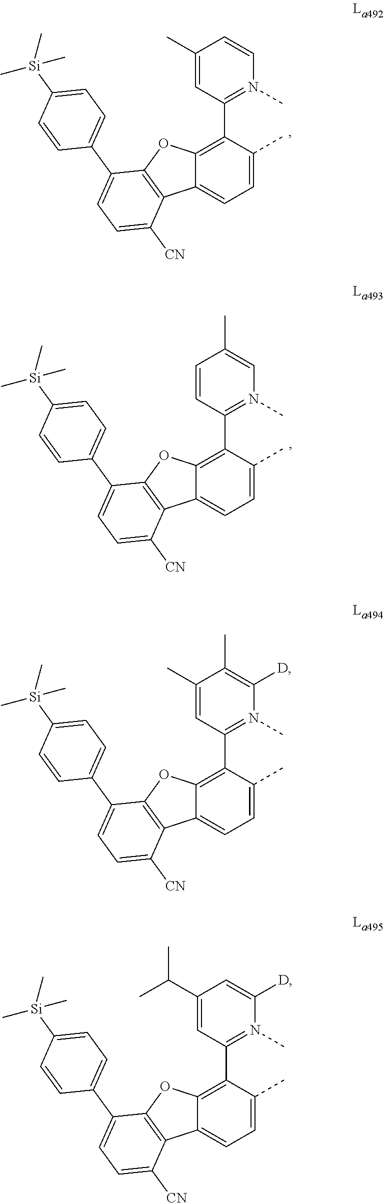

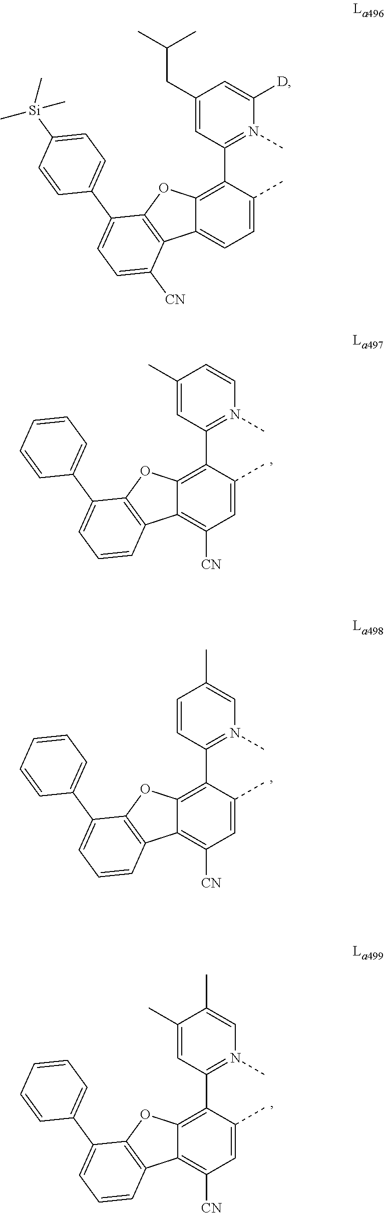

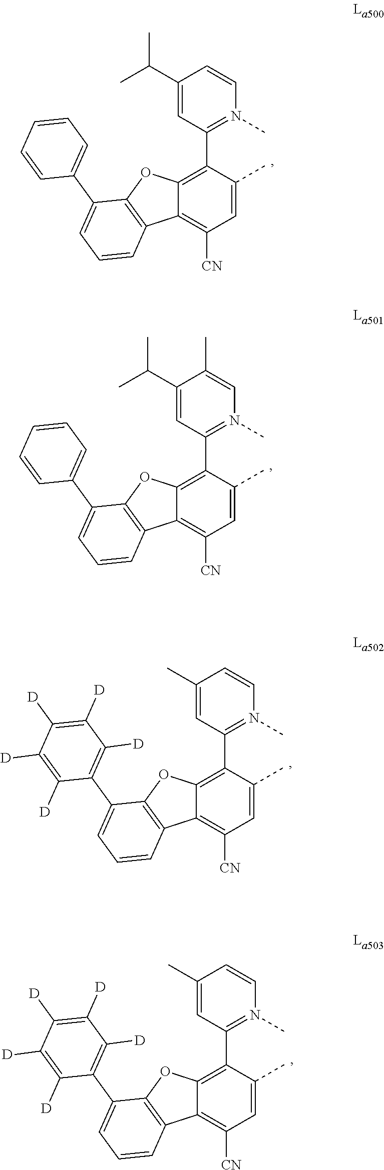

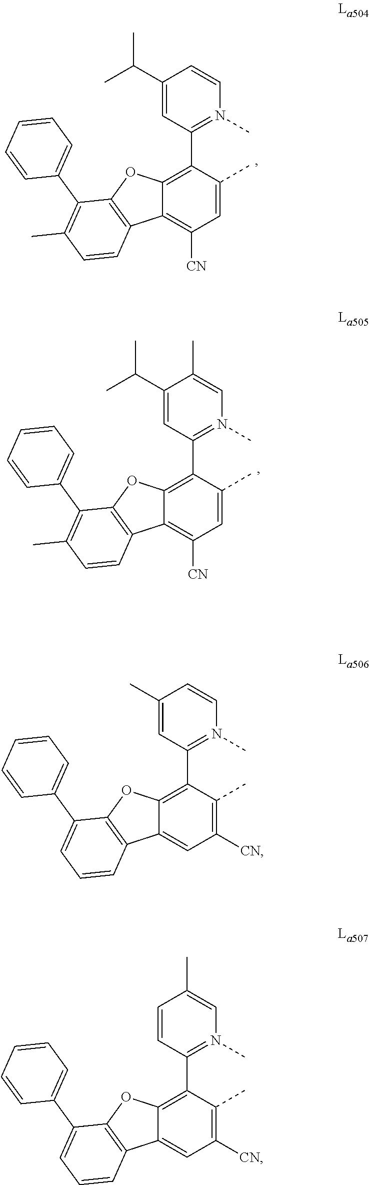

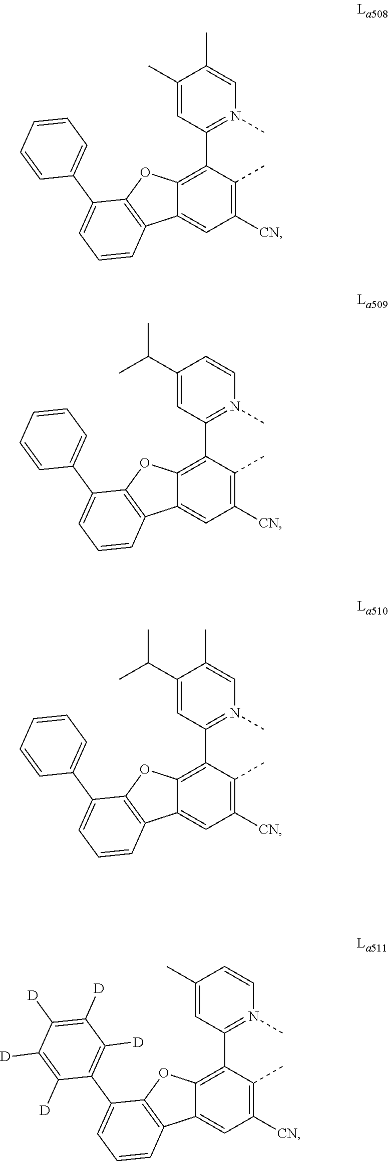

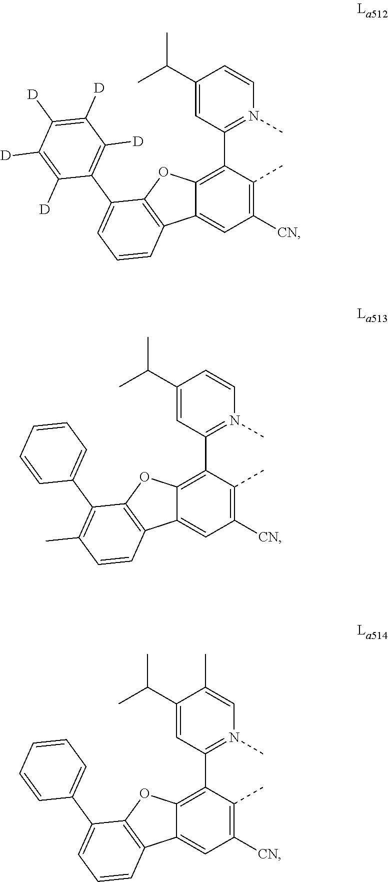

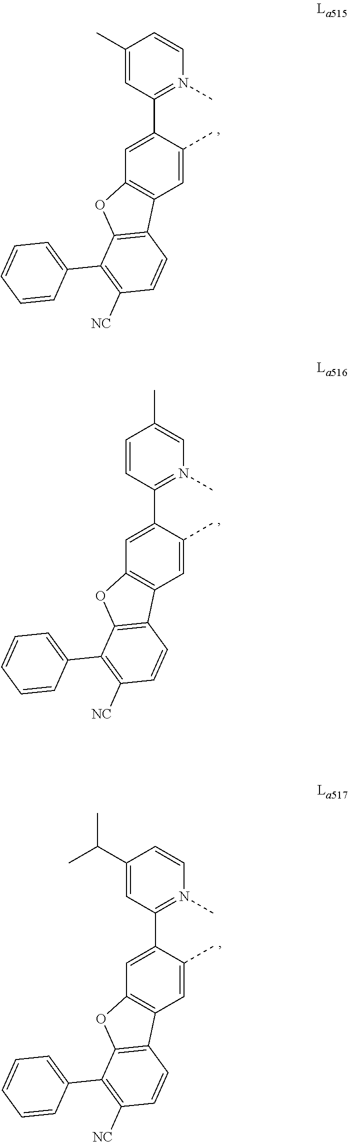

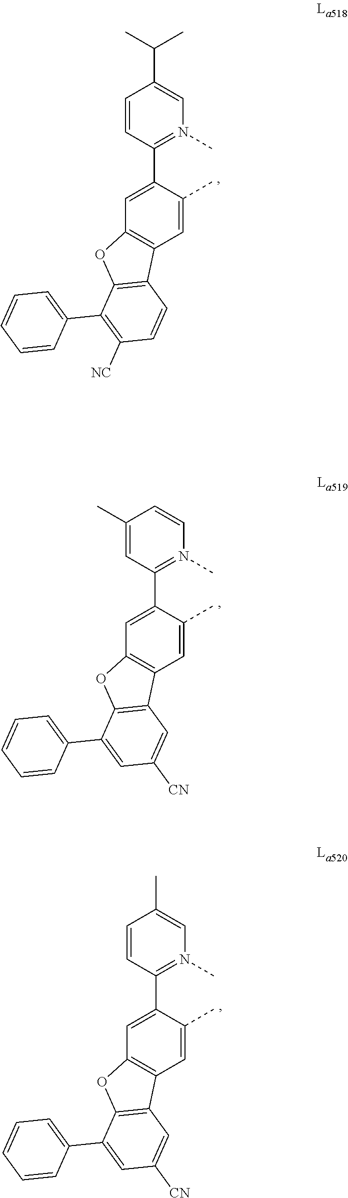

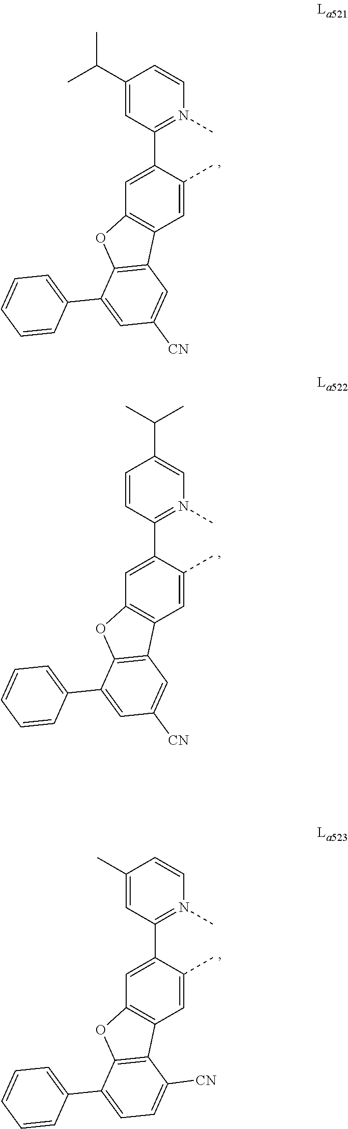

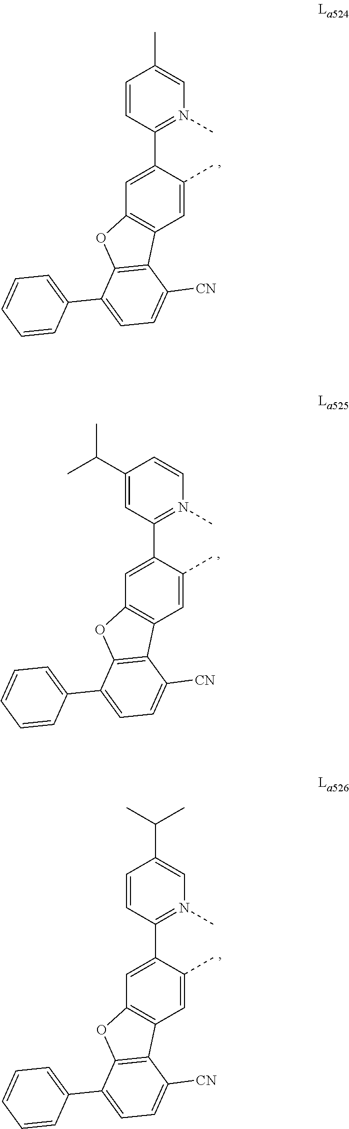

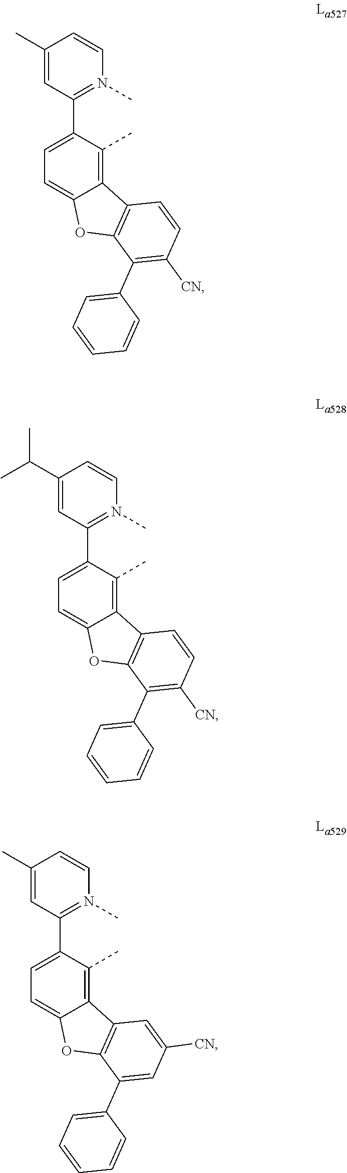

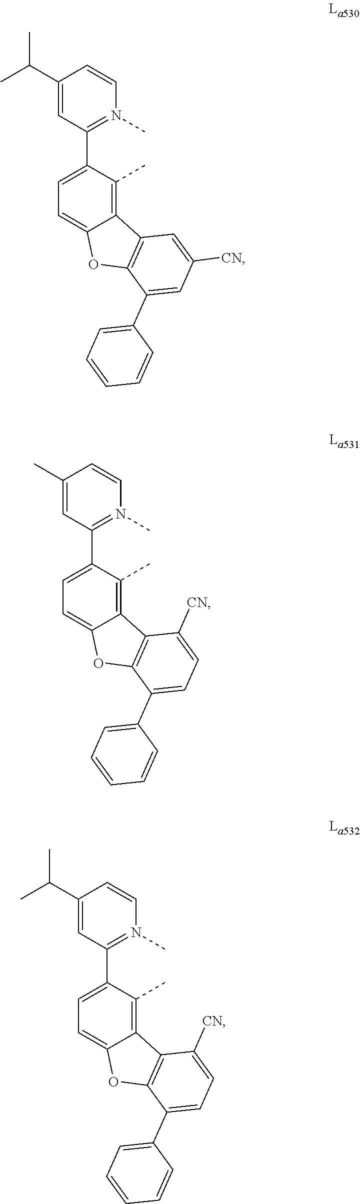

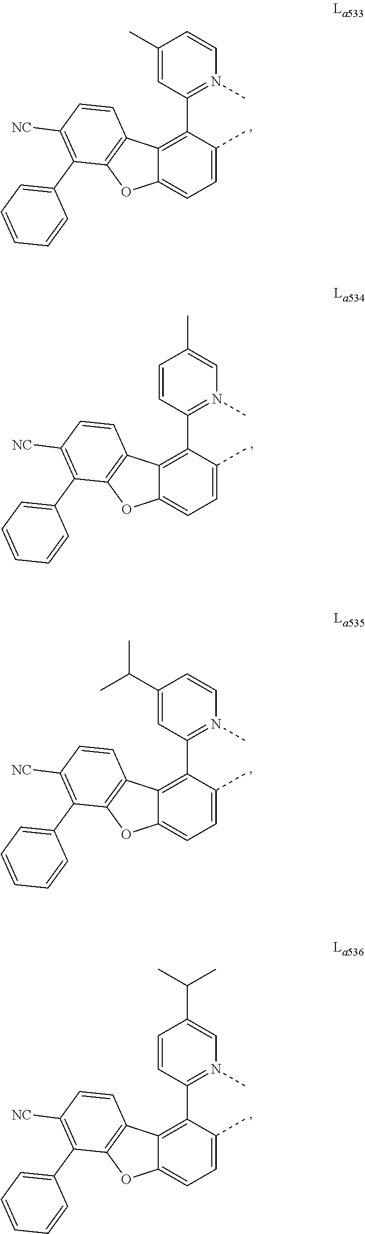

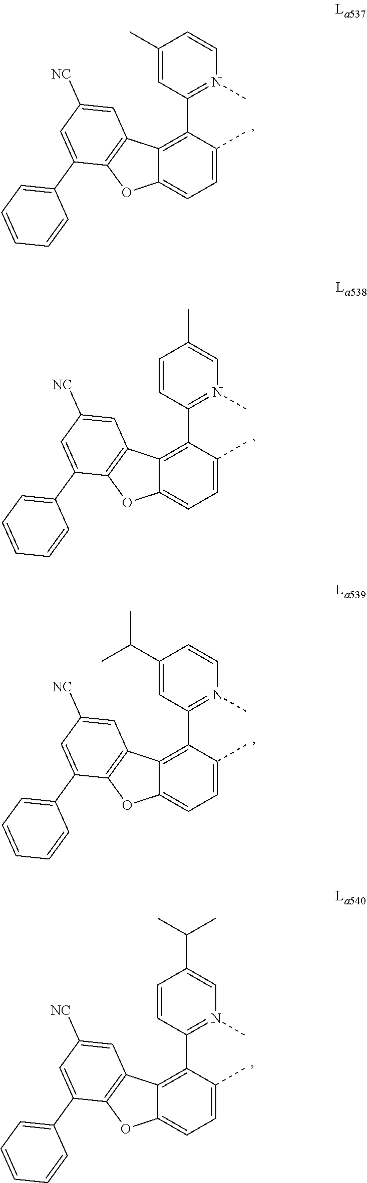

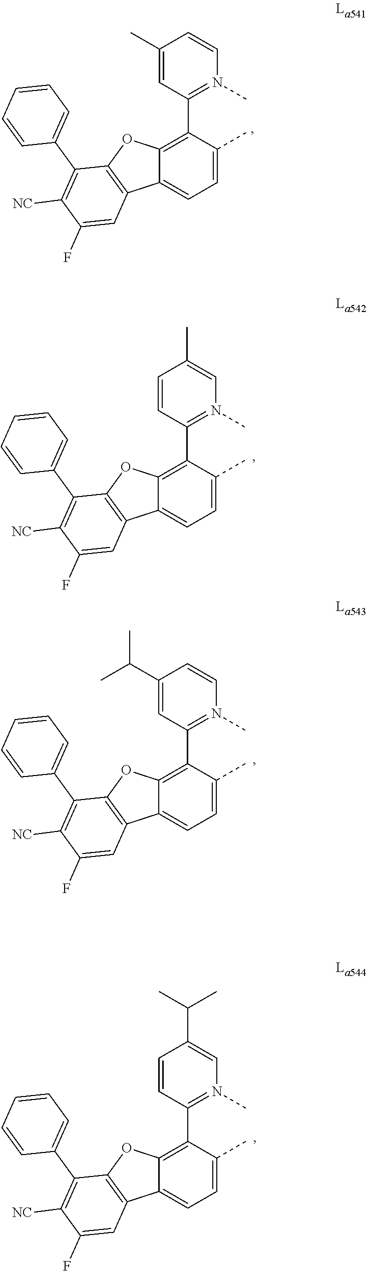

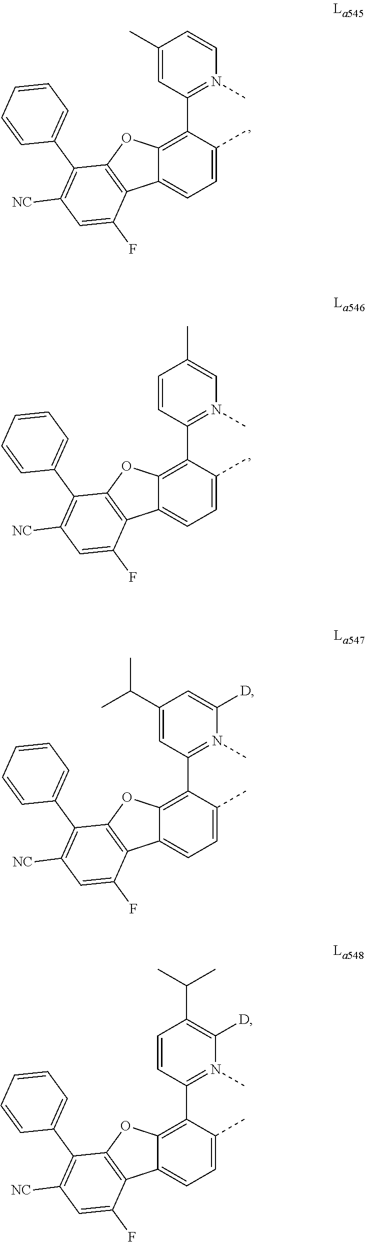

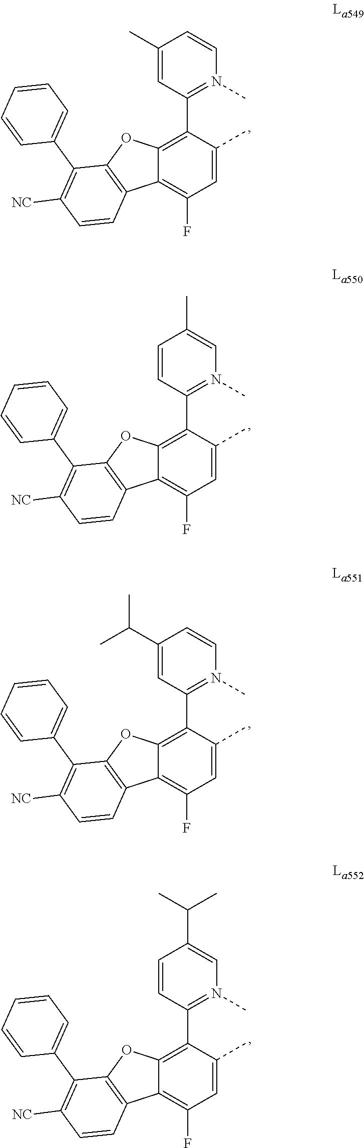

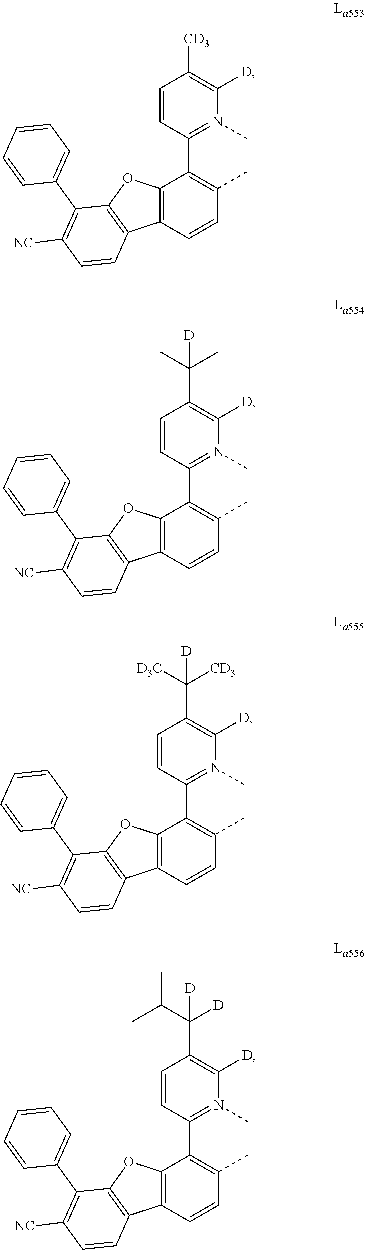

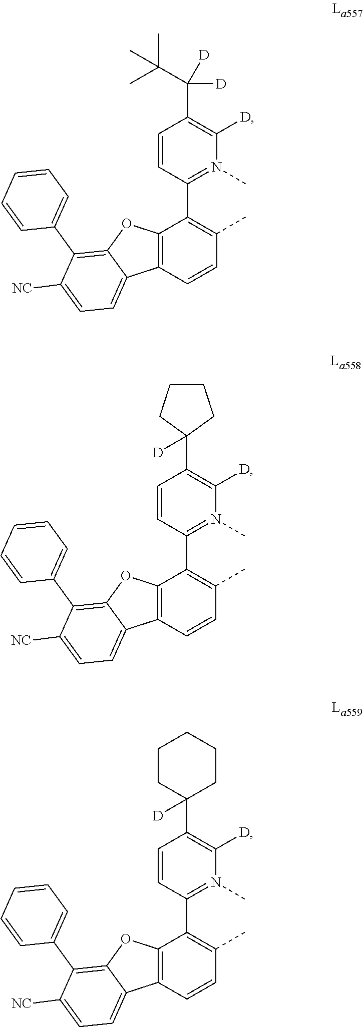

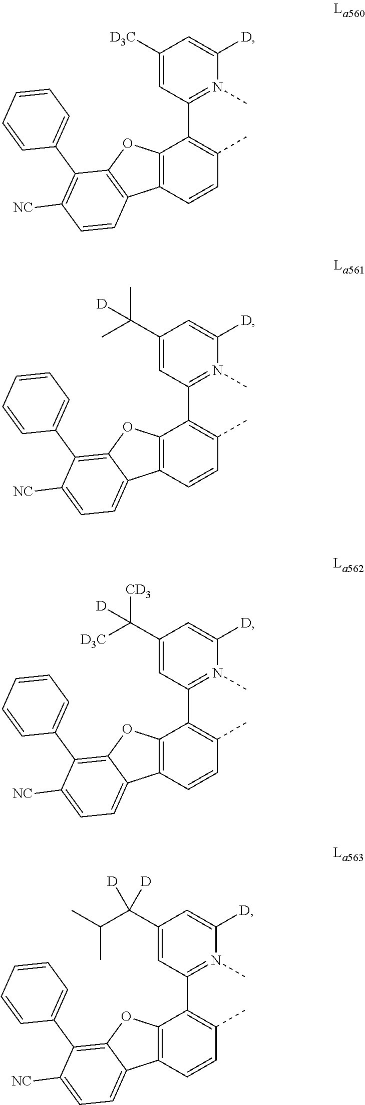

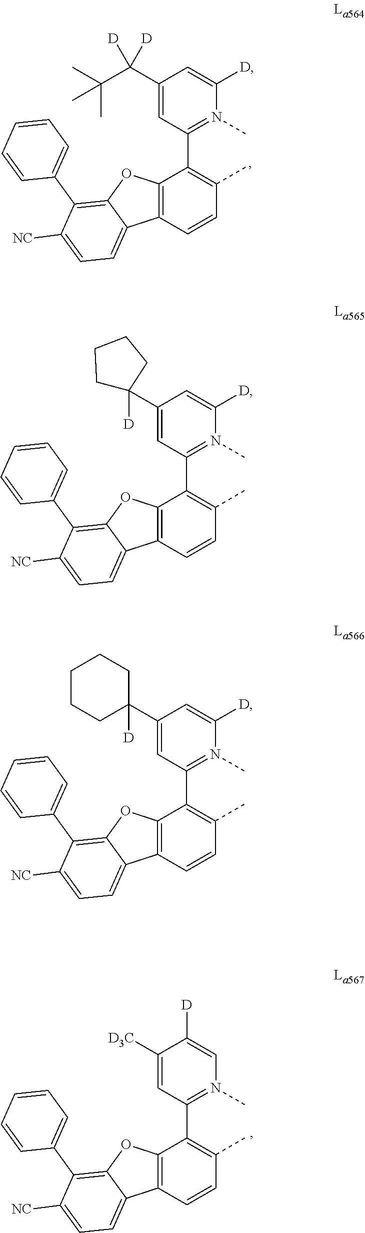

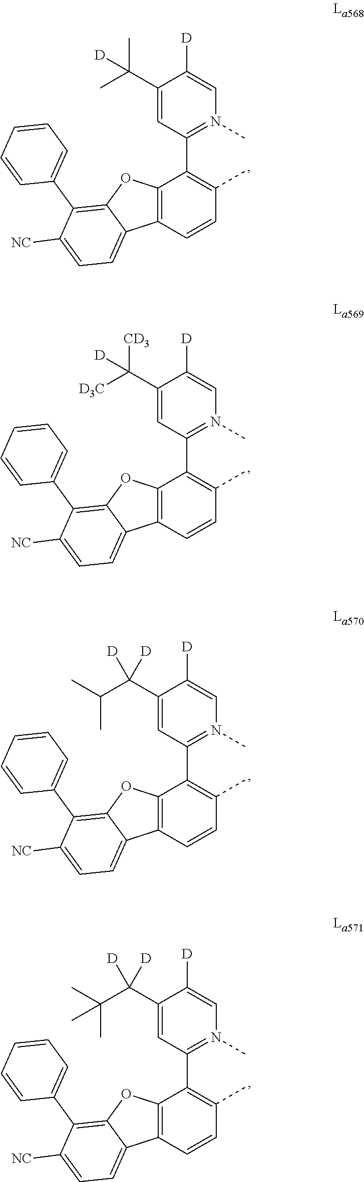

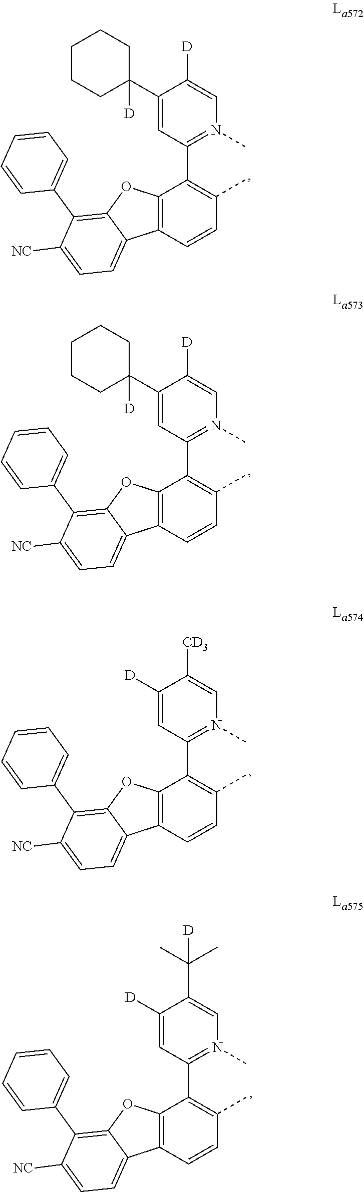

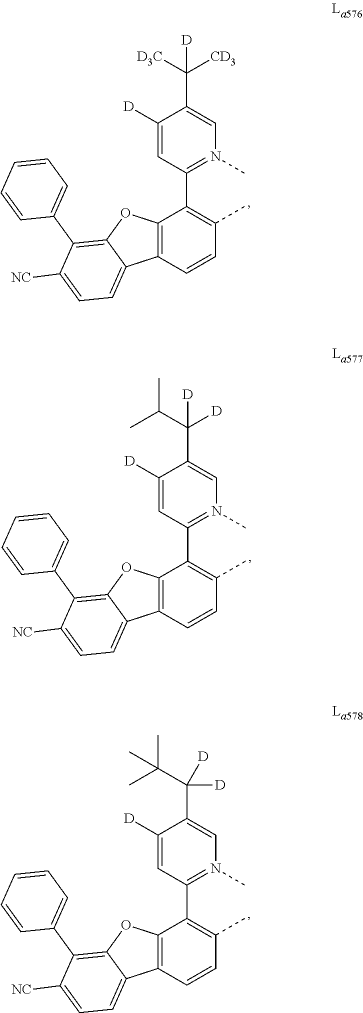

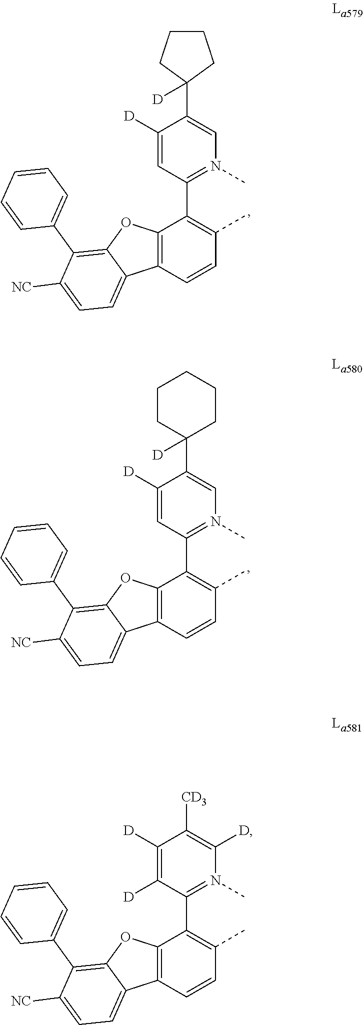

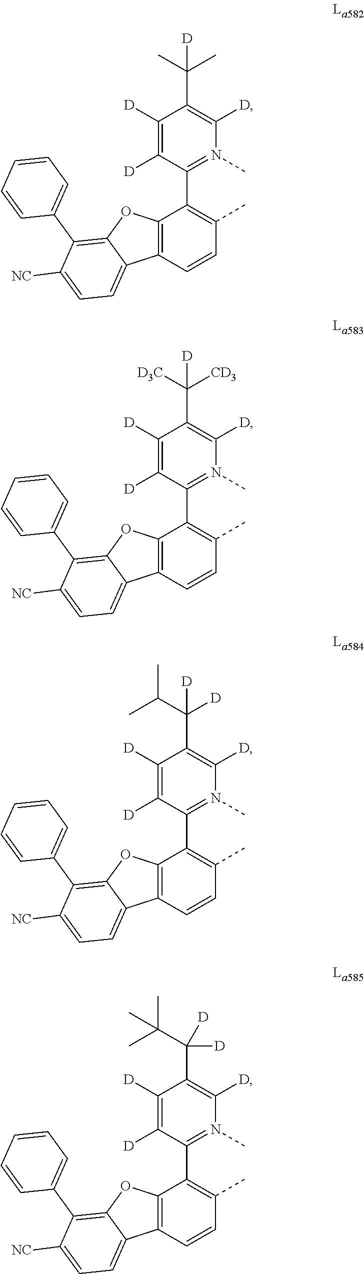

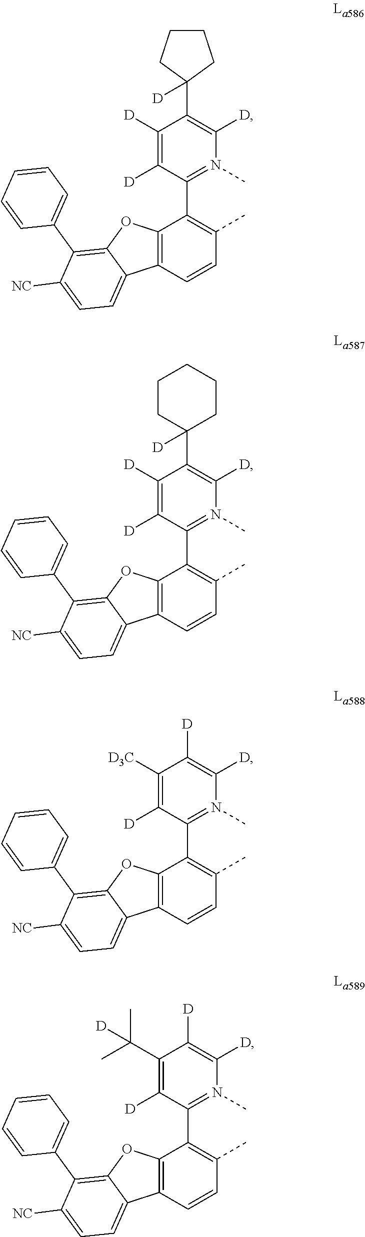

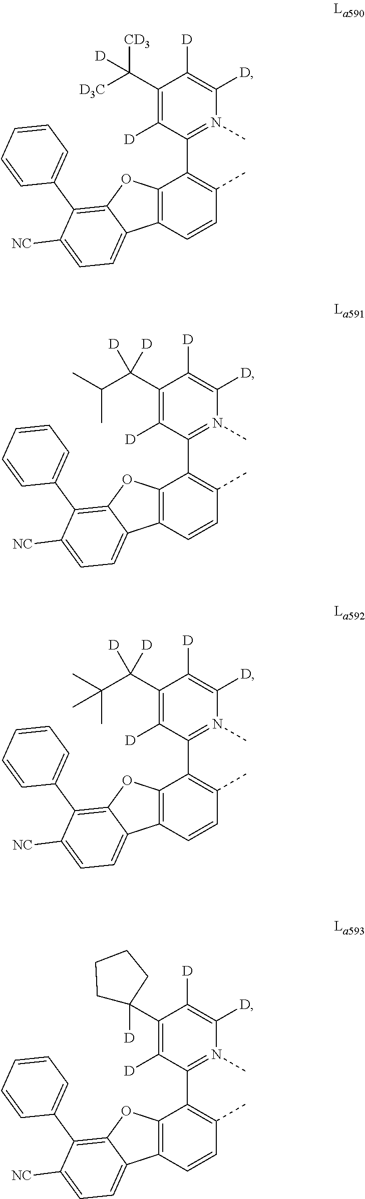

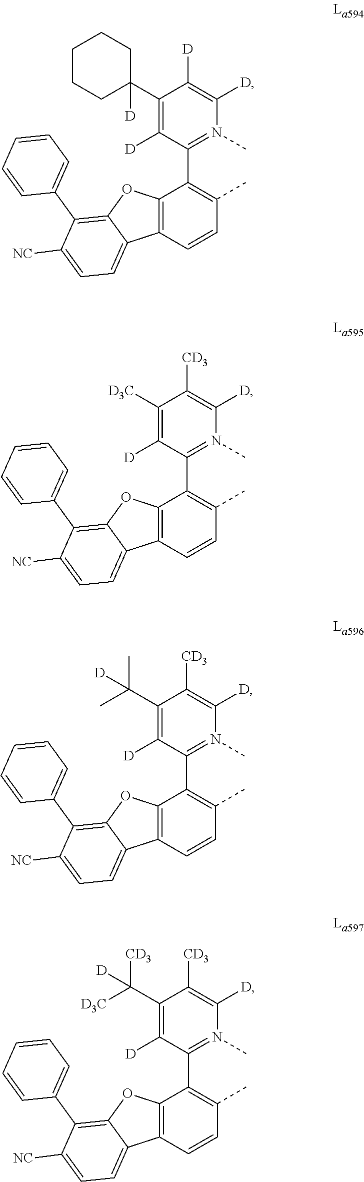

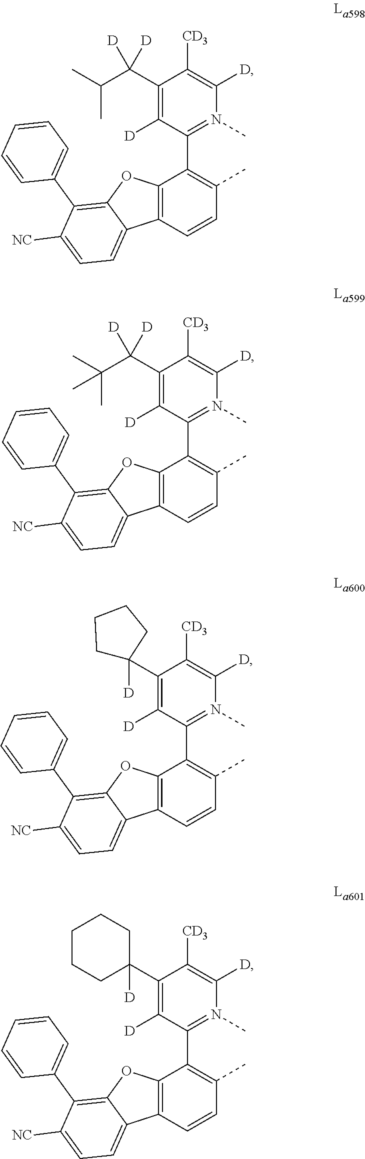

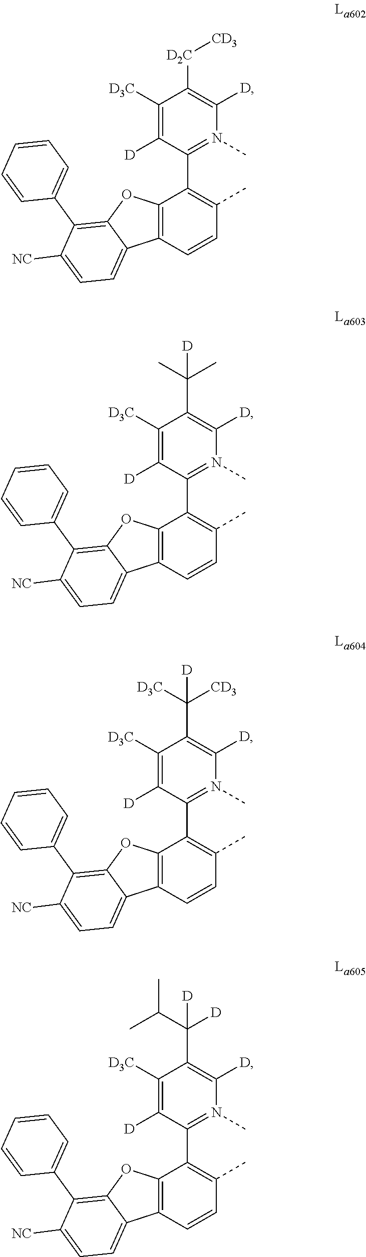

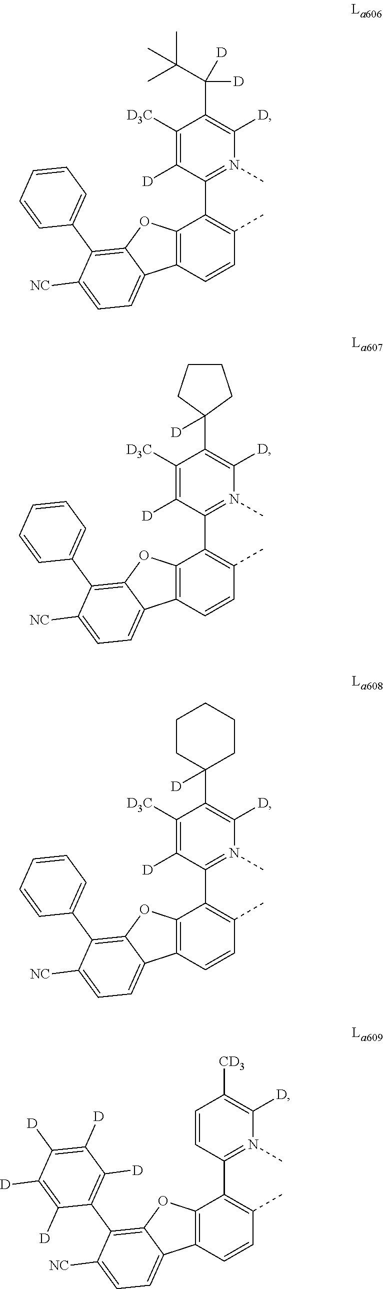

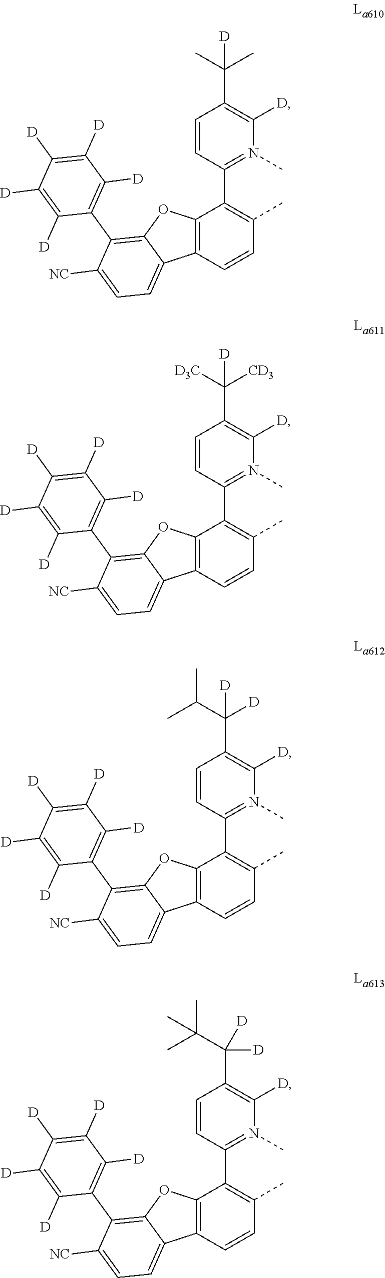

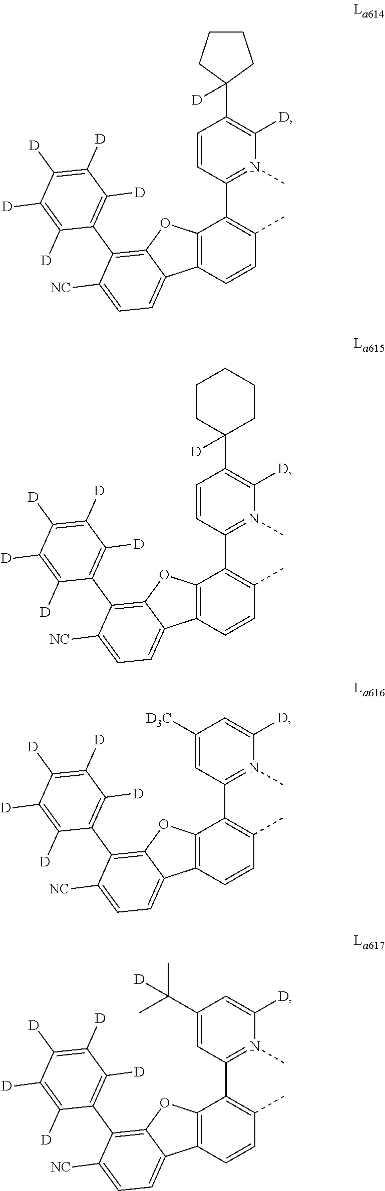

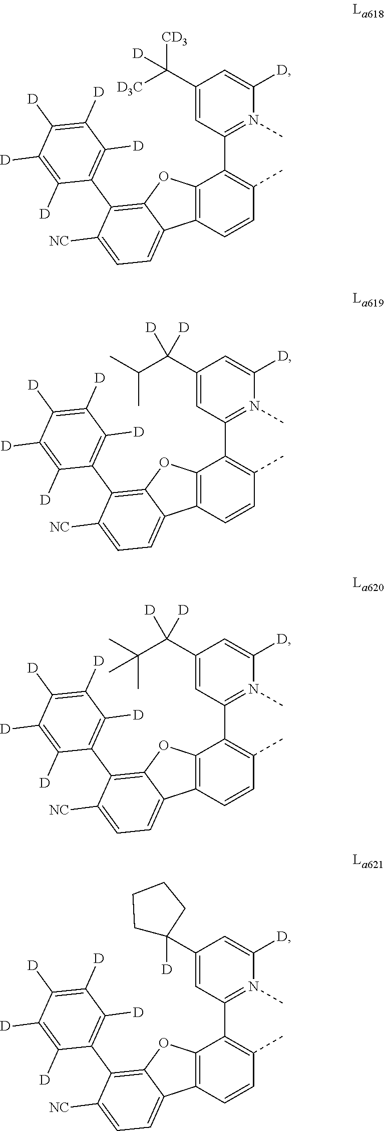

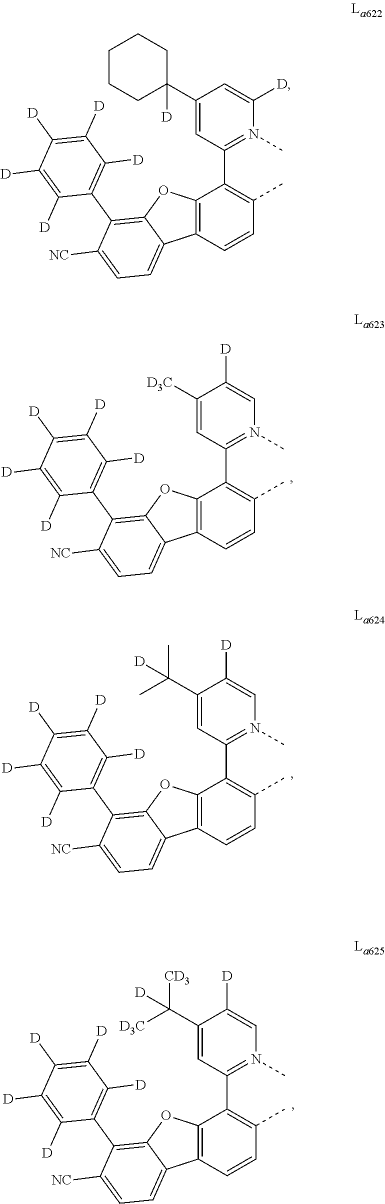

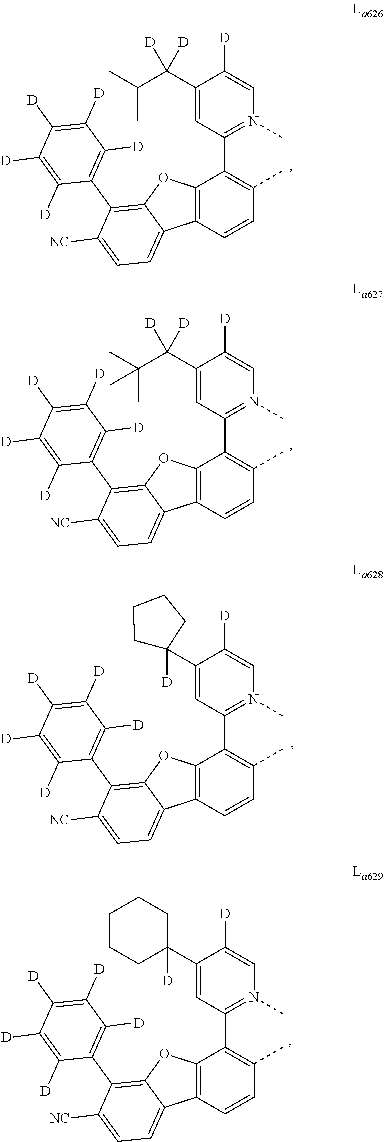

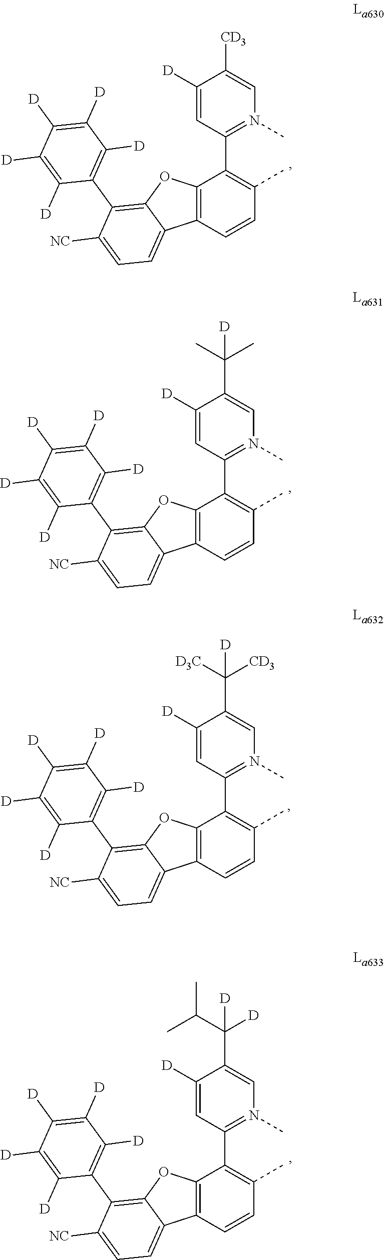

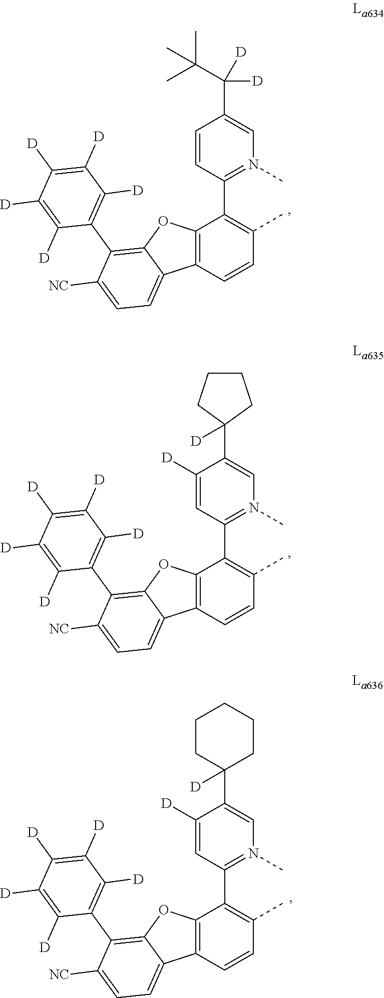

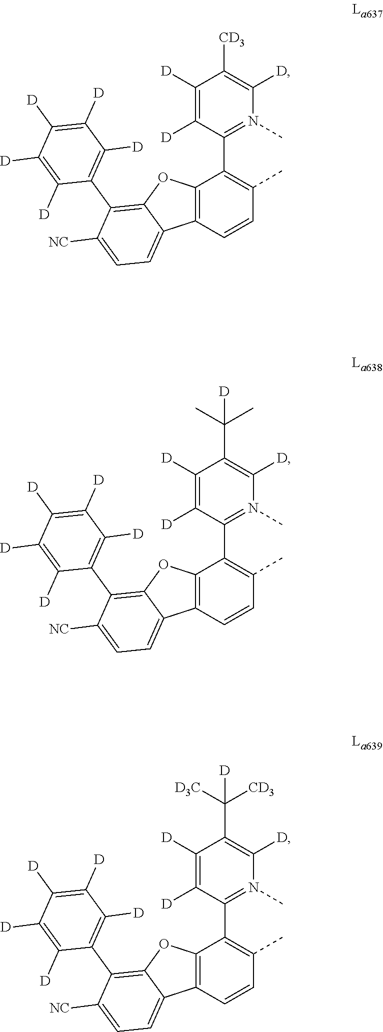

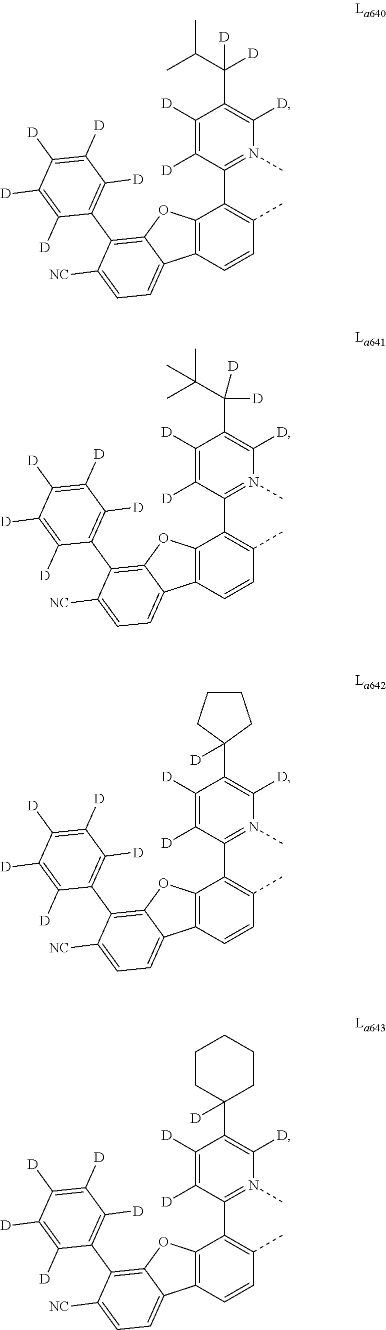

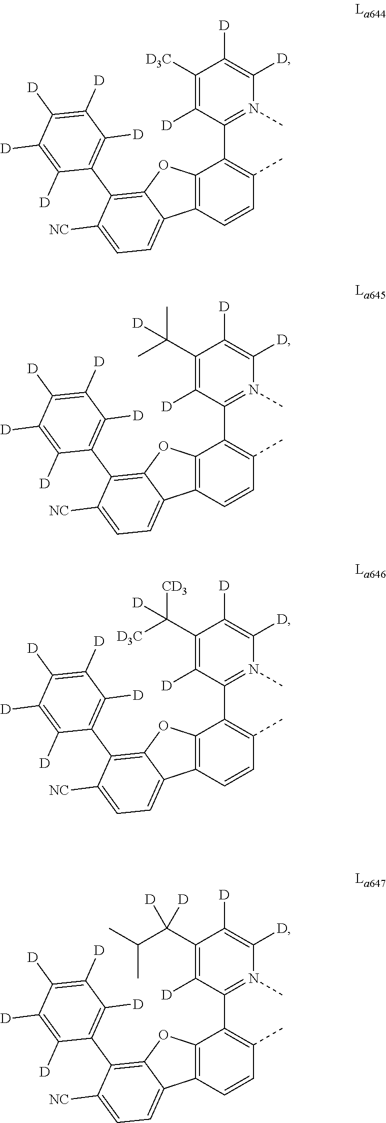

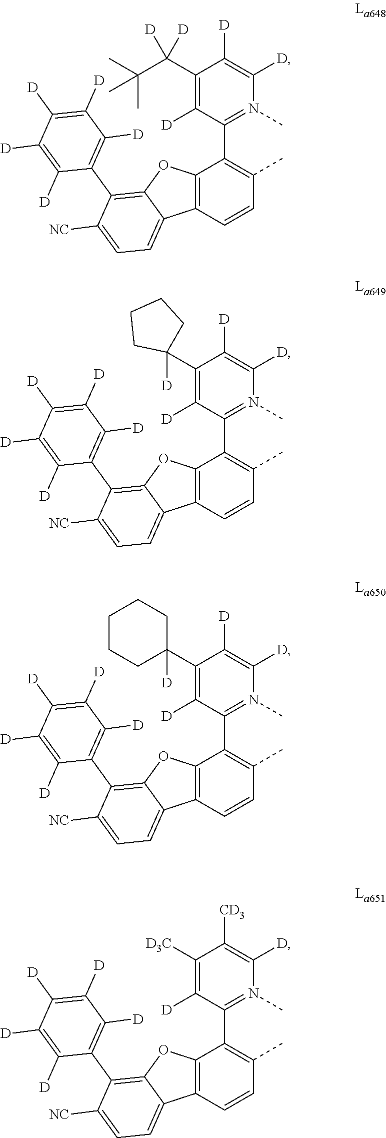

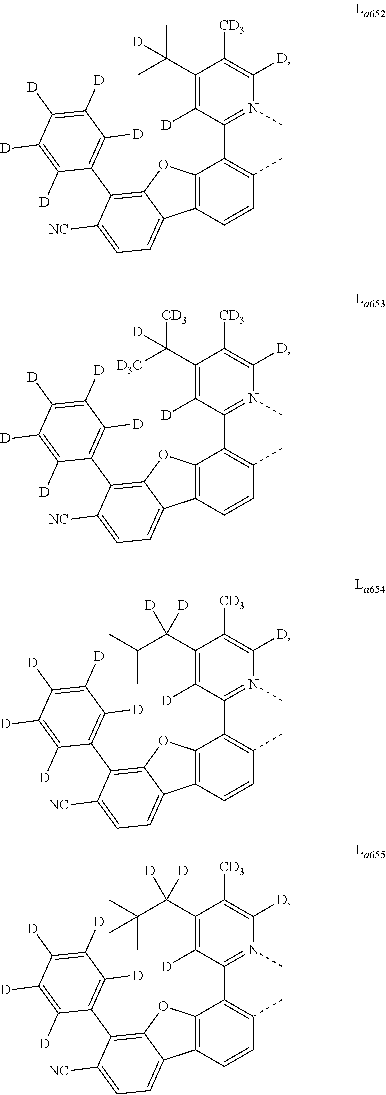

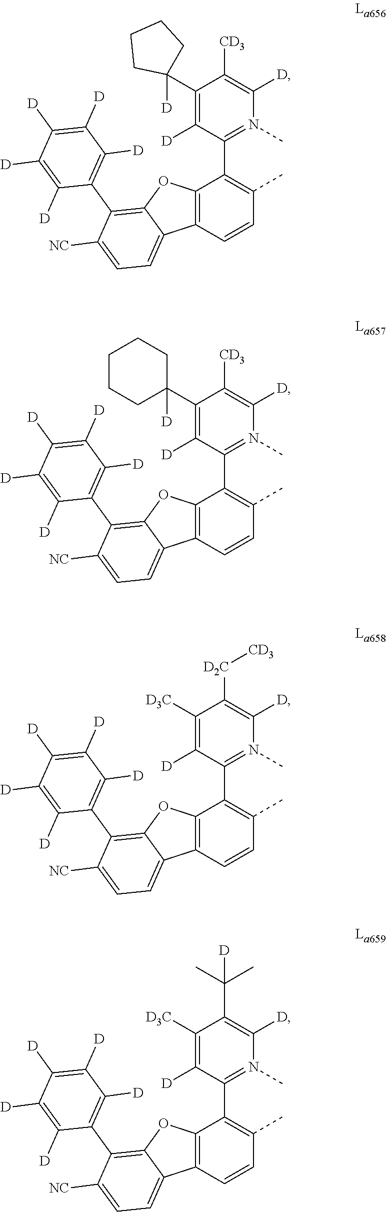

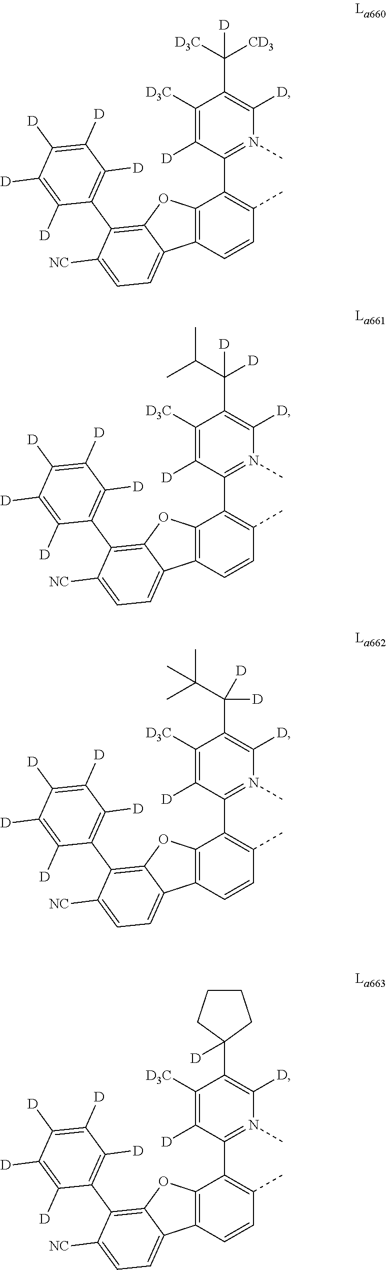

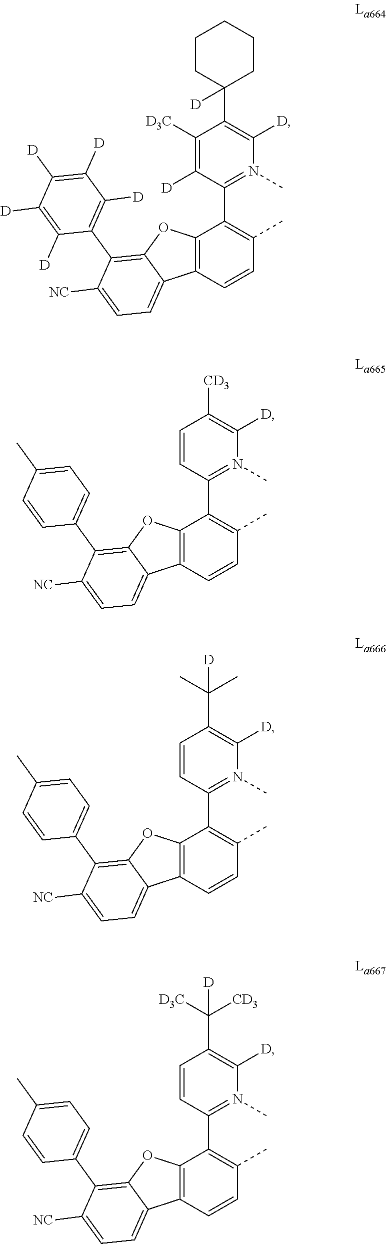

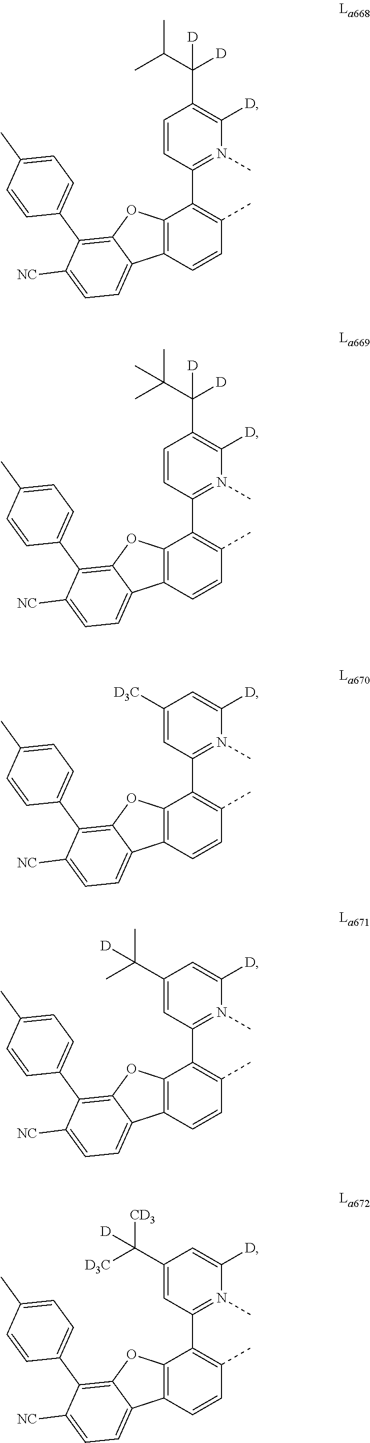

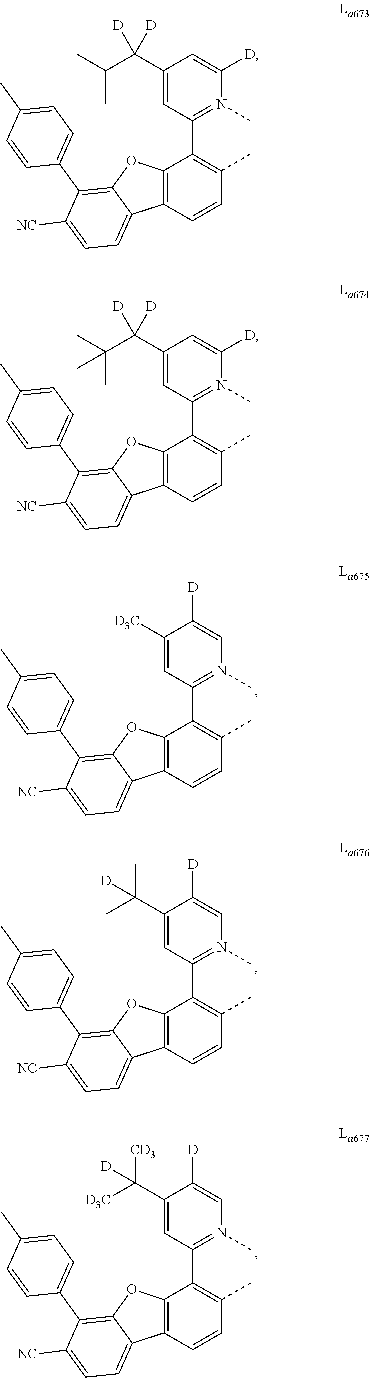

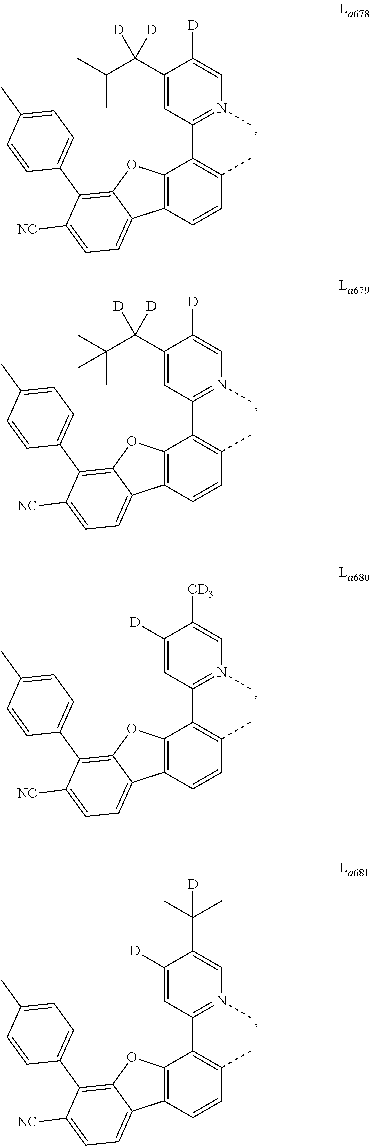

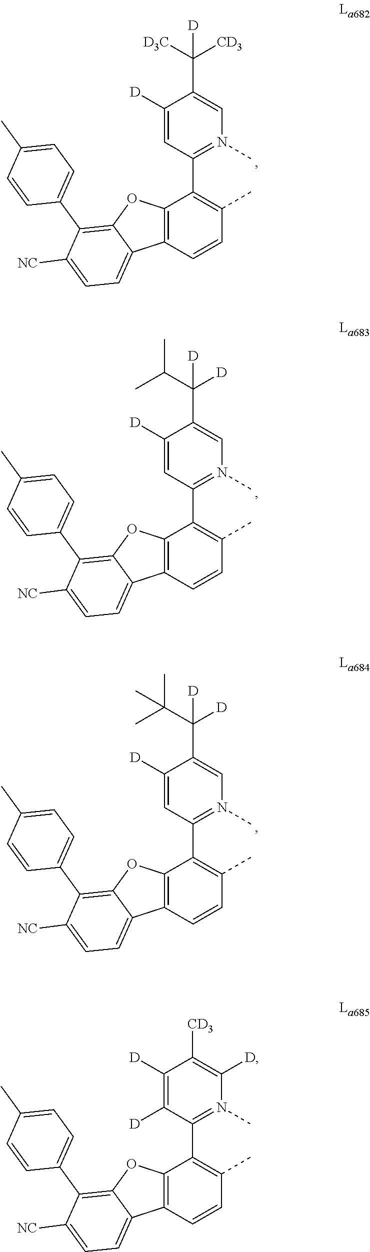

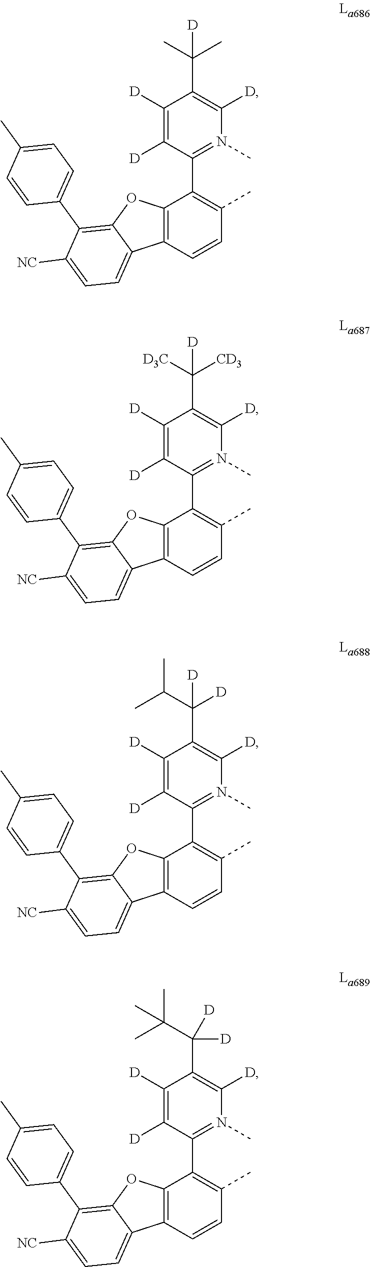

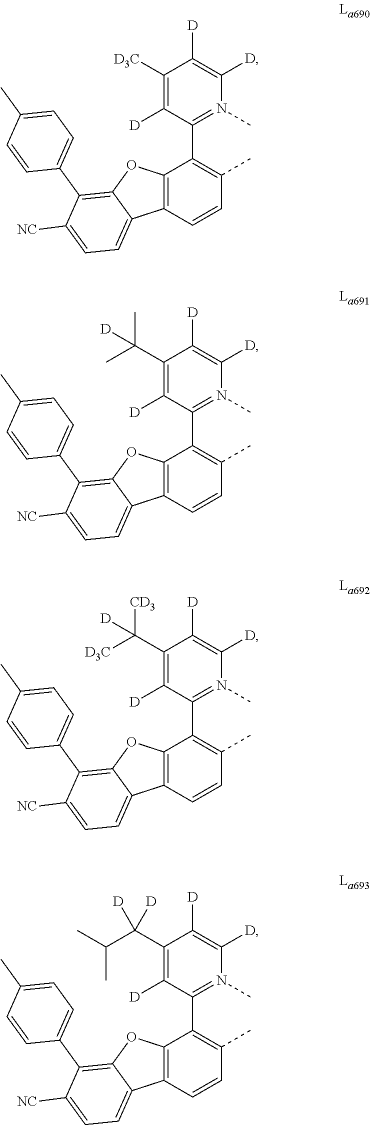

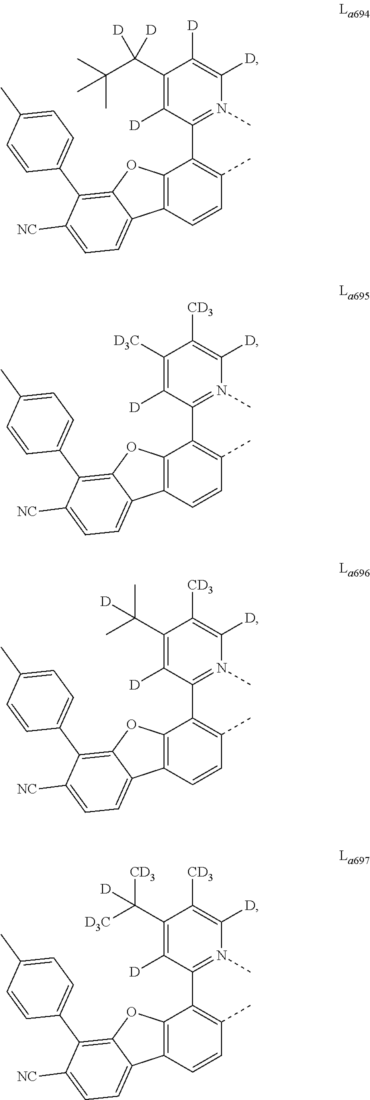

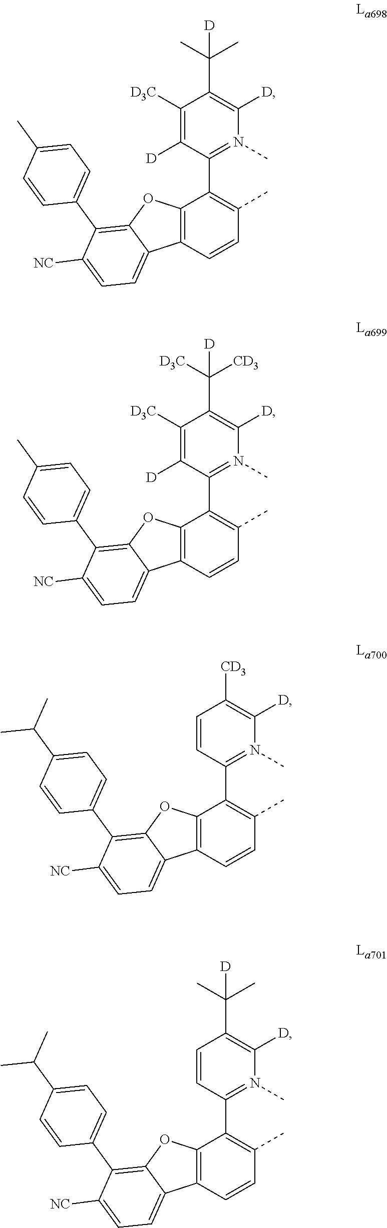

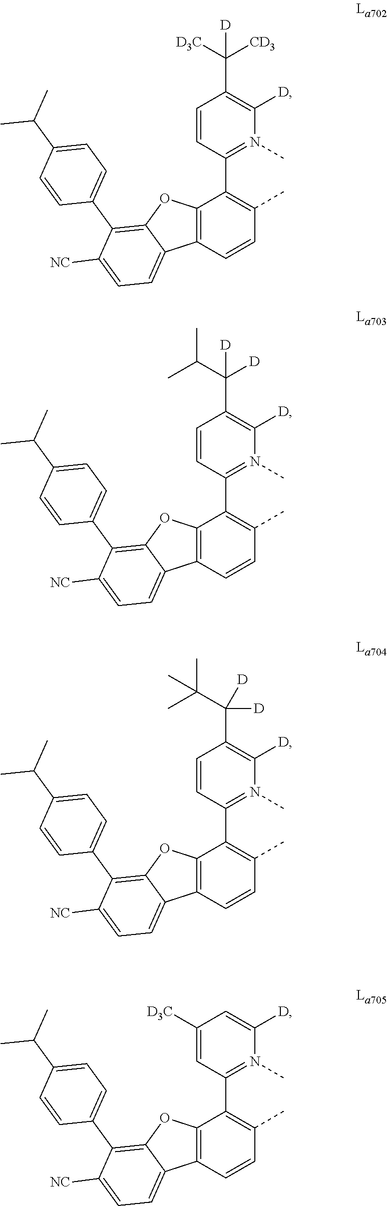

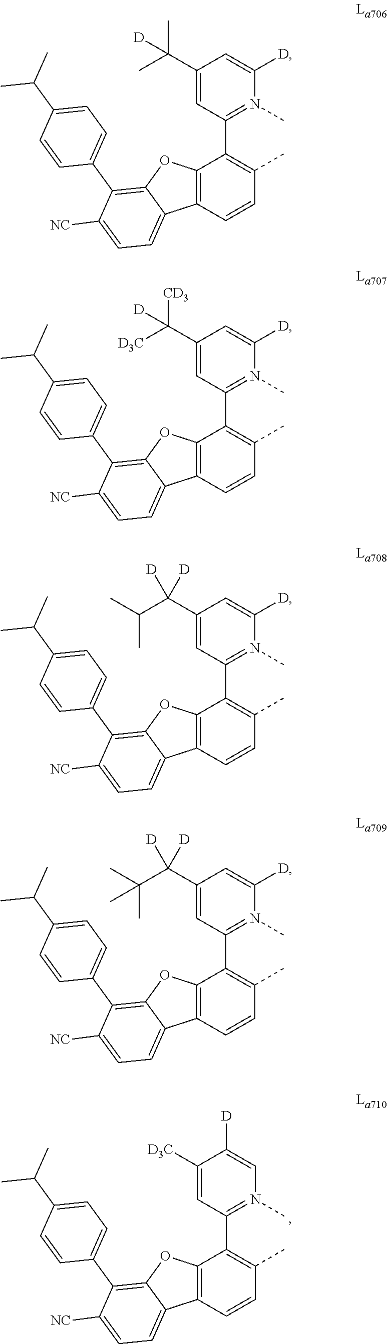

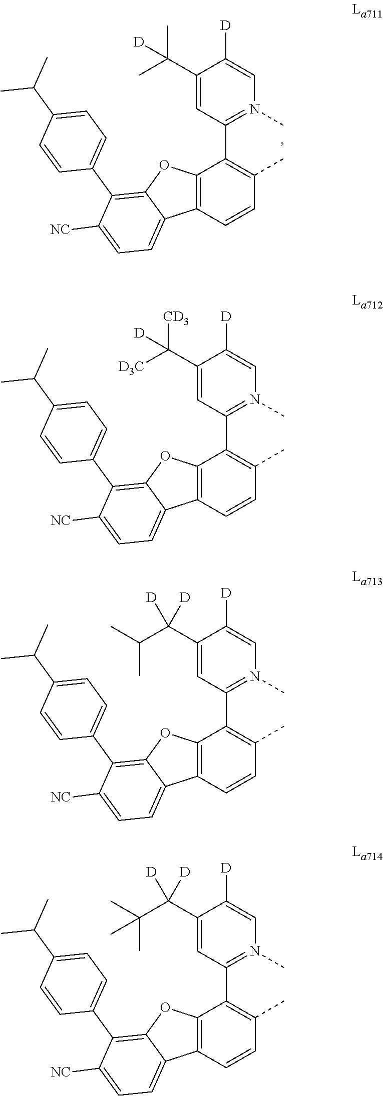

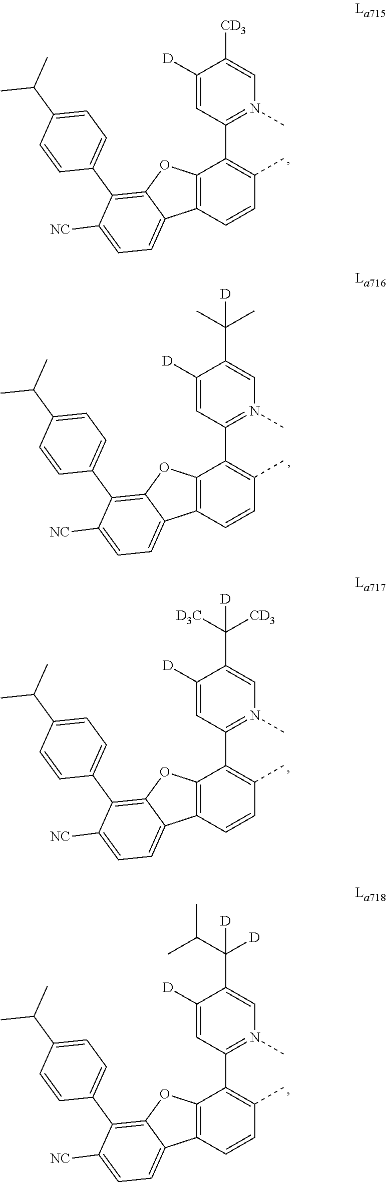

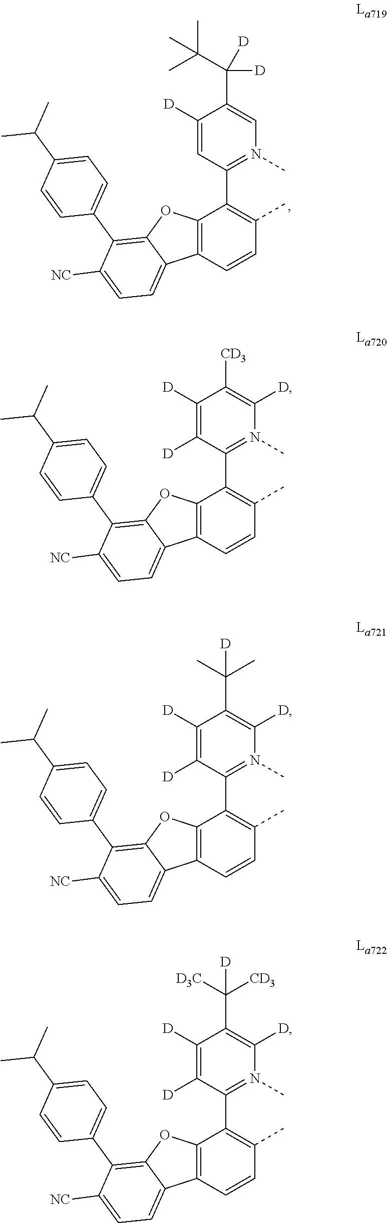

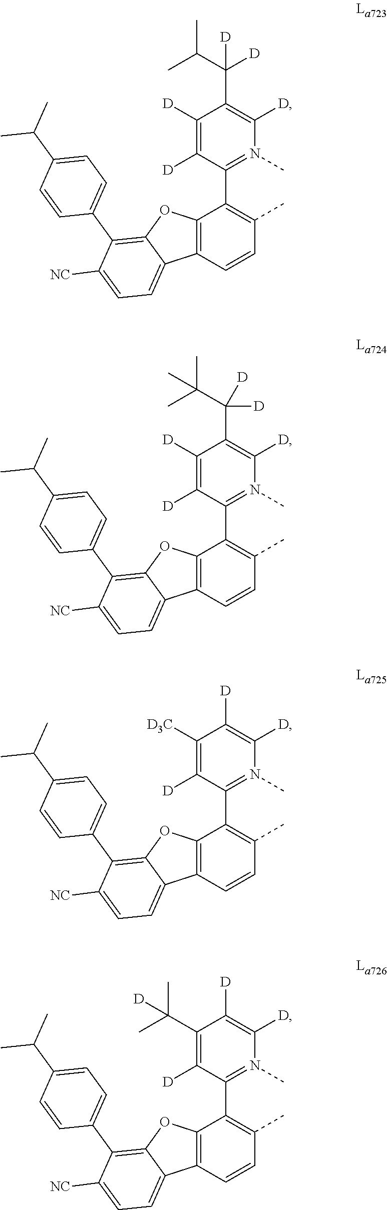

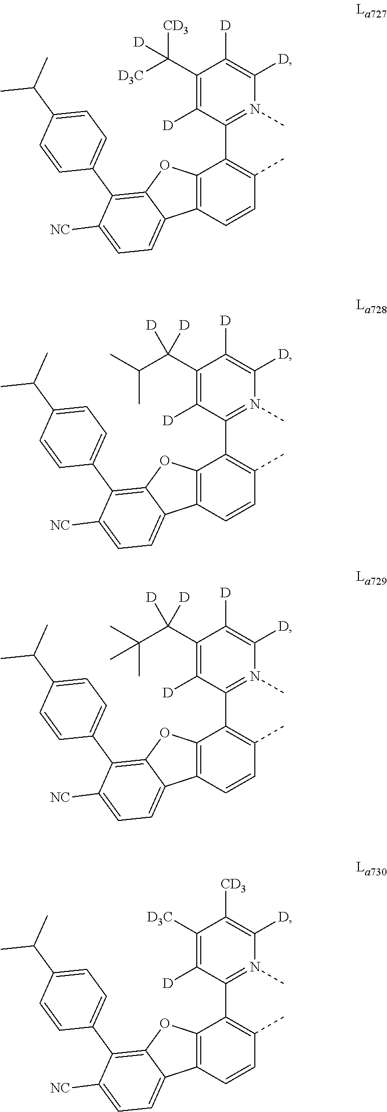

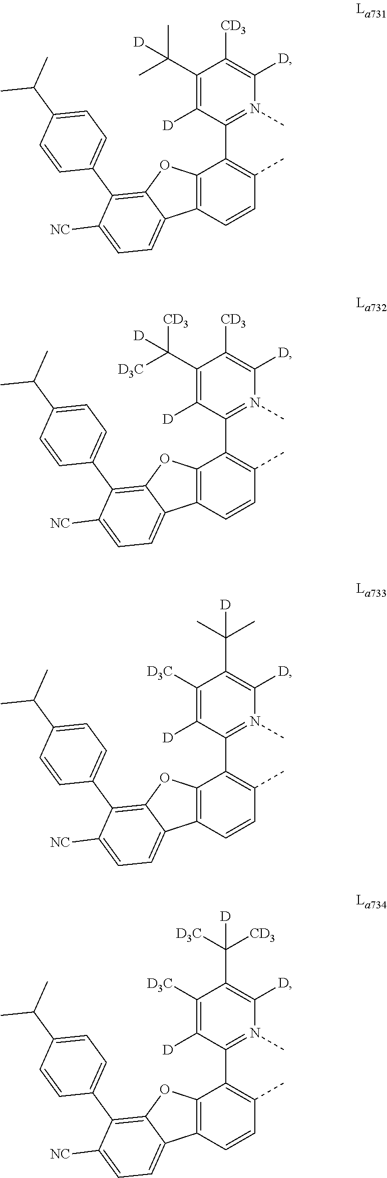

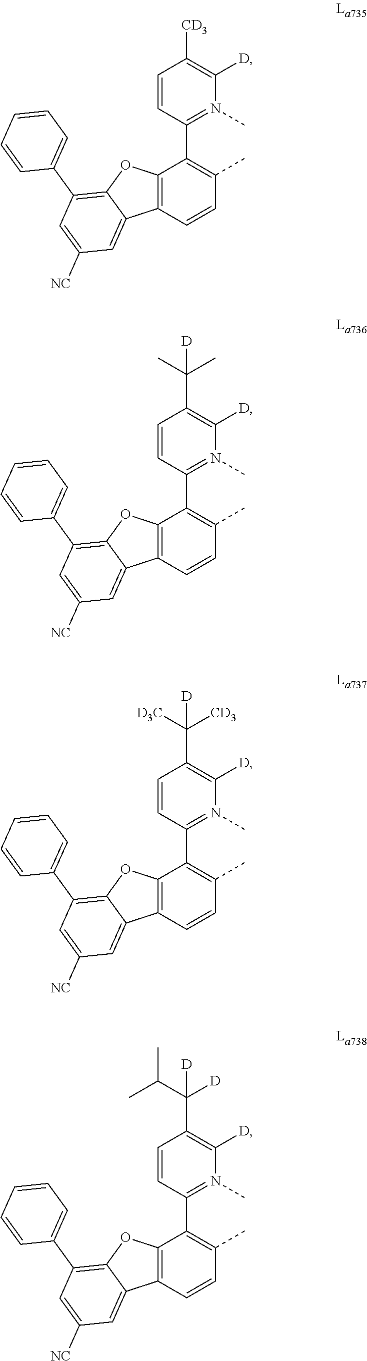

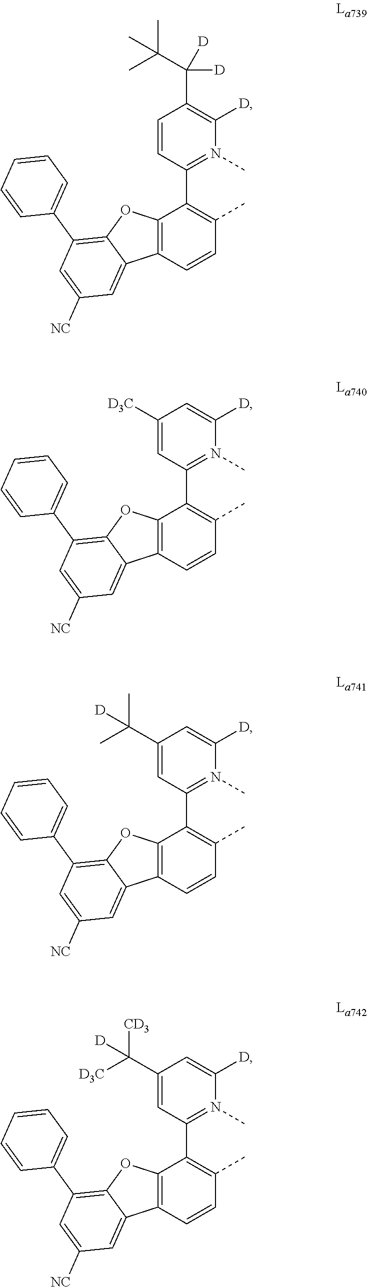

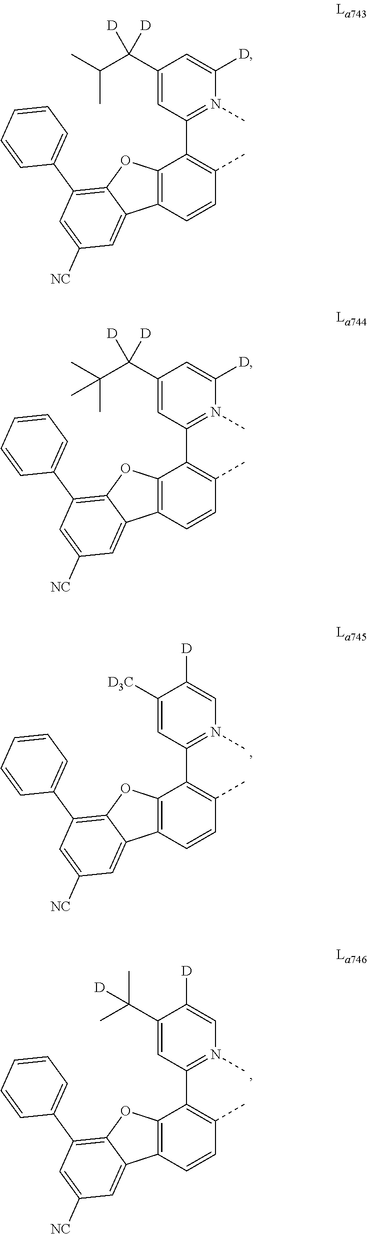

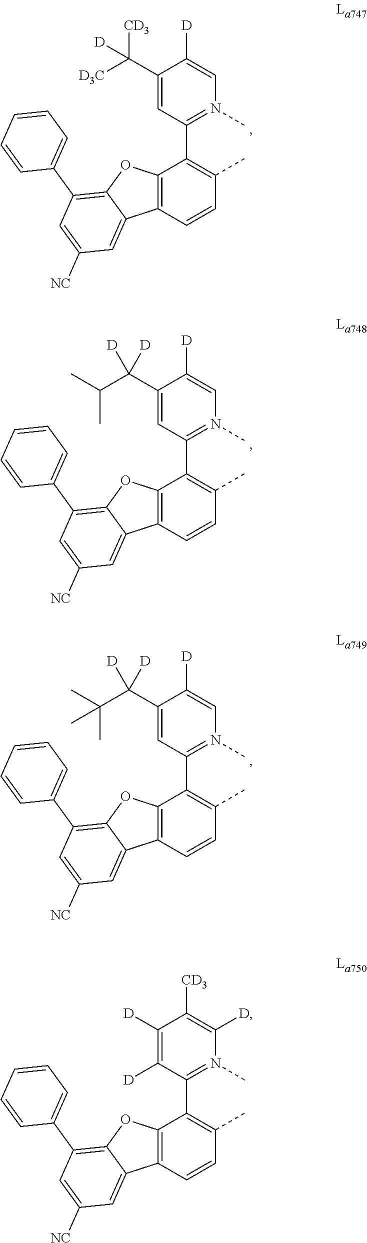

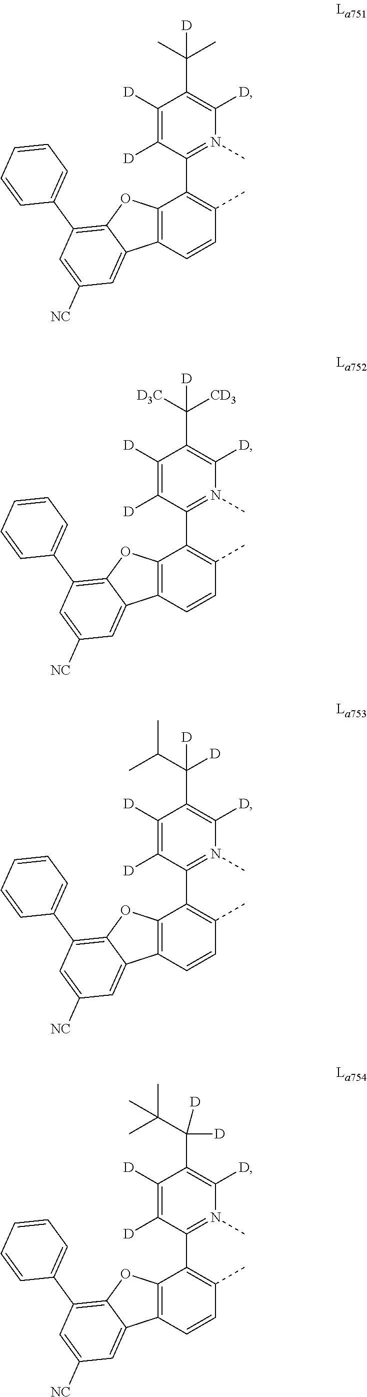

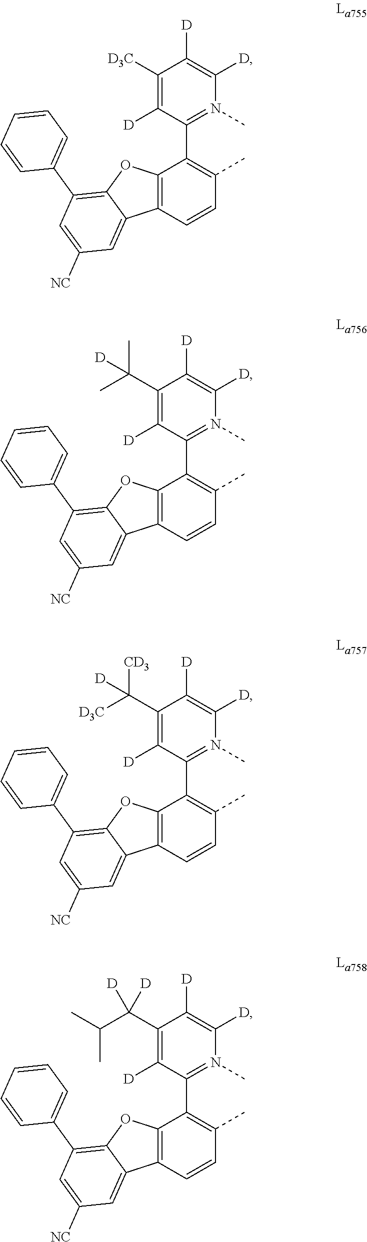

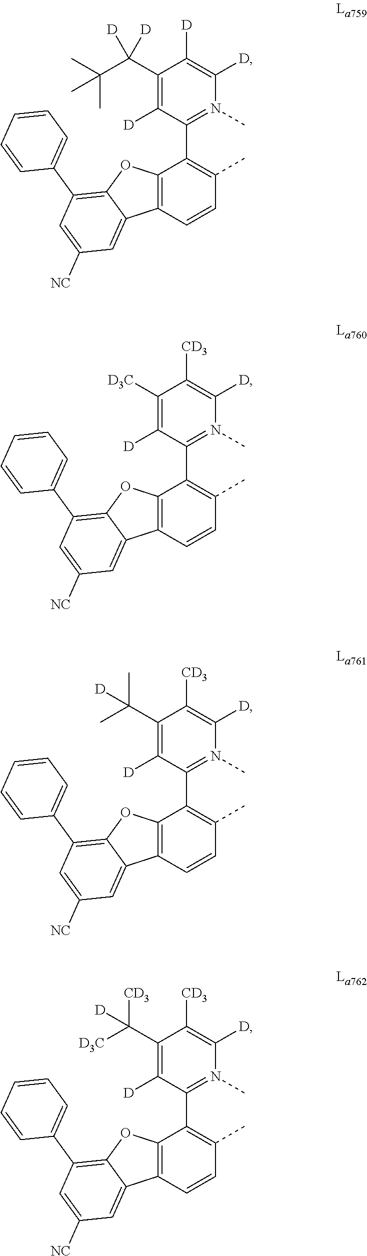

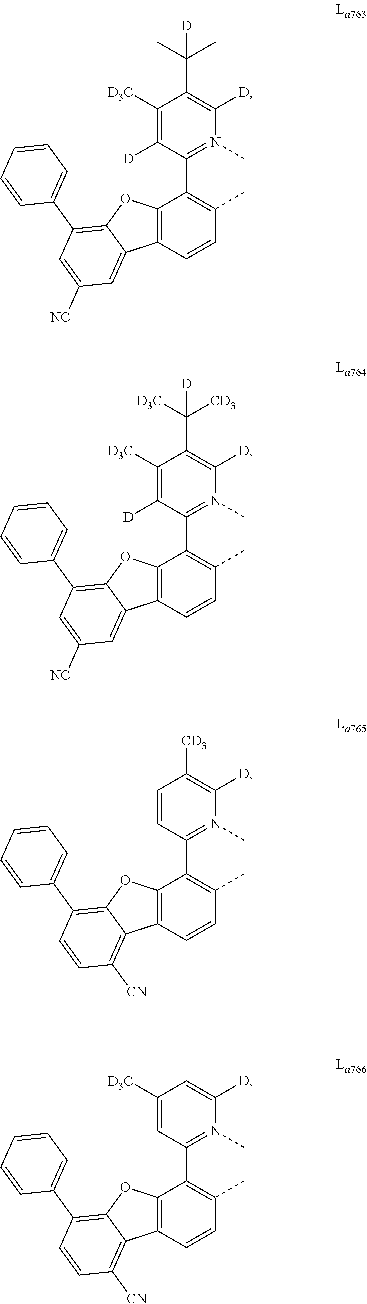

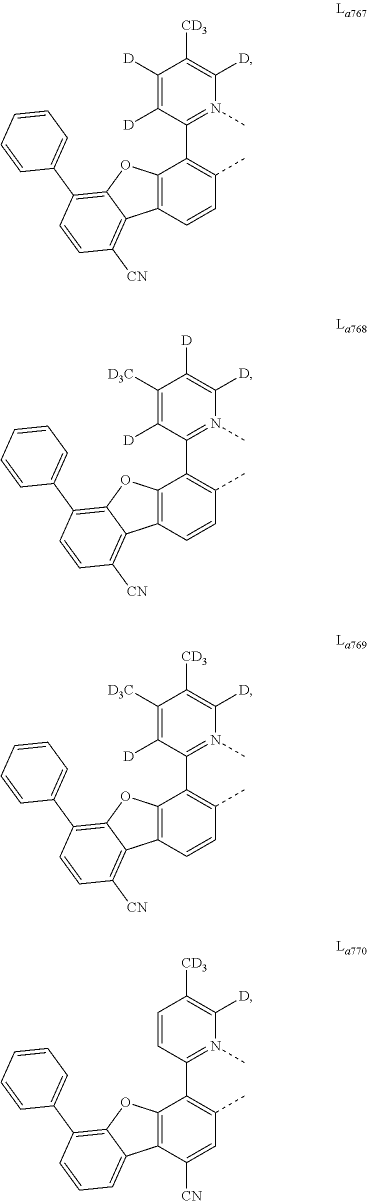

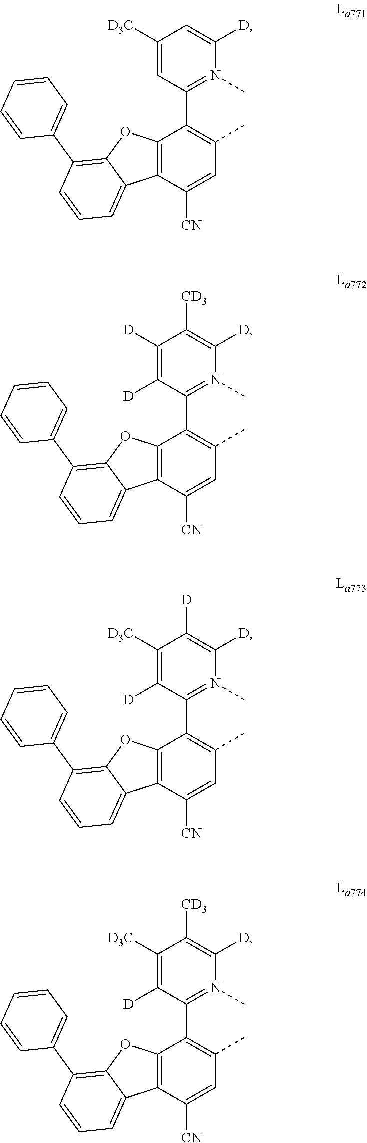

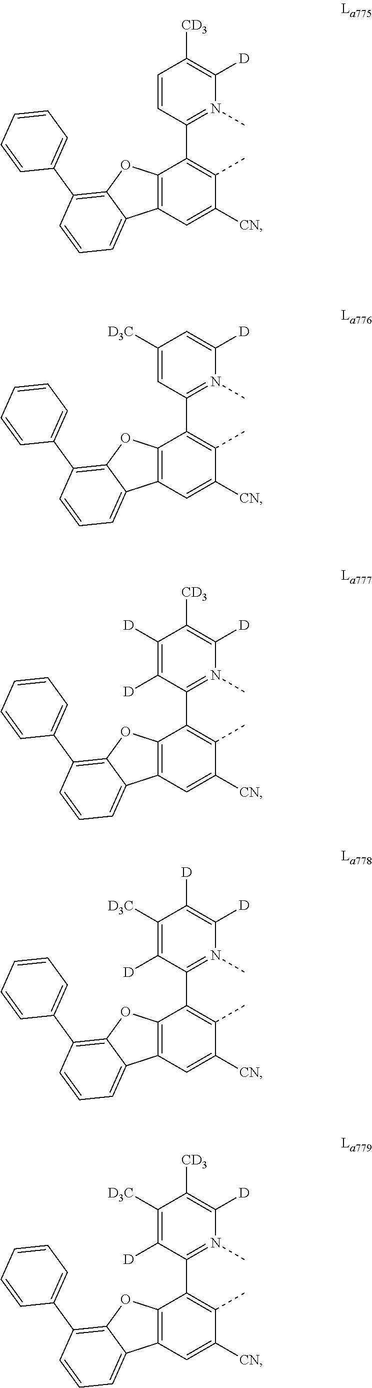

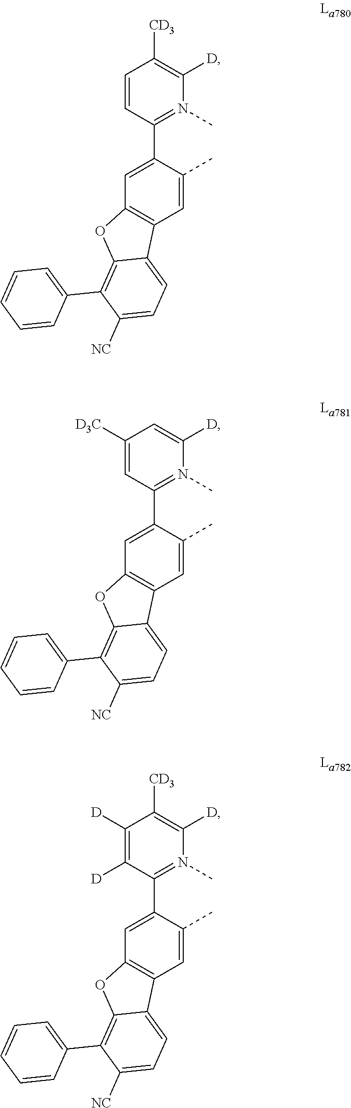

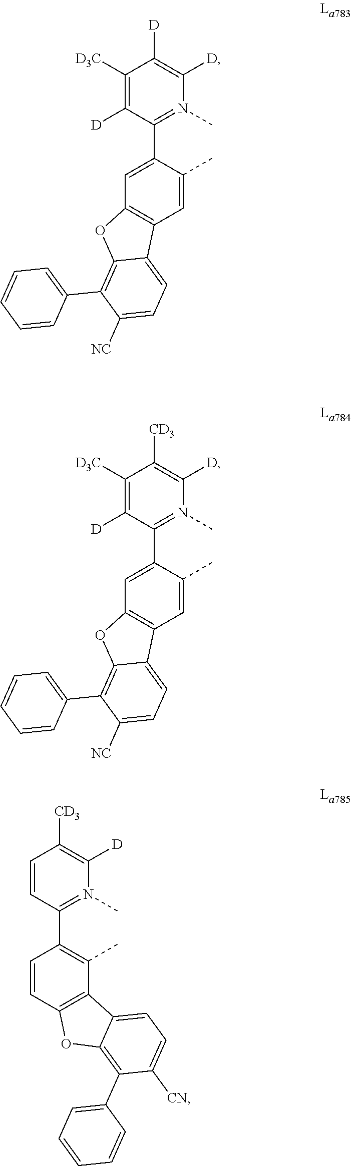

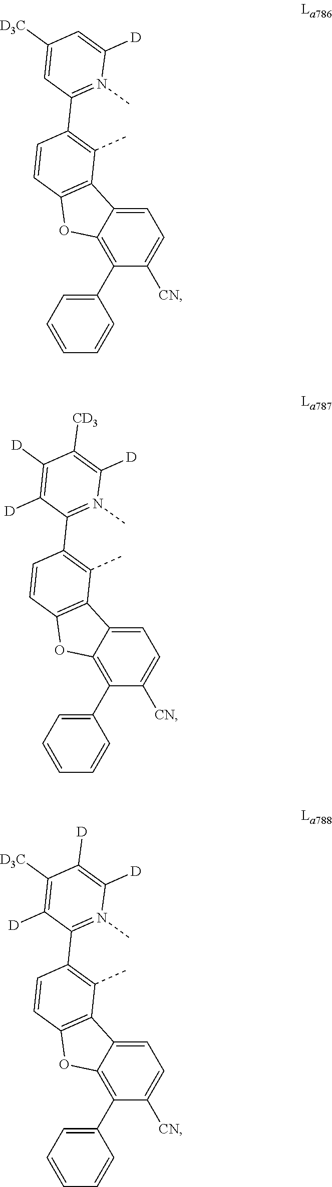

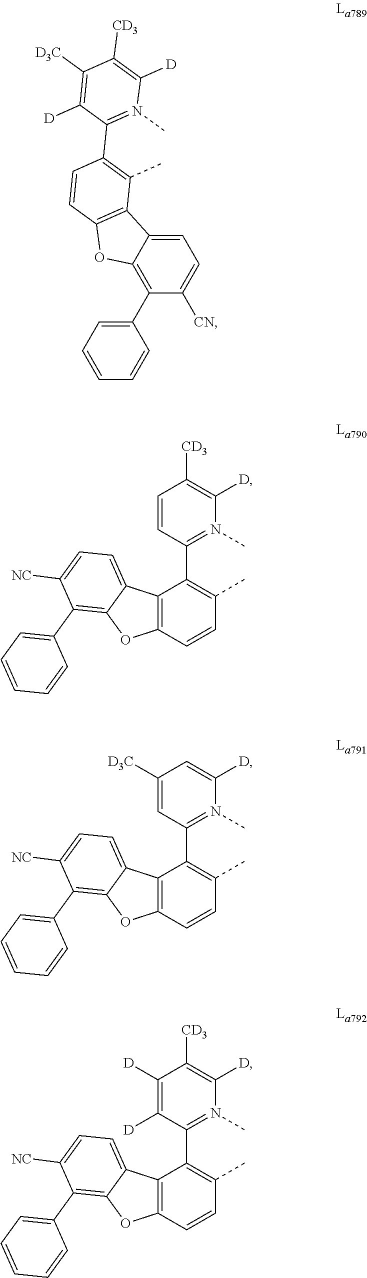

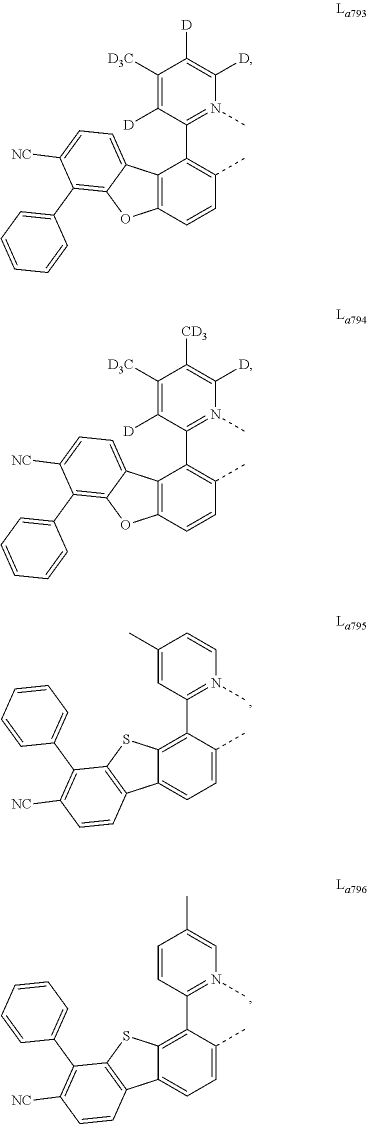

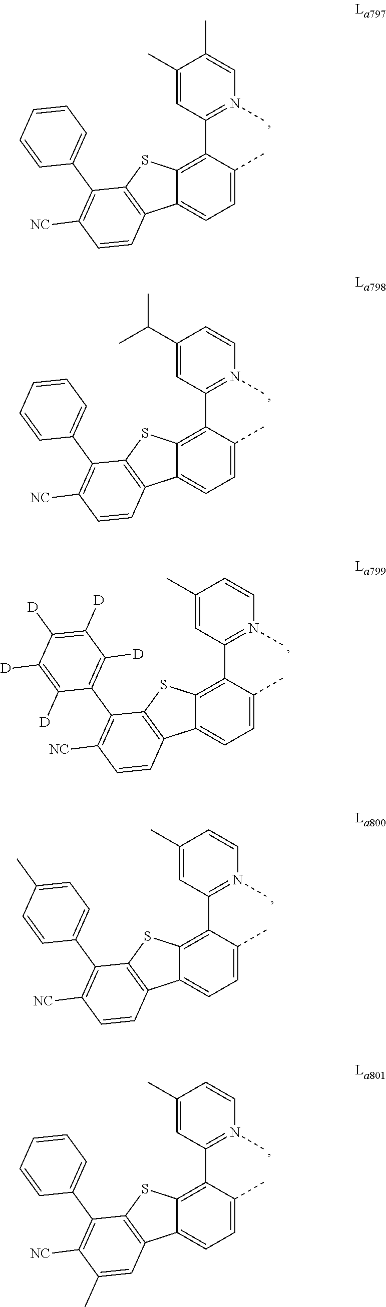

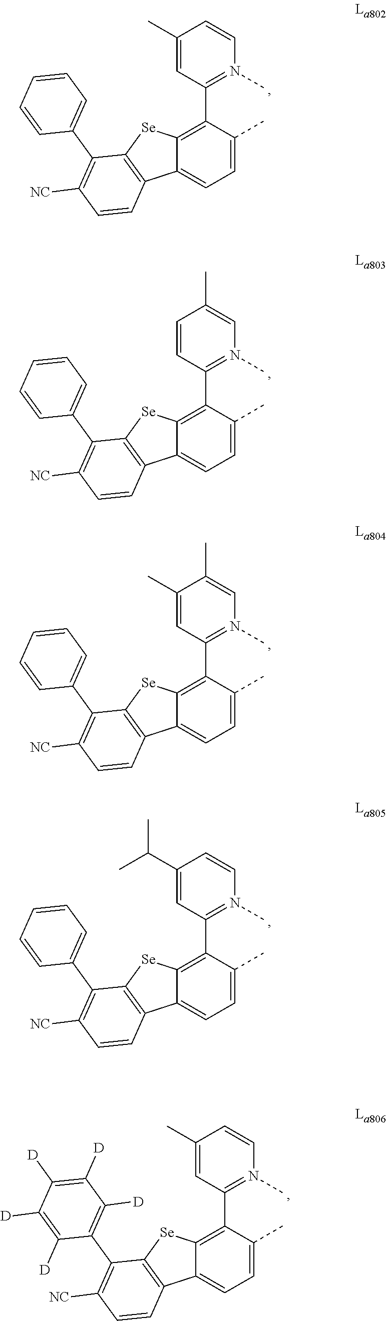

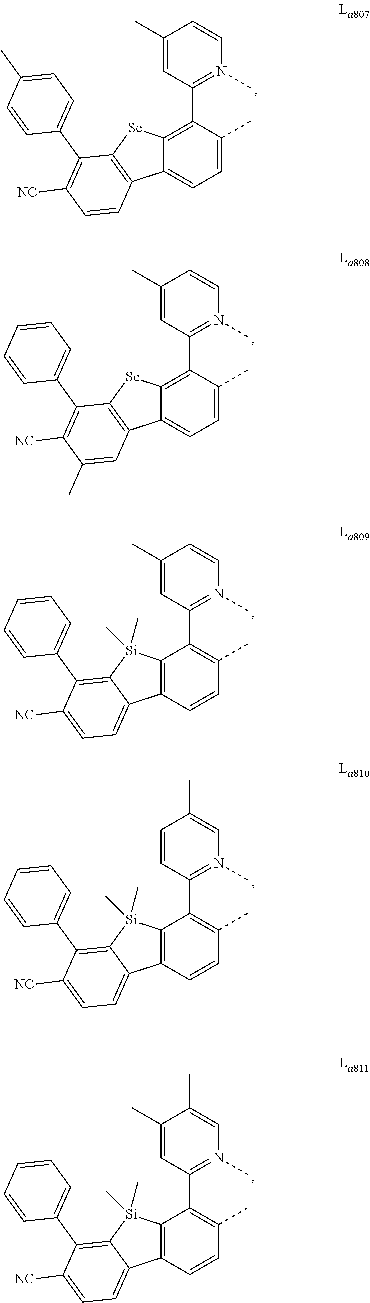

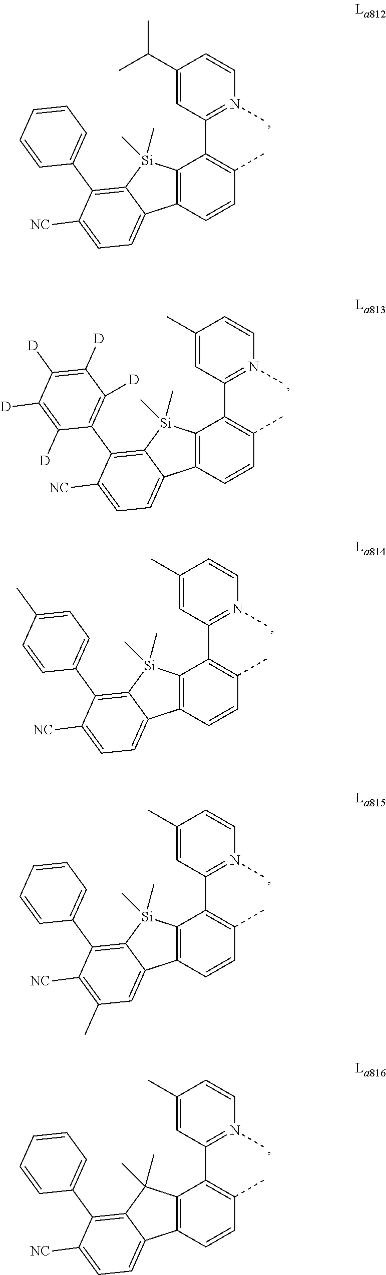

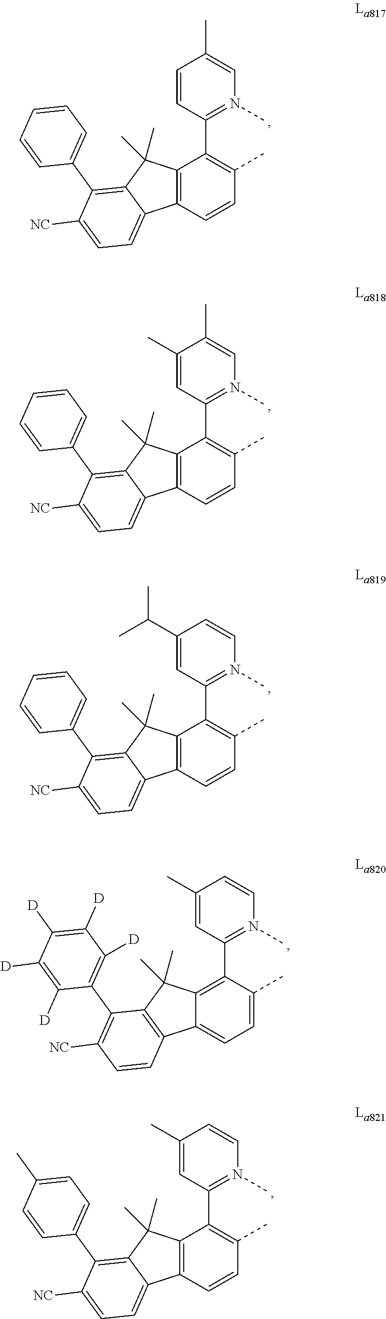

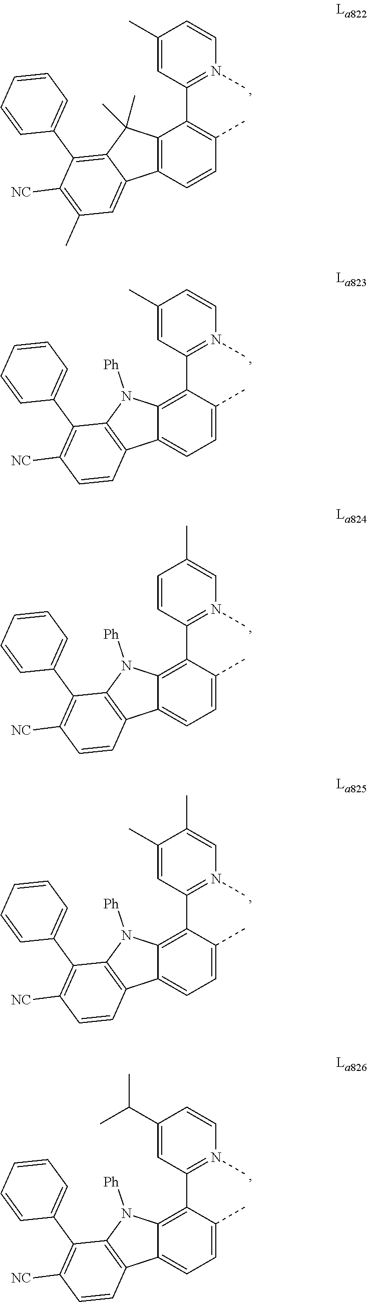

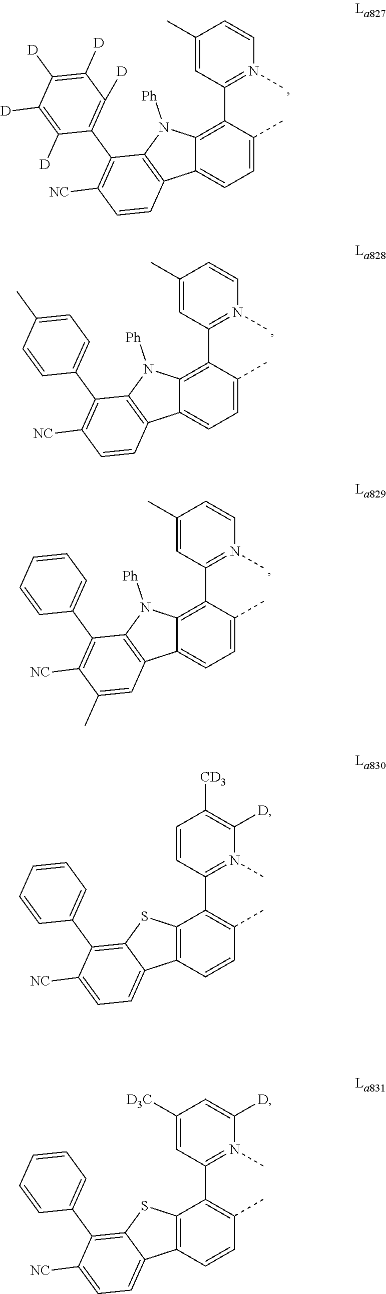

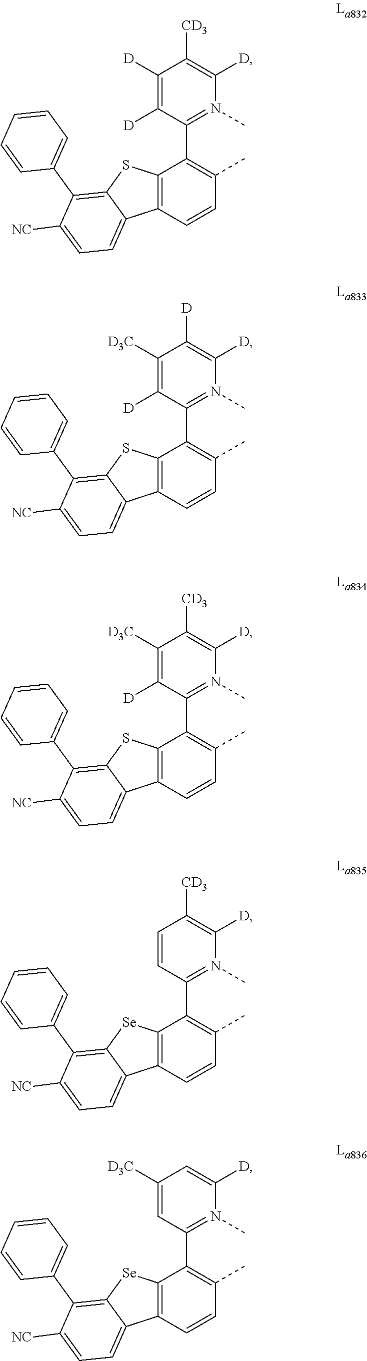

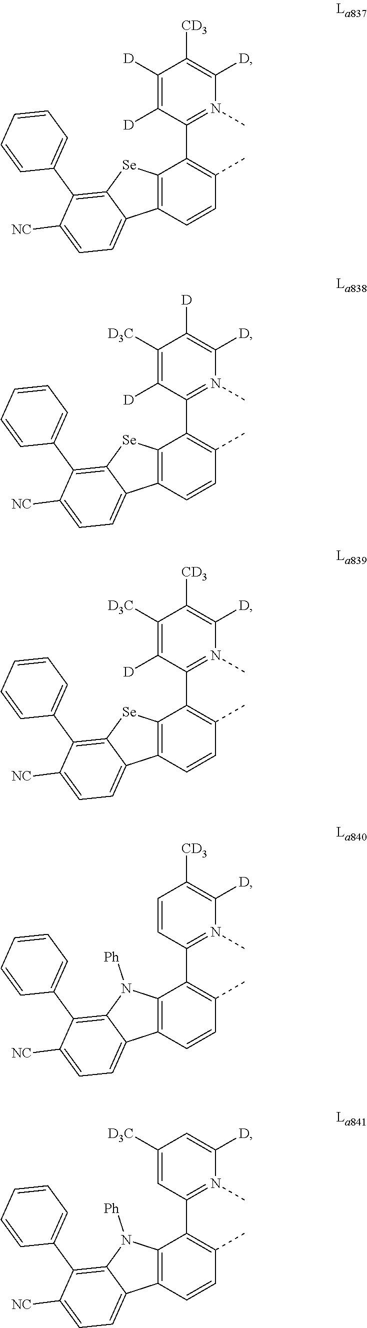

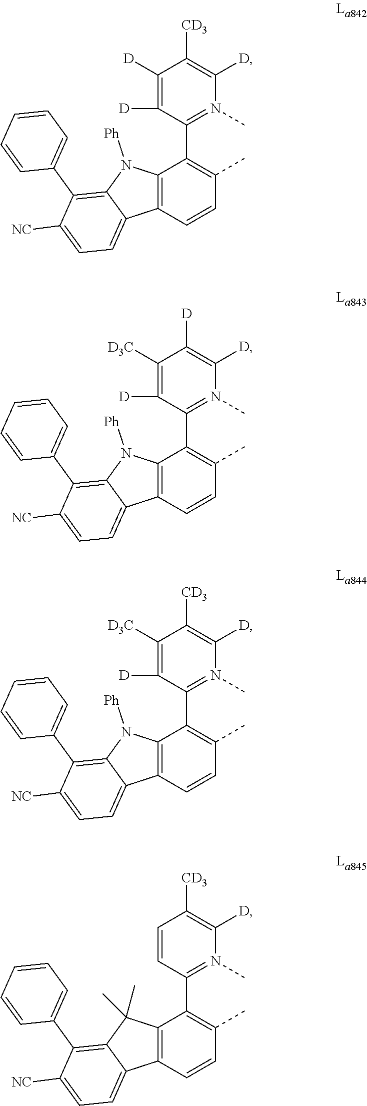

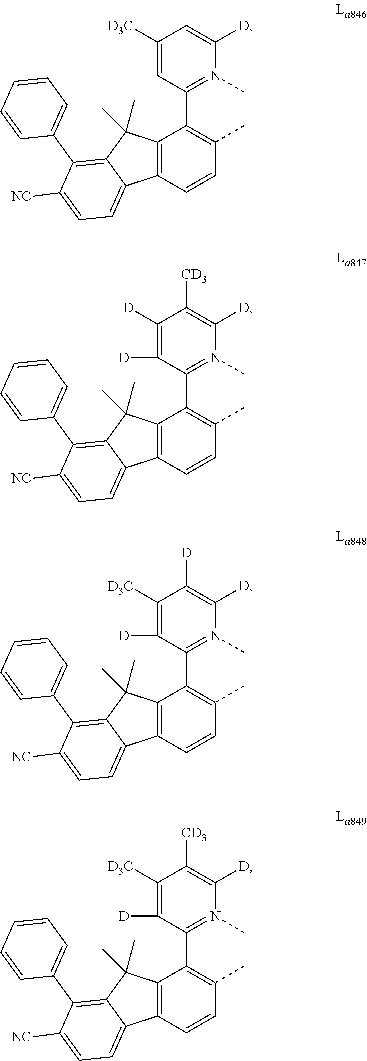

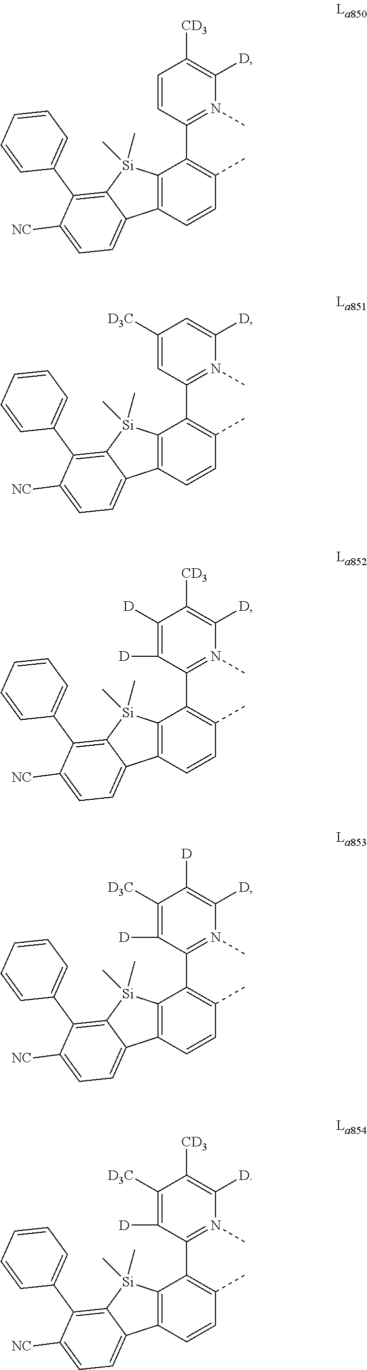

21. The metal complex of claim 2, wherein the ligand L_{b} is, at each occurrence identically or differently, any one selected from the group consisting of: 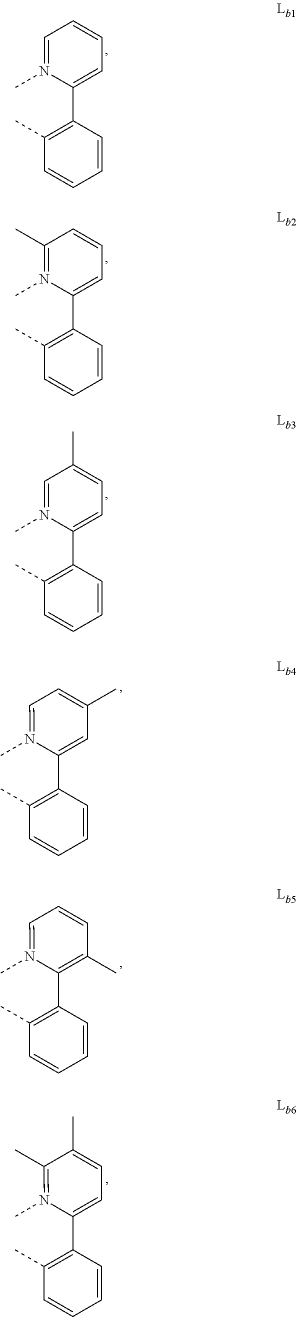 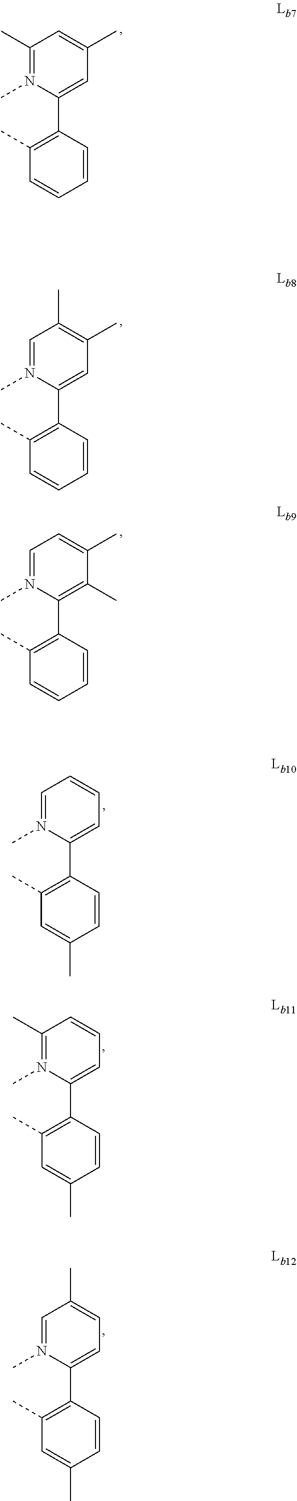 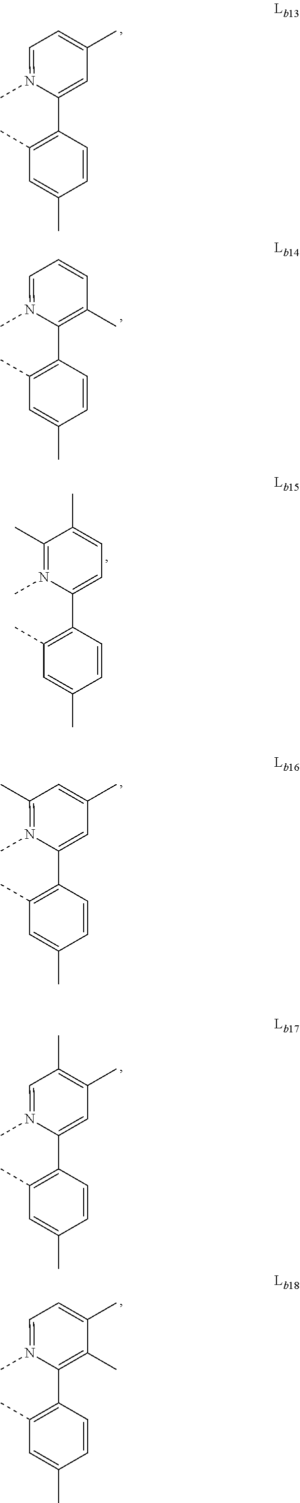 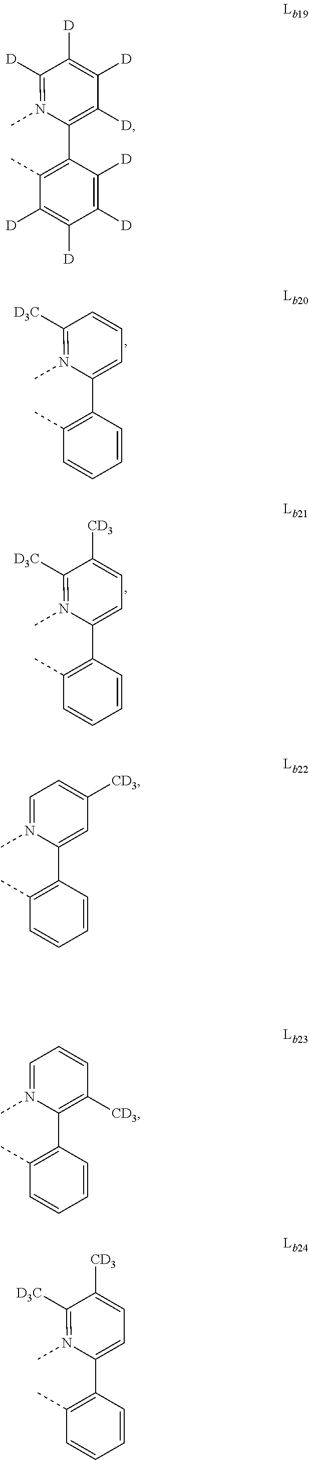 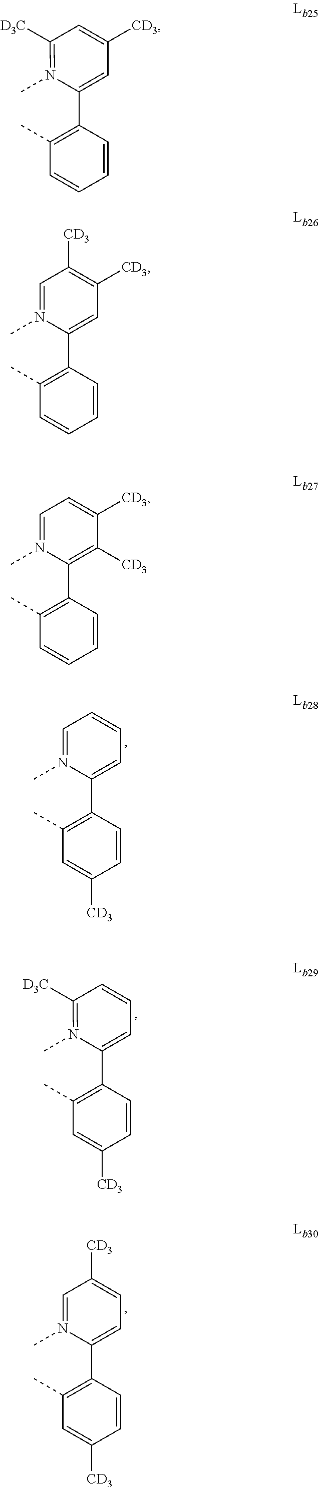 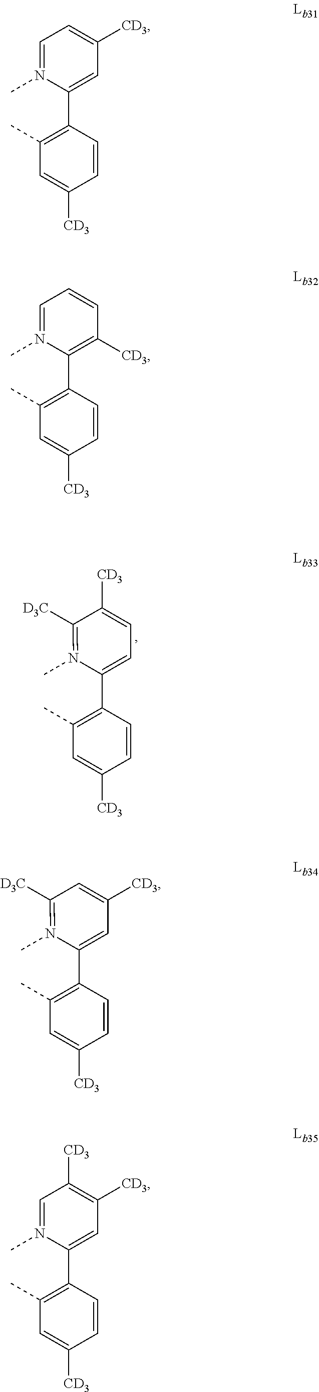 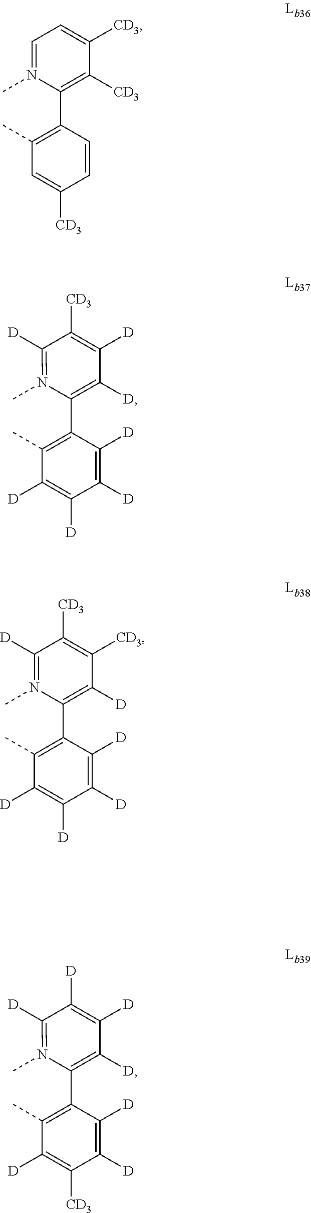 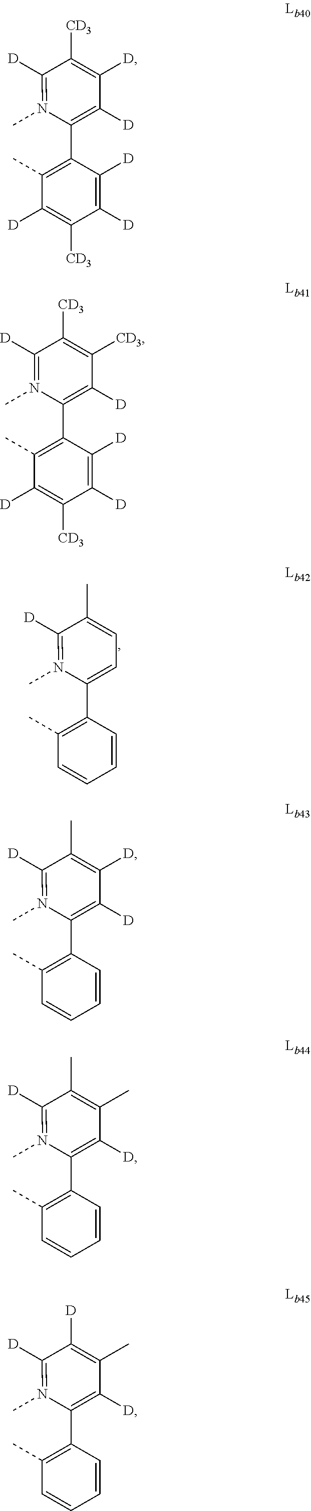 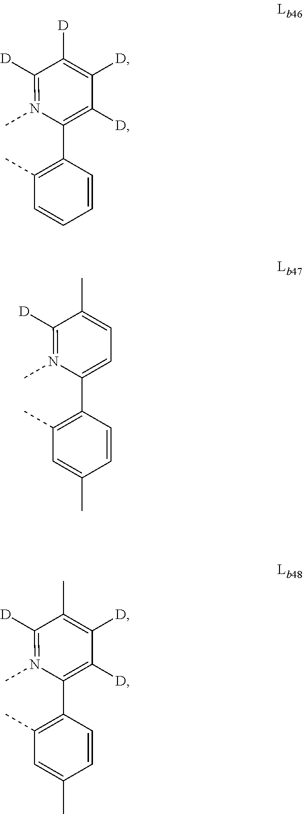 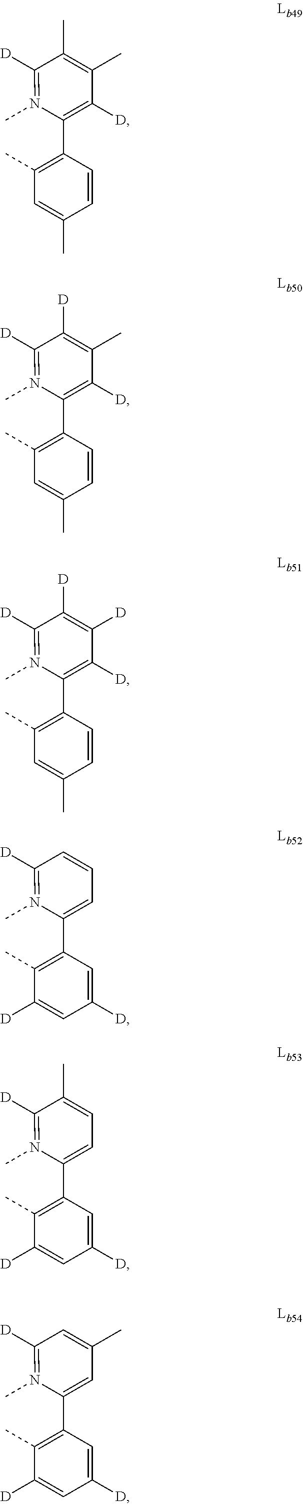 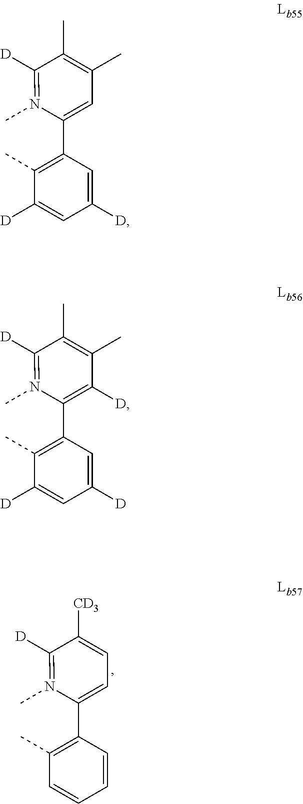 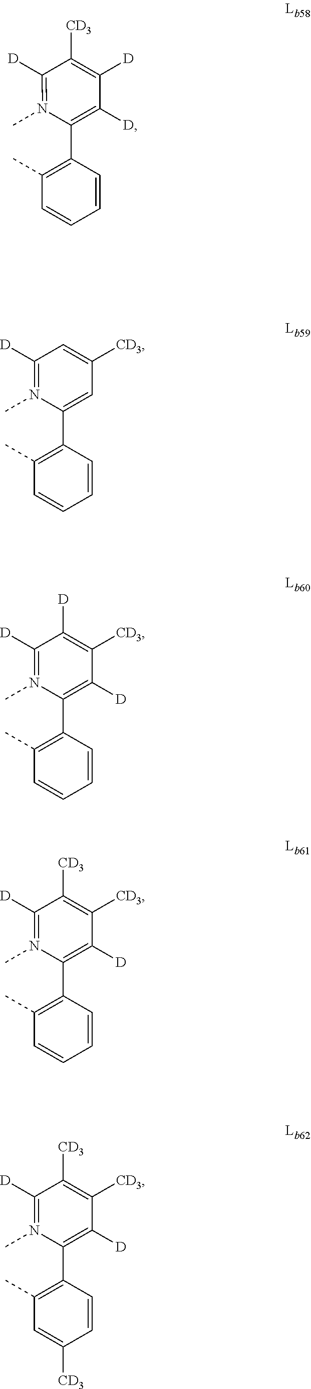 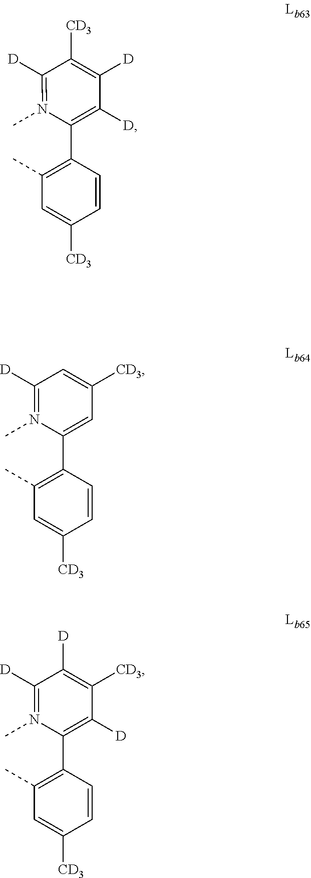 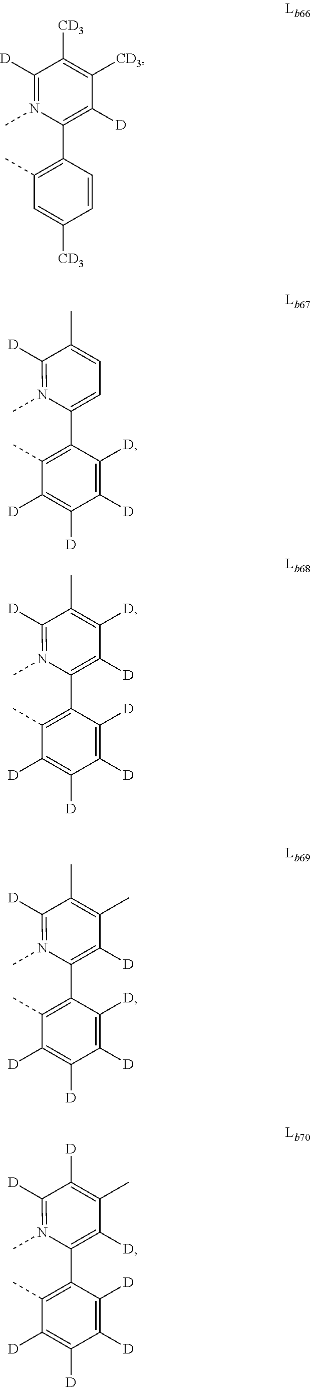 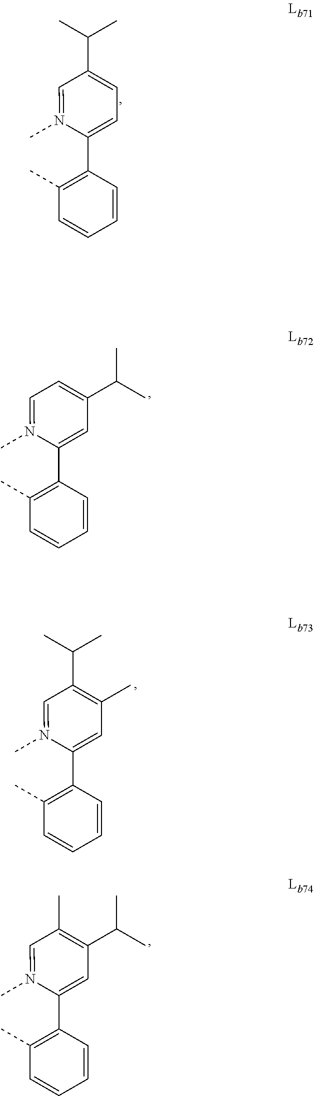 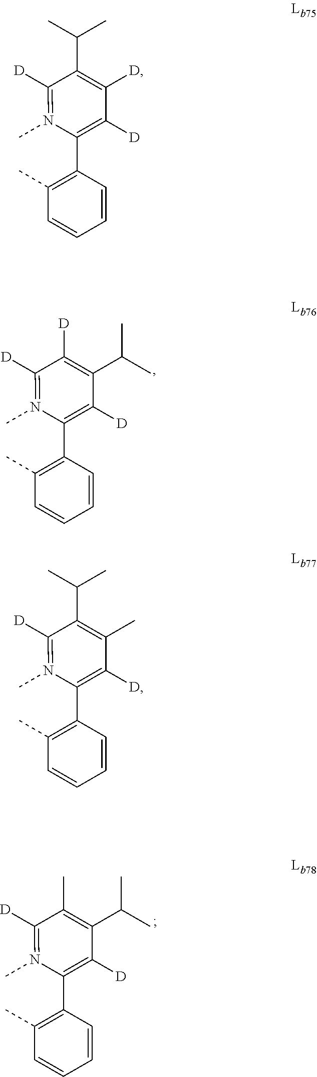
wherein the ligand L_{c} is, at each occurrence identically or differently, any one selected from the group consisting of:

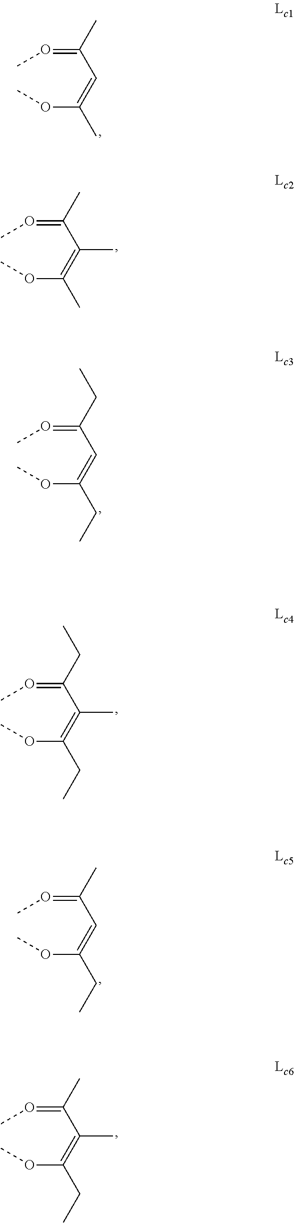

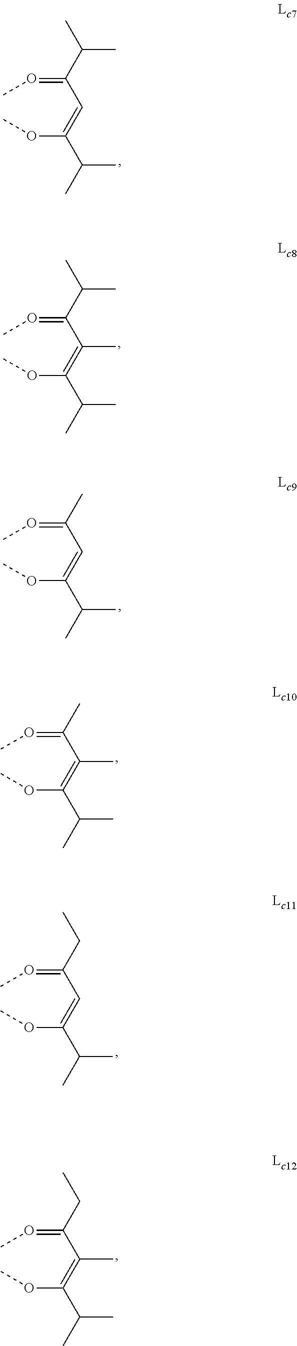

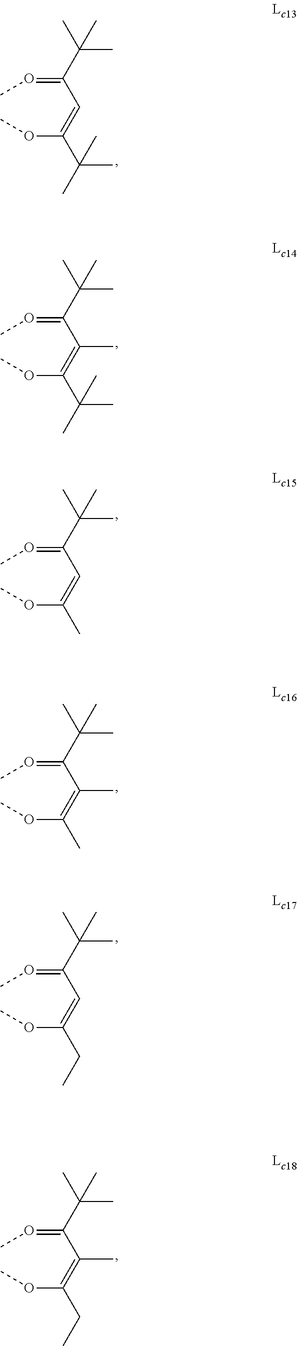

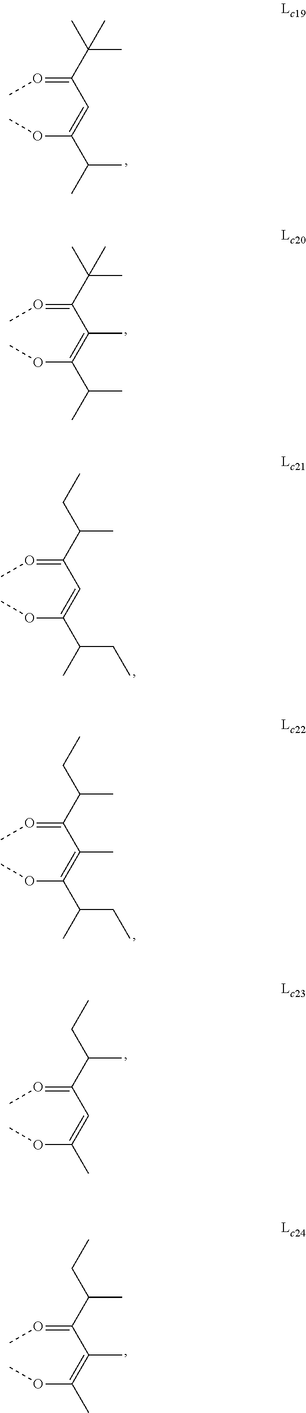

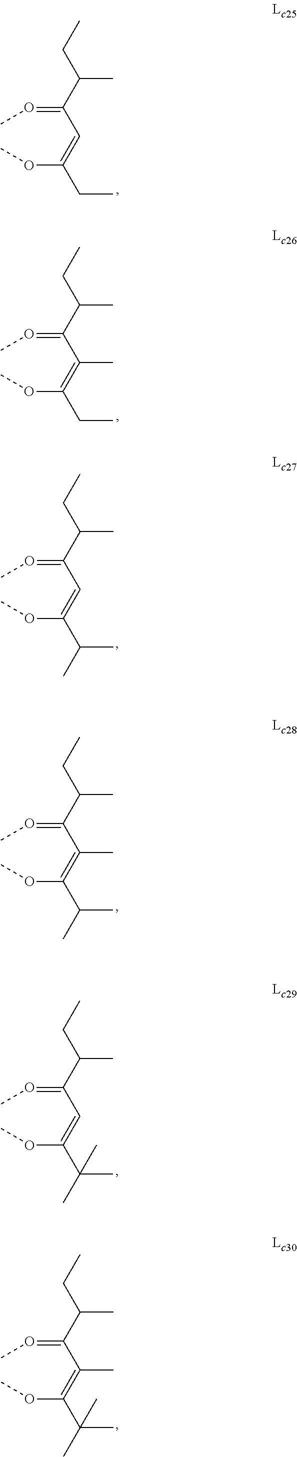

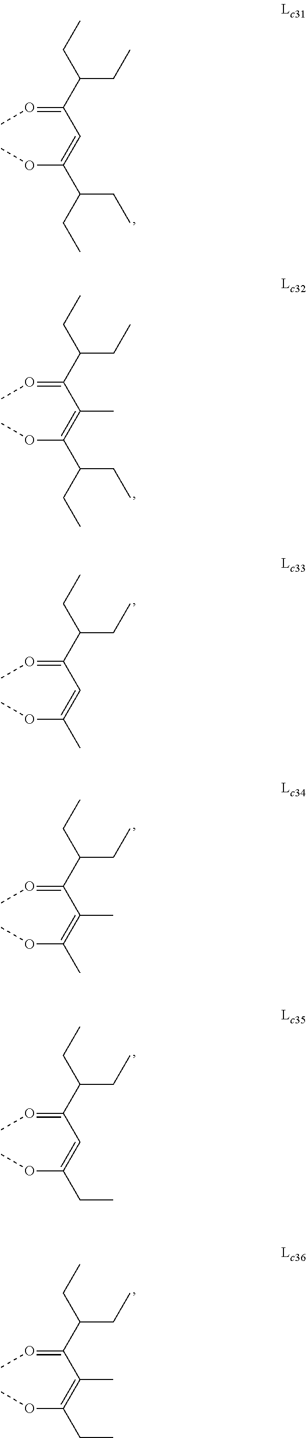

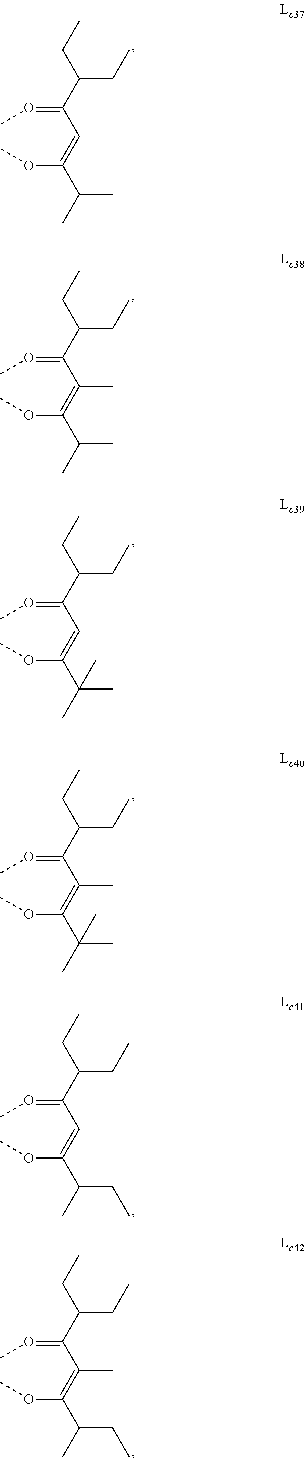

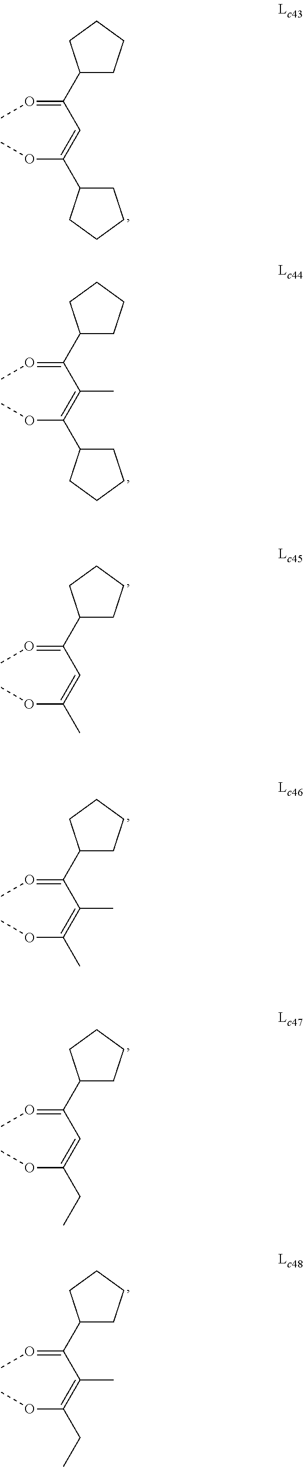

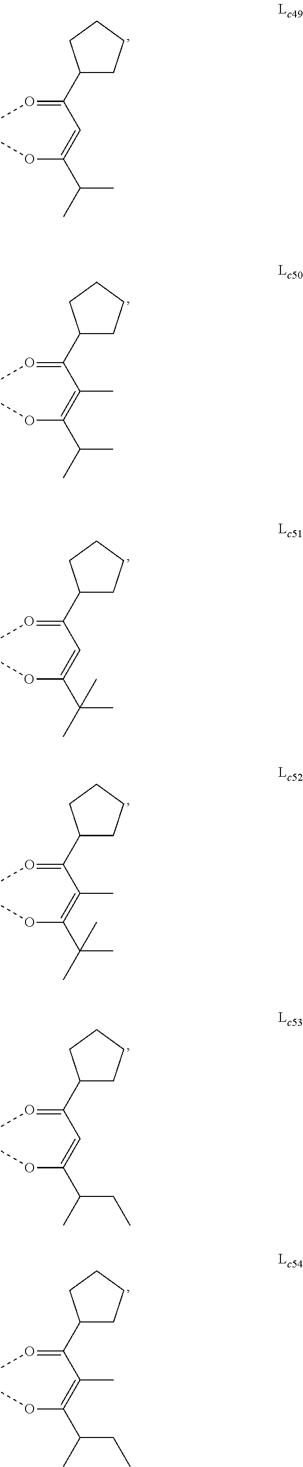

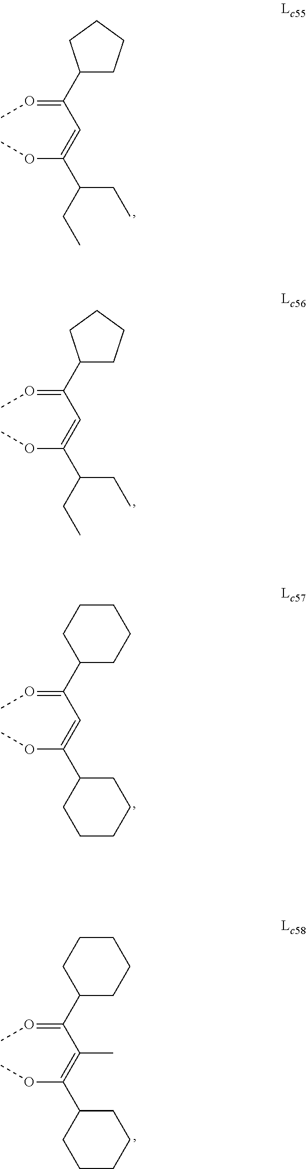

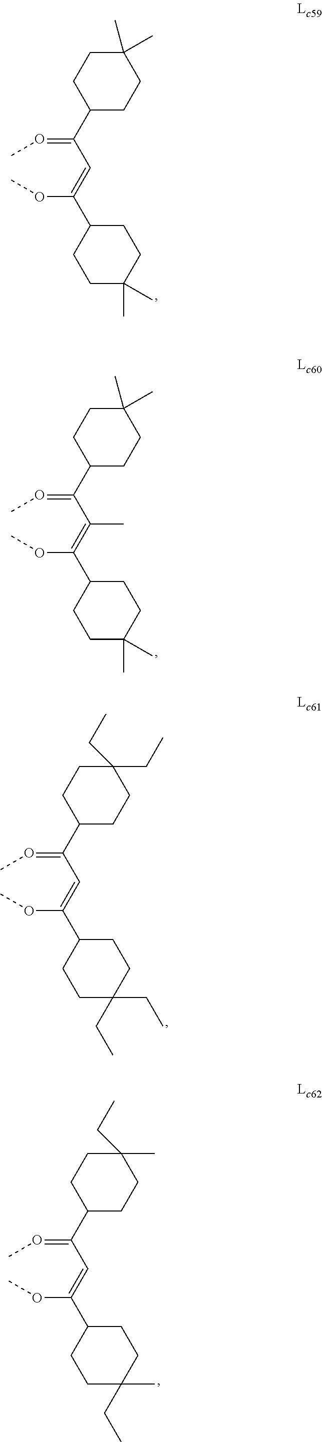

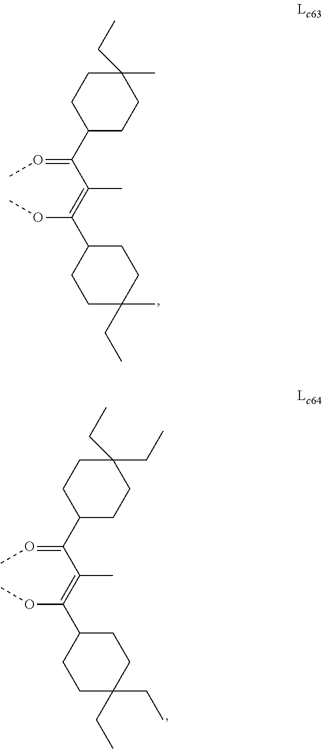

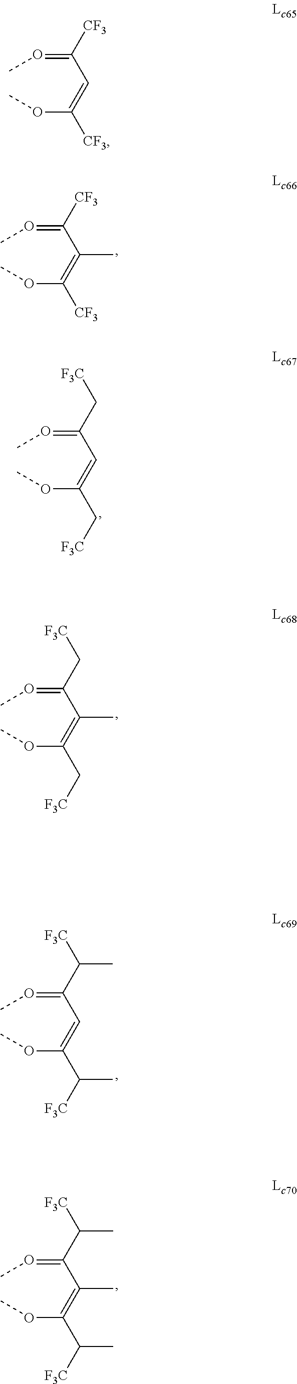

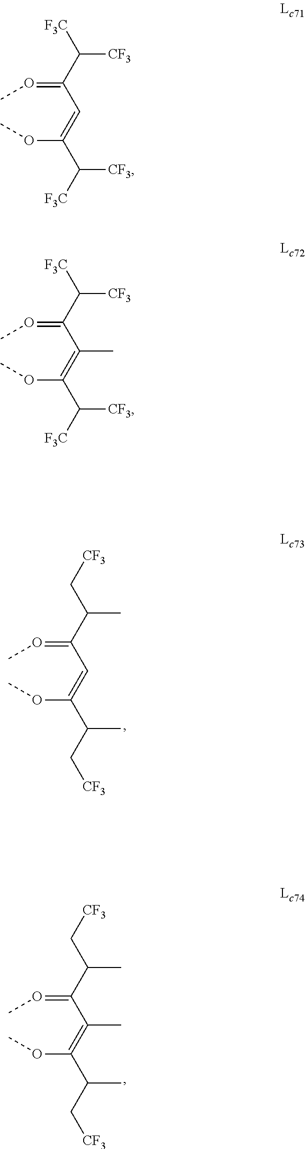

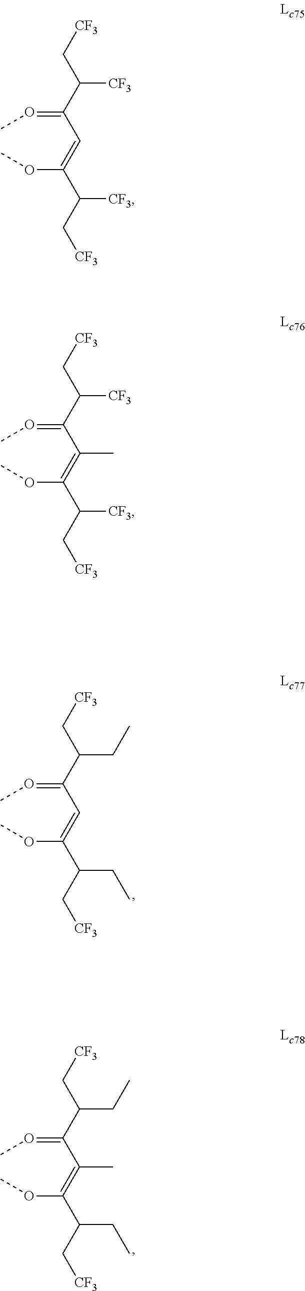

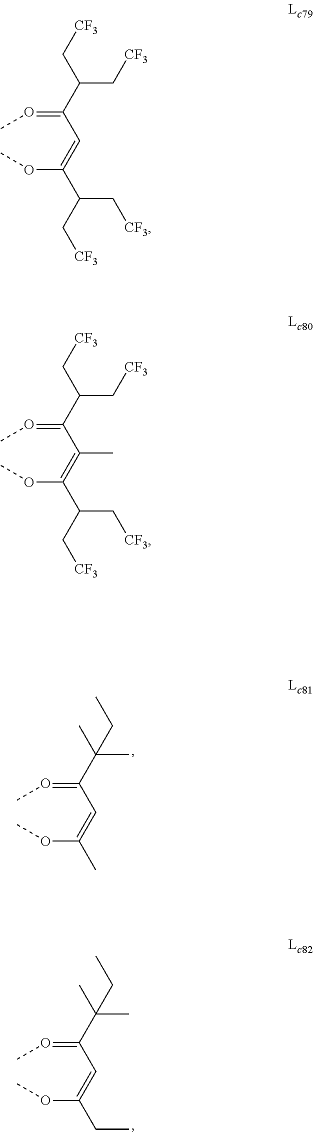

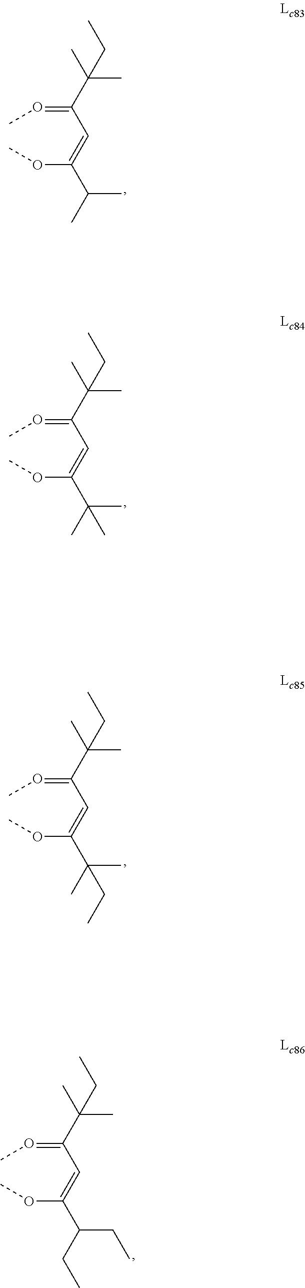

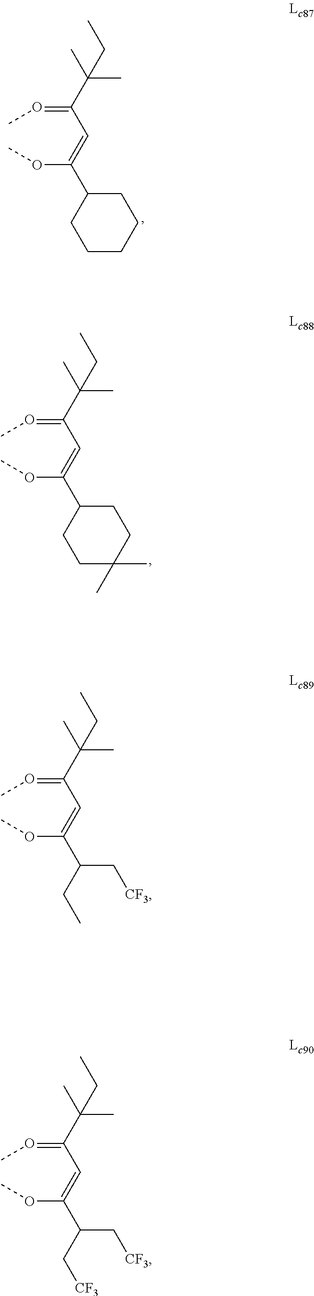

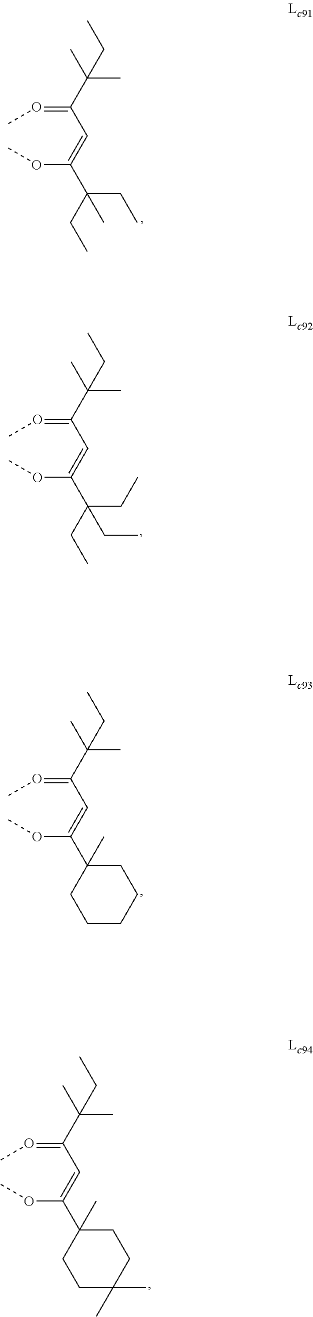

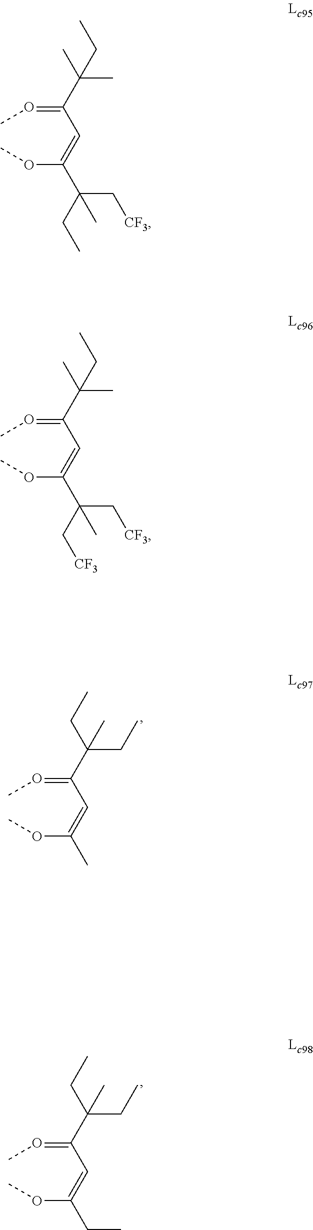

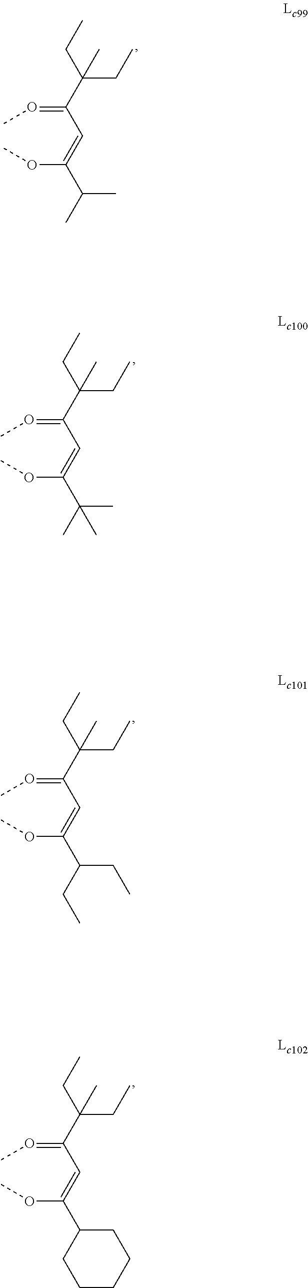

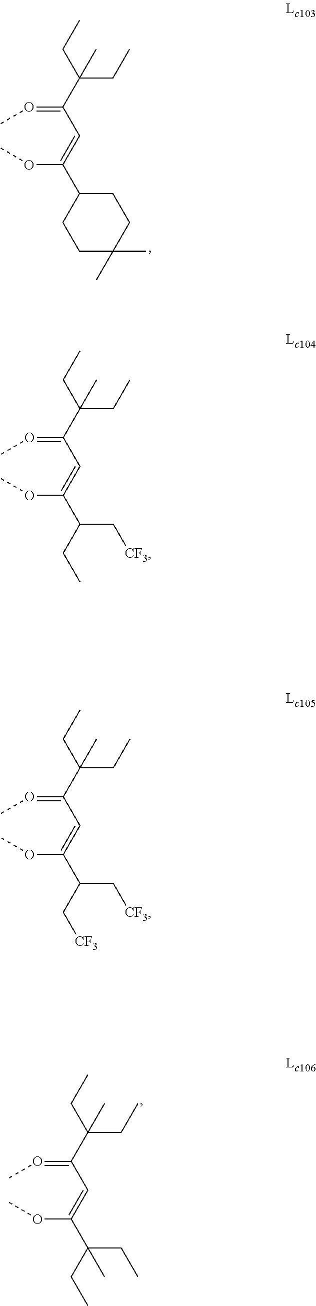

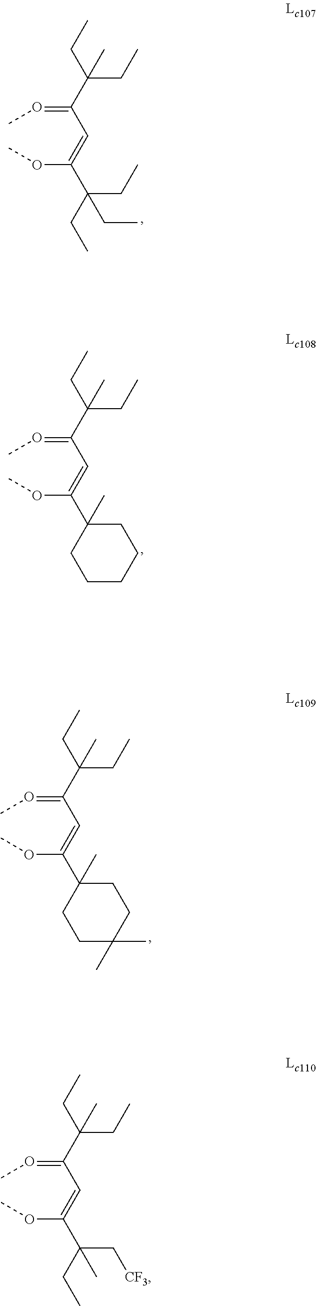

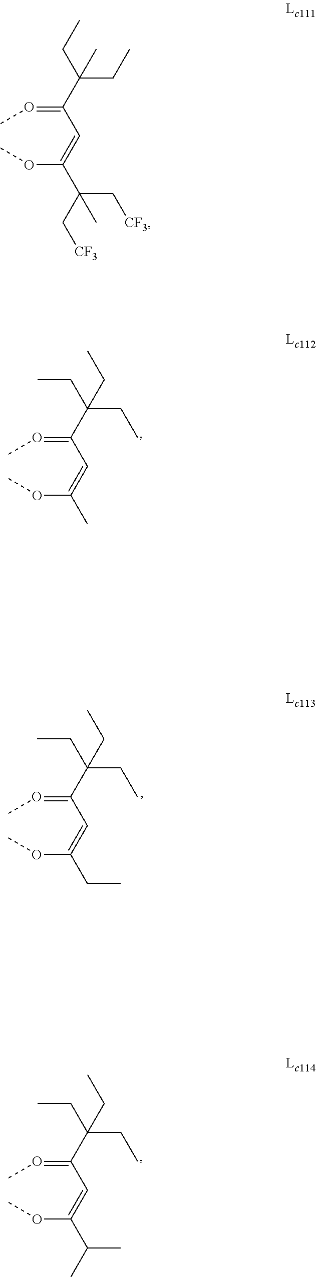

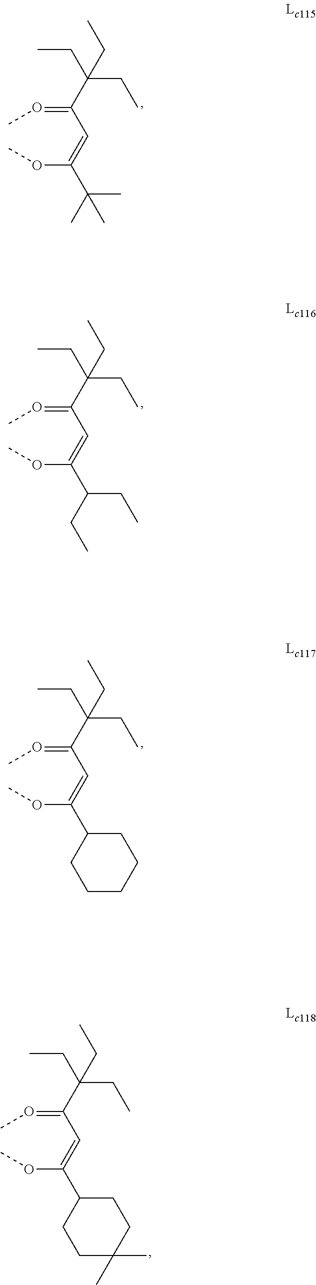

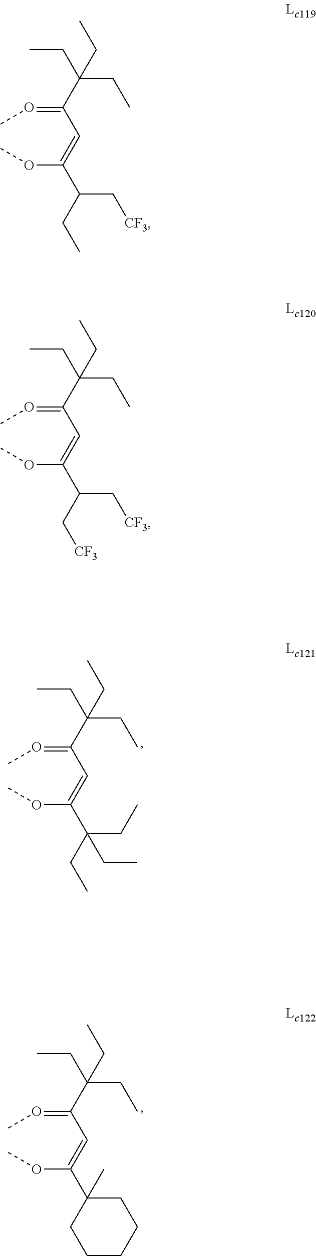

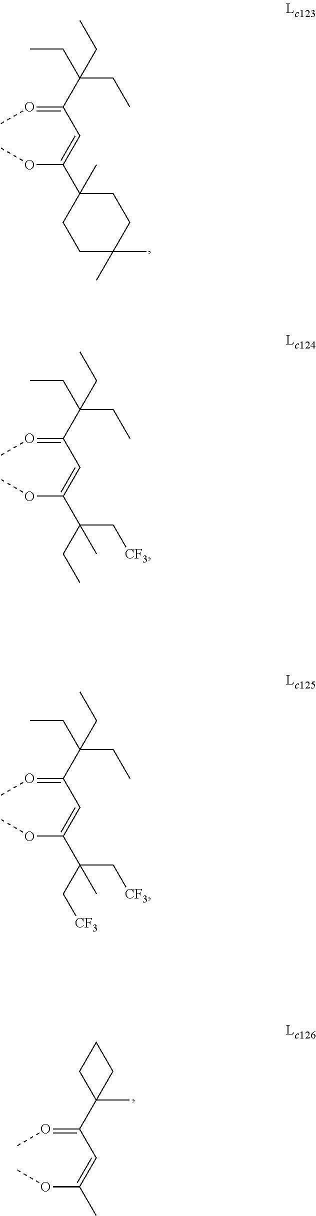

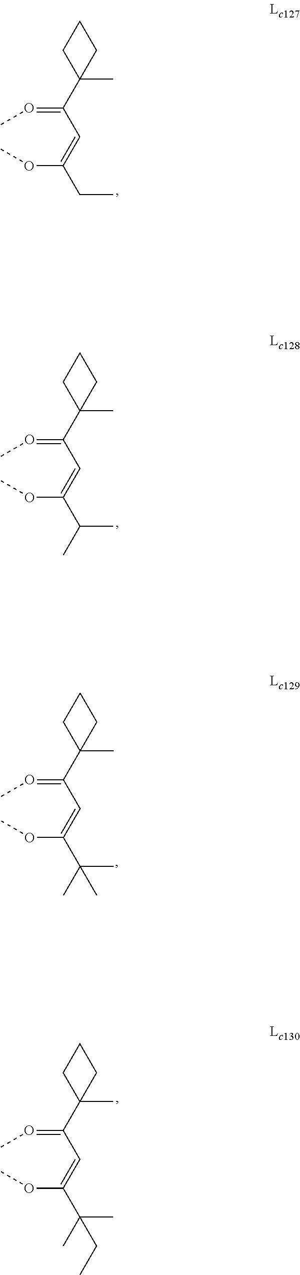

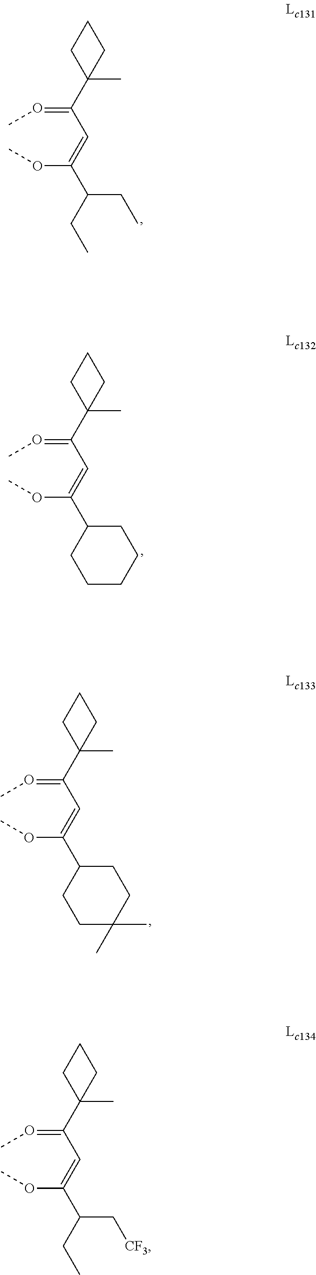

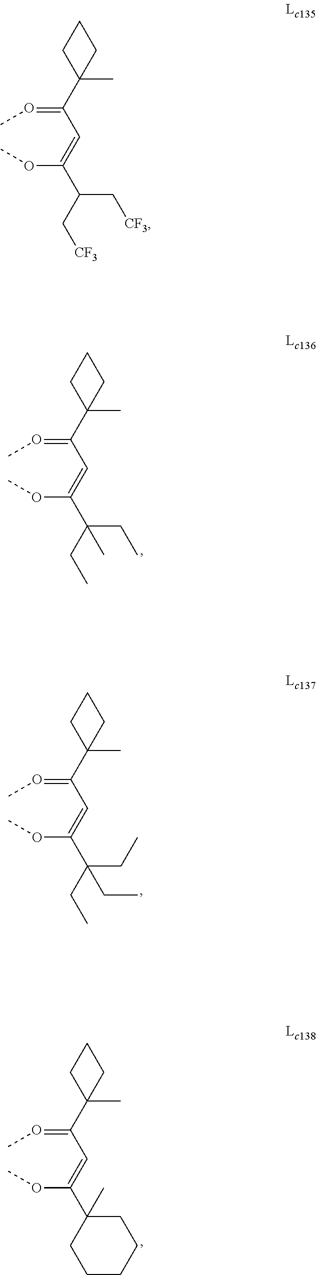

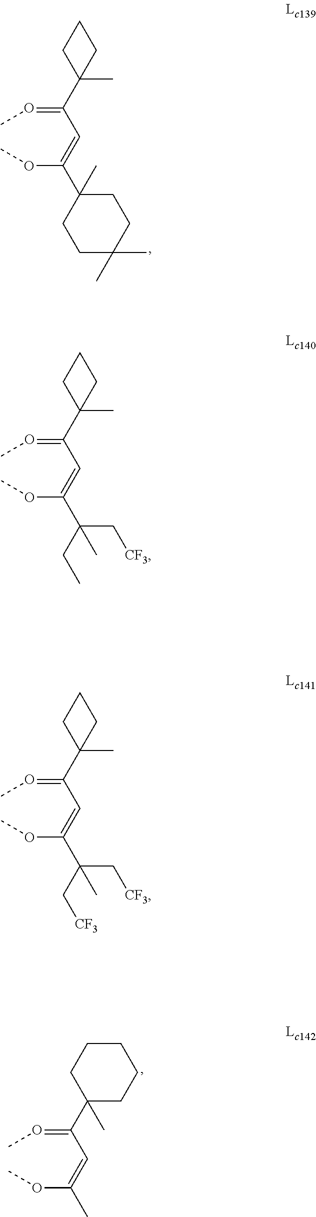

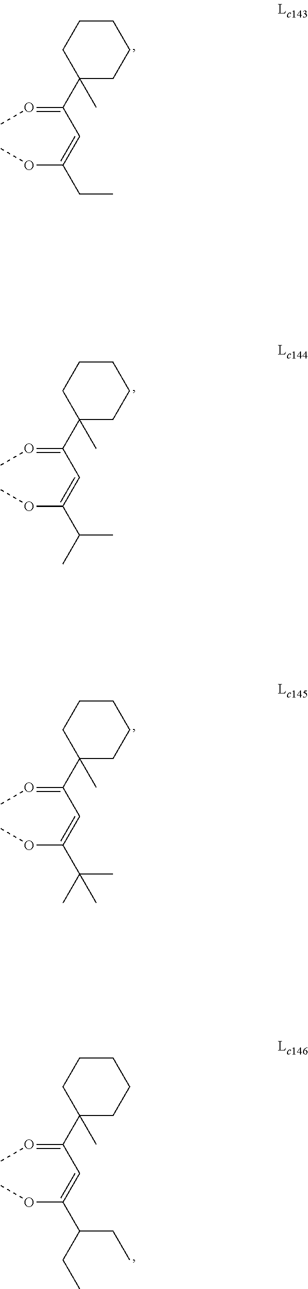

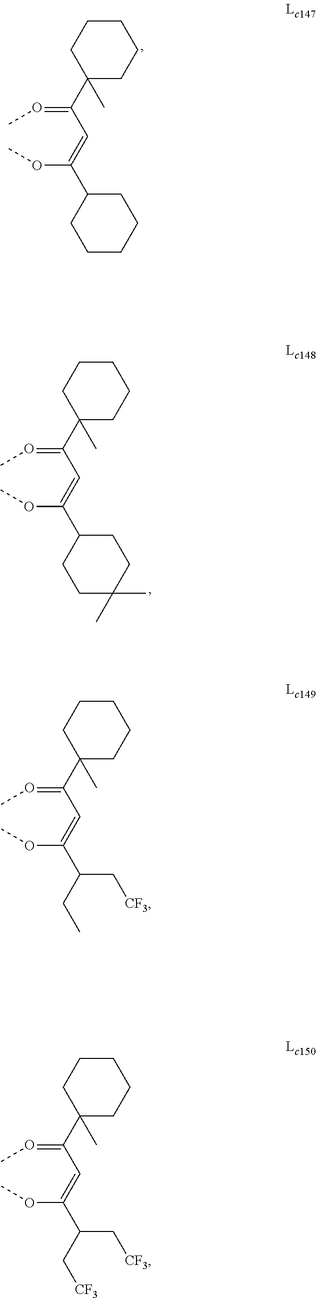

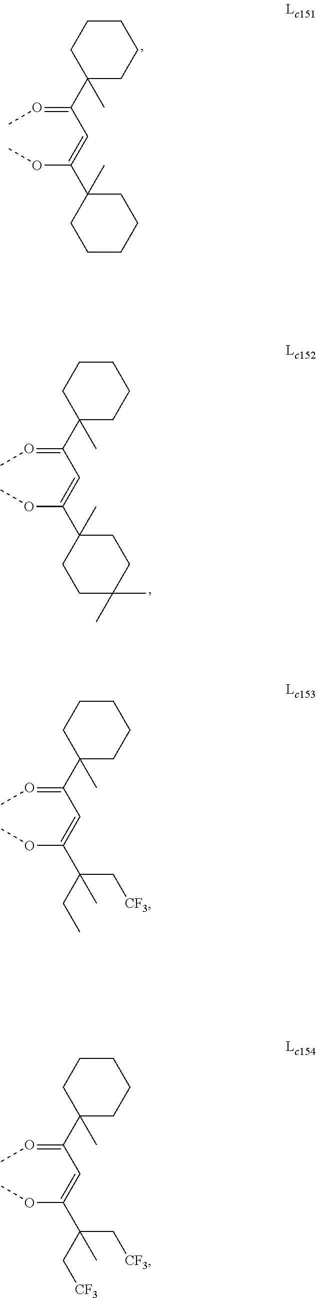

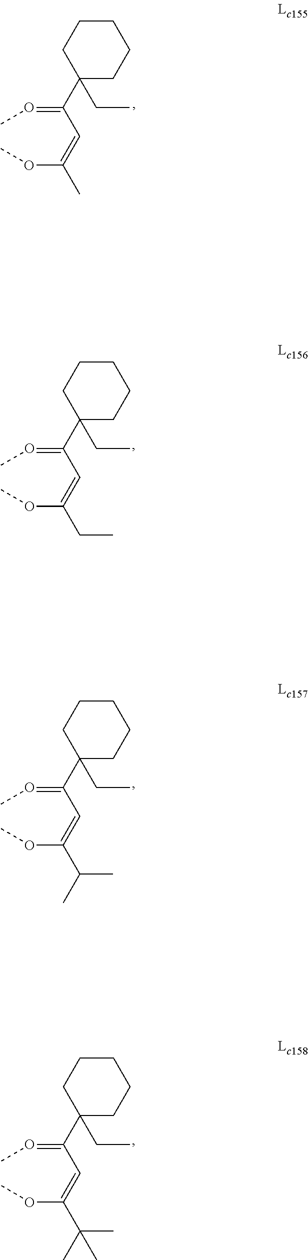

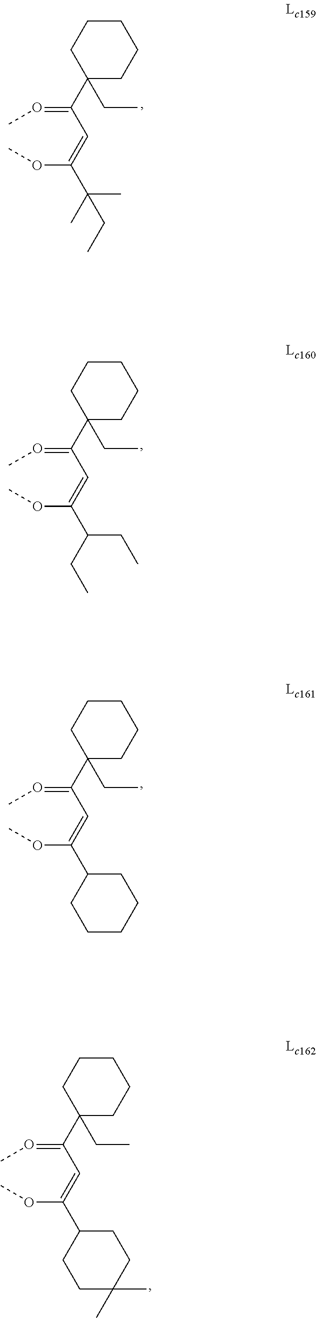

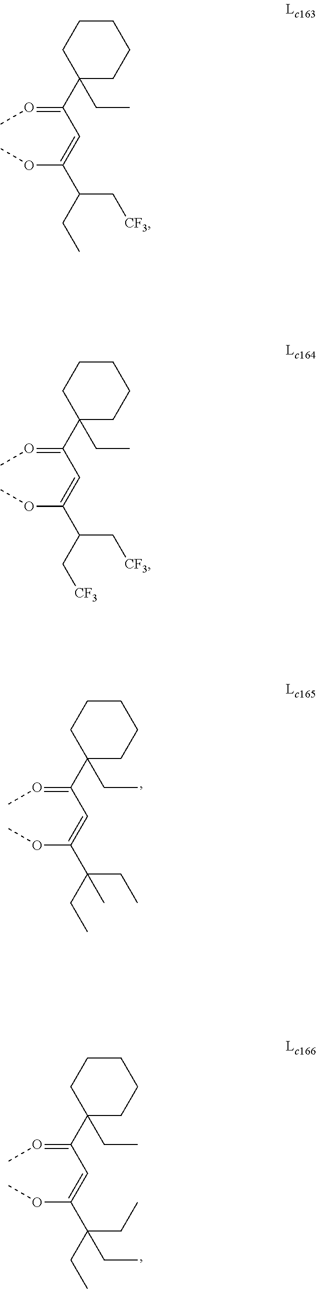

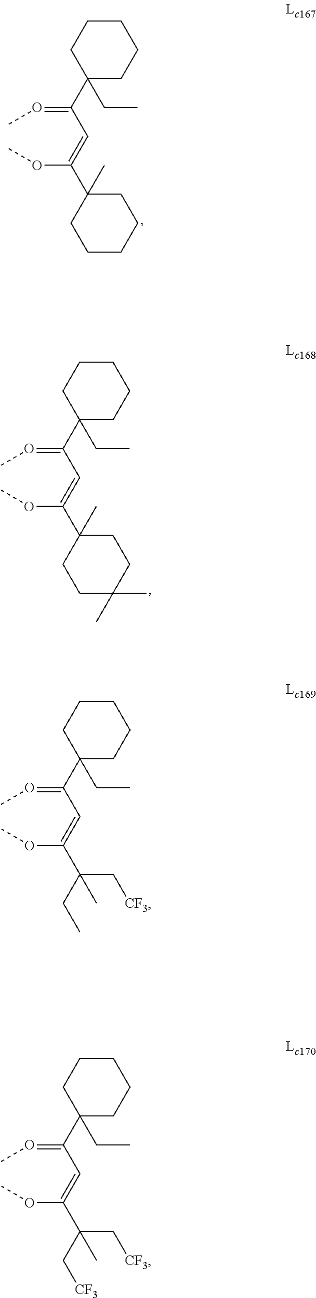

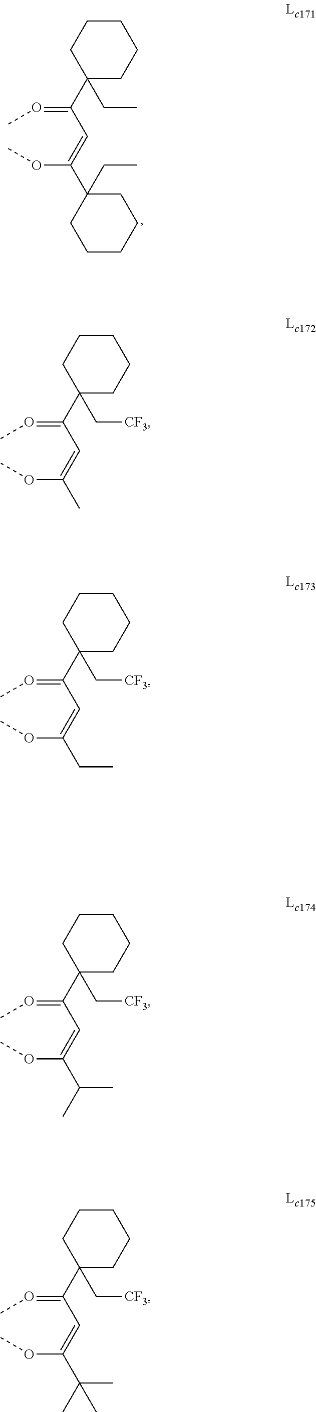

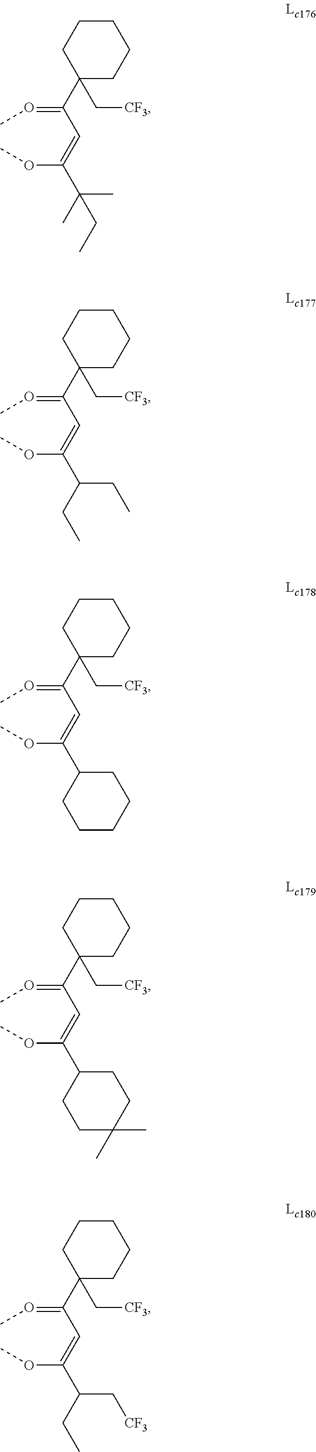

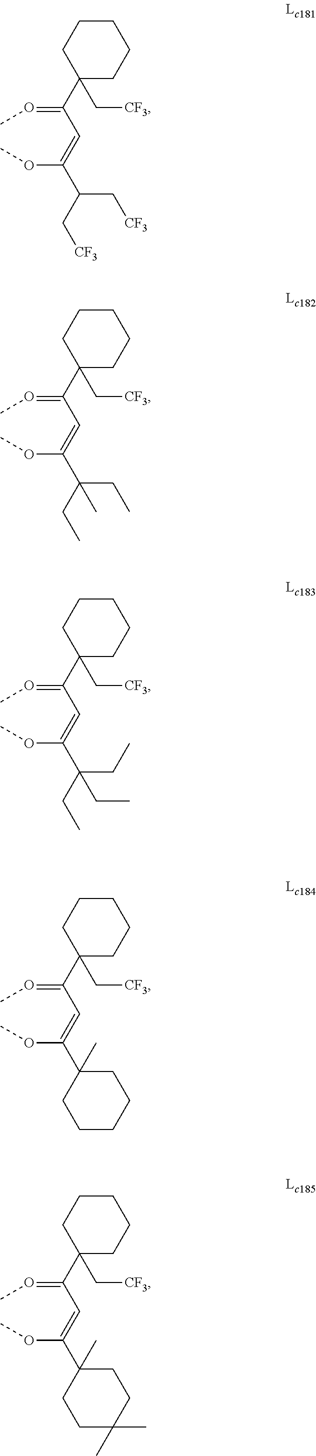

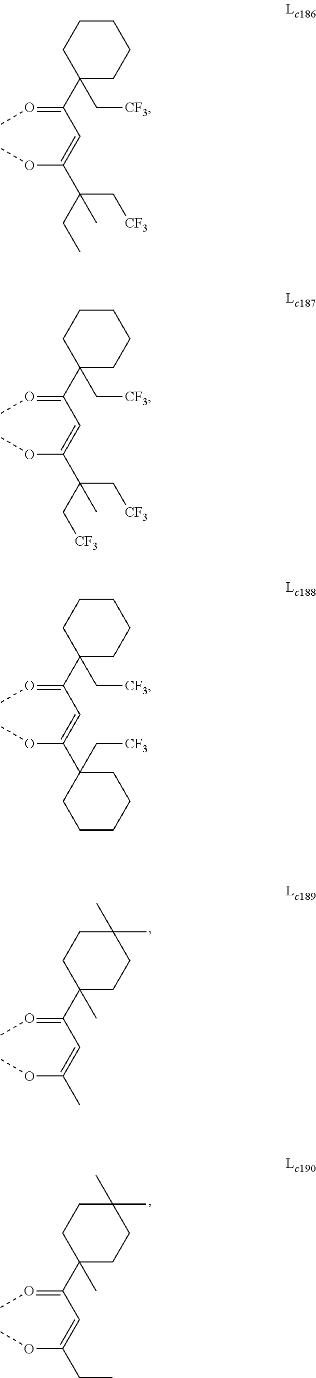

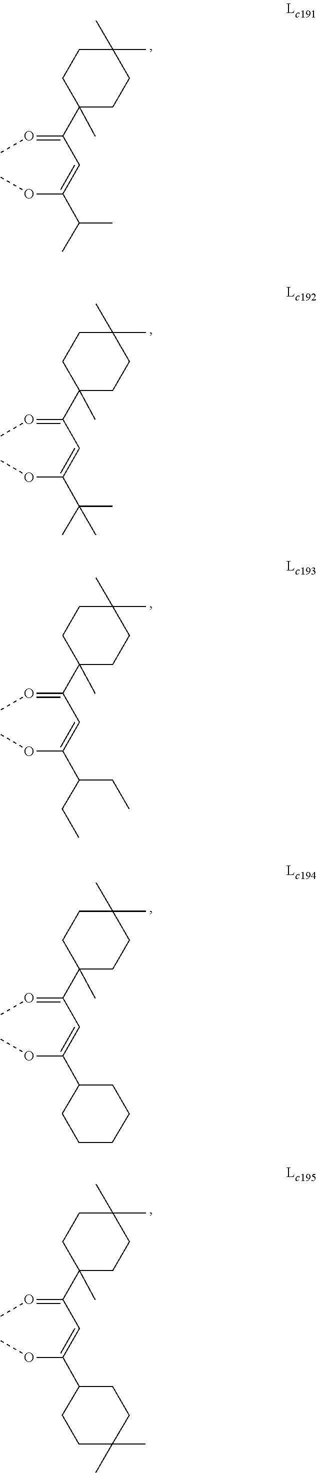

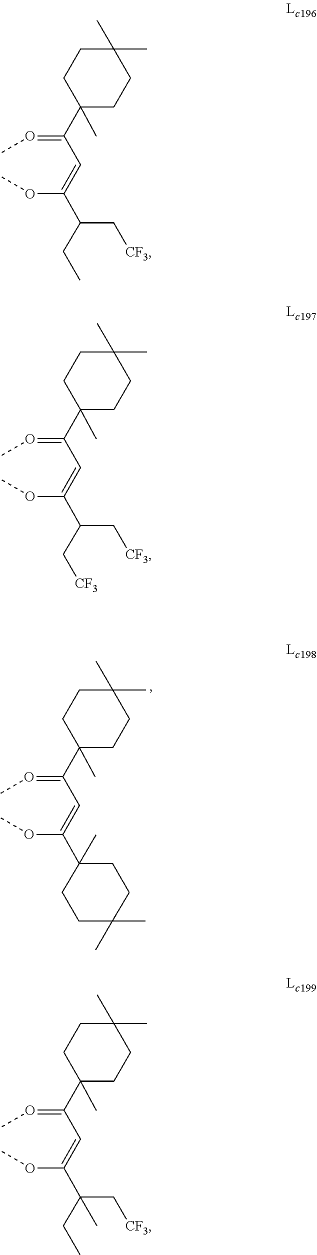

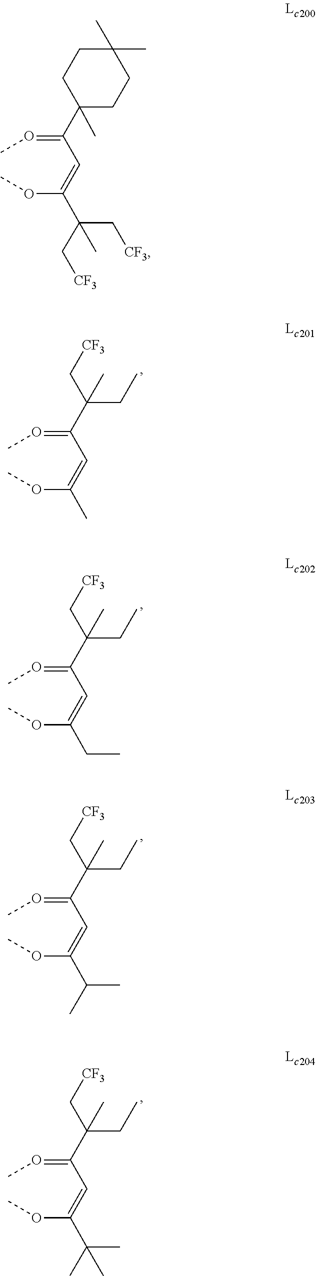

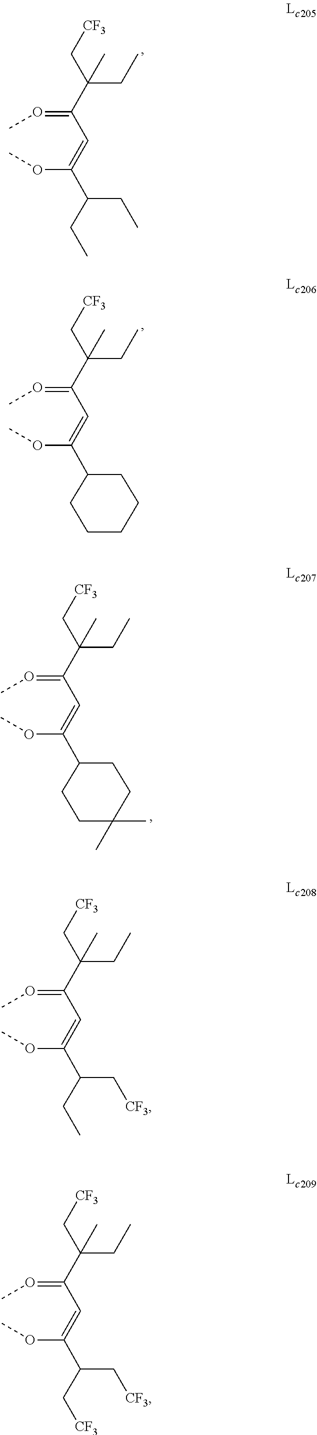

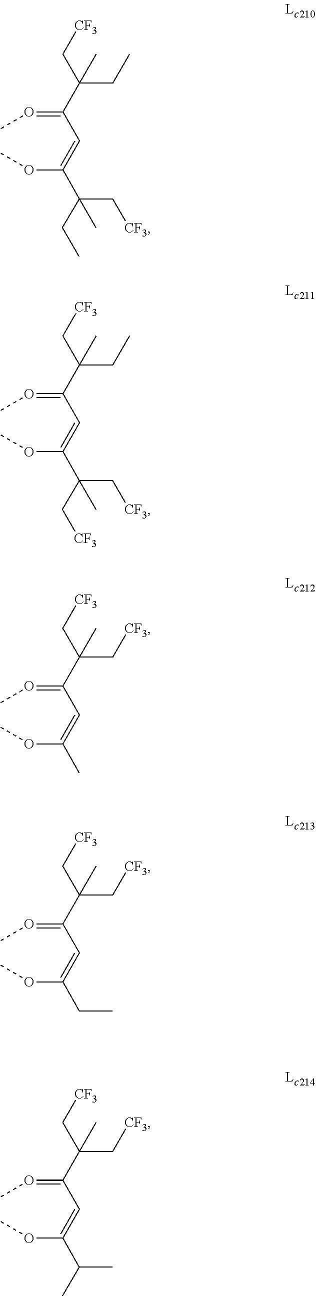

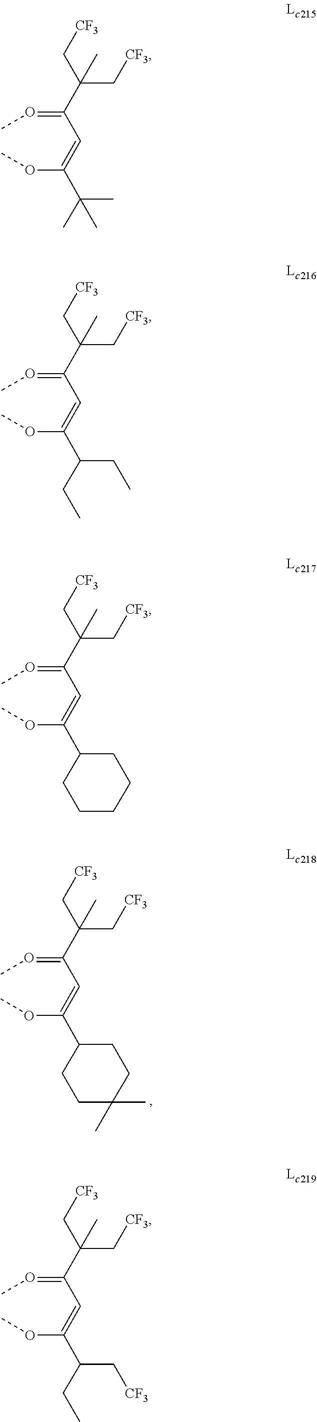

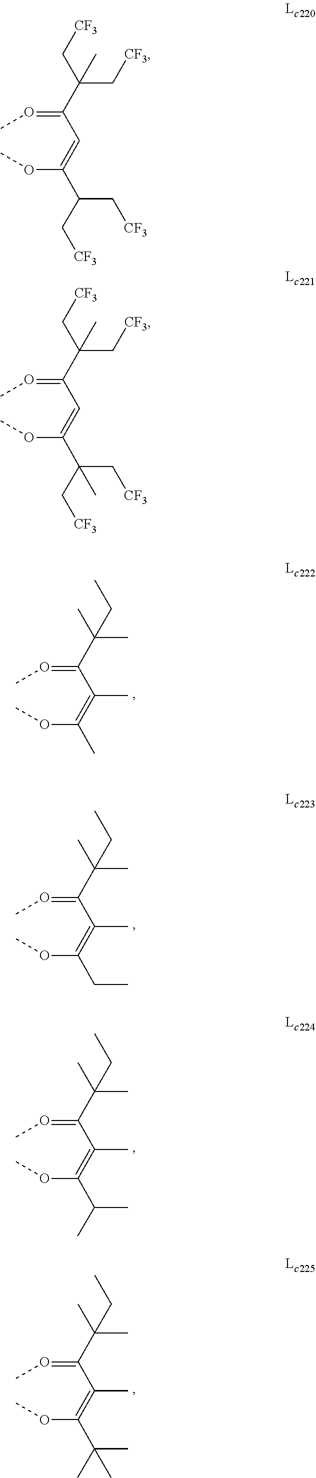

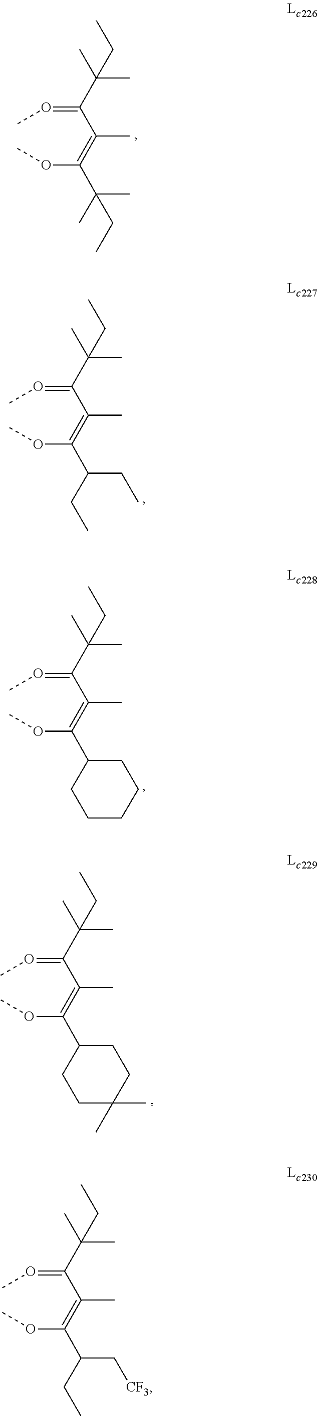

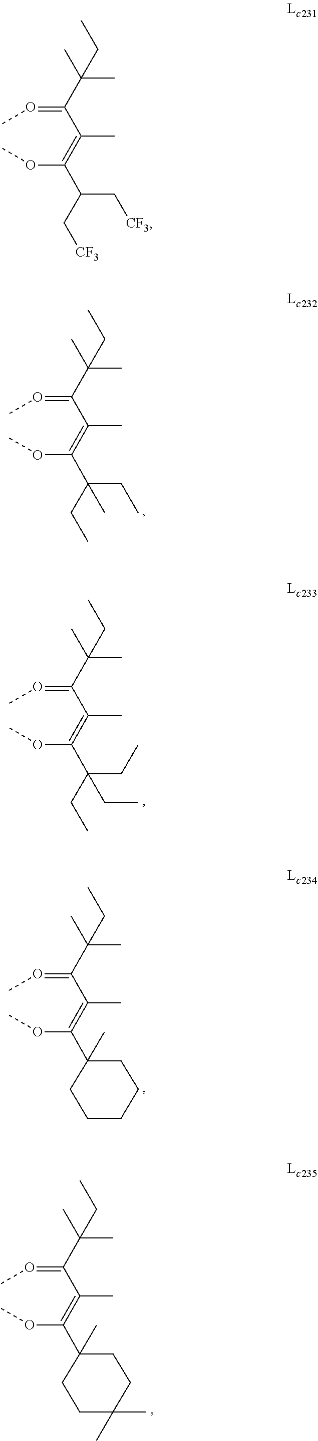

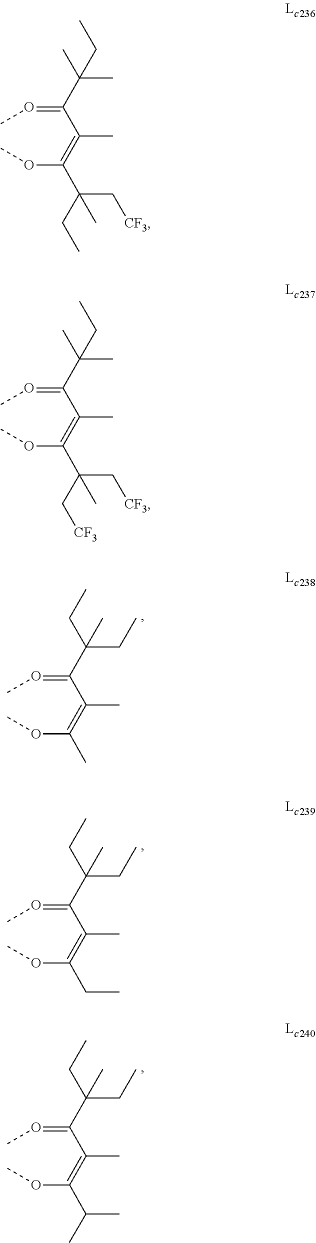

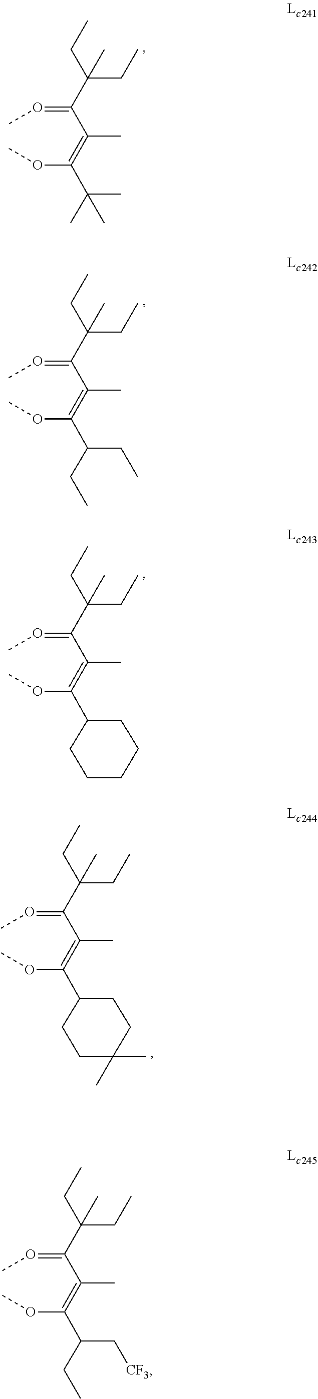

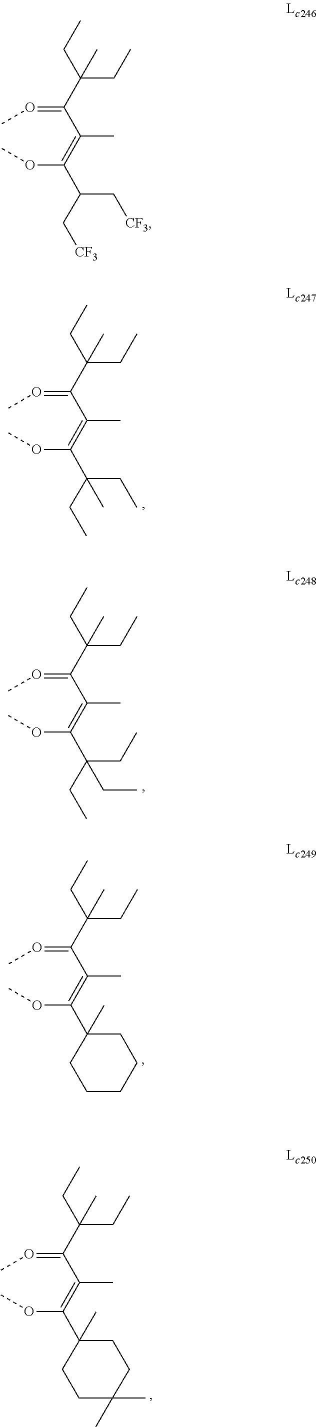

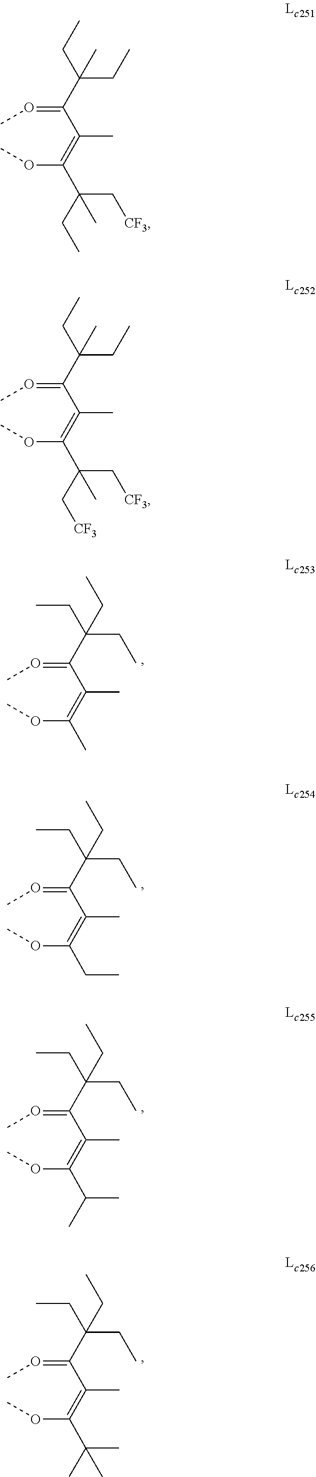

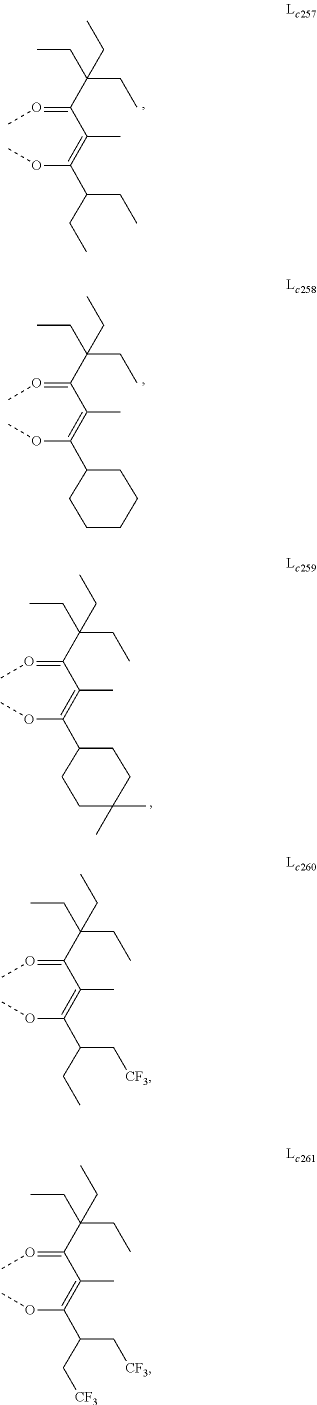

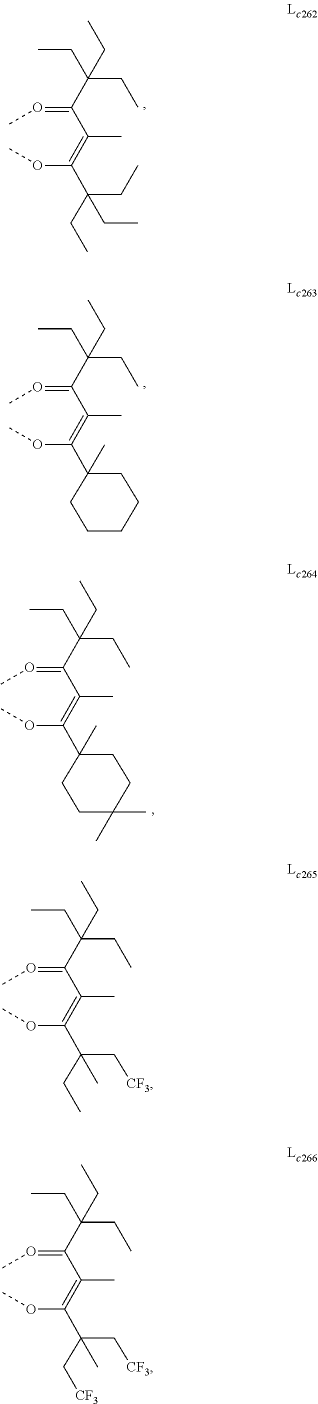

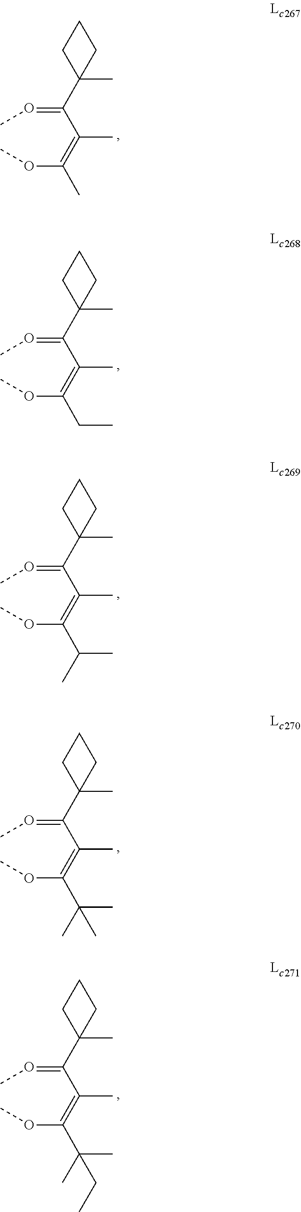

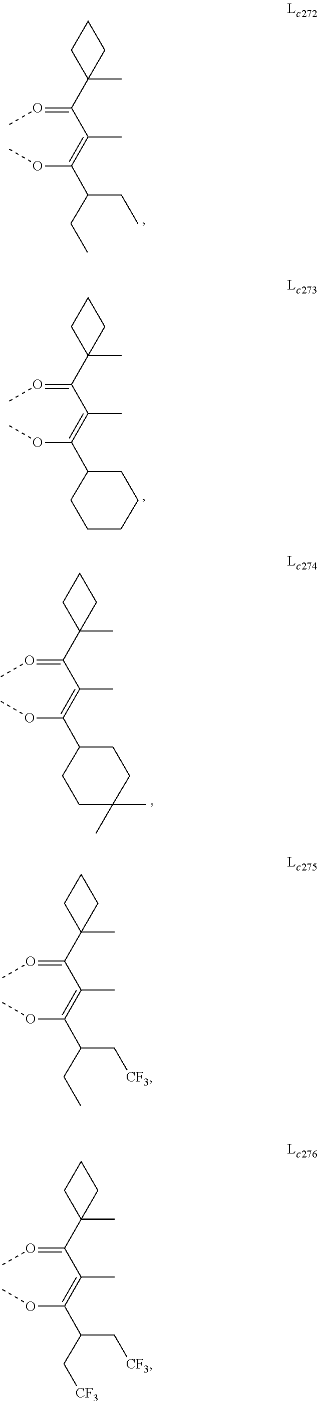

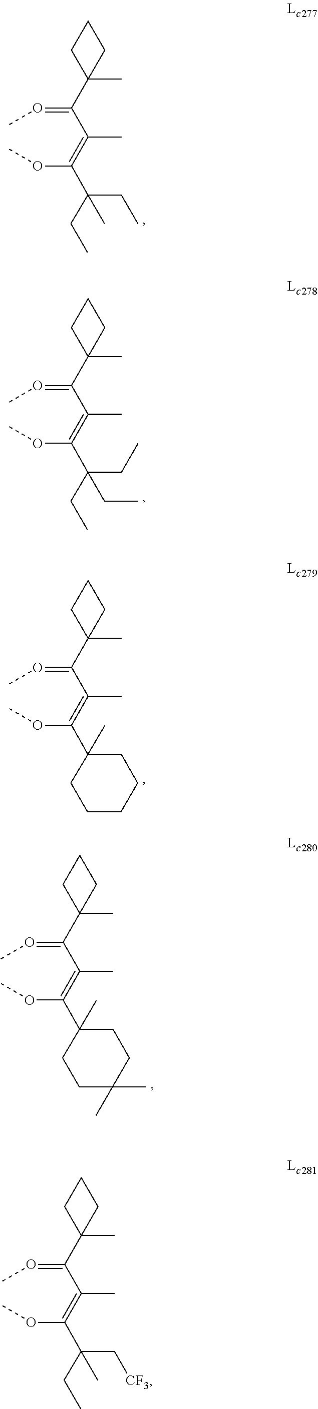

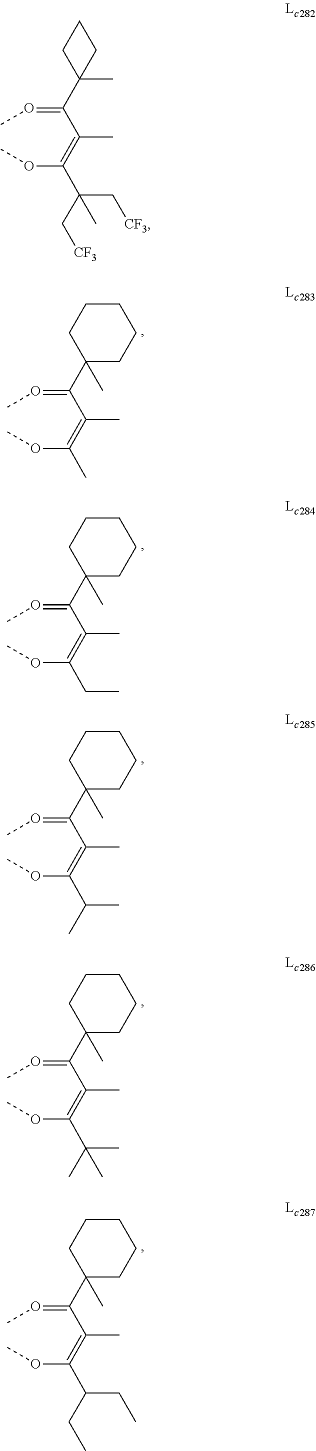

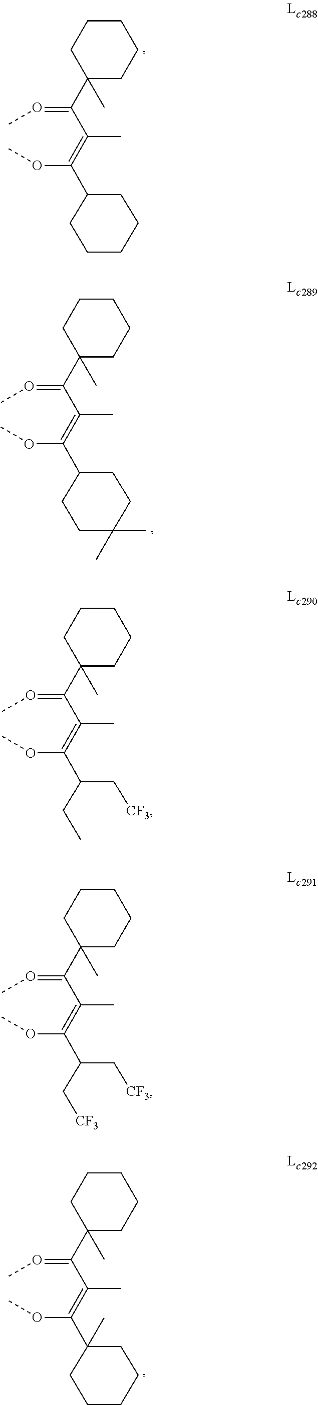

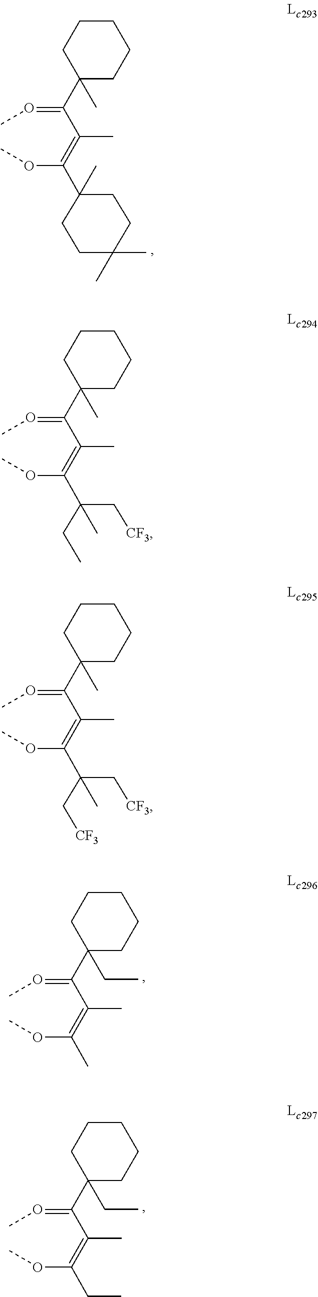

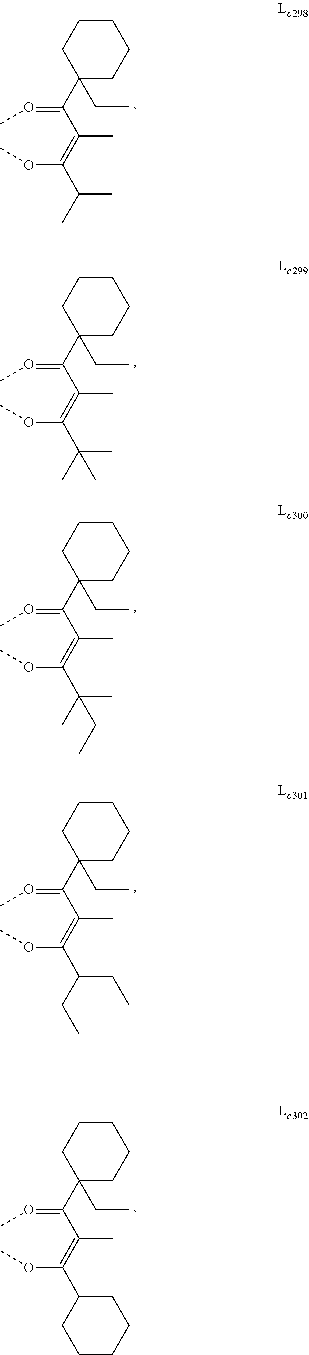

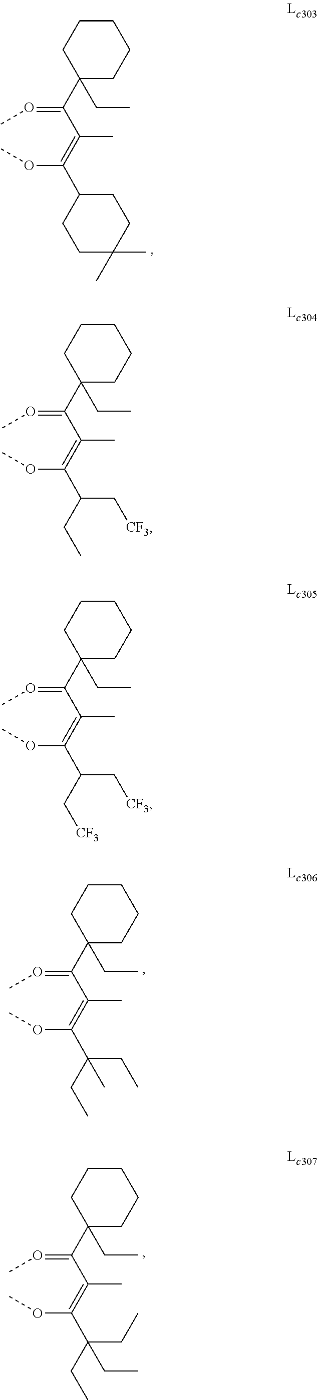

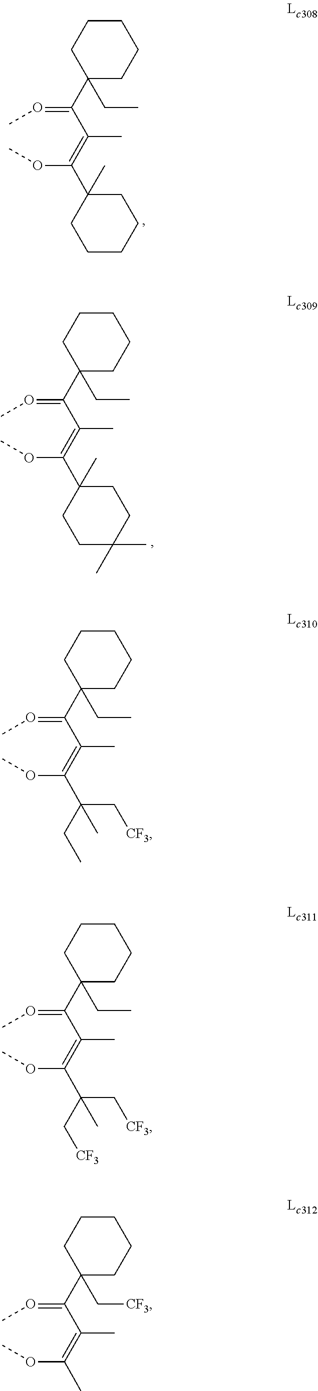

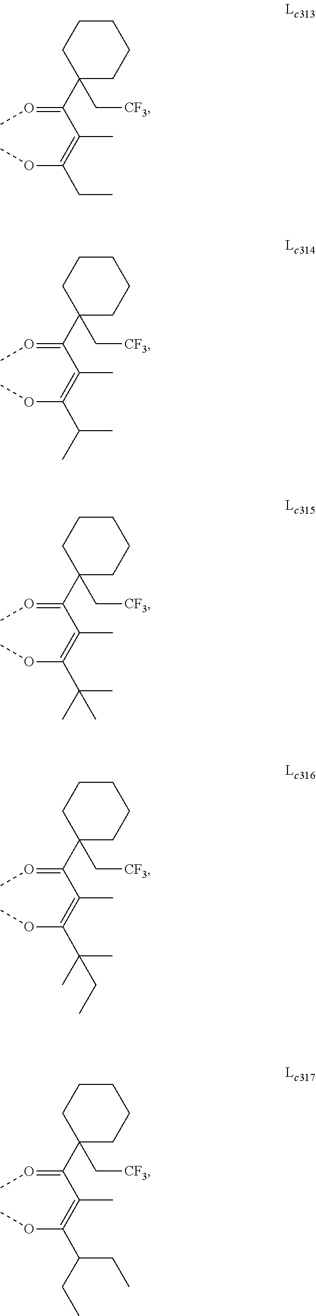

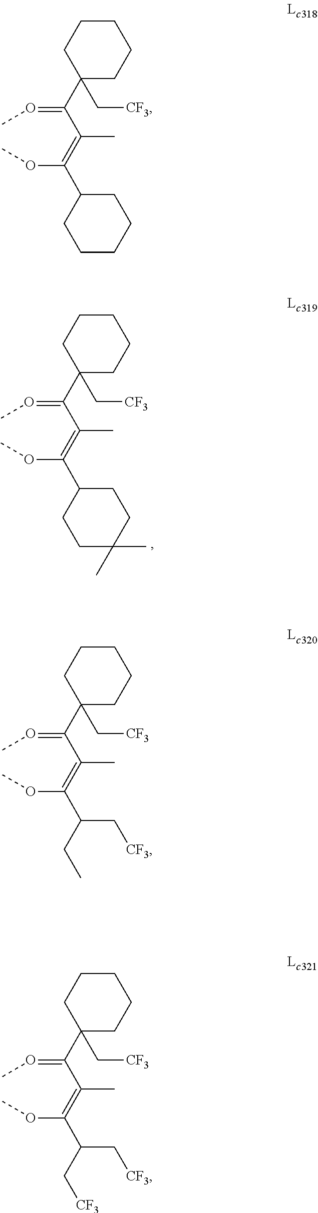

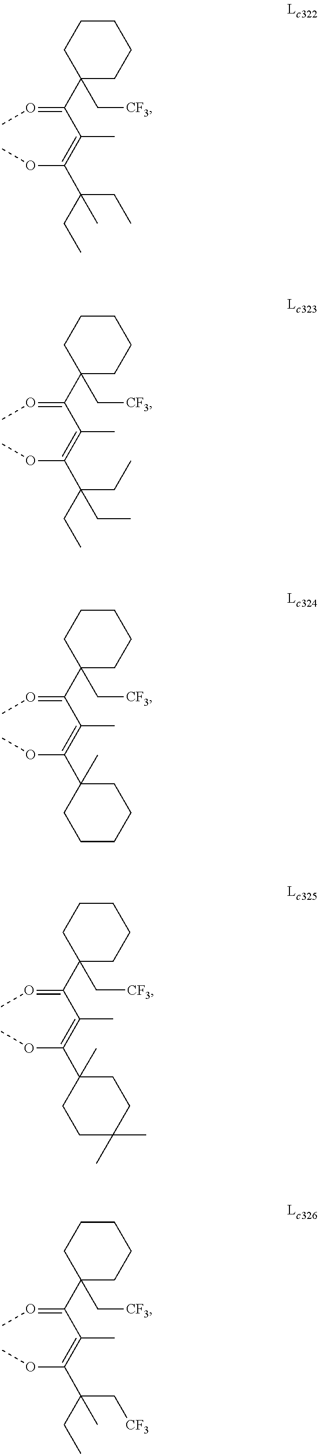

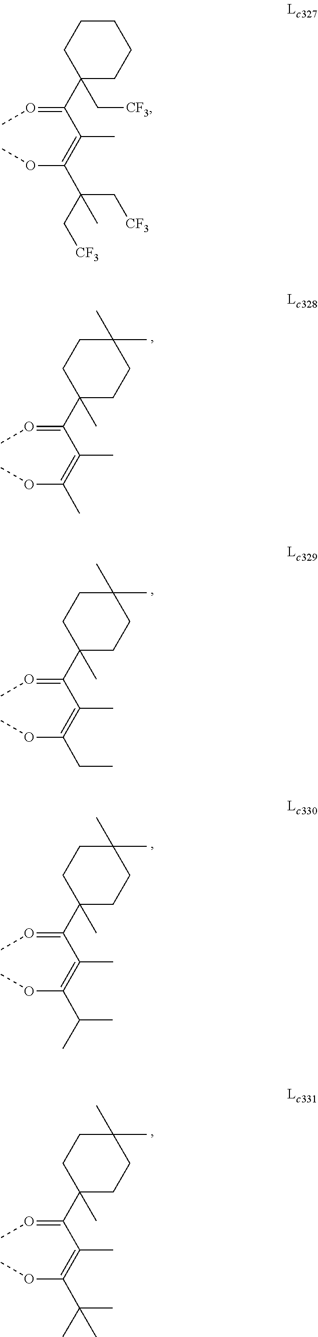

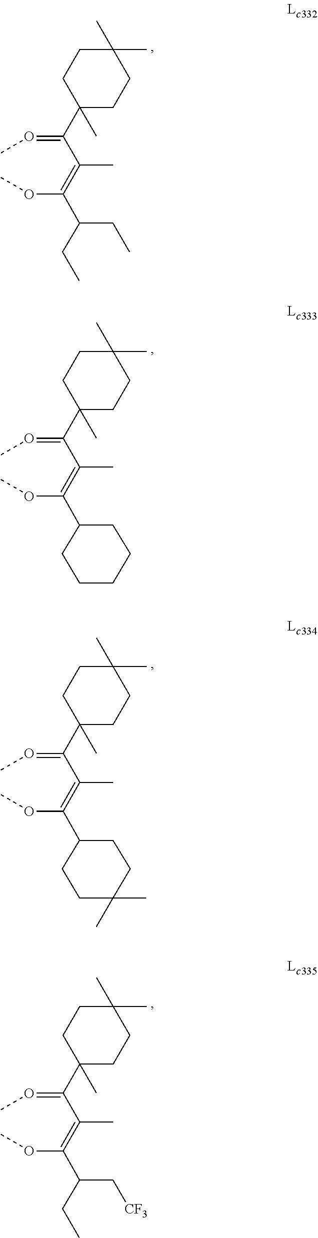

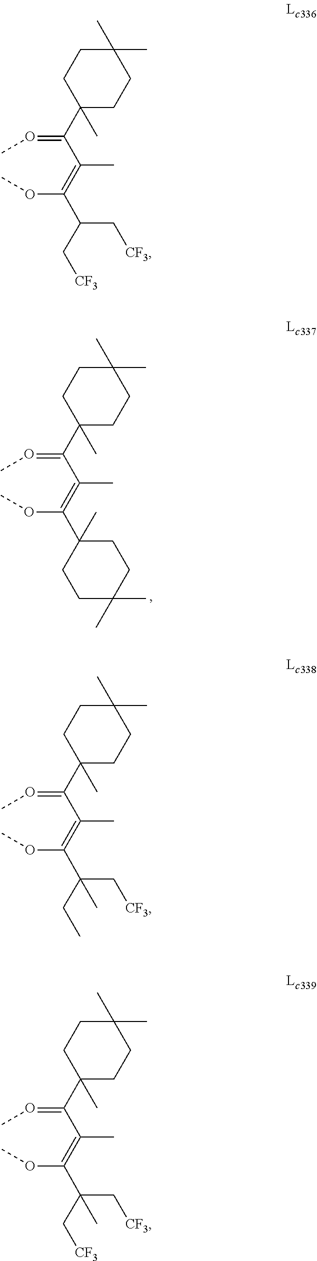

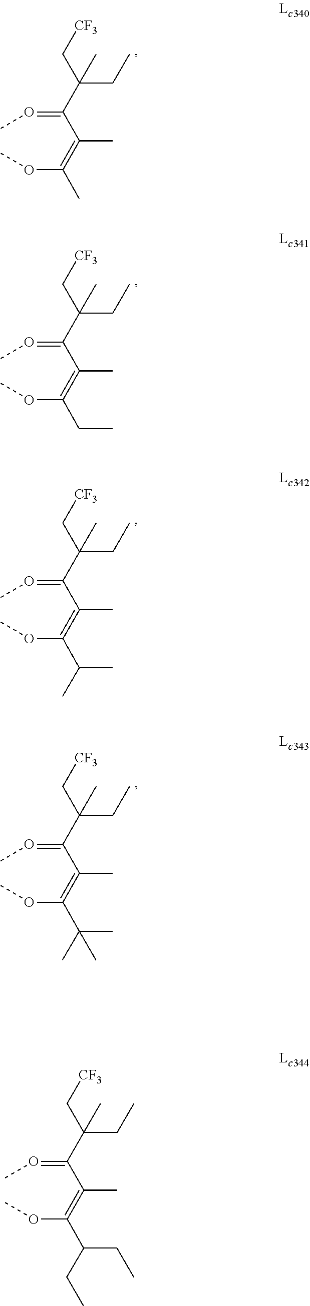

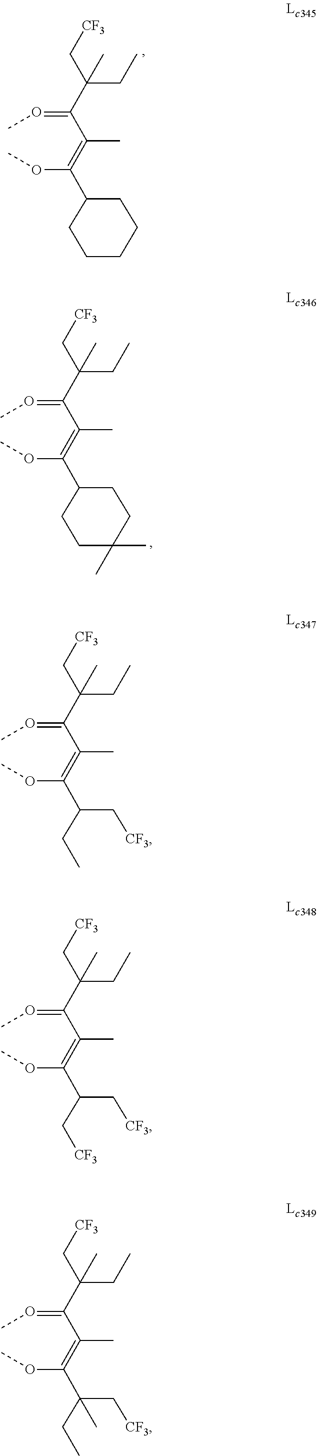

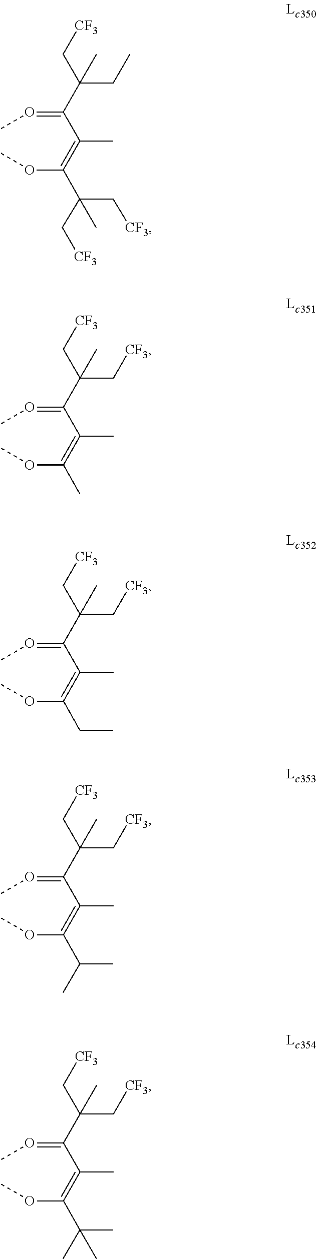

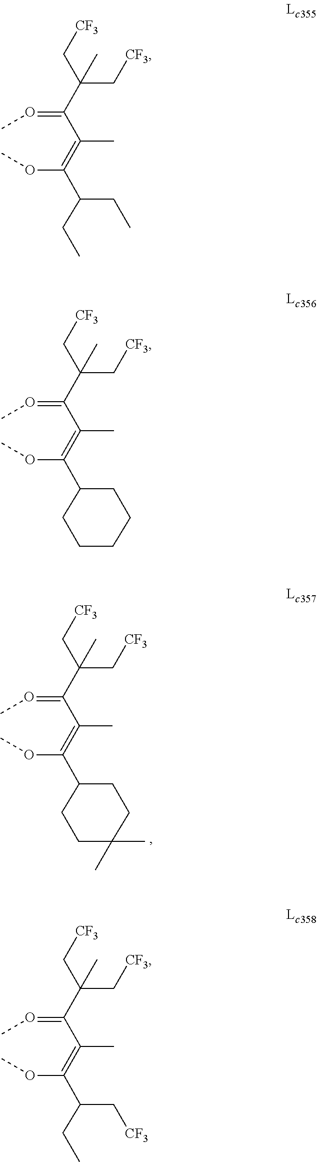

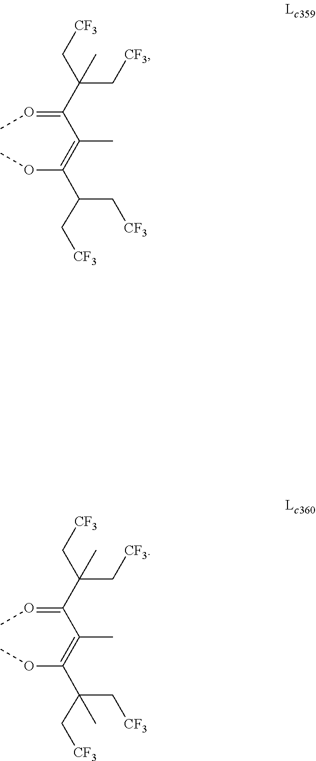

22. The metal complex of claim 2, having a structure represented by any one of Ir(Lₐ)₂(L_{b}), Ir(Lₐ)(L_{b})₂, Ir(Lₐ)(L_{b})(L_{c}), or Ir(Lₐ)₂(L_{c}); wherein
when the metal complex has the structure of Ir(Lₐ)₂(L_{b}), Lₐ is, at each occurrence identically or differently, selected from any one or any two of the group consisting of Lₐ₁ to Lₐ₈₅₄, and L_{b} is selected from any one of the group consisting of L_{b1} to L_{b78};
when the metal complex has the structure of Ir(Lₐ)(L_{b})₂, Lₐ is selected from any one of the group consisting of Lₐ₁ to Lₐ₈₅₄, and L_{b} is, at each occurrence identically or differently, selected from any one or any two of the group consisting of L_{b1} to L_{b78};
when the metal complex has the structure of Ir(Lₐ)(L_{b})(L_{c}), Lₐ is selected from any one of the group consisting of Lₐ₁ to Lₐ₈₅₄, L_{b} is selected from any one of the group consisting of L_{b1} to L_{b78}, and L_{c} is selected from any one of the group consisting of L_{c1} to L_{c360};
when the metal complex has the structure of Ir(Lₐ)₂(L_{c}), Lₐ is, at each occurrence identically or differently, selected from any one or any two of the group consisting of Lₐ₁ to Lₐ₈₅₄, and L_{c} is selected from any one of the group consisting of L_{c1} to L_{c360};
preferably, the metal complex is selected from the group consisting of metal complex 1 to metal complex 706;
wherein metal complex 1 to metal complex 650 have the structure of Ir(Lₐ)(L_{b})₂, wherein the two L_{b} are the same, and Lₐ and L_{b} respectively correspond to structures listed in the following table:

| Metal Complex | Lₐ | L_{b} | Metal Complex | Lₐ | L_{b} |
|---|---|---|---|---|---|
| 1 | Lₐ₂ | L_{b1} | 2 | Lₐ₃ | L_{b1} |
| 3 | Lₐ₆ | L_{b1} | 4 | Lₐ₈ | L_{b1} |
| 5 | Lₐ₉ | L_{b1} | 6 | Lₐ₁₀ | L_{b1} |
| 7 | Lₐ₁₁ | L_{b1} | 8 | Lₐ₁₂ | L_{b1} |
| 9 | Lₐ₁₃ | L_{b1} | 10 | Lₐ₁₄ | L_{b1} |
| 11 | Lₐ₁₅ | L_{b1} | 12 | Lₐ₁₆ | L_{b1} |
| 13 | Lₐ₁₇ | L_{b1} | 14 | Lₐ₁₈ | L_{b1} |
| 15 | Lₐ₁₉ | L_{b1} | 16 | Lₐ₂₀ | L_{b1} |
| 17 | Lₐ₂₁ | L_{b1} | 18 | Lₐ₂₃ | L_{b1} |
| 19 | Lₐ₂₅ | L_{b1} | 20 | Lₐ₂₇ | L_{b1} |
| 21 | Lₐ₂₉ | L_{b1} | 22 | Lₐ₃₁ | L_{b1} |
| 23 | Lₐ₃₃ | L_{b1} | 24 | Lₐ₃₅ | L_{b1} |
| 25 | Lₐ₃₉ | L_{b1} | 26 | Lₐ₄₁ | L_{b1} |
| 27 | Lₐ₄₆ | L_{b1} | 28 | Lₐ₅₀ | L_{b1} |
| 29 | Lₐ₅₃ | L_{b1} | 30 | Lₐ₅₉ | L_{b1} |
| 31 | Lₐ₆₀ | L_{b1} | 32 | Lₐ₈₄ | L_{b1} |
| 33 | Lₐ₈₈ | L_{b1} | 34 | Lₐ₉₁ | L_{b1} |
| 35 | Lₐ₁₁₅ | L_{b1} | 36 | Lₐ₁₂₃ | L_{b1} |
| 37 | Lₐ₁₂₄ | L_{b1} | 38 | Lₐ₁₂₇ | L_{b1} |
| 39 | Lₐ₁₃₄ | L_{b1} | 40 | Lₐ₁₃₆ | L_{b1} |
| 41 | Lₐ₁₄₆ | L_{b1} | 42 | Lₐ₁₆₆ | L_{b1} |
| 43 | Lₐ₁₇₂ | L_{b1} | 44 | Lₐ₂₀₃ | L_{b1} |
| 45 | Lₐ₂₀₄ | L_{b1} | 46 | Lₐ₂₀₇ | L_{b1} |
| 47 | Lₐ₂₄₁ | L_{b1} | 48 | Lₐ₂₄₂ | L_{b1} |
| 49 | Lₐ₂₄₅ | L_{b1} | 50 | Lₐ₂₄₈ | L_{b1} |
| 51 | Lₐ₂₅₀ | L_{b1} | 52 | Lₐ₂₅₄ | L_{b1} |
| 53 | Lₐ₂₅₅ | L_{b1} | 54 | Lₐ₂₅₆ | L_{b1} |
| 55 | Lₐ₂₇₆ | L_{b1} | 56 | Lₐ₂₇₇ | L_{b1} |
| 57 | Lₐ₂₉₄ | L_{b1} | 58 | Lₐ₂₉₅ | L_{b1} |
| 59 | Lₐ₂₉₈ | L_{b1} | 60 | Lₐ₃₀₁ | L_{b1} |
| 61 | Lₐ₃₀₂ | L_{b1} | 62 | Lₐ₃₀₅ | L_{b1} |
| 63 | Lₐ₃₀₇ | L_{b1} | 64 | Lₐ₃₀₈ | L_{b1} |
| 65 | Lₐ₃₃₁ | L_{b1} | 66 | Lₐ₃₃₂ | L_{b1} |
| 67 | Lₐ₃₃₃ | L_{b1} | 68 | Lₐ₃₄₃ | L_{b1} |
| 69 | Lₐ₃₄₄ | L_{b1} | 70 | Lₐ₃₄₅ | L_{b1} |
| 71 | Lₐ₃₄₆ | L_{b1} | 72 | Lₐ₃₄₈ | L_{b1} |
| 73 | Lₐ₃₅₀ | L_{b1} | 74 | Lₐ₃₅₄ | L_{b1} |
| 75 | Lₐ₃₅₅ | L_{b1} | 76 | Lₐ₃₅₆ | L_{b1} |
| 77 | Lₐ₃₅₇ | L_{b1} | 78 | Lₐ₃₆₃ | L_{b1} |
| 79 | Lₐ₃₆₄ | L_{b1} | 80 | Lₐ₃₇₅ | L_{b1} |
| 81 | Lₐ₃₈₅ | L_{b1} | 82 | Lₐ₃₈₆ | L_{b1} |
| 83 | Lₐ₃₉₀ | L_{b1} | 84 | Lₐ₃₉₁ | L_{b1} |
| 85 | Lₐ₃₉₆ | L_{b1} | 86 | Lₐ₃₉₇ | L_{b1} |
| 87 | Lₐ₄₀₃ | L_{b1} | 88 | Lₐ₄₄₅ | L_{b1} |
| 89 | Lₐ₄₄₈ | L_{b1} | 90 | Lₐ₄₅₆ | L_{b1} |
| 91 | Lₐ₄₉₇ | L_{b1} | 92 | Lₐ₅₄₁ | L_{b1} |
| 93 | Lₐ₅₄₉ | L_{b1} | 94 | Lₐ₅₉₃ | L_{b1} |
| 95 | Lₐ₅₆₀ | L_{b1} | 96 | Lₐ₅₆₂ | L_{b1} |
| 97 | Lₐ₅₆₃ | L_{b1} | 98 | Lₐ₅₆₇ | L_{b1} |
| 99 | Lₐ₅₈₁ | L_{b1} | 100 | Lₐ₅₈₈ | L_{b1} |
| 101 | Lₐ₅₉₀ | L_{b1} | 102 | Lₐ₅₉₁ | L_{b1} |
| 103 | Lₐ₅₉₅ | L_{b1} | 104 | Lₐ₅₉₆ | L_{b1} |
| 105 | Lₐ₅₉₇ | L_{b1} | 106 | Lₐ₆₀₃ | L_{b1} |
| 107 | Lₐ₆₁₆ | L_{b1} | 108 | Lₐ₆₁₇ | L_{b1} |
| 109 | Lₐ₆₁₈ | L_{b1} | 110 | Lₐ₆₁₉ | L_{b1} |
| 111 | Lₐ₆₂₀ | L_{b1} | 112 | Lₐ₆₄₄ | L_{b1} |
| 113 | Lₐ₆₄₅ | L_{b1} | 114 | Lₐ₆₄₇ | L_{b1} |
| 115 | Lₐ₇₄₀ | L_{b1} | 116 | Lₐ₇₄₁ | L_{b1} |
| 117 | Lₐ₇₄₂ | L_{b1} | 118 | Lₐ₇₄₃ | L_{b1} |
| 119 | Lₐ₇₅₅ | L_{b1} | 120 | Lₐ₇₅₇ | L_{b1} |
| 121 | Lₐ₇₆₆ | L_{b1} | 122 | Lₐ₇₆₈ | L_{b1} |
| 123 | Lₐ₇₇₁ | L_{b1} | 124 | Lₐ₇₇₆ | L_{b1} |
| 125 | Lₐ₇₉₅ | L_{b1} | 126 | Lₐ₈₀₂ | L_{b1} |
| 127 | Lₐ₈₀₉ | L_{b1} | 128 | Lₐ₈₁₆ | L_{b1} |
| 129 | Lₐ₈₂₃ | L_{b1} | 130 | Lₐ₈₅₁ | L_{b1} |
| 131 | Lₐ₂ | L_{b3} | 132 | Lₐ₃ | L_{b3} |
| 133 | Lₐ₆ | L_{b3} | 134 | Lₐ₈ | L_{b3} |
| 135 | Lₐ₉ | L_{b3} | 136 | Lₐ₁₀ | L_{b3} |
| 137 | Lₐ₁₁ | L_{b3} | 138 | Lₐ₁₂ | L_{b3} |
| 139 | Lₐ₁₃ | L_{b3} | 140 | Lₐ₁₄ | L_{b3} |
| 141 | Lₐ₁₅ | L_{b3} | 142 | Lₐ₁₆ | L_{b3} |
| 143 | Lₐ₁₇ | L_{b3} | 144 | Lₐ₁₈ | L_{b3} |
| 145 | Lₐ₁₉ | L_{b3} | 146 | Lₐ₂₀ | L_{b3} |
| 147 | Lₐ₂₁ | L_{b3} | 148 | Lₐ₂₃ | L_{b3} |
| 149 | Lₐ₂₅ | L_{b3} | 150 | Lₐ₂₇ | L_{b3} |
| 151 | Lₐ₂₉ | L_{b3} | 152 | Lₐ₃₁ | L_{b3} |
| 153 | Lₐ₃₃ | L_{b3} | 154 | Lₐ₃₅ | L_{b3} |
| 155 | Lₐ₃₉ | L_{b3} | 156 | Lₐ₄₁ | L_{b3} |
| 157 | Lₐ₄₆ | L_{b3} | 158 | Lₐ₅₀ | L_{b3} |
| 159 | Lₐ₅₃ | L_{b3} | 160 | Lₐ₅₉ | L_{b3} |
| 161 | Lₐ₆₀ | L_{b3} | 162 | Lₐ₈₄ | L_{b3} |
| 163 | Lₐ₈₈ | L_{b3} | 164 | Lₐ₉₁ | L_{b3} |
| 165 | Lₐ₁₁₅ | L_{b3} | 166 | Lₐ₁₂₃ | L_{b3} |
| 167 | Lₐ₁₂₄ | L_{b3} | 168 | Lₐ₁₂₇ | L_{b3} |
| 169 | Lₐ₁₃₄ | L_{b3} | 170 | Lₐ₁₃₆ | L_{b3} |
| 171 | Lₐ₁₄₆ | L_{b3} | 172 | Lₐ₁₆₆ | L_{b3} |
| 173 | Lₐ₁₇₂ | L_{b3} | 174 | Lₐ₂₀₃ | L_{b3} |
| 175 | Lₐ₂₀₄ | L_{b3} | 176 | Lₐ₂₀₇ | L_{b3} |
| 177 | Lₐ₂₄₁ | L_{b3} | 178 | Lₐ₂₄₂ | L_{b3} |
| 179 | Lₐ₂₄₅ | L_{b3} | 180 | Lₐ₂₄₈ | L_{b3} |
| 181 | Lₐ₂₅₀ | L_{b3} | 182 | Lₐ₂₅₄ | L_{b3} |
| 183 | Lₐ₂₅₅ | L_{b3} | 184 | Lₐ₂₅₆ | L_{b3} |
| 185 | Lₐ₂₇₆ | L_{b3} | 186 | Lₐ₂₇₇ | L_{b3} |
| 187 | Lₐ₂₉₄ | L_{b3} | 188 | Lₐ₂₉₅ | L_{b3} |
| 189 | Lₐ₂₉₈ | L_{b3} | 190 | Lₐ₃₀₁ | L_{b3} |
| 191 | Lₐ₃₀₂ | L_{b3} | 192 | Lₐ₃₀₅ | L_{b3} |
| 193 | Lₐ₃₀₇ | L_{b3} | 194 | Lₐ₃₀₈ | L_{b3} |
| 195 | Lₐ₃₃₁ | L_{b3} | 196 | Lₐ₃₃₂ | L_{b3} |
| 197 | Lₐ₃₃₃ | L_{b3} | 198 | Lₐ₃₄₃ | L_{b3} |
| 199 | Lₐ₃₄₄ | L_{b3} | 200 | Lₐ₃₄₅ | L_{b3} |
| 201 | Lₐ₃₄₆ | L_{b3} | 202 | Lₐ₃₄₈ | L_{b3} |
| 203 | Lₐ₃₅₀ | L_{b3} | 204 | Lₐ₃₅₄ | L_{b3} |
| 205 | Lₐ₃₅₅ | L_{b3} | 206 | Lₐ₃₅₆ | L_{b3} |
| 207 | Lₐ₃₅₇ | L_{b3} | 208 | Lₐ₃₆₃ | L_{b3} |
| 209 | Lₐ₃₆₄ | L_{b3} | 210 | Lₐ₃₇₅ | L_{b3} |
| 211 | Lₐ₃₈₅ | L_{b3} | 212 | Lₐ₃₈₆ | L_{b3} |
| 213 | Lₐ₃₉₀ | L_{b3} | 214 | Lₐ₃₉₁ | L_{b3} |
| 215 | Lₐ₃₉₆ | L_{b3} | 216 | Lₐ₃₉₇ | L_{b3} |
| 217 | Lₐ₄₀₃ | L_{b3} | 218 | Lₐ₄₄₅ | L_{b3} |
| 219 | Lₐ₄₄₈ | L_{b3} | 220 | Lₐ₄₅₆ | L_{b3} |
| 221 | Lₐ₄₉₇ | L_{b3} | 222 | Lₐ₅₄₁ | L_{b3} |
| 223 | Lₐ₅₄₉ | L_{b3} | 224 | Lₐ₅₉₃ | L_{b3} |
| 225 | Lₐ₅₆₀ | L_{b3} | 226 | Lₐ₅₆₂ | L_{b3} |
| 227 | Lₐ₅₆₃ | L_{b3} | 228 | Lₐ₅₆₇ | L_{b3} |
| 229 | Lₐ₅₈₁ | L_{b3} | 230 | Lₐ₅₈₈ | L_{b3} |
| 231 | Lₐ₅₉₀ | L_{b3} | 232 | Lₐ₅₉₁ | L_{b3} |
| 233 | Lₐ₅₉₅ | L_{b3} | 234 | Lₐ₅₉₆ | L_{b3} |
| 235 | Lₐ₅₉₇ | L_{b3} | 236 | Lₐ₆₀₃ | L_{b3} |
| 237 | Lₐ₆₁₆ | L_{b3} | 238 | Lₐ₆₁₇ | L_{b3} |
| 239 | Lₐ₆₁₈ | L_{b3} | 240 | Lₐ₆₁₉ | L_{b3} |
| 241 | Lₐ₆₂₀ | L_{b3} | 242 | Lₐ₆₄₄ | L_{b3} |
| 243 | Lₐ₆₄₅ | L_{b3} | 244 | Lₐ₆₄₇ | L_{b3} |
| 245 | Lₐ₇₄₀ | L_{b3} | 246 | Lₐ₇₄₁ | L_{b3} |
| 247 | Lₐ₇₄₂ | L_{b3} | 248 | Lₐ₇₄₃ | L_{b3} |
| 249 | Lₐ₇₅₅ | L_{b3} | 250 | Lₐ₇₅₇ | L_{b3} |
| 251 | Lₐ₇₆₆ | L_{b3} | 252 | Lₐ₇₆₈ | L_{b3} |
| 253 | Lₐ₇₇₁ | L_{b3} | 254 | Lₐ₇₇₆ | L_{b3} |
| 255 | Lₐ₇₉₅ | L_{b3} | 256 | Lₐ₈₀₂ | L_{b3} |
| 257 | Lₐ₈₀₉ | L_{b3} | 258 | Lₐ₈₁₆ | L_{b3} |
| 259 | Lₐ₈₂₃ | L_{b3} | 260 | Lₐ₈₅₁ | L_{b3} |
| 261 | Lₐ₂ | L_{b4} | 262 | Lₐ₃ | L_{b4} |
| 263 | Lₐ₆ | L_{b4} | 264 | Lₐ₈ | L_{b4} |
| 265 | Lₐ₉ | L_{b4} | 266 | Lₐ₁₀ | L_{b4} |
| 267 | Lₐ₁₁ | L_{b4} | 268 | Lₐ₁₂ | L_{b4} |
| 269 | Lₐ₁₃ | L_{b4} | 270 | Lₐ₁₄ | L_{b4} |
| 271 | Lₐ₁₅ | L_{b4} | 272 | Lₐ₁₆ | L_{b4} |
| 273 | Lₐ₁₇ | L_{b4} | 274 | Lₐ₁₈ | L_{b4} |
| 275 | Lₐ₁₉ | L_{b4} | 276 | Lₐ₂₀ | L_{b4} |
| 277 | Lₐ₂₁ | L_{b4} | 278 | Lₐ₂₃ | L_{b4} |
| 279 | Lₐ₂₅ | L_{b4} | 280 | Lₐ₂₇ | L_{b4} |
| 281 | Lₐ₂₉ | L_{b4} | 282 | Lₐ₃₁ | L_{b4} |
| 283 | Lₐ₃₃ | L_{b4} | 284 | Lₐ₃₅ | L_{b4} |
| 285 | Lₐ₃₉ | L_{b4} | 286 | Lₐ₄₁ | L_{b4} |
| 287 | Lₐ₄₆ | L_{b4} | 288 | Lₐ₅₀ | L_{b4} |
| 289 | Lₐ₅₃ | L_{b4} | 290 | Lₐ₅₉ | L_{b4} |
| 291 | Lₐ₆₀ | L_{b4} | 292 | Lₐ₈₄ | L_{b4} |
| 293 | Lₐ₈₈ | L_{b4} | 294 | Lₐ₉₁ | L_{b4} |
| 295 | Lₐ₁₁₅ | L_{b4} | 296 | Lₐ₁₂₃ | L_{b4} |
| 297 | Lₐ₁₂₄ | L_{b4} | 298 | Lₐ₁₂₇ | L_{b4} |
| 299 | Lₐ₁₃₄ | L_{b4} | 300 | Lₐ₁₃₆ | L_{b4} |
| 301 | Lₐ₁₄₆ | L_{b4} | 302 | Lₐ₁₆₆ | L_{b4} |
| 303 | Lₐ₁₇₂ | L_{b4} | 304 | Lₐ₂₀₃ | L_{b4} |
| 305 | Lₐ₂₀₄ | L_{b4} | 306 | Lₐ₂₀₇ | L_{b4} |
| 307 | Lₐ₂₄₁ | L_{b4} | 308 | Lₐ₂₄₂ | L_{b4} |
| 309 | Lₐ₂₄₅ | L_{b4} | 310 | Lₐ₂₄₈ | L_{b4} |
| 311 | Lₐ₂₅₀ | L_{b4} | 312 | Lₐ₂₅₄ | L_{b4} |
| 313 | Lₐ₂₅₅ | L_{b4} | 314 | Lₐ₂₅₆ | L_{b4} |
| 315 | Lₐ₂₇₆ | L_{b4} | 316 | Lₐ₂₇₇ | L_{b4} |
| 317 | Lₐ₂₉₄ | L_{b4} | 318 | Lₐ₂₉₅ | L_{b4} |
| 319 | Lₐ₂₉₈ | L_{b4} | 320 | Lₐ₃₀₁ | L_{b4} |
| 321 | Lₐ₃₀₂ | L_{b4} | 322 | Lₐ₃₀₅ | L_{b4} |
| 323 | Lₐ₃₀₇ | L_{b4} | 324 | Lₐ₃₀₈ | L_{b4} |
| 325 | Lₐ₃₃₁ | L_{b4} | 326 | Lₐ₃₃₂ | L_{b4} |
| 327 | Lₐ₃₃₃ | L_{b4} | 328 | Lₐ₃₄₃ | L_{b4} |
| 329 | Lₐ₃₄₄ | L_{b4} | 330 | Lₐ₃₄₅ | L_{b4} |
| 331 | Lₐ₃₄₆ | L_{b4} | 332 | Lₐ₃₄₈ | L_{b4} |
| 333 | Lₐ₃₅₀ | L_{b4} | 334 | Lₐ₃₅₄ | L_{b4} |
| 335 | Lₐ₃₅₅ | L_{b4} | 336 | Lₐ₃₅₆ | L_{b4} |
| 337 | Lₐ₃₅₇ | L_{b4} | 338 | Lₐ₃₆₃ | L_{b4} |
| 339 | Lₐ₃₆₄ | L_{b4} | 340 | Lₐ₃₇₅ | L_{b4} |
| 341 | Lₐ₃₈₅ | L_{b4} | 342 | Lₐ₃₈₆ | L_{b4} |
| 343 | Lₐ₃₉₀ | L_{b4} | 344 | Lₐ₃₉₁ | L_{b4} |
| 345 | Lₐ₃₉₆ | L_{b4} | 346 | Lₐ₃₉₇ | L_{b4} |
| 347 | Lₐ₄₀₃ | L_{b4} | 348 | Lₐ₄₄₅ | L_{b4} |
| 349 | Lₐ₄₄₈ | L_{b4} | 350 | Lₐ₄₅₆ | L_{b4} |
| 351 | Lₐ₄₉₇ | L_{b4} | 352 | Lₐ₅₄₁ | L_{b4} |
| 353 | Lₐ₅₄₉ | L_{b4} | 354 | Lₐ₅₉₃ | L_{b4} |
| 355 | Lₐ₅₆₀ | L_{b4} | 356 | Lₐ₅₆₂ | L_{b4} |
| 357 | Lₐ₅₆₃ | L_{b4} | 358 | Lₐ₅₆₇ | L_{b4} |
| 359 | Lₐ₅₈₁ | L_{b4} | 360 | Lₐ₅₈₈ | L_{b4} |
| 361 | Lₐ₅₉₀ | L_{b4} | 362 | Lₐ₅₉₁ | L_{b4} |
| 363 | Lₐ₅₉₅ | L_{b4} | 364 | Lₐ₅₉₆ | L_{b4} |
| 365 | Lₐ₅₉₇ | L_{b4} | 366 | Lₐ₆₀₃ | L_{b4} |
| 367 | Lₐ₆₁₆ | L_{b4} | 368 | Lₐ₆₁₇ | L_{b4} |
| 369 | Lₐ₆₁₈ | L_{b4} | 370 | Lₐ₆₁₉ | L_{b4} |
| 371 | Lₐ₆₂₀ | L_{b4} | 372 | Lₐ₆₄₄ | L_{b4} |
| 373 | Lₐ₆₄₅ | L_{b4} | 374 | Lₐ₆₄₇ | L_{b4} |
| 375 | Lₐ₇₄₀ | L_{b4} | 376 | Lₐ₇₄₁ | L_{b4} |
| 377 | Lₐ₇₄₂ | L_{b4} | 378 | Lₐ₇₄₃ | L_{b4} |
| 379 | Lₐ₇₅₅ | L_{b4} | 380 | Lₐ₇₅₇ | L_{b4} |
| 381 | Lₐ₇₆₆ | L_{b4} | 382 | Lₐ₇₆₈ | L_{b4} |
| 383 | Lₐ₇₇₁ | L_{b4} | 384 | Lₐ₇₇₆ | L_{b4} |
| 385 | Lₐ₇₉₅ | L_{b4} | 386 | Lₐ₈₀₂ | L_{b4} |
| 387 | Lₐ₈₀₉ | L_{b4} | 388 | Lₐ₈₁₆ | L_{b4} |
| 389 | Lₐ₈₂₃ | L_{b4} | 390 | Lₐ₈₅₁ | L_{b4} |
| 391 | Lₐ₂ | L_{b8} | 392 | Lₐ₃ | L_{b8} |
| 393 | Lₐ₆ | L_{b8} | 394 | Lₐ₈ | L_{b8} |
| 395 | Lₐ₉ | L_{b8} | 396 | Lₐ₁₀ | L_{b8} |
| 397 | Lₐ₁₁ | L_{b8} | 398 | Lₐ₁₂ | L_{b8} |
| 399 | Lₐ₁₃ | L_{b8} | 400 | Lₐ₁₄ | L_{b8} |
| 401 | Lₐ₁₅ | L_{b8} | 402 | Lₐ₁₆ | L_{b8} |
| 403 | Lₐ₁₇ | L_{b8} | 404 | Lₐ₁₈ | L_{b8} |
| 405 | Lₐ₁₉ | L_{b8} | 406 | Lₐ₂₀ | L_{b8} |
| 407 | Lₐ₂₁ | L_{b8} | 408 | Lₐ₂₃ | L_{b8} |
| 409 | Lₐ₂₅ | L_{b8} | 410 | Lₐ₂₇ | L_{b8} |
| 411 | Lₐ₂₉ | L_{b8} | 412 | Lₐ₃₁ | L_{b8} |
| 413 | Lₐ₃₃ | L_{b8} | 414 | Lₐ₃₅ | L_{b8} |
| 415 | Lₐ₃₉ | L_{b8} | 416 | Lₐ₄₁ | L_{b8} |
| 417 | Lₐ₄₆ | L_{b8} | 418 | Lₐ₅₀ | L_{b8} |
| 419 | Lₐ₅₃ | L_{b8} | 420 | Lₐ₅₉ | L_{b8} |
| 421 | Lₐ₆₀ | L_{b8} | 422 | Lₐ₈₄ | L_{b8} |
| 423 | Lₐ₈₈ | L_{b8} | 424 | Lₐ₉₁ | L_{b8} |
| 425 | Lₐ₁₁₅ | L_{b8} | 426 | Lₐ₁₂₃ | L_{b8} |
| 427 | Lₐ₁₂₄ | L_{b8} | 428 | Lₐ₁₂₇ | L_{b8} |
| 429 | Lₐ₁₃₄ | L_{b8} | 430 | Lₐ₁₃₆ | L_{b8} |
| 431 | Lₐ₁₄₆ | L_{b8} | 432 | Lₐ₁₆₆ | L_{b8} |
| 433 | Lₐ₁₇₂ | L_{b8} | 434 | Lₐ₂₀₃ | L_{b8} |
| 435 | Lₐ₂₀₄ | L_{b8} | 436 | Lₐ₂₀₇ | L_{b8} |
| 437 | Lₐ₂₄₁ | L_{b8} | 438 | Lₐ₂₄₂ | L_{b8} |
| 439 | Lₐ₂₄₅ | L_{b8} | 440 | Lₐ₂₄₈ | L_{b8} |
| 441 | Lₐ₂₅₀ | L_{b8} | 442 | Lₐ₂₅₄ | L_{b8} |
| 443 | Lₐ₂₅₅ | L_{b8} | 444 | Lₐ₂₅₆ | L_{b8} |
| 445 | Lₐ₂₇₆ | L_{b8} | 446 | Lₐ₂₇₇ | L_{b8} |
| 447 | Lₐ₂₉₄ | L_{b8} | 448 | Lₐ₂₉₅ | L_{b8} |
| 449 | Lₐ₂₉₈ | L_{b8} | 450 | Lₐ₃₀₁ | L_{b8} |
| 451 | Lₐ₃₀₂ | L_{b8} | 452 | Lₐ₃₀₅ | L_{b8} |
| 453 | Lₐ₃₀₇ | L_{b8} | 454 | Lₐ₃₀₈ | L_{b8} |
| 455 | Lₐ₃₃₁ | L_{b8} | 456 | Lₐ₃₃₂ | L_{b8} |
| 457 | Lₐ₃₃₃ | L_{b8} | 458 | Lₐ₃₄₃ | L_{b8} |
| 459 | Lₐ₃₄₄ | L_{b8} | 460 | Lₐ₃₄₅ | L_{b8} |
| 461 | Lₐ₃₄₆ | L_{b8} | 462 | Lₐ₃₄₈ | L_{b8} |
| 463 | Lₐ₃₅₀ | L_{b8} | 464 | Lₐ₃₅₄ | L_{b8} |
| 465 | Lₐ₃₅₅ | L_{b8} | 466 | Lₐ₃₅₆ | L_{b8} |
| 467 | Lₐ₃₅₇ | L_{b8} | 468 | Lₐ₃₆₃ | L_{b8} |
| 469 | Lₐ₃₆₄ | L_{b8} | 470 | Lₐ₃₇₅ | L_{b8} |
| 471 | Lₐ₃₈₅ | L_{b8} | 472 | Lₐ₃₈₆ | L_{b8} |
| 473 | Lₐ₃₉₀ | L_{b8} | 474 | Lₐ₃₉₁ | L_{b8} |
| 475 | Lₐ₃₉₆ | L_{b8} | 476 | Lₐ₃₉₇ | L_{b8} |
| 477 | Lₐ₄₀₃ | L_{b8} | 478 | Lₐ₄₄₅ | L_{b8} |
| 479 | Lₐ₄₄₈ | L_{b8} | 480 | Lₐ₄₅₆ | L_{b8} |
| 481 | Lₐ₄₉₇ | L_{b8} | 482 | Lₐ₅₄₁ | L_{b8} |
| 483 | Lₐ₅₄₉ | L_{b8} | 484 | Lₐ₅₉₃ | L_{b8} |
| 485 | Lₐ₅₆₀ | L_{b8} | 486 | Lₐ₅₆₂ | L_{b8} |
| 487 | Lₐ₅₆₃ | L_{b8} | 488 | Lₐ₅₆₇ | L_{b8} |
| 489 | Lₐ₅₈₁ | L_{b8} | 490 | Lₐ₅₈₈ | L_{b8} |
| 491 | Lₐ₅₉₀ | L_{b8} | 492 | Lₐ₅₉₁ | L_{b8} |
| 493 | Lₐ₅₉₅ | L_{b8} | 494 | Lₐ₅₉₆ | L_{b8} |
| 495 | Lₐ₅₉₇ | L_{b8} | 496 | Lₐ₆₀₃ | L_{b8} |
| 497 | Lₐ₆₁₆ | L_{b8} | 498 | Lₐ₆₁₇ | L_{b8} |
| 499 | Lₐ₆₁₈ | L_{b8} | 500 | Lₐ₆₁₉ | L_{b8} |
| 501 | Lₐ₆₂₀ | L_{b8} | 502 | Lₐ₆₄₄ | L_{b8} |
| 503 | Lₐ₆₄₅ | L_{b8} | 504 | Lₐ₆₄₇ | L_{b8} |
| 505 | Lₐ₇₄₀ | L_{b8} | 506 | Lₐ₇₄₁ | L_{b8} |
| 507 | Lₐ₇₄₂ | L_{b8} | 508 | Lₐ₇₄₃ | L_{b8} |
| 509 | Lₐ₇₅₅ | L_{b8} | 510 | Lₐ₇₅₇ | L_{b8} |
| 511 | Lₐ₇₆₆ | L_{b8} | 512 | Lₐ₇₆₈ | L_{b8} |
| 513 | Lₐ₇₇₁ | L_{b8} | 514 | Lₐ₇₇₆ | L_{b8} |
| 515 | Lₐ₇₉₅ | L_{b8} | 516 | Lₐ₈₀₂ | L_{b8} |
| 517 | Lₐ₈₀₉ | L_{b8} | 518 | Lₐ₈₁₆ | L_{b8} |
| 519 | Lₐ₈₂₃ | L_{b8} | 520 | Lₐ₈₅₁ | L_{b8} |
| 521 | Lₐ₂ | L_{b30} | 522 | Lₐ₃ | L_{b30} |
| 523 | Lₐ₆ | L_{b30} | 524 | Lₐ₈ | L_{b30} |
| 525 | Lₐ₉ | L_{b30} | 526 | Lₐ₁₀ | L_{b30} |
| 527 | Lₐ₁₁ | L_{b30} | 528 | Lₐ₁₂ | L_{b30} |
| 529 | Lₐ₁₃ | L_{b30} | 530 | Lₐ₁₄ | L_{b30} |
| 531 | Lₐ₁₅ | L_{b30} | 532 | Lₐ₁₆ | L_{b30} |
| 533 | Lₐ₁₇ | L_{b30} | 534 | Lₐ₁₈ | L_{b30} |
| 535 | Lₐ₁₉ | L_{b30} | 536 | Lₐ₂₀ | L_{b30} |
| 537 | Lₐ₂₁ | L_{b30} | 538 | Lₐ₂₃ | L_{b30} |
| 539 | Lₐ₂₅ | L_{b30} | 540 | Lₐ₂₇ | L_{b30} |
| 541 | Lₐ₂₉ | L_{b30} | 542 | Lₐ₃₁ | L_{b30} |
| 543 | Lₐ₃₃ | L_{b30} | 544 | Lₐ₃₅ | L_{b30} |
| 545 | Lₐ₃₉ | L_{b30} | 546 | Lₐ₄₁ | L_{b30} |
| 547 | Lₐ₄₆ | L_{b30} | 548 | Lₐ₅₀ | L_{b30} |
| 549 | Lₐ₅₃ | L_{b30} | 550 | Lₐ₅₉ | L_{b30} |
| 551 | Lₐ₆₀ | L_{b30} | 552 | Lₐ₈₄ | L_{b30} |
| 553 | Lₐ₈₈ | L_{b30} | 554 | Lₐ₉₁ | L_{b30} |
| 555 | Lₐ₁₁₅ | L_{b30} | 556 | Lₐ₁₂₃ | L_{b30} |
| 557 | Lₐ₁₂₄ | L_{b30} | 558 | Lₐ₁₂₇ | L_{b30} |
| 559 | Lₐ₁₃₄ | L_{b30} | 560 | Lₐ₁₃₆ | L_{b30} |
| 561 | Lₐ₁₄₆ | L_{b30} | 562 | Lₐ₁₆₆ | L_{b30} |
| 563 | Lₐ₁₇₂ | L_{b30} | 564 | Lₐ₂₀₃ | L_{b30} |
| 565 | Lₐ₂₀₄ | L_{b30} | 566 | Lₐ₂₀₇ | L_{b30} |
| 567 | Lₐ₂₄₁ | L_{b30} | 568 | Lₐ₂₄₂ | L_{b30} |
| 569 | Lₐ₂₄₅ | L_{b30} | 570 | Lₐ₂₄₈ | L_{b30} |
| 571 | Lₐ₂₅₀ | L_{b30} | 572 | Lₐ₂₅₄ | L_{b30} |
| 573 | Lₐ₂₅₅ | L_{b30} | 574 | Lₐ₂₅₆ | L_{b30} |
| 575 | Lₐ₂₇₆ | L_{b30} | 576 | Lₐ₂₇₇ | L_{b30} |
| 577 | Lₐ₂₉₄ | L_{b30} | 578 | Lₐ₂₉₅ | L_{b30} |
| 579 | Lₐ₂₉₈ | L_{b30} | 580 | Lₐ₃₀₁ | L_{b30} |
| 581 | Lₐ₃₀₂ | L_{b30} | 582 | Lₐ₃₀₅ | L_{b30} |
| 583 | Lₐ₃₀₇ | L_{b30} | 584 | Lₐ₃₀₈ | L_{b30} |
| 585 | Lₐ₃₃₁ | L_{b30} | 586 | Lₐ₃₃₂ | L_{b30} |
| 587 | Lₐ₃₃₃ | L_{b30} | 588 | Lₐ₃₄₃ | L_{b30} |
| 589 | Lₐ₃₄₄ | L_{b30} | 590 | Lₐ₃₄₅ | L_{b30} |
| 591 | Lₐ₃₄₆ | L_{b30} | 592 | Lₐ₃₄₈ | L_{b30} |
| 593 | Lₐ₃₅₀ | L_{b30} | 594 | Lₐ₃₅₄ | L_{b30} |
| 595 | Lₐ₃₅₅ | L_{b30} | 596 | Lₐ₃₅₆ | L_{b30} |
| 597 | Lₐ₃₅₇ | L_{b30} | 598 | Lₐ₃₆₃ | L_{b30} |
| 599 | Lₐ₃₆₄ | L_{b30} | 600 | Lₐ₃₇₅ | L_{b30} |
| 601 | Lₐ₃₈₅ | L_{b30} | 602 | Lₐ₃₈₆ | L_{b30} |
| 603 | Lₐ₃₉₀ | L_{b30} | 604 | Lₐ₃₉₁ | L_{b30} |
| 605 | Lₐ₃₉₆ | L_{b30} | 606 | Lₐ₃₉₇ | L_{b30} |
| 607 | Lₐ₄₀₃ | L_{b30} | 608 | Lₐ₄₄₅ | L_{b30} |
| 609 | Lₐ₄₄₈ | L_{b30} | 610 | Lₐ₄₅₆ | L_{b30} |
| 611 | Lₐ₄₉₇ | L_{b30} | 612 | Lₐ₅₄₁ | L_{b30} |
| 613 | Lₐ₅₄₉ | L_{b30} | 614 | Lₐ₅₉₃ | L_{b30} |
| 615 | Lₐ₅₆₀ | L_{b30} | 616 | Lₐ₅₆₂ | L_{b30} |
| 617 | Lₐ₅₆₃ | L_{b30} | 618 | Lₐ₅₆₇ | L_{b30} |
| 619 | Lₐ₅₈₁ | L_{b30} | 620 | Lₐ₅₈₈ | L_{b30} |
| 621 | Lₐ₅₉₀ | L_{b30} | 622 | Lₐ₅₉₁ | L_{b30} |
| 623 | Lₐ₅₉₅ | L_{b30} | 624 | Lₐ₅₉₆ | L_{b30} |
| 625 | Lₐ₅₉₇ | L_{b30} | 626 | Lₐ₆₀₃ | L_{b30} |
| 627 | Lₐ₆₁₆ | L_{b30} | 628 | Lₐ₆₁₇ | L_{b30} |
| 629 | Lₐ₆₁₈ | L_{b30} | 630 | Lₐ₆₁₉ | L_{b30} |
| 631 | Lₐ₆₂₀ | L_{b30} | 632 | Lₐ₆₄₄ | L_{b30} |
| 633 | Lₐ₆₄₅ | L_{b30} | 634 | Lₐ₆₄₇ | L_{b30} |
| 635 | Lₐ₇₄₀ | L_{b30} | 636 | Lₐ₇₄₁ | L_{b30} |
| 637 | Lₐ₇₄₂ | L_{b30} | 638 | Lₐ₇₄₃ | L_{b30} |
| 639 | Lₐ₇₅₅ | L_{b30} | 640 | Lₐ₇₅₇ | L_{b30} |
| 641 | Lₐ₇₆₆ | L_{b30} | 642 | Lₐ₇₆₈ | L_{b30} |
| 643 | Lₐ₇₇₁ | L_{b30} | 644 | Lₐ₇₇₆ | L_{b30} |
| 645 | Lₐ₇₉₅ | L_{b30} | 646 | Lₐ₈₀₂ | L_{b30} |
| 647 | Lₐ₈₀₉ | L_{b30} | 648 | Lₐ₈₁₆ | L_{b30} |
| 649 | Lₐ₈₂₃ | L_{b30} | 650 | Lₐ₈₅₁ | L_{b30} |

wherein metal complex 651 to metal complex 706 have the structure of Ir(Lₐ)₂L_{c}, wherein the two Lₐ are the same, and Lₐ and L_{c} respectively correspond to structures listed in the following table:

| Metal Complex | Lₐ | L_{c} | Metal Complex | Lₐ | L_{c} |
|---|---|---|---|---|---|
| 651 | Lₐ₂₇₈ | L_{c1} | 652 | Lₐ₂₇₉ | L_{c1} |
| 653 | Lₐ₂₈₀ | L_{c1} | 654 | Lₐ₂₈₁ | L_{c1} |
| 655 | Lₐ₂₈₂ | L_{c1} | 656 | Lₐ₂₈₃ | L_{c1} |
| 657 | Lₐ₂₈₄ | L_{c1} | 658 | Lₐ₂₈₅ | L_{c1} |
| 659 | Lₐ₂₈₆ | L_{c1} | 660 | Lₐ₂₈₇ | L_{c1} |
| 661 | Lₐ₂₈₈ | L_{c1} | 662 | Lₐ₂₈₉ | L_{c1} |
| 663 | Lₐ₂₉₀ | L_{c1} | 664 | Lₐ₂₉₁ | L_{c1} |
| 665 | Lₐ₂₉₂ | L_{c1} | 666 | Lₐ₃₃₅ | L_{c1} |
| 667 | Lₐ₃₃₆ | L_{c1} | 668 | Lₐ₃₃₇ | L_{c1} |
| 669 | Lₐ₃₃₈ | L_{c1} | 670 | Lₐ₃₃₉ | L_{c1} |
| 671 | Lₐ₃₄₀ | L_{c1} | 672 | Lₐ₃₄₁ | L_{c1} |
| 673 | Lₐ₄₃₇ | L_{c1} | 674 | Lₐ₄₃₈ | L_{c1} |
| 675 | Lₐ₄₃₉ | L_{c1} | 676 | Lₐ₄₄₀ | L_{c1} |
| 677 | Lₐ₄₄₁ | L_{c1} | 678 | Lₐ₄₄₂ | L_{c1} |
| 679 | Lₐ₂₇₈ | L_{c31} | 680 | Lₐ₂₇₉ | L_{c31} |
| 681 | Lₐ₂₈₀ | L_{c31} | 682 | Lₐ₂₈₁ | L_{c31} |
| 683 | Lₐ₂₈₂ | L_{c31} | 684 | Lₐ₂₈₃ | L_{c31} |
| 685 | Lₐ₂₈₄ | L_{c31} | 686 | Lₐ₂₈₅ | L_{c31} |
| 687 | Lₐ₂₈₆ | L_{c31} | 688 | Lₐ₂₈₇ | L_{c31} |
| 689 | Lₐ₂₈₈ | L_{c31} | 690 | Lₐ₂₈₉ | L_{c31} |
| 691 | Lₐ₂₉₀ | L_{c31} | 692 | Lₐ₂₉₁ | L_{c31} |
| 693 | Lₐ₂₉₂ | L_{c31} | 694 | Lₐ₃₃₅ | L_{c31} |
| 695 | Lₐ₃₃₆ | L_{c31} | 696 | Lₐ₃₃₇ | L_{c31} |
| 697 | Lₐ₃₃₈ | L_{c31} | 698 | Lₐ₃₃₉ | L_{c31} |
| 699 | Lₐ₃₄₀ | L_{c31} | 700 | Lₐ₃₄₁ | L_{c31} |
| 701 | Lₐ₄₃₇ | L_{c31} | 702 | Lₐ₄₃₈ | L_{c31} |
| 703 | Lₐ₄₃₉ | L_{c31} | 704 | Lₐ₄₄₀ | L_{c31} |
| 705 | Lₐ₄₄₁ | L_{c31} | 706 | Lₐ₄₄₂ | L_{c31} |

23. An electroluminescent device, comprising:
an anode,
a cathode, and
an organic layer disposed between the anode and the cathode, wherein the organic layer comprises the metal complex of claim 1.

24. The electroluminescent device of claim 23, wherein the organic layer is a light-emitting layer, and the metal complex is a light-emitting material;
preferably, the electroluminescent device emits green or white light.

25. The electroluminescent device of claim 24, wherein the light-emitting layer further comprises at least one host compound;
preferably, the light-emitting layer further comprises at least two host compounds;
more preferably, at least one of the host compounds comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

26. A compound formulation, comprising the metal complex of claim 1.
